(19) United States
(12) Patent Application Publication
(10) Pub. No.: US 2011/0156016 A1
(43) Pub. Date: Jun. 30, 2011

(54) ORGANIC LIGHT-EMITTING MEDIUM AND ORGANIC EL ELEMENT

(76) Inventors: Masahiro Kawamura, Chiba (JP); Masakazu Funahashi, Chiba (JP); Mitsunori Ito, Chiba (JP); Yumiko Mizuki, Chiba (JP)

(21) Appl. No.: 13/056,294

(22) PCT Filed: Jul. 27, 2009
(86) PCT No.: PCT/JP2009/063349

§ 371 Date: Jan. 27, 2011

(30) Foreign Application Priority Data
Jul. 28, 2008 (JP) 2008-193978

(51) Int. Cl. H01L 51/54; C09K 11/06

(52) U.S. Cl. 257/40; 252/301.16; 257/E51.028

(57) ABSTRACT

An organic light-emitting medium including a diaminopyrene derivative represented by the following formula (1) and an anthracene derivative represented by the following formula (2);

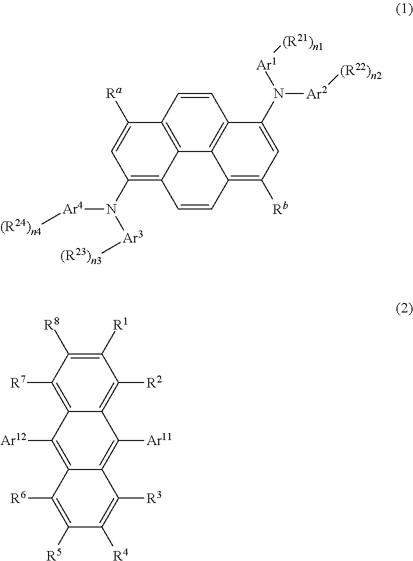

### TECHNICAL FIELD

The invention relates to an organic light-emitting medium and an organic EL device using the same.

### BACKGROUND ART

An organic EL device (organic electroluminescence device) utilizing light emission of an organic compound has heretofore been known. An organic EL device has a plurality of organic thin films which are stacked one on another between an anode and a cathode. In this configuration, if a voltage is applied between an anode and a cathode, holes and electrons are injected to the organic thin films from the anode and the cathode, respectively. Due to the holes and electrons thus injected, molecules in the excited state are generated in an emitting layer of the organic thin films. Energy generated when the molecules in the excited state are returned to the ground state is emitted as light.

As examples of the materials used in an emitting layer, Patent Document 1 discloses combination of an anthracene host and arylamine. In Patent Documents 2 to 4, combination of an anthracene host with a specific structure and a diaminopyrene dopant is disclosed. Further, Patent Documents 5 and 6 each disclose an anthracene-based host material.

However, any of the above-mentioned materials has problems of difficulty in obtaining a high luminous efficiency and a short lifetime.

### RELATED ART DOCUMENTS

### Patent Document

Patent Document 1: WO2004/018588

Patent Document 2: WO2004/018587

Patent Document 3: JP-A-2004-204238

Patent Document 4: WO2005/108348

Patent Document 5: WO2005/054162

Patent Document 6: WO2005/061656

### SUMMARY OF THE INVENTION

An object of the invention is to provide an organic EL device which contains combination of a specific host material and a specific dopant material which are capable of obtaining an organic EL device with a high luminous efficiency and a long life.

As a result of intensive studies made to solve the above-mentioned subject, the inventors have found that the above-mentioned subject can be solved by the following invention.

As a result of intensive studies made by the inventors in order to solve the above-mentioned problem, the inventors found that the above-mentioned problems can be found by the following invention:

1. An organic light-emitting medium comprising a diaminopyrene derivative represented by the following formula (1) and an anthracene derivative represented by the following formula (2):

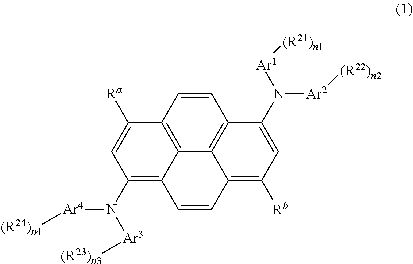

wherein Ar¹ to Ar⁴ are independently a substituted or unsubstituted aryl group having 5 to 50 atom that form a ring (hereinafter referred to as the “ring carbon atoms”) or a substituted or unsubstituted heterocyclic group having 5 to 50 ring carbon atoms,

R²¹ to R²⁴ are independently a hydrogen atom, a substituted or unsubstituted alkyl group having 1 to 50 carbon atoms, a substituted or unsubstituted aryl group having 5 to 50 ring carbon atoms, a substituted or unsubstituted aralkyl group having 6 to 50 ring carbon atoms, a substituted or unsubstituted cycloalkyl group having 3 to 50 ring carbon atoms, a substituted or unsubstituted alkoxy group having 1 to 50 carbon atoms, a substituted or unsubstituted aryloxy group having 5 to 50 carbon atoms, a substituted or unsubstituted arylamino group having 5 to 50 ring carbon atoms, a substituted or unsubstituted alkylamino group having 1 to 20 carbon atoms, a substituted or unsubstituted heterocyclic group having 5 to 50 ring carbon atoms, a substituted or unsubstituted silyl group, a cyano group or a halogen atom,

n1 to n4 are independently an integer of 0 to 5,

when n1 to n4 each are 2 or more, R²¹s to R²⁴s each may be the same or different and may combine with each other to form a saturated or unsaturated ring, and

R^{a} and R^{b} are independently a substituted or unsubstituted aryl group having 5 to 50 ring carbon atoms or a substituted or unsubstituted heterocyclic group having 5 to 50 ring carbon atoms;

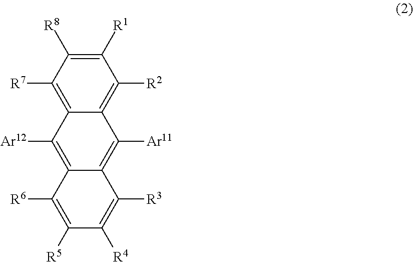

wherein Ar¹¹ and Ar¹² are independently a substituted or unsubstituted aryl group having 6 to 50 ring carbon atoms or a heterocyclic group having 5 to 50 atoms that form a ring (hereinafter referred to as the “ring atoms”),

any one of R¹ to R⁸ is a substituted or unsubstituted aryl group having 6 to 50 ring carbon atoms or a substituted or unsubstituted heterocyclic group having 5 to 50 ring carbon atoms,

R¹ to R⁸ that are not a substituted or unsubstituted aryl group having 6 to 50 ring carbon atoms and a substituted or unsubstituted heterocyclic group having 5 to 50 ring atoms are independently a group selected from a hydrogen atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted silyl group, a carboxy group, a halogen atom, a cyano group, a nitro group and a hydroxyl group.

2. The organic light-emitting medium according to 1, wherein any one of R¹, R², R⁷ and R⁸ in the formula (2) is a substituted or unsubstituted aryl group having 6 to 50 ring carbon atoms or a substituted or unsubstituted heterocyclic group having 5 to 50 ring atoms.
3. The organic fight-emitting medium according to 2, wherein one of R¹ and R⁸ in the formula (2) is a substituted or unsubstituted aryl group having 6 to 50 ring carbon atoms or a substituted or unsubstituted heterocyclic group having 5 to 50 ring atoms, and the other is a hydrogen atom.
4. The organic light-emitting medium according to 2, wherein any one of R¹, R², R⁷ and R⁸ in the formula (2) is a substituted or unsubstituted aryl group having 6 to 50 ring carbon atoms.
5. The organic light-emitting medium according to 4, wherein one of R¹ and R⁸ in the formula (2) is a substituted or.
6. The organic light-emitting medium according to 5, wherein the substituted or unsubstituted aryl group having 6 to 50 ring carbon atoms is a substituted or unsubstituted phenyl group, naphthyl group, fluorenyl group or phenanthryl group.
7. The organic light-emitting medium according to any of 1 to 6, wherein Ar¹¹ in the formula (2) is a substituted or unsubstituted heterocyclic group having 5 to 50 ring atoms.
8. The organic light-emitting medium according to any of 1 to 6, wherein Ar¹¹ and Ar¹² in the formula (2) are independently a substituted or unsubstituted fused aryl group having 10 to 50 ring carbon atoms.
9. The organic light-emitting medium according to 8, wherein Ar¹¹ and Ar¹² in the formula (2) are the same groups.
10. The organic light-emitting medium according to 9, wherein Ar¹¹ and Ar¹² in the formula (2) are a substituted or unsubstituted 9-phenanthrenyl group.
11. The organic light-emitting medium according to 9, wherein Ar¹¹ and Ar¹² in the formula (2) are a substituted or unsubstituted 2-naphthyl group.
12. The organic light-emitting medium according to 9, wherein Ar¹¹ and Ar¹² in the formula (2) are a substituted or unsubstituted 1-naphthyl group.
13. The organic light-emitting medium according to 8, wherein Ar¹¹ and Ar¹² in the formula (2) are different groups.
14. The organic light-emitting medium according to any of 1 to 9 and 13, wherein Ar¹¹ and Ar¹² in the formula (2) are independently a substituted or unsubstituted phenyl group.
15. The organic light-emitting medium according to claim 14, wherein Ar¹¹ and Ar¹² in the formula (2) are independently a substituted or unsubstituted aryl group having 6 to 30 ring carbon atoms or a phenyl group substituted with a substituted or unsubstituted heterocyclic group having 5 to 30 ring atoms.
16. The organic light-emitting medium according to 13, wherein Ar¹¹ and Ar¹² in the formula (2) are independently a substituted or unsubstituted 9-phenanthrenyl group, a substituted or unsubstituted 1-naphthyl group, a substituted or unsubstituted 2-naphthyl group, a substituted or unsubstituted fluoranthenyl group, or a substituted or unsubstituted pyrenyl group.
17. The organic light-emitting medium according to 13, wherein one of Ar¹¹ and Ar¹² in the formula (2) is a substituted or unsubstituted phenyl group, and the other is a substituted or unsubstituted fused aryl group having 10 to 50 ring carbon atoms.
18. The organic light-emitting medium according to 17, wherein the substituted or unsubstituted fused aryl group having 10 to 50 ring carbon atoms is a substituted or unsubstituted 1-naphthyl group.
19. The organic light-emitting medium according to 17, wherein the substituted or unsubstituted fused aryl group having 10 to 50 ring carbon atoms is a substituted or unsubstituted 2-naphthyl group.
20. The organic light-emitting medium according to 17, wherein the substituted or unsubstituted fused aryl group having 10 to 50 ring carbon atoms is a substituted or unsubstituted fluoranthenyl group.
21. The organic light-emitting medium according to 17, wherein the substituted or unsubstituted fused aryl group having 10 to 50 ring carbon atoms is a substituted or unsubstituted pyrenyl group.
22. The organic light-emitting medium according to any of 1 to 21, wherein R^{a} and R^{b} in the formula (1) are independently is a substituted or unsubstituted phenyl group, a substituted or unsubstituted naphthyl group, or a substituted or unsubstituted fluorenyl group.
23. The organic light-emitting medium according to any of 1 to 22, wherein Ar¹ to Ar⁴ in the formula (1) are independently a group selected from a substituted or unsubstituted phenyl group, a substituted or unsubstituted naphthyl group, a substituted or unsubstituted fluorenyl group and a substituted or unsubstituted dibenzofuranyl group.
24. The organic light-emitting medium according to 23, wherein at least one of Ar¹ to Ar⁴ in the formula (1) is a substituted or unsubstituted fluorenyl group.
25. The organic light-emitting medium according to any of 1 to 24, wherein R²¹ to R²⁴ in the formula (1) are independently a substituted or unsubstituted phenyl group, a substituted or unsubstituted methyl group, a substituted or unsubstituted ethyl group, a substituted or unsubstituted isopropyl group, a substituted or unsubstituted t-butyl group, a substituted or unsubstituted cyclopropyl group, a substituted or unsubstituted cyclopentyl group, a substituted or unsubstituted cyclohexyl group, a substituted or unsubstituted trimethylsilyl group, or a cyano group.
26. An organic electroluminescence device comprising:

an anode, a cathode, and

one or more organic thin film layers between the anode and the cathode, wherein at least one of the organic thin film layers comprises the organic light-emitting medium according to any of 1 to 25.

27. The organic electroluminescence device according to 26, wherein the organic thin film layer comprising the organic light-emitting medium is an emitting layer.

According to the invention, it is possible to provide an organic EL device capable of obtaining a high luminous efficiency and a long life, and an organic light-emitting medium which can be used in organic thin film layers of the organic EL device.

### BEST MODE FOR CARRYING OUT THE INVENTION

### Organic Light-Emitting Medium

The organic light-emitting medium of the invention contains a specific diaminopyrene derivative and a specific anthracene derivative. The organic light-emitting medium contributes to light emission as a constituent of organic thin film layers of the organic EL device, and, for example, presents in the layer as a deposited substance. By using the organic light-emitting medium of the invention in an organic EL device, a high luminous efficiency can be obtained, which contributes to a longer life. Hereinafter, the diaminopyrene derivative and the anthracene derivative of the present invention will be explained.

### (Diaminopyrene Derivative)

The diaminopyrene derivative of the invention is represented by the following formula (1):

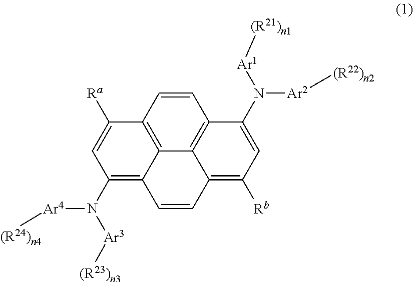

In the formula (1), Ar¹ to Ar⁴ are independently a substituted or unsubstituted aryl group having 5 to 50 ring carbon atoms or a substituted or unsubstituted heterocyclic group having 5 to 50 ring carbon atoms,

R²¹ to R²⁴ are independently a hydrogen atom, a substituted or unsubstituted alkyl group having 1 to 50 carbon atoms, a substituted or unsubstituted aryl group having 5 to 50 ring carbon atoms, a substituted or unsubstituted aralkyl group having 6 to 50 ring carbon atoms, a substituted or unsubstituted cycloalkyl group having 3 to 50 ring carbon atoms, a substituted or unsubstituted alkoxy group having 1 to 50 carbon atoms, a substituted or unsubstituted aryloxy group having 5 to 50 carbon atoms, a substituted or unsubstituted arylamino group having 5 to 50 ring carbon atoms, a substituted or unsubstituted alkylamino group having 1 to 20 carbon atoms, a substituted or unsubstituted heterocyclic group having 5 to 50 ring carbon atoms, a substituted or unsubstituted silyl group, a cyano group or a halogen atom,

n1 to n4 are independently an integer of 0 to 5,

when n1 to n4 each are 2 or more, R²¹s to R²⁴s each may be the same or different and may combine with each other to form a saturated or unsaturated ring, and

R^{a} and R^{b} are independently a substituted or unsubstituted aryl group having 5 to 50 ring carbon atoms or a substituted or unsubstituted heterocyclic group having 5 to 50 ring carbon atoms.

Preferably, the diaminopyrene derivative is represented by the following formula (1′):

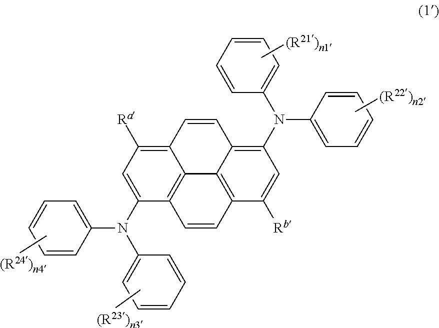

In the formula (1′), R^{21′} to R^{24′} are independently a hydrogen atom, a substituted or unsubstituted aryl group having 6 to 50 ring carbon atoms, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms or a substituted or unsubstituted silyl group having 3 to 20 carbon atoms, and when one or two sets of adjacent alkyl groups present on the same benzene ring, the adjacent alkyl groups may be bonded to each other to form a substituted or unsubstituted divalent bonding group;

n1′ to n4′ are independently an integer of 1 to 5; and

Ra′ and Rb′ are independently an aryl group having 6 to 50 ring carbon atoms.

In the invention, the hydrogen atom includes a deuterium atom.

The “ring carbon atoms” mean carbon atoms which constitute a saturated ring, an unsaturated ring or an aromatic ring. The “ring atoms” mean carbon atoms and hetero atoms which constitute a hetero ring (including a saturated ring, an unsaturated ring and an aromatic ring). For example, in the case of a phenyl group substituted by a naphthyl group, it means a substituted aryl group having 16 ring carbon atoms, or in the case of a phenyl group substituted by a methyl group, it means a substituted aryl group having 6 ring carbon atoms.

In the definition of each formula of the invention, as the substituent for the “substituted or unsubstituted”, the following alkyl group, aryl group, cycloalkyl group, alkoxy group, heterocyclic group, aralykyl group, aryloxy group, arylthio group, alkoxycarbonyl group, halogen atom, hydroxyl group, nitro group, cyano group, carboxy group or the like can be given. Preferably, the substituent is an alkyl group, an aryl group, a cycloalkyl group or a heterocyclic group.

In formula (1), Ar¹ to Ar⁴ are independently a substituted or unsubstituted aryl group having 5 to 50 ring carbon atoms or a substituted or unsubstituted heterocyclic group having 5 to 50 ring carbon atoms. n1 to n4 are preferably independently an integer of 1 to 5, more preferably an integer of 1 to 3.

Specific examples of the substituted or unsubstituted aryl group represented by Ar¹ to Ar⁴ include a phenyl group, a naphthyl group, an anthryl group, a naphthacenyl group, a pyrenyl group, a fluoranthenyl group, a chrysenyl group, a fluorenyl group, a perylenyl group, a biphenyl group, a terphenyl group, a tolyl group, an ethylphenyl group and a p-t-butylpheneyl group. A phenyl group, a naphthyl group and a fluorenyl group are preferable.

As the substituted or unsubstituted heterocyclic group represented by Ar¹ to Ar⁴, for example, residues such as imidazole, benzoimidazole, pyrrole, furan, thiophene, benzothiophene, oxadiazoline, indoline, carbazole, pyridine, quinoline, isoquinoline, benzoquinone, pyralozine, imidazolidine, piperidine, dibenzofuran, benzofuran and dibenzothiphene can be given. Of these, benzoimidazole, thiophene, carbazole and dibenzofuran are preferable.

In the formula (1), R²¹ to R²⁴ are independently a hydrogen atom, a substituted or unsubstituted alkyl group having 1 to 50 carbon atoms (preferably 1 to 20 carbon atoms, particularly preferably 1 to 4 carbon atoms), a substituted or unsubstituted aryl group having 5 to 50 ring carbon atoms (preferably 5 to 20 ring carbon atoms, particularly preferably 6 to 10 ring carbon atoms), a substituted or unsubstituted aralkyl group having 6 to 50 ring carbon atoms (preferably 6 to 20 ring carbon atoms), a substituted or unsubstituted cycloalkyl group having 3 to 50 ring carbon atoms (preferably 3 to 12 ring carbon atoms), a substituted or unsubstituted alkoxy group having 1 to 50 carbon atoms (preferably 1 to 6 carbon atoms), a substituted or unsubstituted aryloxy group having 5 to 50 ring carbon atoms (preferably 5 to 18 ring carbon atoms), a substituted or unsubstituted arylamino group having 5 to 50 ring carbon atoms (preferably 5 to 18 ring carbon atoms), a substituted or unsubstituted alkylamino group having 1 to 20 carbon atoms (preferably 1 to 6 carbon atoms), a substituted or unsubstituted heterocyclic group having 5 to 50 ring carbon atoms (preferably 5 to 20 ring carbon atoms), a substituted or unsubstituted silyl group, a cyano group or a halogen atom.

As the substituted or unsubstituted alkyl group represented by R²¹ to R²⁴, for example, a methyl group, an ethyl group, a propyl group, an isopropyl group, a butyl group, a sec-butyl group, a tert-butyl group, a pentyl group, a hexyl group, a heptyl group, an octyl group, a stearyl group, a 2-phenylisopropyl group, a trichloromethyl group, a trifluoromethyl group, a benzyl group, an α-phenoxybenzyl group, an α,α-dimethylbenzyl group, an α,α-methylphenylbenzyl group, an α,α-ditrifluoromethylbenzyl group, a triphenylmethyl group, an α-benzyloxybenzyl group or the like can be given.

In respect of stability, of these, it is preferred that the alkyl group be an alkyl group having 1 to 4 carbon atoms. For example, it is a methyl group, an ethyl group, a propyl group, an isopropyl group, a butyl group, a sec-butyl group and a tert-butyl group.

The examples for the substituted or unsubstituted aryl group represented by R²¹ to R²⁴ are the same as those for Ar¹ to Ar⁴ mentioned above.

As the substituted or unsubstituted aralkyl group represented by R²¹ to R²⁴, a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, a 1-pyrrolylmethyl group, a 2-(1-pyrrolyl)ethyl group, a methylbenzyl group, a cyanobenzyl group or the like can be given, for example.

As the substituted or unsubstituted cycloalkyl group represented by R²¹ to R²⁴, a cyclopropyl group, a cyclobutyl group, a cyclopentyl group, a cyclohexyl group, a cycloheptyl group, a cyclooctyl group, a cyclononyl group, a bicycloheptyl group, a bicyclooctyl group, a tricycloheptyl group, an admantyl group or the like can be given, for example. Of these, a cyclopentyl group, a cyclohexyl group, a cycloheptyl group, a bicycloheptyl group, a bicyclooctyl group and an adamantyl group can be given, with a cyclopropyl group, a cyclobutyl group, a cyclopentyl group, a cyclohexyl group and a cycloheptyl group being preferable.

As the substituted or unsubstituted alkoxy group represented by R²¹ to R²⁴, a methoxy group, an ethoxy group, a propoxy group, an isopropoxy group, a butoxy group, an isobutoxy group, a sec-butoxy group, a tert-butoxy group, various pentyloxy groups and various hexyloxy groups can be given, for example.

As the substituted or unsubstituted aryloxy group represented by R²¹ to R²⁴, a phenoxy group, a tolyloxy group, a naphthyloxy group or the like can be given, for example.

As the substituted or unsubstituted arylamino group represented by R²¹ to R²⁴, a diphenylamino group, a ditolylamino group, a dinaphthylamino group, a naphthylphenylamino group or the like can be given, for example.

As the substituted or unsubstituted alkylamino group represented by R²¹ to R²⁴, a dimethylamino group, a diethylamino group, a dihexylamino group or the like can be given, for example.

The examples of the substituted or unsubstituted heterocyclic group represented by R²¹ to R²⁴ are the same as those for Ar¹ to Ar⁴, mentioned above.

As the substituent for the silyl group represented by R²¹ to R²⁴, an alkyl group having 1 to 20 carbon atoms, an aryl group having 6 to 14 carbon atoms and an alkoxy group having 1 to 20 carbon atoms can be given, for example. As the alkyl group having 1 to 20 carbon atoms include, for example, a methyl group, an ethyl group, an n-propyl group, an isopropyl group, an n-butyl group, an isobutyl group, an s-butyl group, a t-butyl group and a pentyl group or the like can be given, for example. Of these, an alkyl group having 1 to 5 carbon atoms is preferable. As the aryl group having 6 to 14 carbon atoms, a phenyl group, a naphthyl group and an anthryl group or the like can be given, for example. Of these, an aryl group having 6 to 10 carbon atoms is preferable. As an alkoxy group having 1 to 20 carbon atoms, a methoxy group, an ethoxy group, a propoxy group, a buthoxy group or the like can be given, for example. Of these, an alkoxy group having 1 to 5 carbon atoms is preferable.

As the halogen atom represented by R²¹ to R²⁴, a fluorine atom, a chlorine atom, a bromine atom or the like can be given.

In the formula (1), n1 to n4 are independently an integer of 0 to 5, with 0 to 3 being further preferable.

When n1 to n4 each are 2 or more, R²¹s to R²⁴s each may be the same or different and may combine with each other to form a saturated or unsaturated ring.

Examples of such ring include, for example, a cycloalkane having 4 to 12 carbon atoms such as cyclobutene, cyclopentane and cyclohexane, a cycloalkene having 4 to 12 carbon atoms such as cyclobutene, cyclopentene, cyclohexene, cycloheptene and cyclooctene, cycloalkadiene having 6 to 12 carbon atoms such as cyclohexadiene, cycloheptadiene and cyclooctadiene.

The substituted or unsubstituted aryl group having 5 to 50 ring carbon atoms and the substituted or unsubstituted heterocyclic group having 5 to 50 ring carbon atoms represented by Ra and Rb are the same as those for Ar¹ to Ar⁴, mentioned above.

The substituted or unsubstituted aryl group, the substituted or unsubstituted alkyl group, the substituted or unsubstituted cycloalkyl group, the substituted or unsubstituted aralkyl group, the substituted or unsubstituted silyl group, the substituted or unsubstituted divalent bonding group formed by adjacent alkyl groups in the formula (1′) are each the same as those mentioned above.

In a preferred embodiment of the invention, the diaminopyrene derivative of the formula (1) is shown by the following chemical formula:

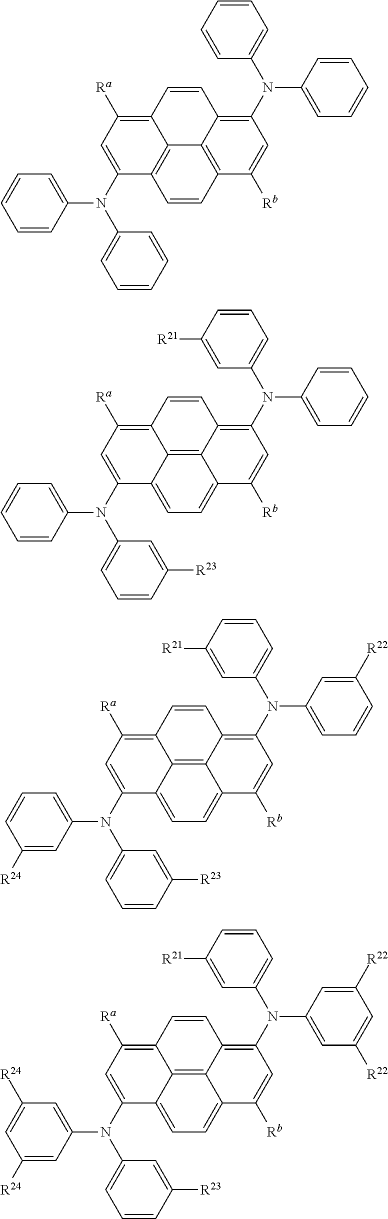

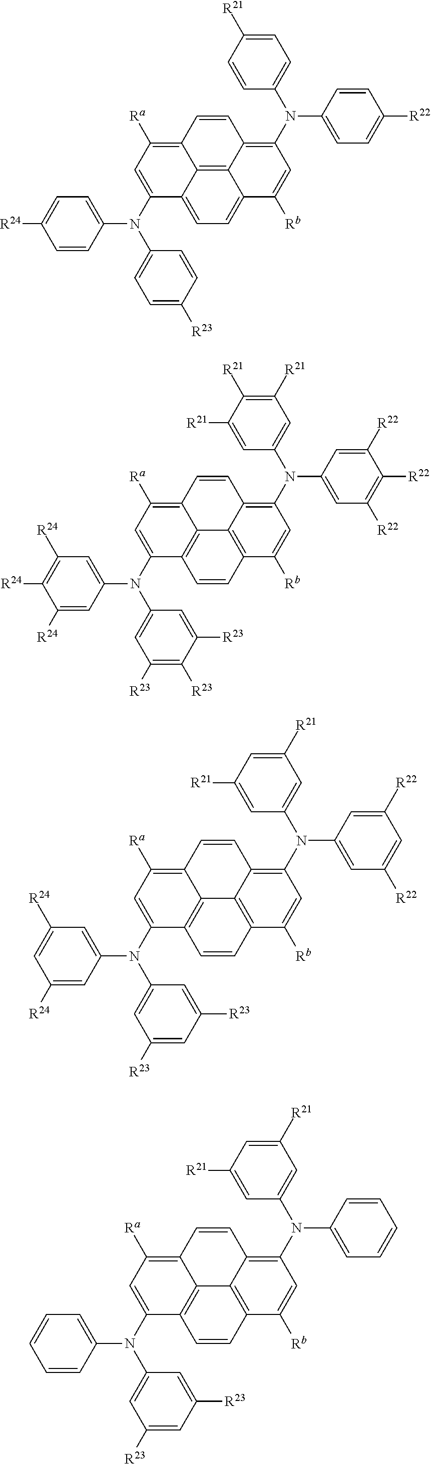

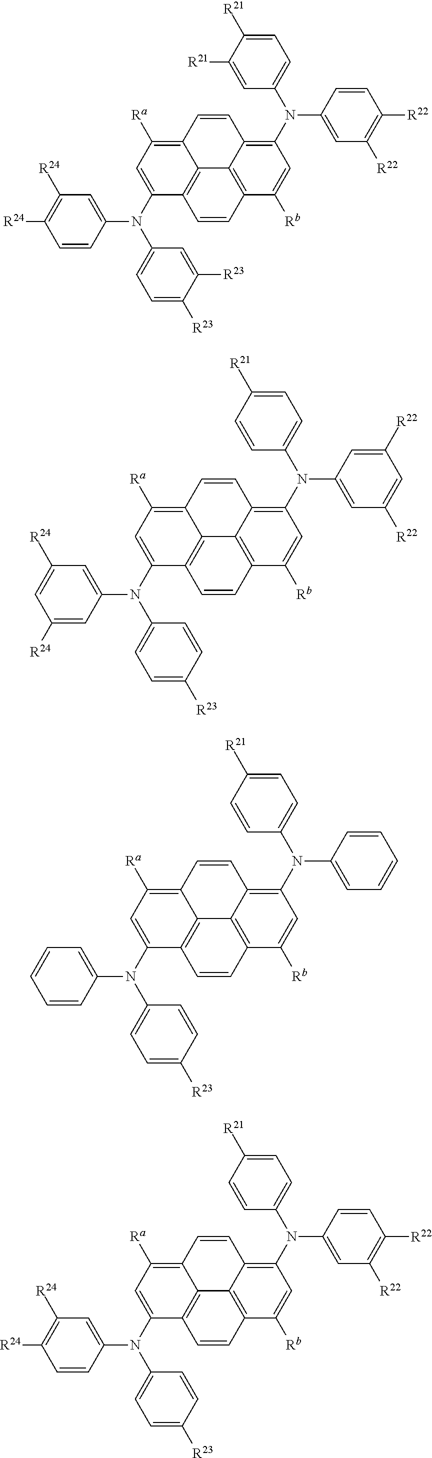

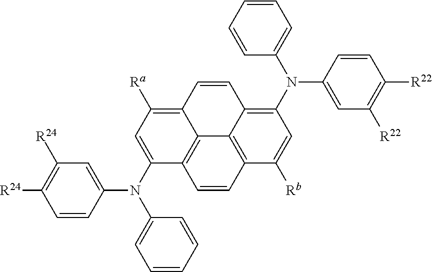

In the above formula, R²¹ to R²⁴ and R^{a} and R^{b} are the same as those mentioned above. R²¹ to R²⁴ may be the same or different. It is preferred that R²¹ and R²³, and R²² and R²⁴ be respectively the same. Although R^{a} and R^{b} may be the same or different, it is preferred that R^{a} and R^{b} be the same.

Specific examples of the diaminopyrene derivative represented by the formula (1) include those shown by the following formulas:

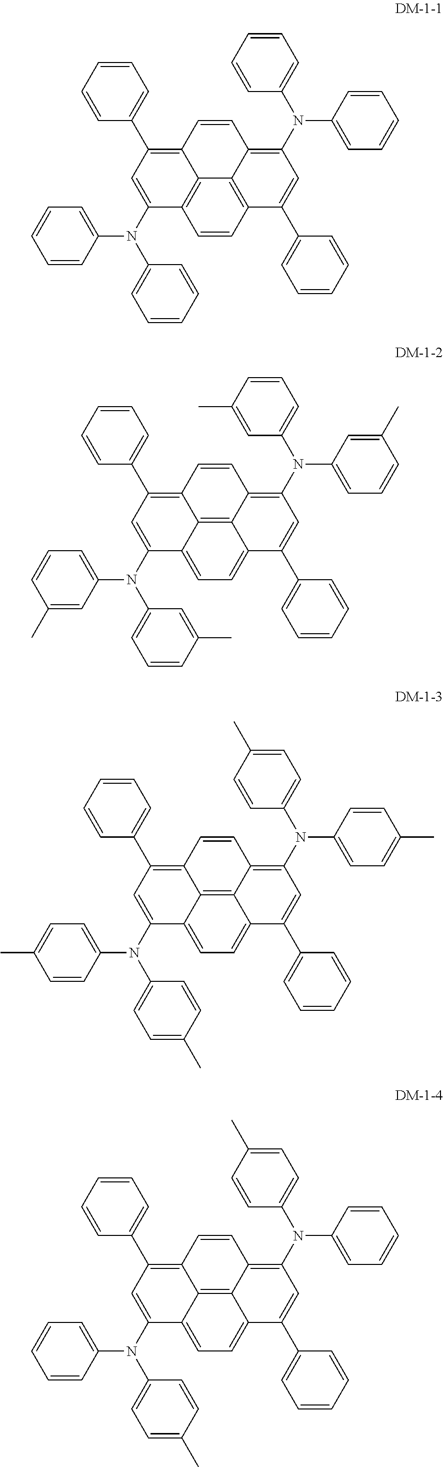

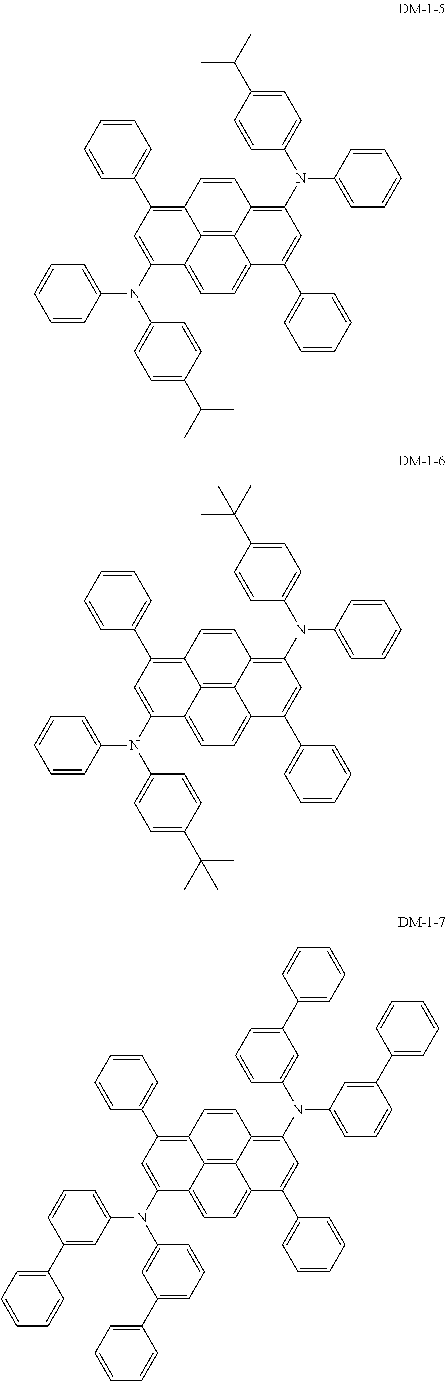

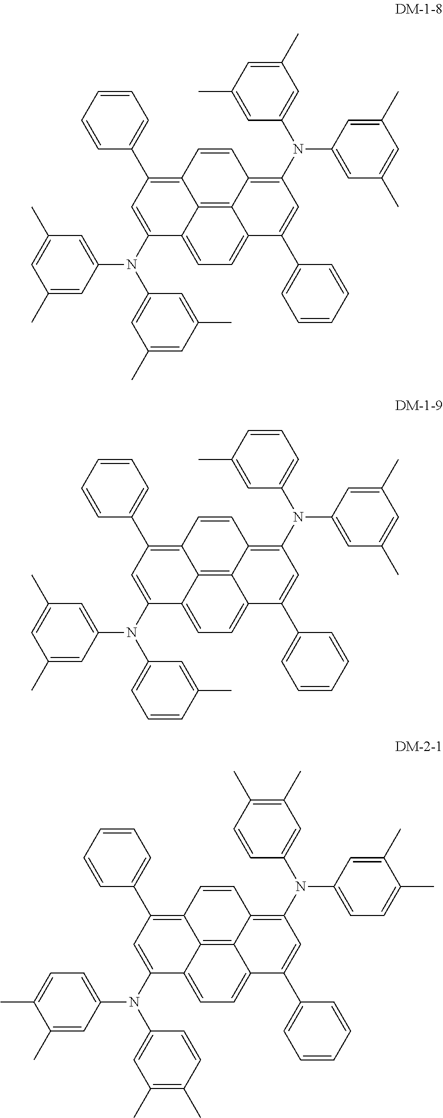

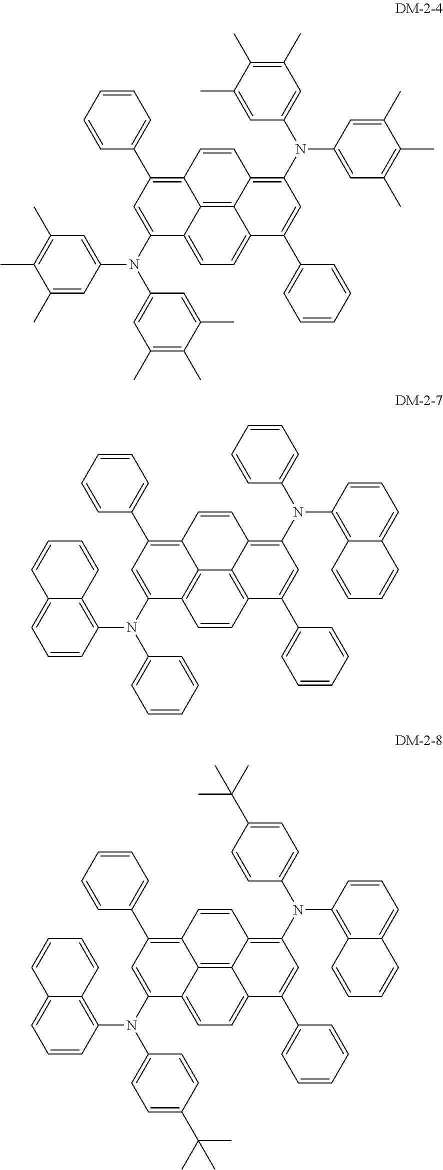

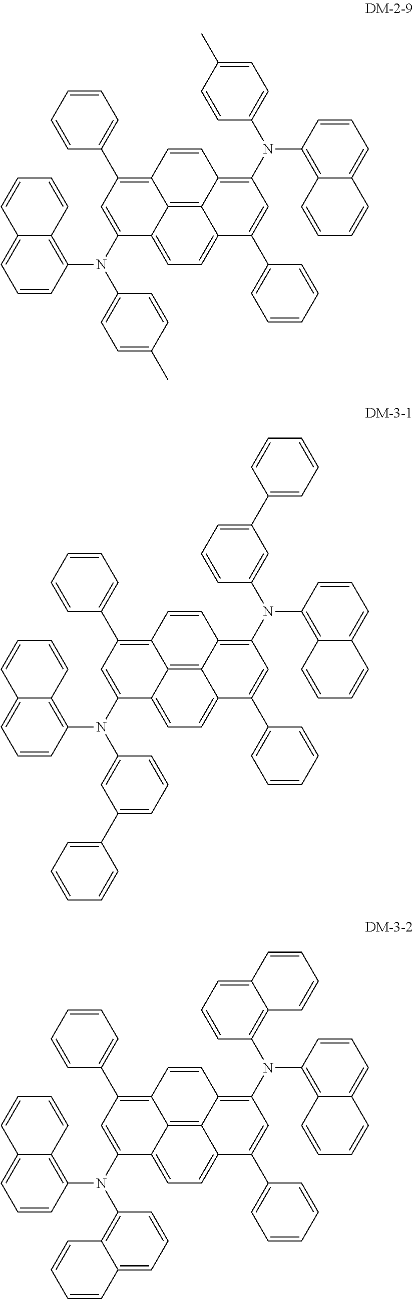

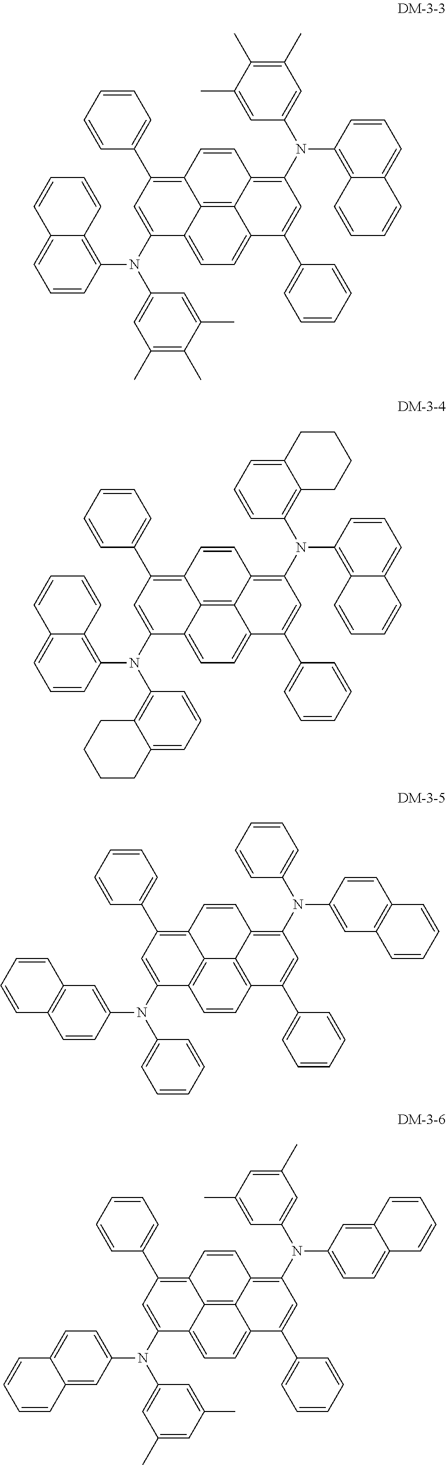

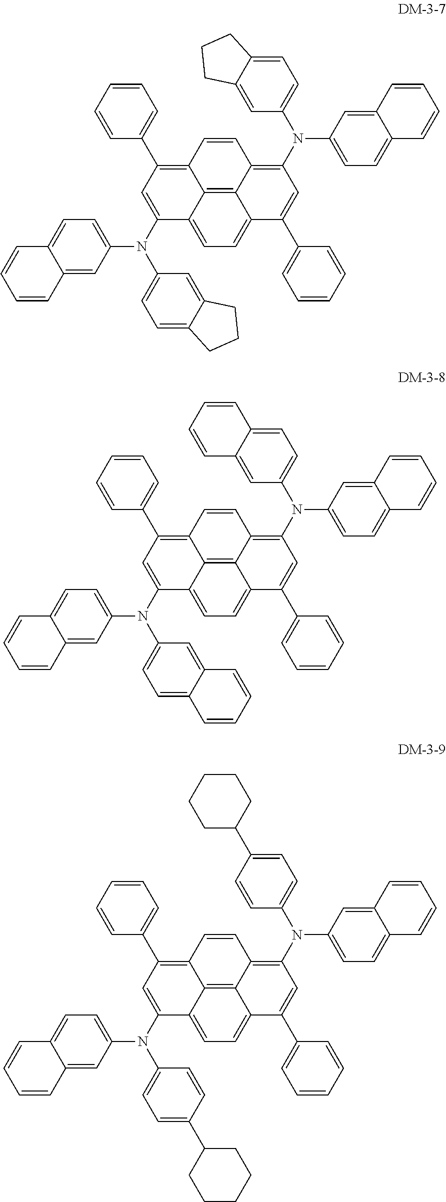

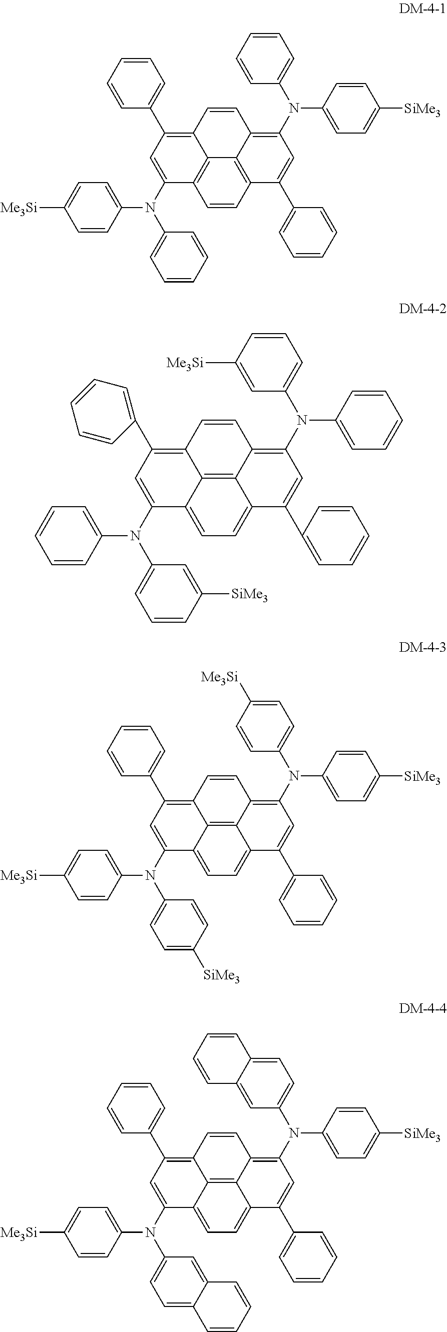

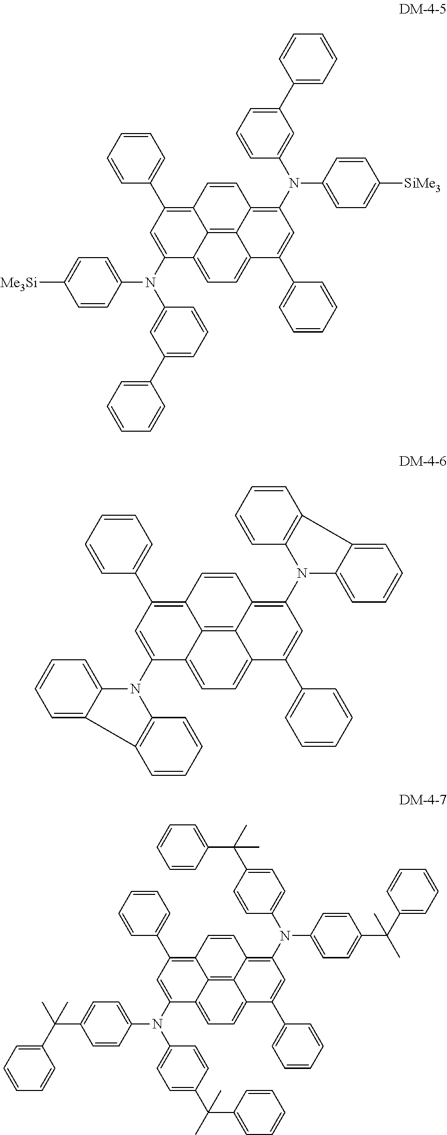

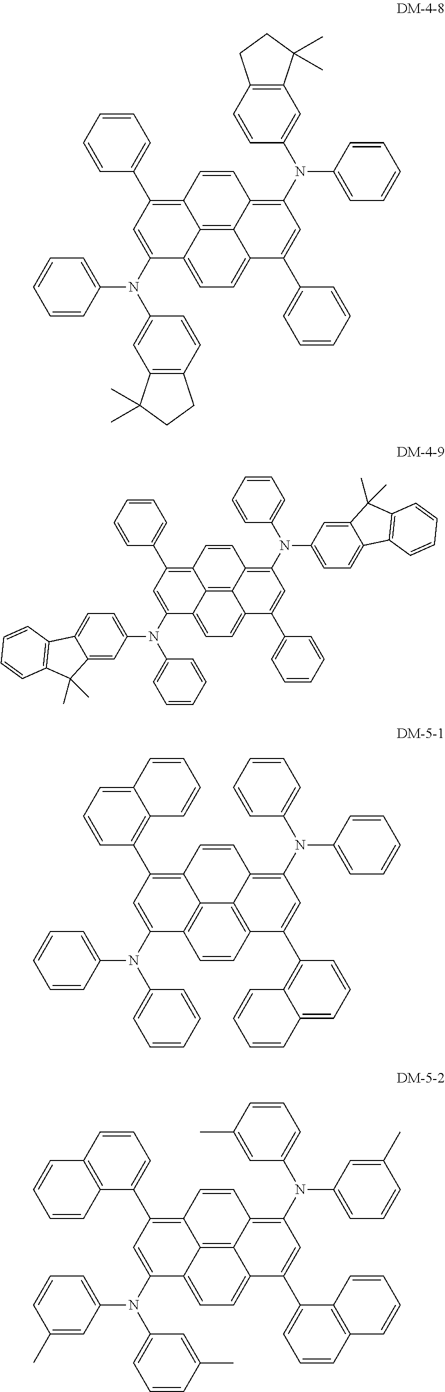

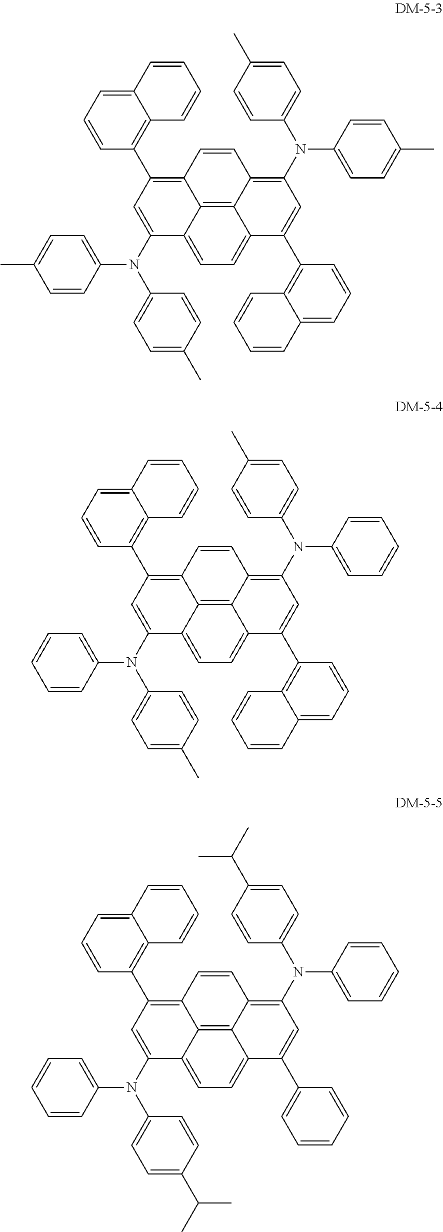

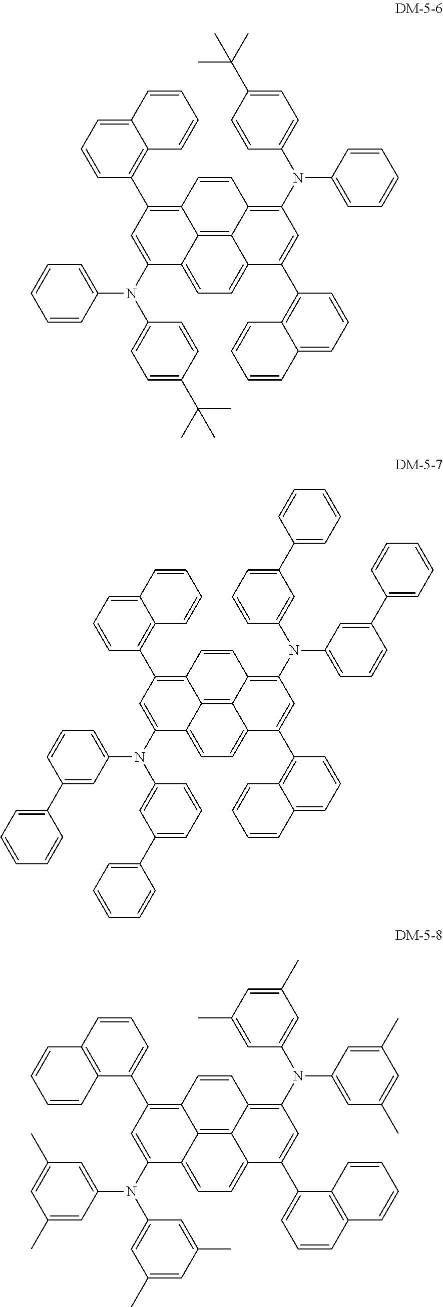

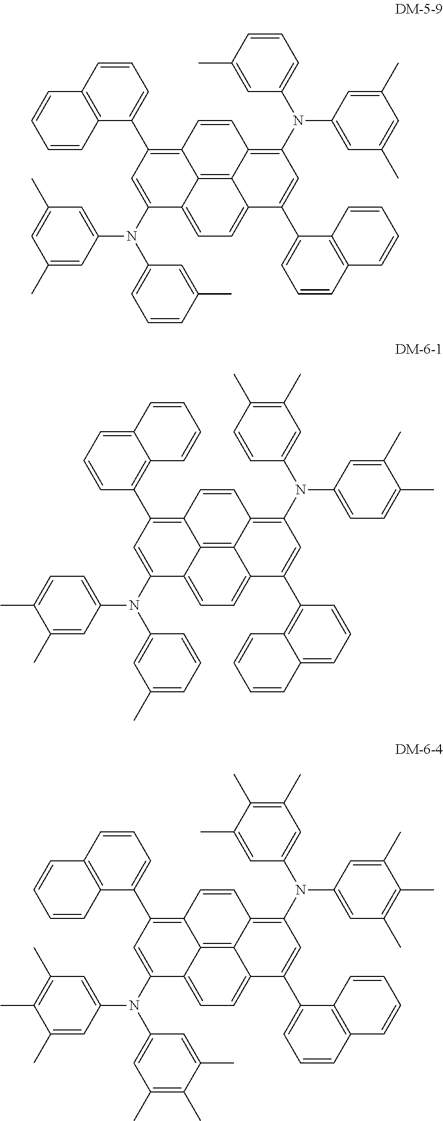

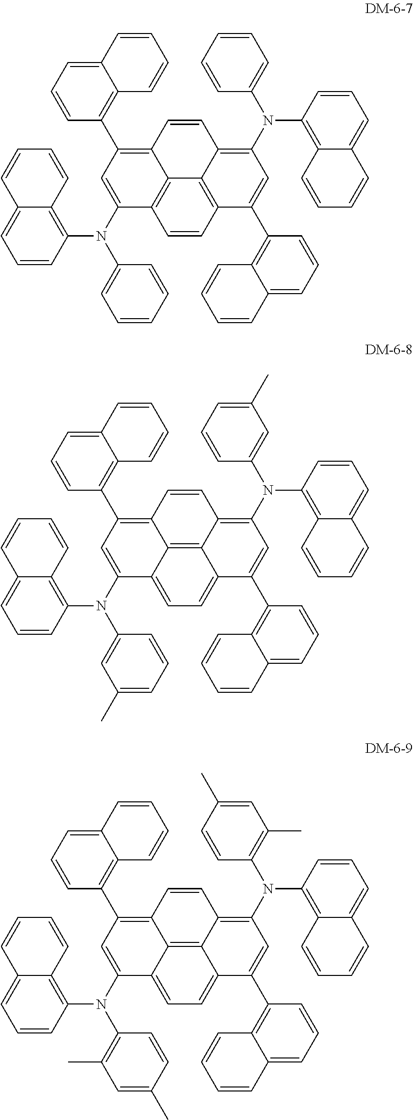

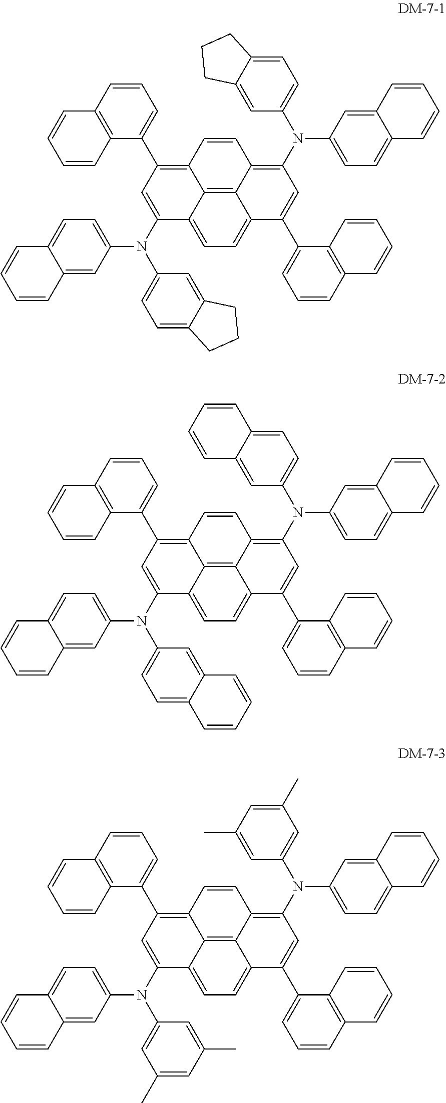

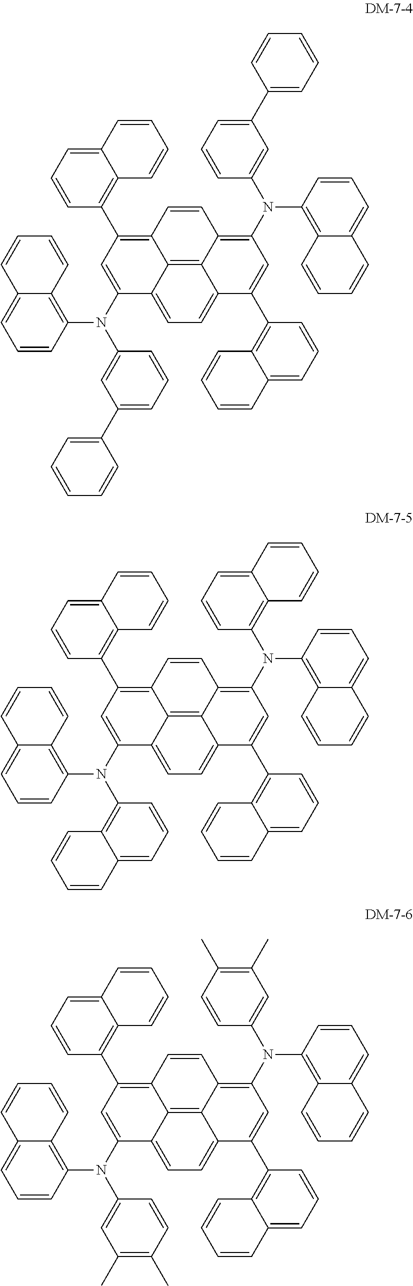

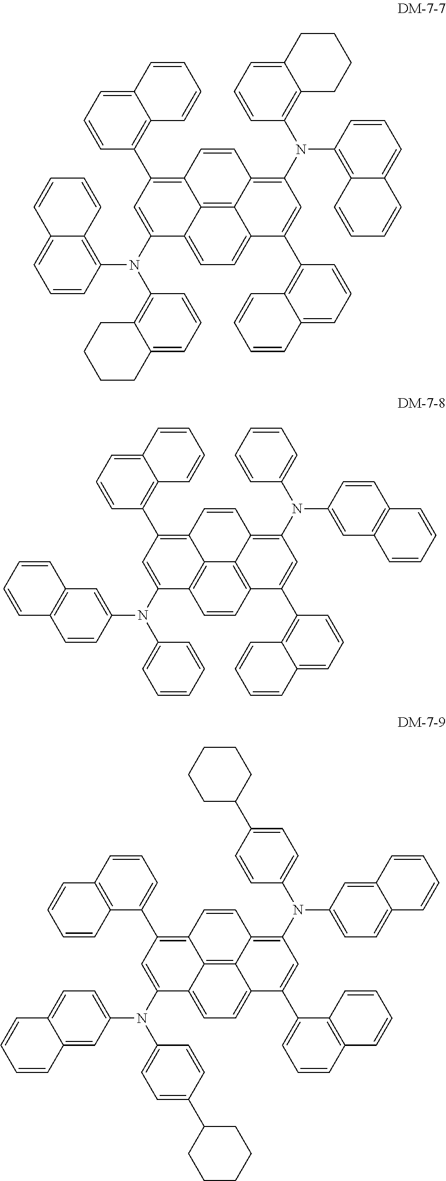

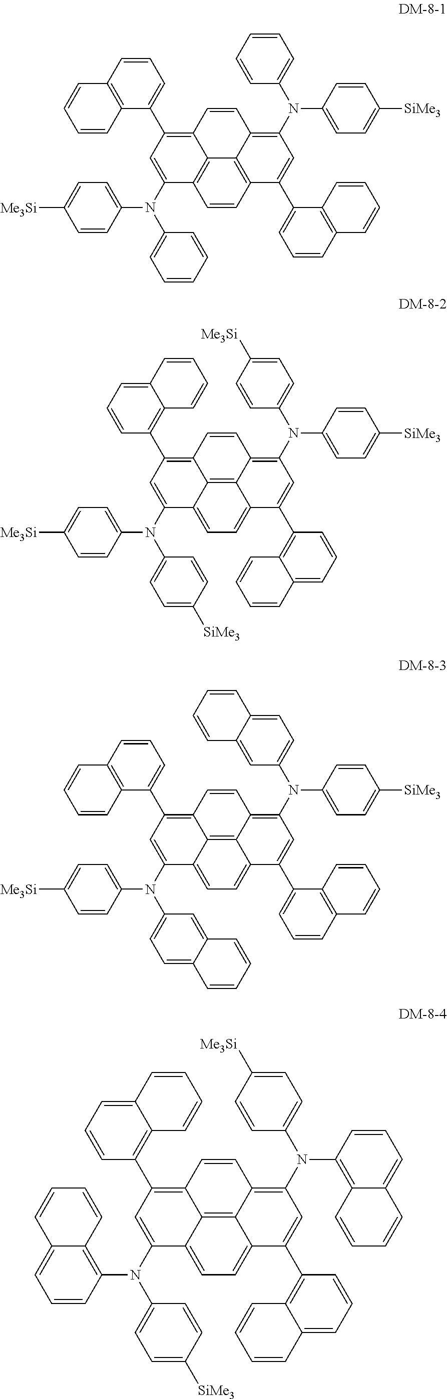

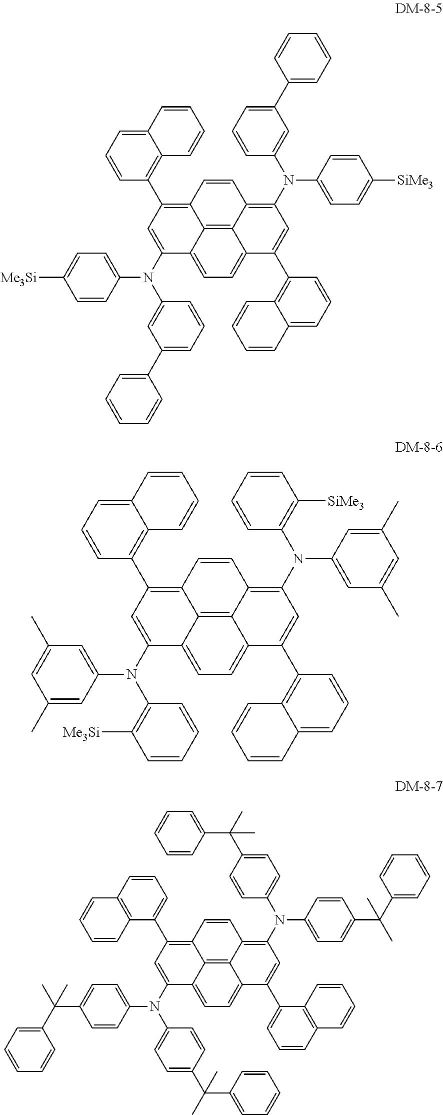

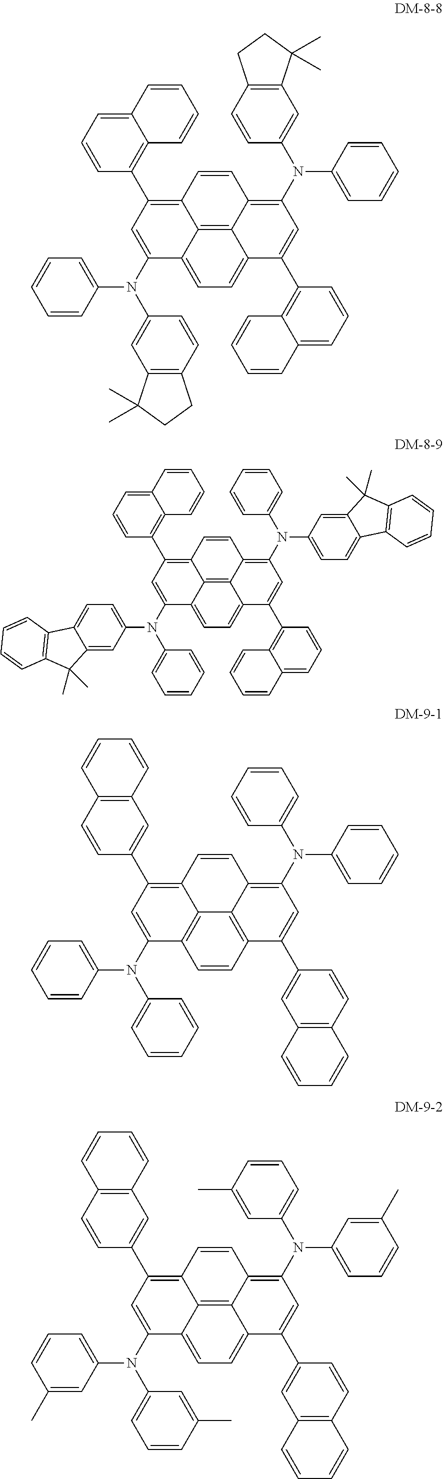

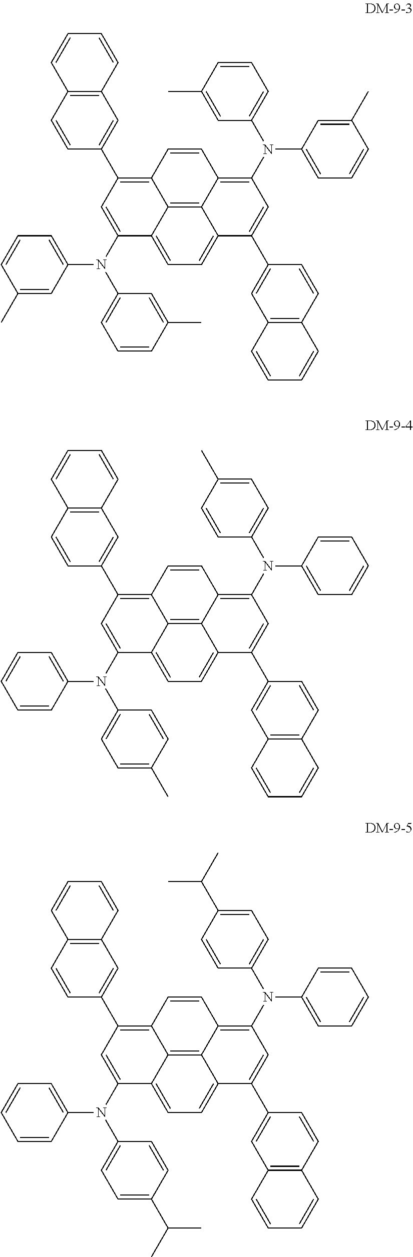

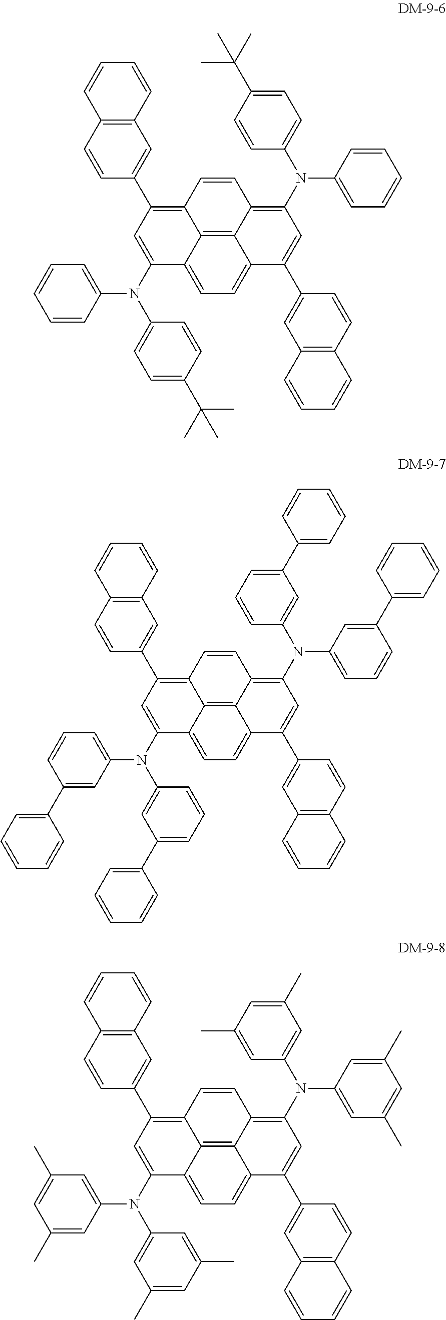

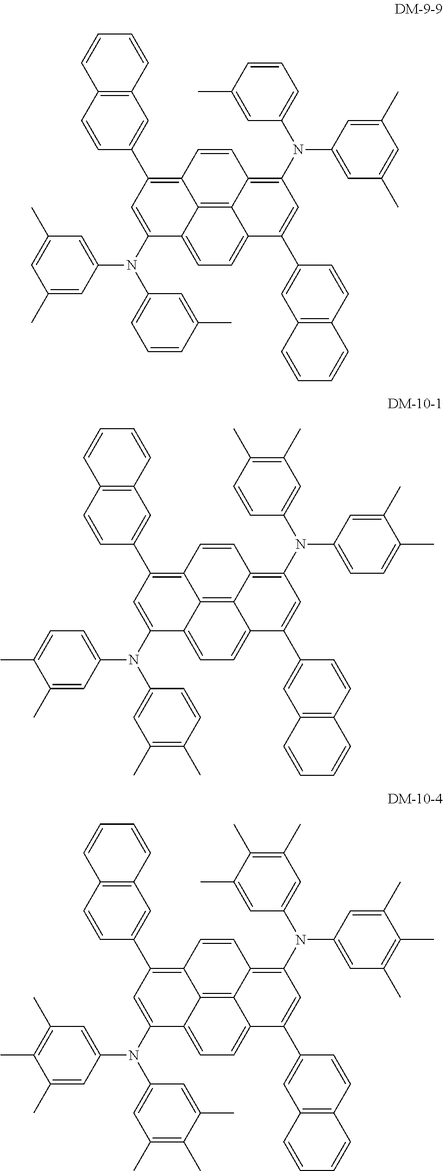

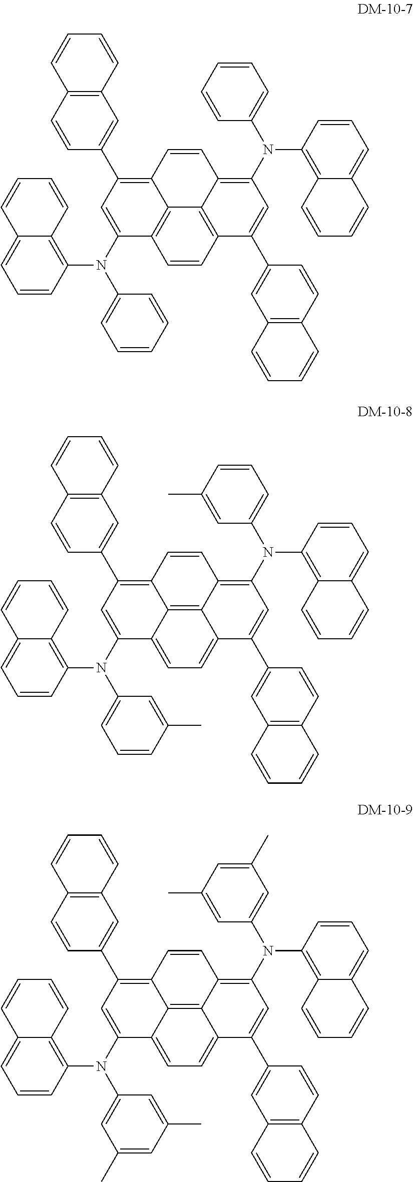

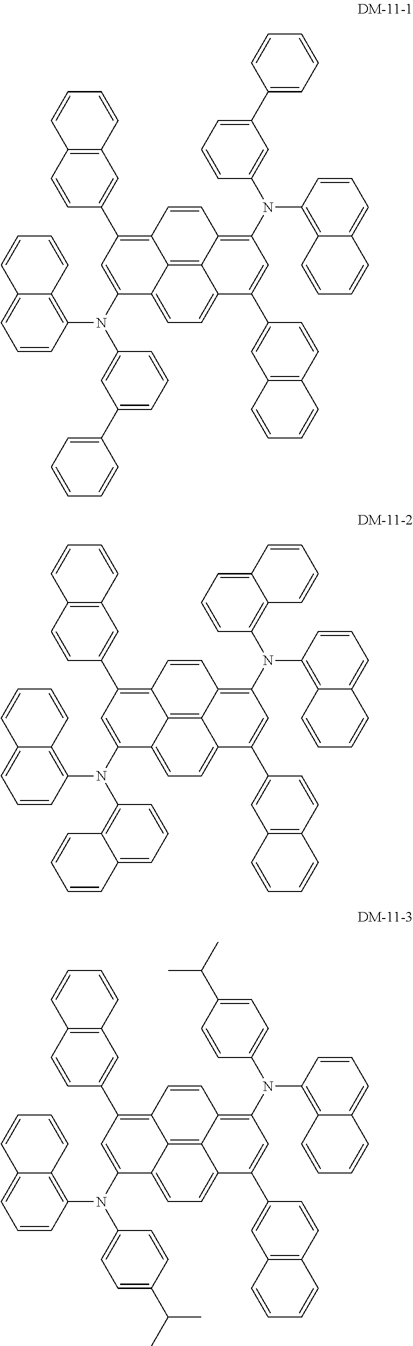

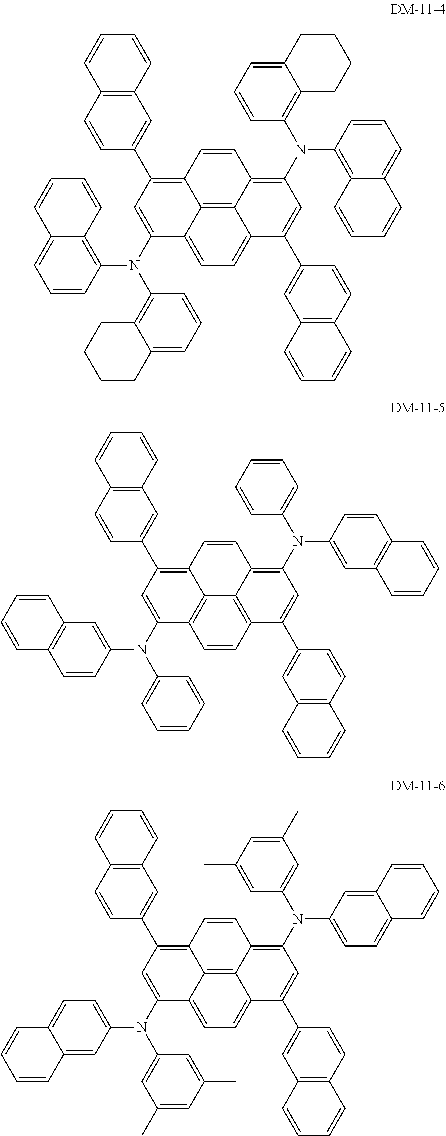

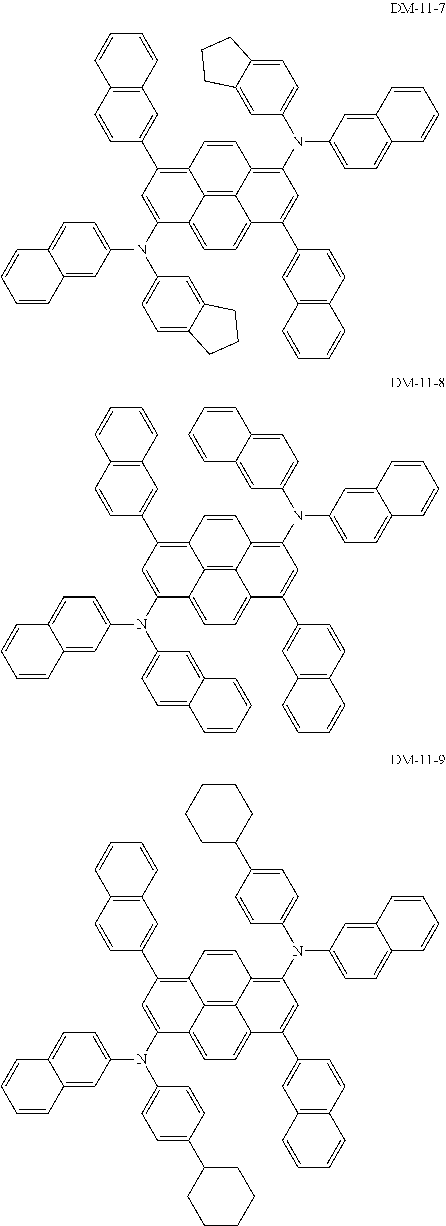

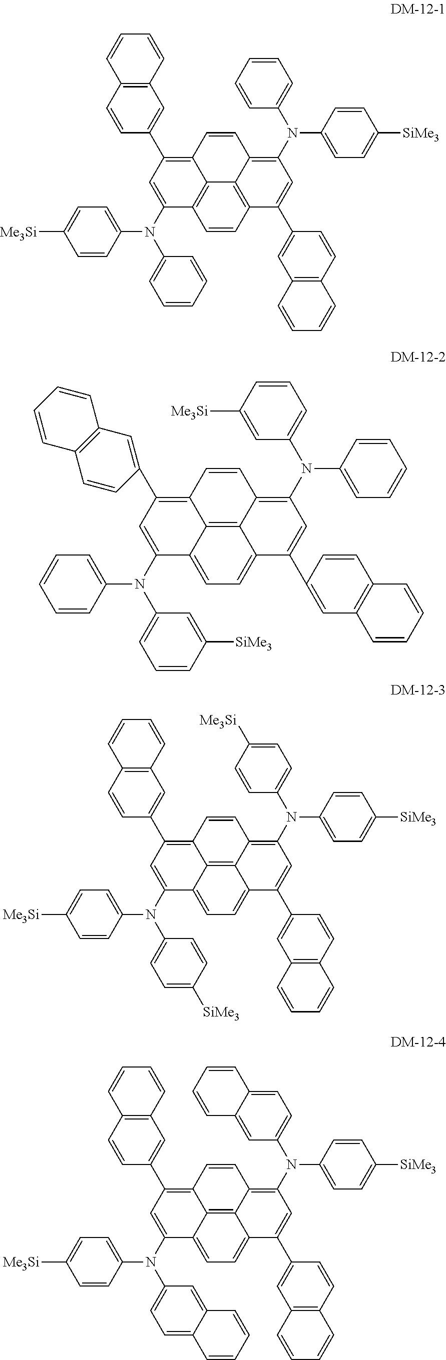

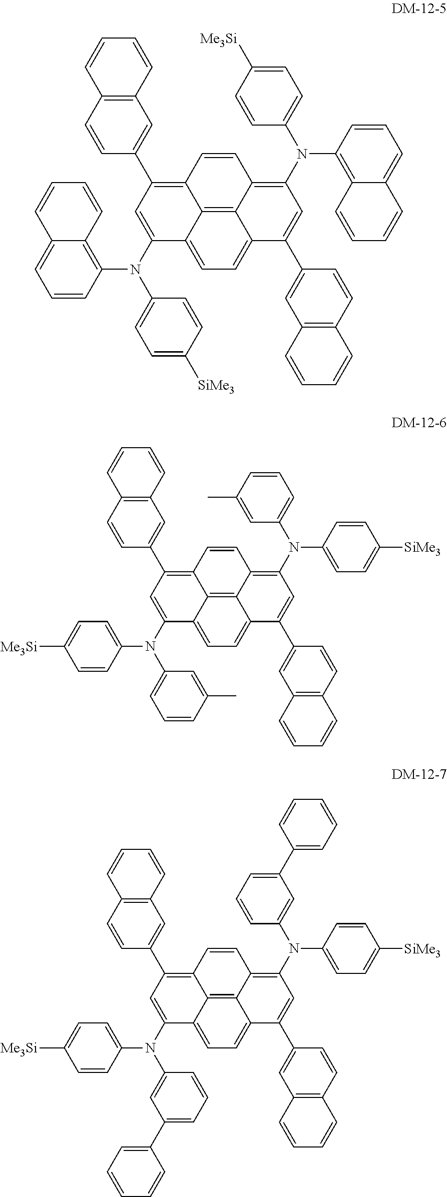

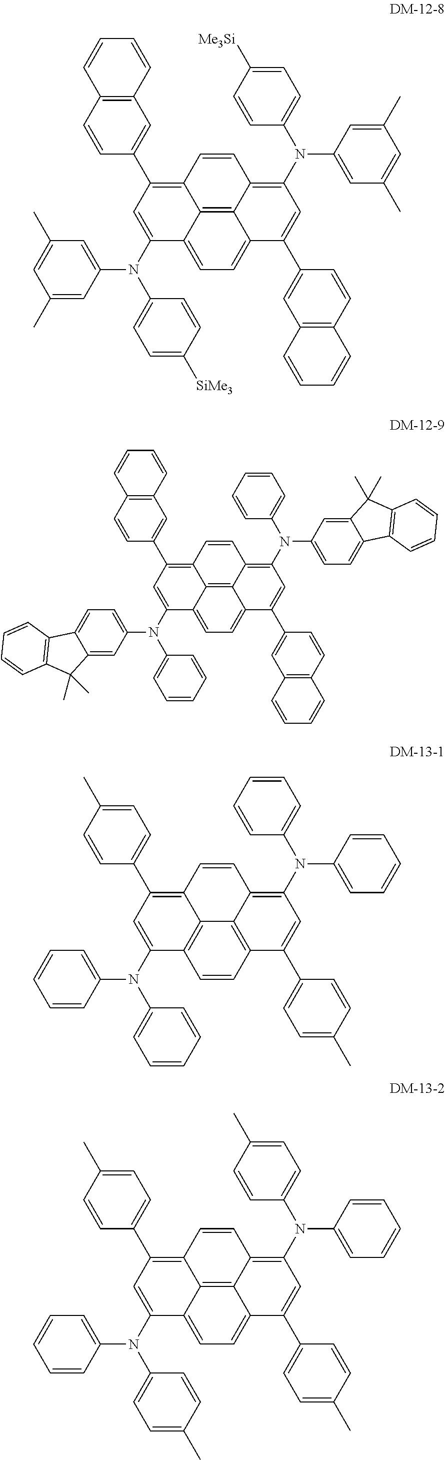

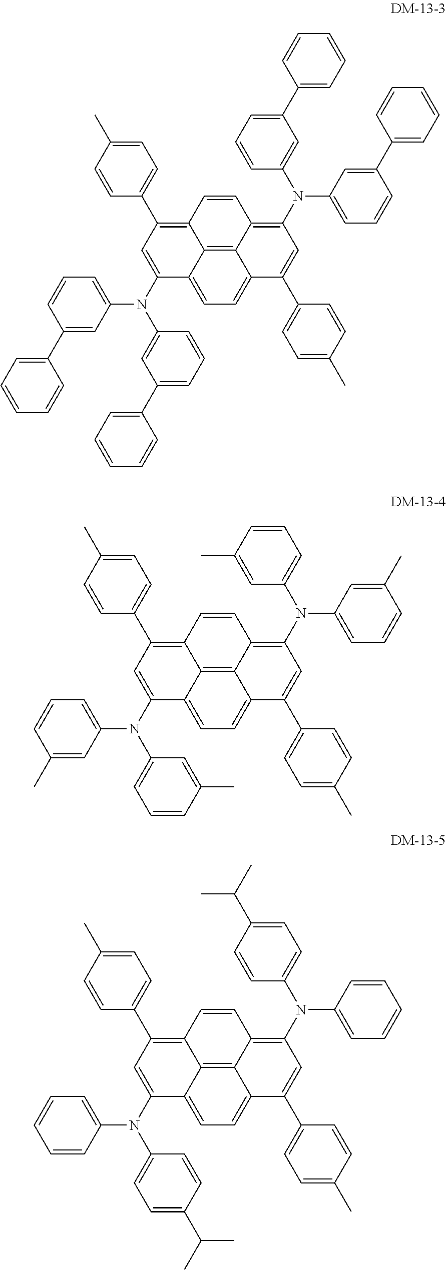

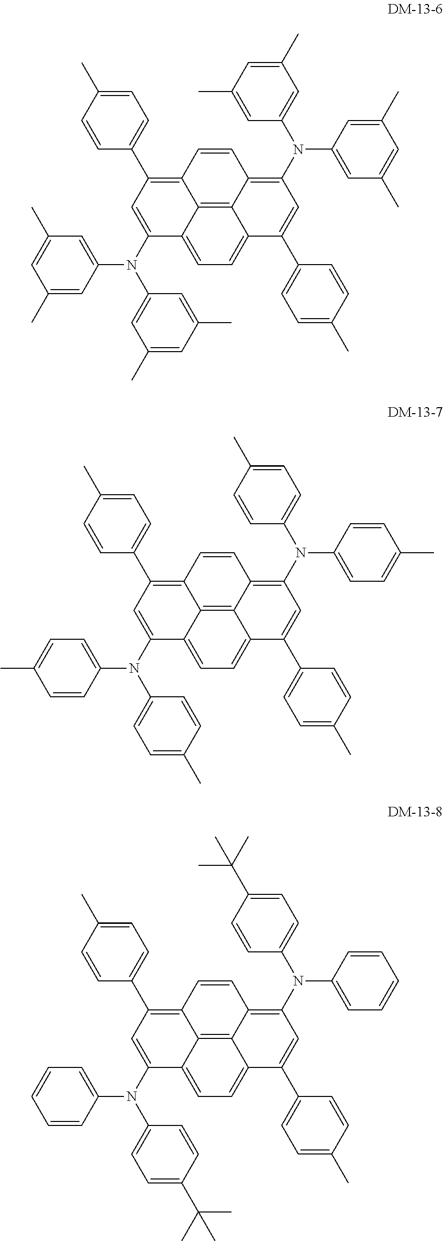

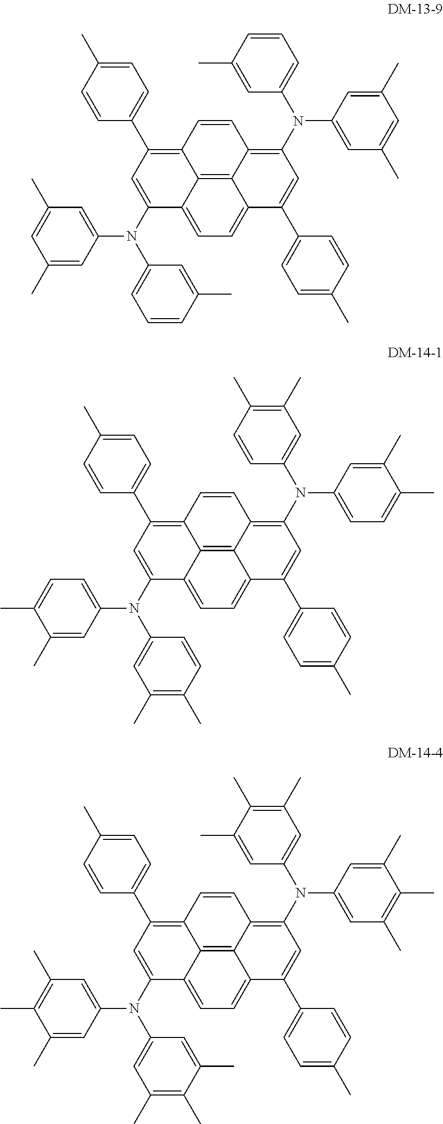

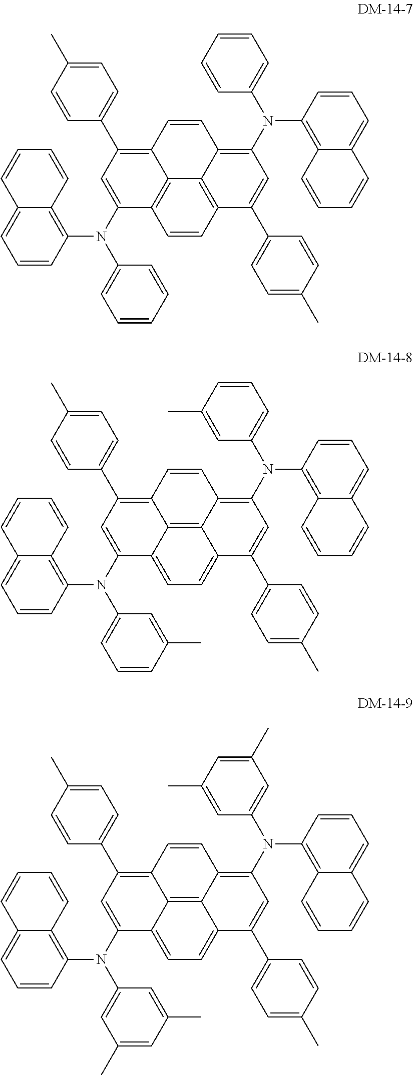

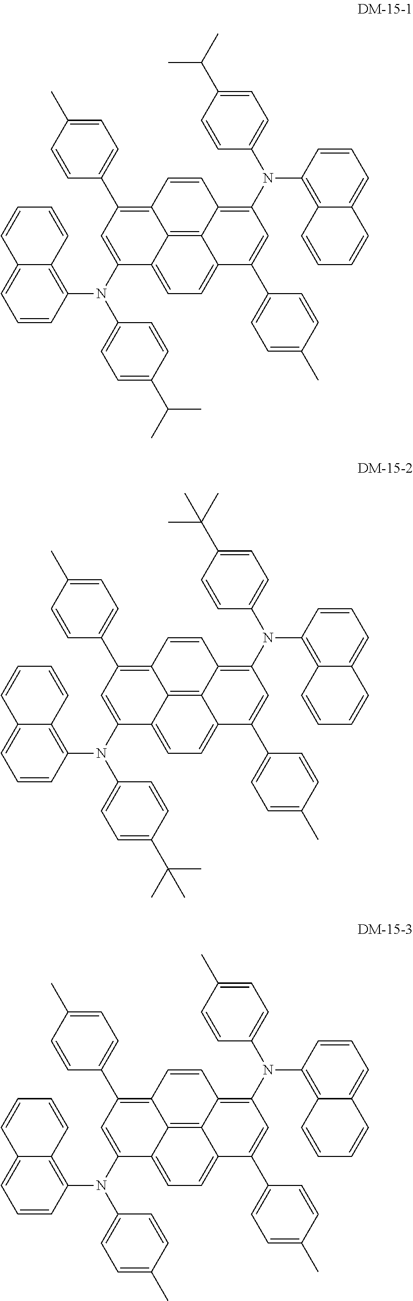

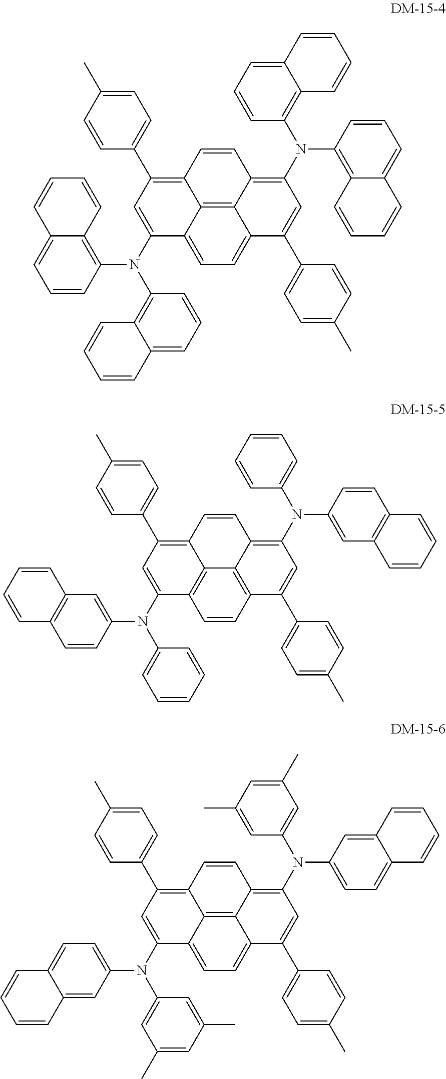

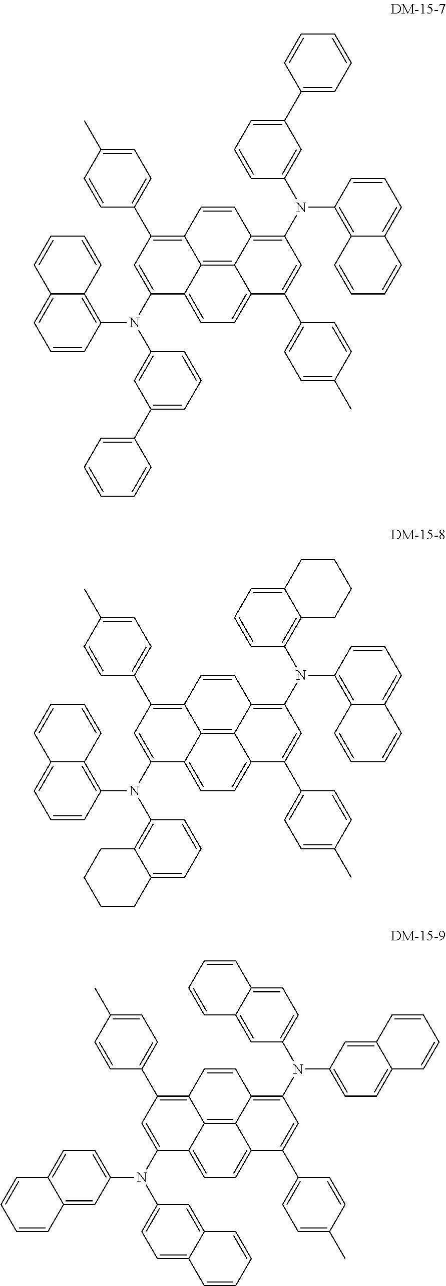

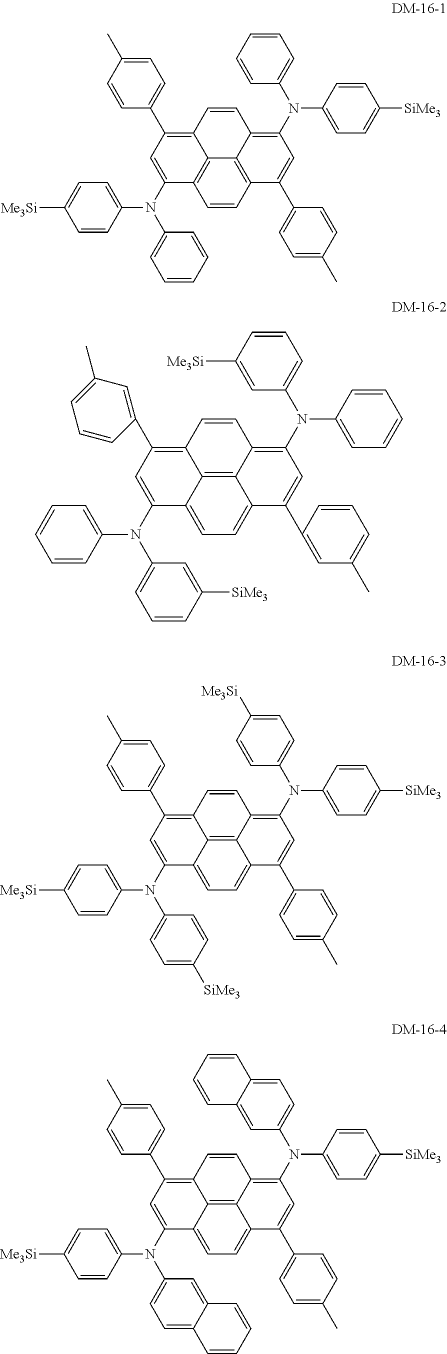

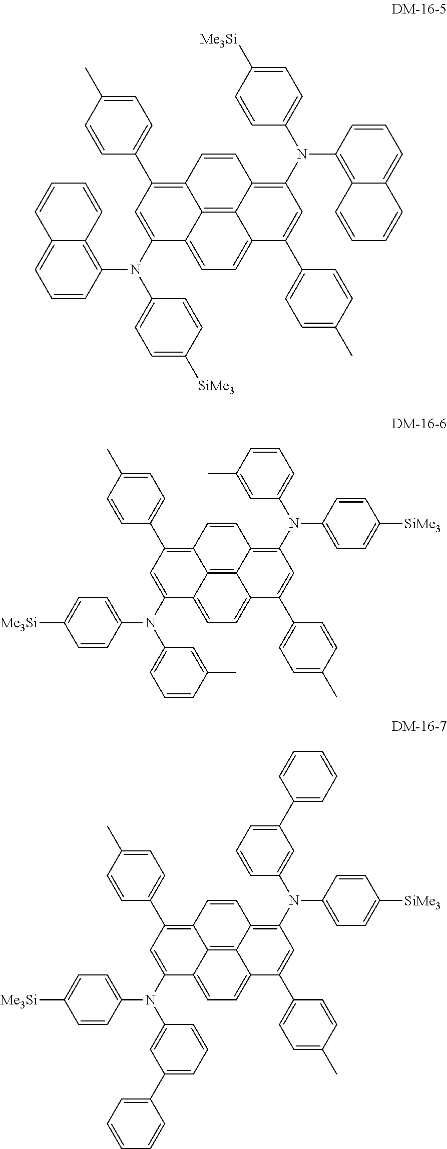

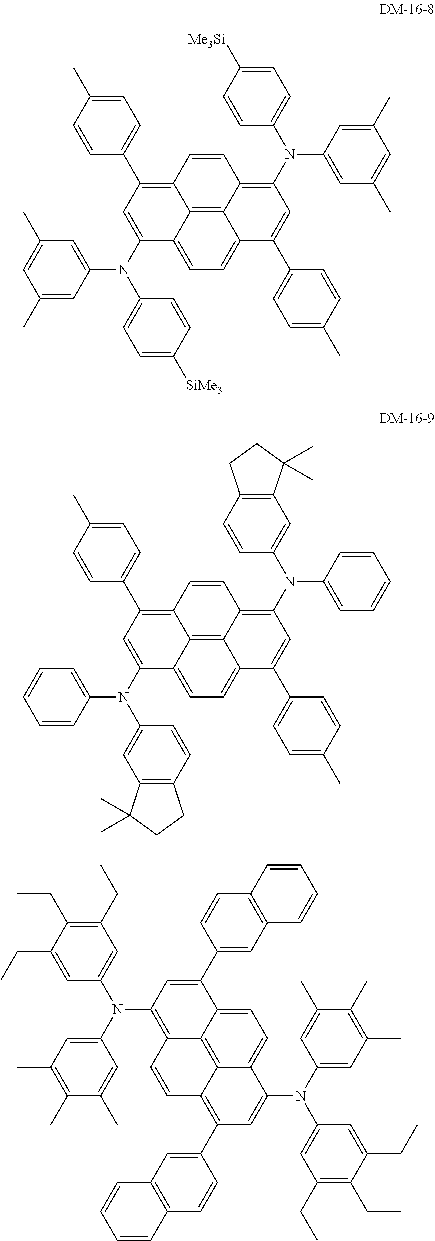

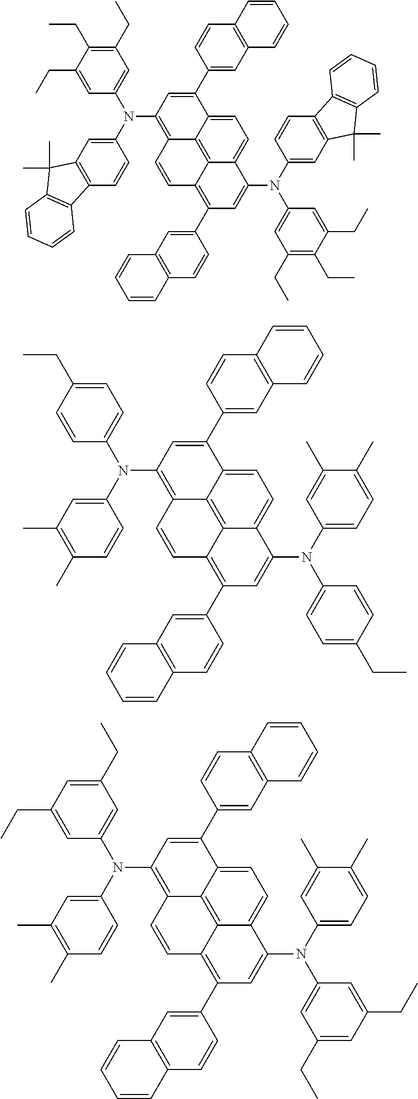

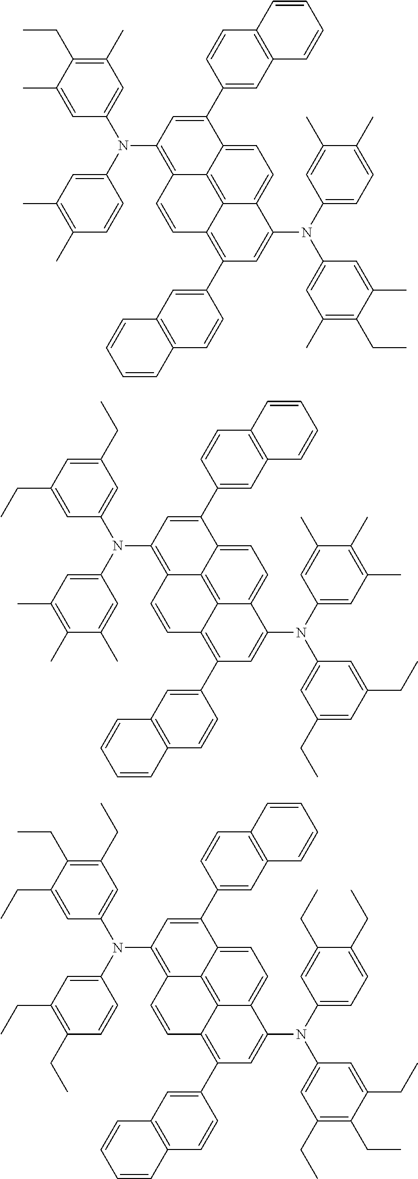

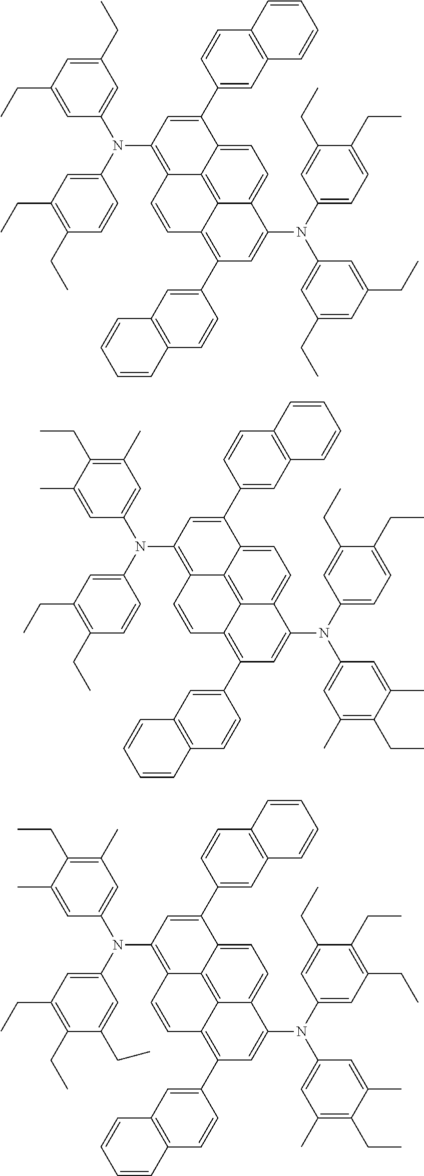

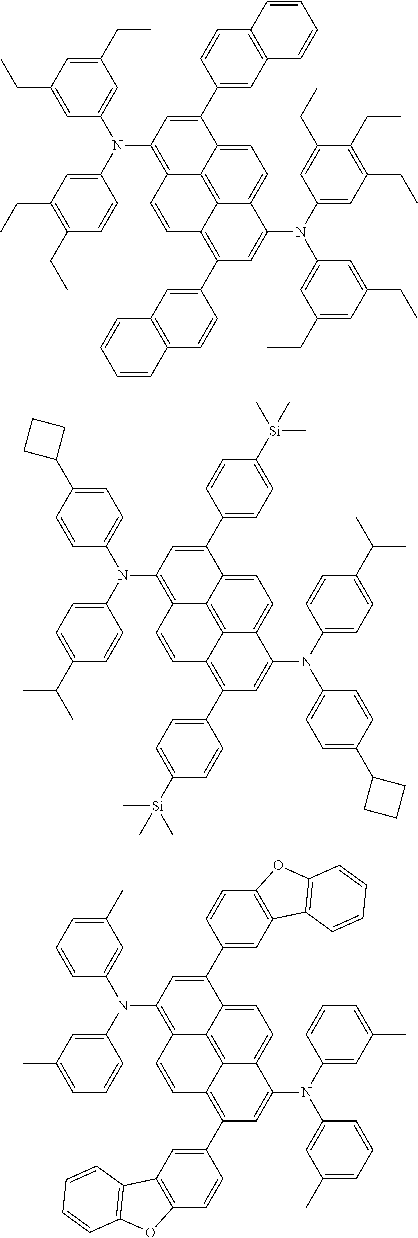

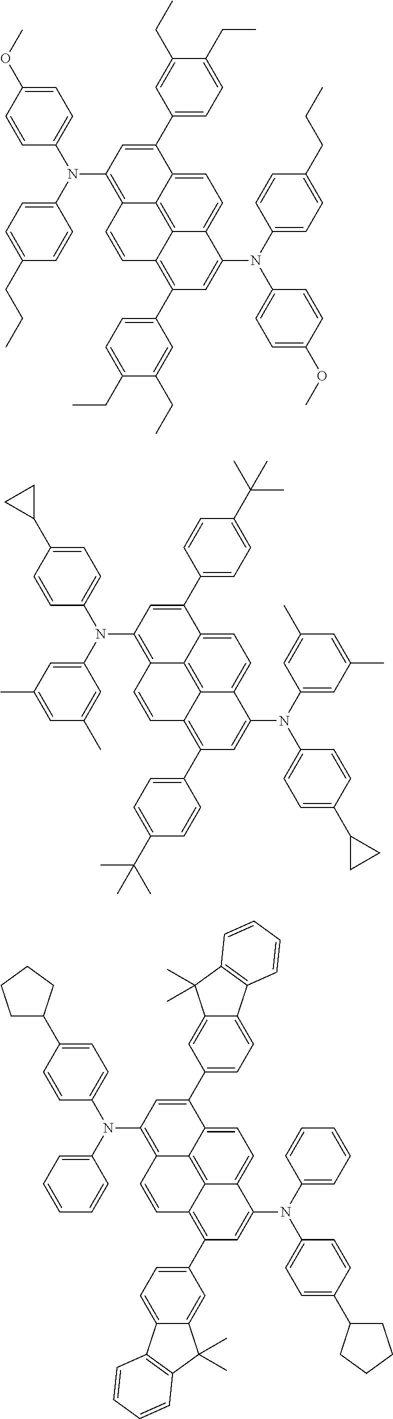

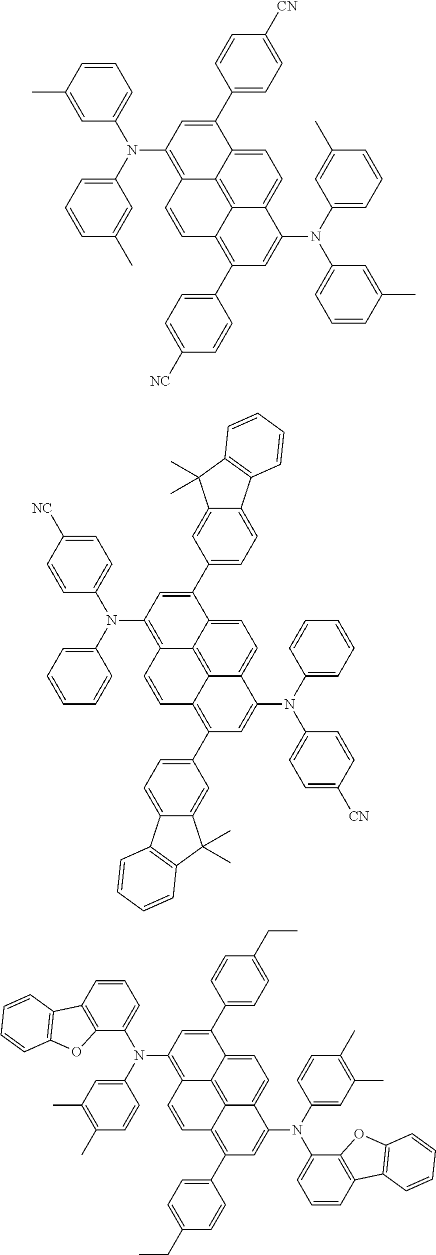

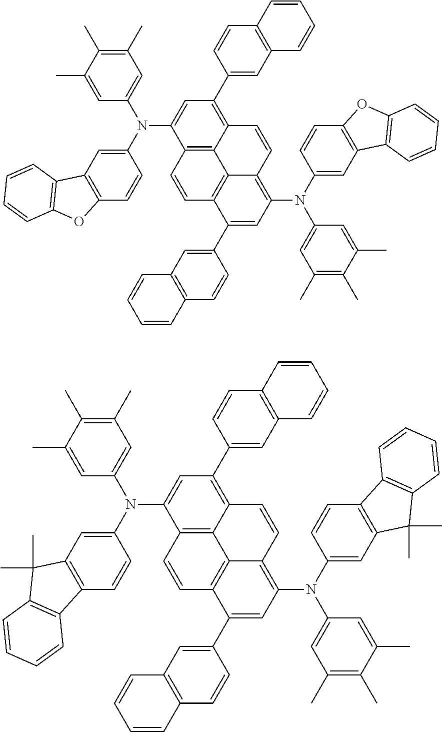

### (Anthracene Derivative)

The anthracene derivative of the invention is represented by the following formula (2):

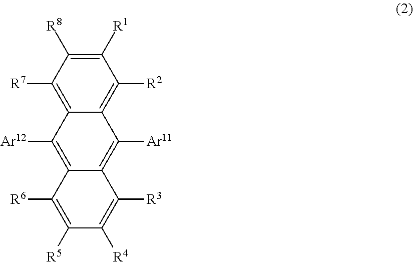

In the formula (2), Ar¹¹ and Ar¹² are independently a substituted or unsubstituted aryl group having 6 to 50 ring carbon atoms or a heterocyclic group having 5 to 50 ring atoms,

any one of R¹ to R⁸ is a substituted or unsubstituted aryl group having 6 to 50 ring carbon atoms or a substituted or unsubstituted heterocyclic group having 5 to 50 ring carbon atoms,

R¹ to R⁸ that are not a substituted or unsubstituted aryl group having 6 to 50 ring carbon atoms and a substituted or unsubstituted heterocyclic group having 5 to 50 ring atoms are independently a group selected from a hydrogen atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted silyl group, a carboxy group, a halogen atom, a cyano group, a nitro group and a hydroxyl group. The specific examples of the substituent are as mentioned above.

In the anthracene derivative of the invention, any one of R¹, R², R⁷ and R⁸ is a substituted or unsubstituted aryl group having 6 to 50 ring carbon atoms or a substituted or unsubstituted heterocyclic group having 5 to 50 ring atoms. More preferably, one of R¹ and R⁷ is a substituted or unsubstituted aryl group having 6 to 50 ring carbon atoms or a substituted or unsubstituted heterocyclic group having 5 to 50 ring atoms, and the other is a hydrogen atom, or one of R² and R⁸ is a substituted or unsubstituted aryl group having 6 to 50 ring carbon atoms or a substituted or unsubstituted heterocyclic group having 5 to 50 ring atoms, and the other is a hydrogen atom.

In the anthracene derivative of the invention, it is preferred that any one of R¹, R², R⁷ and R⁸ be a substituted or unsubstituted aryl group having 6 to 50 ring carbon atoms, and it is more preferred that one of R¹ and R⁷ be a substituted or unsubstituted aryl group having 6 to 50 ring carbon atoms, and the other be a hydrogen atom, or one of R² and R⁸ be a substituted or unsubstituted aryl group having 6 to 50 ring carbon atoms, and the other be a hydrogen atom.

The above-mentioned substituted or unsubstituted aryl group having 6 to 50 ring carbon atoms is preferably a substituted or unsubstituted phenyl group, naphthyl group or phenanthryl group.

In addition to the above-mentioned requirements regarding R¹ to R⁸, it is preferred that the anthracene derivative of the invention be any of the following anthracene derivatives (A), (B) and (C). Selection is made according to the structure or required characteristics of an organic EL device to which this derivative is applied.

### (Anthracene Derivative (A))

In this anthracene derivative, Ar¹¹ and Ar¹² in formula (2) are independently a substituted or unsubstituted fused aryl group having 10 to 50 ring carbon atoms. As for this anthracene derivative, it can be divided into a case where Ar¹¹ and Ar¹² are the same substituted or unsubstituted fused aryl group and a case where Ar¹¹ and Ar¹² are the different substituted or unsubstituted fused aryl group.

Specifically, an anthracene derivative shown by the following formulas (2-1) to (2-3) (preferably Ar¹¹ and Ar¹² are the same) and an anthracene derivative in which Ar¹¹ and Ar¹² in formula (2) are different substituted or unsubstituted fused aryl groups can be given.

In the anthracene derivative shown by the following formula (2-1), Ar¹¹ and Ar¹² are a substituted or unsubstituted 9-phenanthreneyl group.

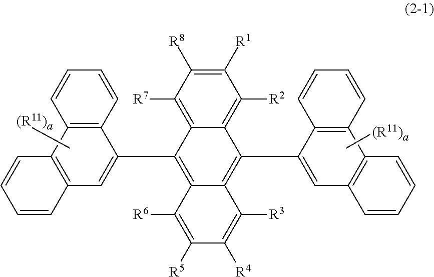

In the formula (2-1), R¹ to R⁸ are the same as mentioned above, R¹¹ is a group selected from a hydrogen atom, a substituted or unsubstituted aryl group having 6 to 50 ring carbon atoms, a substituted or unsubstituted heterocyclic group having 5 to 50 ring atoms, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralykyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted silyl group, a carboxy group, a halogen atom, a cyano group, a nitro group and a hydroxyl group.

a is an integer of 0 to 9. When a is an integer of 2 or more, a plurality of R¹¹s may be the same or different, on the condition that two substituted and unsubstituted phenanthrenyl groups are the same.

In the anthracene derivative shown by the following formula (2-2), Ar¹¹ and Ar¹² in the formula (2) are each a substituted or unsubstituted 2-naphthyl group.

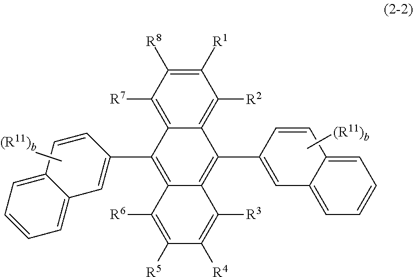

In the formula (2-2), R¹ to R⁸ and R¹¹ are the same as those mentioned above, and b is an integer of 1 to 7. If b is an integer of 2 or more, a plurality of R¹¹s may be the same or different.

In the anthracene derivative shown by the following formula (2-3), Ar¹¹ and Ar¹² in the formula (2) are each a substituted or unsubstituted 1-naphthyl group.

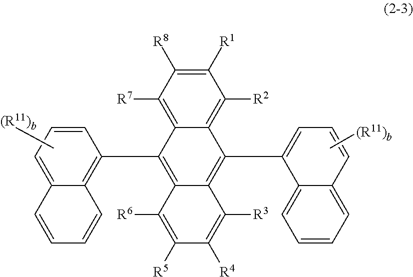

In the formula (2-2), R¹ to R⁸, R¹¹ and b are the same as those mentioned above. If b is an integer of 2 or more, they may be the same or different.

In addition to the above-mentioned anthracene derivatives shown by the formulas (2-1) to (2-3), an anthracene derivative in which Ar¹¹ and Ar¹² in formula (2) are the same substituted or unsubstituted fluoranthenyl group and an anthracene derivative in which Ar¹¹ and Ar¹² in formula (2) are the same substituted or unsubstituted pyrenyl group are preferable.

As the anthracene derivative in which Ar¹¹ and Ar¹² in formula (2) are different substituted or unsubstituted fused aryl groups, it is preferred that Ar¹¹ and Ar¹² be any of the groups constituting the anthracene derivatives shown by formulas (2-1) to (2-3), a substituted or unsubstituted 9-phenanthrene group, a substituted or unsubstituted 1-naphthyl group, a substituted or unsubstituted 2-naphthyl group and a substituted or unsubstituted fluoranthenyl group.

Specifically, a case where Ar¹¹ is a 1-naphthyl group and Ar¹² is a 2-naphthyl group, a case where Ar¹¹ is a 1-naphthyl group and Ar¹² is a 9-phenanthrenyl group, and a case where Ar¹¹ is a 2-naphthyl group and Ar¹² is a 9-phenanthryl group are preferable.

### (Anthracene Derivative (B))

In this anthracene derivative, one of Ar¹¹ and Ar¹² in formula (2) is a substituted or unsubstituted phenyl group, and the other is a substituted or unsubstituted fused aryl group having 10 to 50 ring carbon atoms. Specific examples of this anthracene derivative include an anthracene derivative shown by the following formulas (2-4) and (2-5).

The anthracene derivative shown by the following formula (2-4) is one in which Ar¹¹ in formula (2) is a substituted or unsubstituted 1-naphthyl croup and Ar¹² is a substituted or unsubstituted phenyl group.

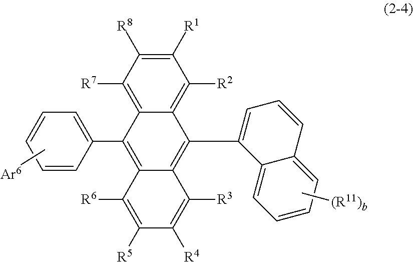

In the formula (2-4), R¹ to R⁸, R¹¹ and b are the same as those mentioned above, Ar¹¹ is a substituted or unsubstituted aryl group having 6 to 50 ring carbon atoms, a substituted or unsubstituted alkyl group having 1 to 50 ring carbon atoms, a substituted or unsubstituted cycloalkyl group having 3 to 50 ring carbon atoms, a substituted or unsubstituted aralkyl group having 7 to 50 carbon atoms, a substituted or unsubstituted heterocyclic group having 5 to 50 ring atoms, a 9,9-dimethylfluoren-1-yl group, a 9,9-dimethylfluoren-2-yl group, a 9,9-dimethylfluoren-3-yl group, a 9,9-dimethylfluoren-4-ylgroup, a dibenzofuran-1-yl group, a dibenzofuran-2-yl group, a dibenzofuran-3-yl group or a dibenzofuran-4-yl group. Ar⁶ may form, together with a benzene ring to which it is bonded, a substituted or unsubstituted fluorenyl group or a substituted or unsubstituted dibenzofluorenyl group. When b is an integer of 2 or more, a plurality of R¹¹s may be the same or different.

The anthracene derivative shown by the following formula (2-5) is one in which Ar¹¹ is a substituted or unsubstituted 2-naphthyl group and Ar¹² is a substituted or unsubstituted phenyl group in the formula (2).

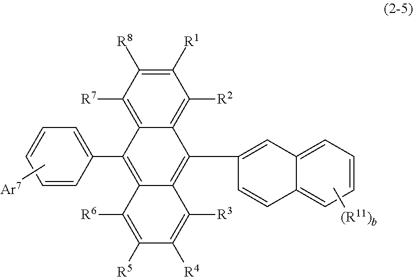

In the formula (2-5), R¹ to R⁸, R¹¹ and b are as mentioned above, Ar⁷ is a substituted or unsubstituted alkyl group having 1 to 50 ring carbon atoms, a substituted or unsubstituted cycloalkyl group having 3 to 50 ring carbon atoms, a substituted or unsubstituted aralkyl group having 7 to 50 carbon atoms, a substituted or unsubstituted heterocyclic group having 5 to 50 ring atoms, a dibenzofuran-1-yl group, a dibenzofuran-2-ylgroup, a dibenzofuran-3-yl group or a dibenzofuran-4-yl group. Ar⁷ may, together with a benzene ring to which it is bonded, form a substituted or unsubstituted fluorenyl group or a substituted or unsubstituted dibenzofluorenyl group. When b is an integer of 2 or more, a plurality of R¹¹s may be the same or different.

In addition to the above-mentioned anthracene derivative shown by the formulas (2-4) and (2-5), an anthracene derivative in which Ar¹¹ is a substituted or unsubstituted fluoranthenyl group and Ar¹² is a substituted or unsubstituted phenyl group in the formula (2) is also preferable.

### (Anthracene Derivative (C))

The anthracene derivative is shown by the following formula (2-6), and it is preferred that it be a derivative shown by any of the formulas (2-6-1), (2-6-2) and (2-6-3).

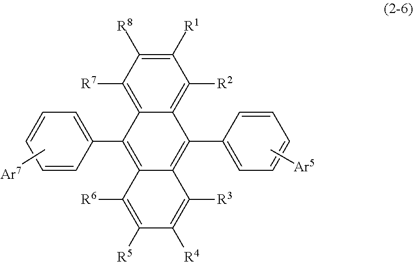

In the formula (2-6), R¹ to R⁸ and Ar⁶ are as mentioned above,

Ar⁵ is a substituted or unsubstituted aryl group having 6 to 50 ring carbon atoms, a substituted or unsubstituted alkyl group having 1 to 50 ring carbon atoms, a substituted or unsubstituted cycloalkyl group having 3 to 50 ring carbon atoms, a substituted or unsubstituted aralkyl group having 7 to 50 carbon atoms or a substituted or unsubstituted heterocyclic group having 5 to 50 ring atoms, and Ar⁵ and Ar⁸ are independently selected.

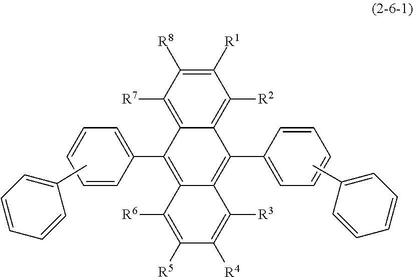

In the formula (2-6-1), R¹ to R⁸ are as defined above.

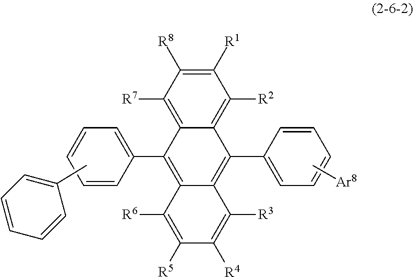

In the formula (2-6-2), R¹ to R⁸ are as defined above. Ar⁸ is a substituted or unsubstituted fused aryl group having 10 to 20 ring carbon atoms.

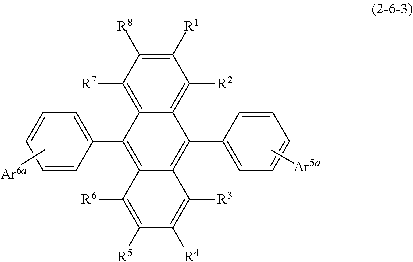

In the formula (2-6-3), R¹ to R⁸ are as defined in the formula (2).

Ar^{5a} and Ar^{6a} are independently a substituted or unsubstituted fused aryl group having 10 to 20 ring carbon atoms.

As the aryl group having 6 to 50 ring carbon atoms shown by R¹ to R⁸, R¹¹, Ar⁵ and Ar⁶, Ar¹¹ and Ar¹², a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 6-chrycenyl group, a 1-benzo[c]phenanthryl group, a 2-benzo[c]phenanthryl group, a 3-benzo[c]phenanthryl group, a 4-benzo[c]phenanthryl group, a 5-benzo[c]phenanthryl group, a 6-benzo[c]phenanthryl group, a 1-benzo[g]chrycenyl group, a 2-benzo[g]chrycenyl group, a 3-benzo[g]chrycenyl group, a 4-benzo[g]chrycenyl group, a 5-benzo[g]chrycenyl group, a 6-benzo[g]chrycenyl group, a 7-benzo[g]chrycenyl group, a 8-benzo[g]chrycenyl group, a 9-benzo[g]chrycenyl group, a 10-benzo[g]chrycenyl group, a 11-benzo[g]chrycenyl group, a 12-benzo[g]chrycenyl group, a 13-benzo[g]chrycenyl group, a 14-benzo[g]chrycenyl group, a 1-triphenyl group, a 2-triphenyl group, a 1-fluorenyl group, a 2-fluorenyl group, a 3-fluorenyl group, a 4-fluorenyl group, a 9-fluorenyl group, a 9,9-dimethylfluorene-2-yl group, a benzofluorenyl group, a dibenzofluorenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group or the like can be given. Of these, an unsubstituted phenyl group, a substituted phenyl group and a substituted or unsubstituted aryl group having 10 to 14 ring carbon atoms (for example, a 1-naphthyl group, a 2-naphthyl group, a 9-phenanthryl group), a substituted or unsubstituted fluorenyl group (a 2-fluorenyl group) and a substituted or unsubstituted pyrenyl group (a 1-pyrenyl group, a 2-pyrenyl group, a 4-pyrenyl group) are preferable. Above-mentioned groups are preferable as the substituted or unsubstituted aryl group having 6 to 50 ring carbon atoms.

Examples of the substituted or unsubstituted fused aryl group having 10 to 20 ring carbon atoms of Ar^{5a}, Ar^{6a} and Ar⁸ include 1-naphthyl, 2-naphthyl, 1-anthryl, 2-anthryl, 9-anthryl, 1-phenanthryl, 2-phenanthryl, 3-phenanthryl, 4-phenanthryl, 9-phenanthryl, 1-naphthacenyl, 2-naphthacenyl, 9-naphthacenyl, 1-pyrenyl, 2-pyrenyl, 4-pyrenyl, and 2-fluorenyl. In particular, 1-naphthyl, 2-naphthyl, 9-phenanthryl, pyrenyl (1-pyrenyl, 2-pyrenyl and 4-pyrenyl), and fluorenyl (2-fluorenyl) are preferable. Preferred examples of the substituted or unsubstituted fused aryl group having 10 to 20 ring carbon atoms include the above-mentioned groups.

Examples of the heterocyclic groups having 5 to 50 ring atoms shown by R¹ to R⁸, Ar¹¹, Ar¹², R¹¹ and Ar⁵ to Ar⁷ include 1-pyrrolyl, 2-pyrrolyl, 3-pyrrolyl, pyrazinyl, 2-pyridinyl, 3-pyridinyl, 4-pyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 1-dibenzofuranyl, 2-dibenzofuranayl, 3-dibenzofuranyl, 4-dibenzofuranyl, 1-dibenzothiophenyl, 2-dibenzothiophenyl, 3-dibenzothiophenyl, 4-dibenzothiophenyl, quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, 1-phenanthrydinyl, 2-phenanthrydinyl, 3-phenanthrydinyl, 4-phenanthrydinyl, 6-phenanthrydinyl, 7-phenanthrydinyl, 8-phenanthrydinyl, 9-phenanthrydinyl, 10-phenanthrydinyl, 1-acrydinyl, 2-acrydinyl, 3-acrydinyl, 4-acrydinyl, 9-acrydinyl, 1,7-phenanthroline-2-yl, 1,7-phenanthroline-3-yl, 1,7-phenanthroline-4-yl, 1,7-phenanthroline-5-yl, 1,7-phenanthroline-6-yl, 1,7-phenanthroline-8-yl, 1,7-phenanthroline-9-yl, 1,7-phenanthroline-10-yl, 1,8-phenanthroline-2-yl, 1,8-phenanthroline-3-yl, 1,8-phenanthroline-4-yl, 1,8-phenanthroline-5-yl, 1,8-phenanthroline-6-yl, 1,8-phenanthroline-7-yl, 1,8-phenanthroline-9-yl, 1,8-phenanthroline-10-yl, 1,9-phenanthroline-2-yl, 1,9-phenanthroline-3-yl, 1,9-phenanthroline-4-yl, 1,9-phenanthroline-5-yl, 1,9-phenanthroline-6-yl, 1,9-phenanthroline-7-yl, 1,9-phenanthroline-8-yl, 1,9-phenanthroline-10-yl, 1,10-phenanthroline-2-yl, 1,10-phenanthroline-3-yl, 1,10-phenanthroline-4-yl, 1,10-phenanthroline-5-yl, 2,9-phenanthroline-1-yl, 2,9-phenanthroline-3-yl, 2,9-phenanthroline-4-yl, 2,9-phenanthroline-5-yl, 2,9-phenanthroline-6-yl, 2,9-phenanthroline-7-yl, 2,9-phenanthroline-8-yl, 2,9-phenanthroline-10-yl, 2,8-phenanthroline-1-yl, 2,8-phenanthroline-3-yl, 2,8-phenanthroline-4-yl, 2,8-phenanthroline-5-yl, 2,8-phenanthroline-6-yl, 2,8-phenanthroline-7-yl, 2,8-phenanthroline-9-yl, 2,8-phenanthroline-10-yl, 2,7-phenanthroline-1-yl, 2,7-phenanthroline-3-yl, 2,7-phenanthroline-4-yl, 2,7-phenanthroline-5-yl, 2,7-phenanthroline-6-yl, 2,7-phenanthroline-8-yl, 2,7-phenanthroline-9-yl, 2,7-phenanthroline-10-yl, 1-phenazinyl, 2-phenazinyl, 1-phenothiazinyl, 2-phenothiazinyl, 3-phenothiazinyl, 4-phenothiazinyl, 10-phenothiazinyl, 1-phenoxazinyl, 2-phenoxazinyl, 3-phenoxazinyl, 4-phenoxazinyl, 10-phenoxazinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrole-1-yl, 2-methylpyrrole-3-yl, 2-methylpyrrole-4-yl, 2-methylpyrrole-5-yl, 3-methylpyrrole-1-yl, 3-methylpyrrole-2-yl, 3-methylpyrrole-4-yl, 3-methylpyrrole-5-yl, 2-t-butylpyrrole-4-yl, 3-(2-phenylpropyl)pyrrole-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, and 4-t-butyl-3-indolyl groups. Of these, 1-dibenzofuranayl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-carbozolyl, 2-carbazolyl, 3-carbazolyl, 4-carbazolyl and 9-carbazolyl groups are preferable. As the substituted or unsubstituted heterocyclic group having 5 to 50 ring atoms, the groups mentioned above are preferable.

Examples of the alkyl group having 1 to 50 carbon atoms of R¹ to R⁸, R¹¹ and Ar⁵ to Ar⁷ include methyl, ethyl, propyl, isopropyl, n-butyl, s-butyl, isobutyl, t-butyl, n-pentyl, n-hexyl, n-heptyl, n-octyl, hydroxymethyl, 1-hydroxyethyl, 2-hydroxyethyl, 2-hydroxyisobutyl, 1,2-dihydroxyethyl, 1,3-dihydroxyisopropyl, 2,3-dihydroxy-t-butyl, 1,2,3-trihydroxypropyl, chloromethyl, 1-chloroethyl, 2-chloroethyl, 2-chloroisobutyl, 1,2-dichloroethyl, 1,3-dichloroisopropyl, 2,3-dichloro-t-butyl, 1,2,3-trichloropropyl, bromomethyl, 1-bromoethyl, 2-bromoethyl, 2-bromoisobutyl, 1,2-dibromoethyl, 1,3-dibromoisopropyl, 2,3-dibromo-t-butyl, 1,2,3-tribromopropyl, iodomethyl, 1-iodoethyl, 2-iodoethyl, 2-iodoisobutyl, 1,2-iodoethyl, 1,3-diiodoisopropyl, 2,3-diiodo-t-butyl, 1,2,3-triiodopropyl, aminomethyl, 1-aminoethyl, 2-aminoethyl, 2-aminoisobutyl, 1,2-diaminoethyl, 1,3-diaminoisopropyl, 2,3-diamino-t-butyl, 1,2,3-triaminopropyl, cyanomethyl, 1-cyanoethyl, 2-cyanoethyl, 2-cyanoisobutyl, 1,2-dicyanoethyl, 1,3-dicyanoisopropyl, 2,3-dicyano-t-butyl and 1,2,3-tricyanopropyl, nitromethyl, 1-nitroethyl, 2-nitroethyl, 2-nitroisobutyl, 1,2-dinitroethyl, 1,3-dinitroisopropyl, 2,3-dinitro-t-butyl, 1,2,3-trinitropropyl. Preferred are methyl, ethyl, propyl, isopropyl, n-butyl, s-butyl, isobutyl, and t-butyl. As the substituted or unsubstituted alkyl group having 1 to 50 carbon atoms, the above-mentioned groups are preferable.

Examples of the cycloalkyl group having 3 to 50 ring carbon atoms of R¹ to R⁸, R¹¹ and Ar⁵ to Ar⁷ include cyclopropyl, cyclobutyl, cyclopentyl, cyclohexyl, 4-methylcyclohexyl, 1-adamantyl, 2-adamantyl, 1-norbornyl and 2-norbornyl. Preferred are cyclopentyl and cyclohexyl. As the substituted or unsubstituted cycloalkyl group having 3 to 50 ring carbon atoms, the above-mentioned groups are preferable.

The alkoxy group having 1 to 50 carbon atoms of R¹ to R⁸ and R¹¹ is a group represented by —OZ, wherein Z is selected from the above-mentioned substituted or unsubstituted alkyl groups having 1 to 50 carbon atoms of R¹ to R⁸.

Examples of the aralkyl group having 7 to 50 carbon atoms of R¹ to R⁸, R¹¹ and Ar⁵ to Ar⁷ (thearyl part having 6 to 49 carbon atoms, the alkyl part having 1 to 44 carbon atoms) include benzyl, 1-phenylethyl, 2-phenylethyl, 1-phenylisopropyl, 2-phenylisopropyl, phenyl-t-butyl, α-naphthylmethyl, 1-α-naphthylmethyl, 2-α-naphthylethyl, 1-α-naphthylisopropyl, 2-α-naphthylisopropyl, β-naphthylmethyl, 1-β-naphthylethyl, 2-β-naphthylethyl, 1-β-naphthylisopropyl, 2-β-naphthylisopropyl, 1-pyrrolylmethyl, 2-(1-pyrrolyl)ethyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. As the substituted or unsubstituted aralkyl group having 7 to 50 carbon atoms, the above-mentioned groups are preferable.

The aryloxy group and arylthio group having 6 to 50 ring carbon atoms of R¹ to R⁸ and R¹¹ are each represented by —OY and —SY, wherein Y is selected from the above-mentioned substituted or unsubstituted aryl groups having 6 to 50 ring carbon atoms of R¹ to R⁸.

The alkoxycarbony group (the alkyl part has 1 to 49 carbon atoms) having 2 to 50 carbon atoms of R¹ to R⁸ and R¹¹ are represented —COOZ, wherein Z is selected from the above-mentioned substituted or unsubstituted alkyl groups having 1 to 49 carbon atoms of R¹ to R⁸.

Examples of the substituted silyl group of R¹ to R⁸ and R¹¹ include trimethylsilyl, triethylsilyl, t-butyldimethylsilyl, vinyldimethylsilyl, propyldimethylsilyl, and triphenylsilyl.

These substituents may further have a substituent. Preferred substituents include an aryl group, a heterocylc group, an alkyl group, a cycloalkyl group and a silyl group.

Preferable specific examples of these are as mentioned above.

The term “substituted or unsubstituted” means that these substituents may further have a substituent such as an alkyl group, a cycloalkyl group, an alkoxy group, a cyano group, a silyl group, an aryl group, a heterocyclic ring group, and a halogen atom. The preferable substituents are an alkyl group, a cycloalkyl group, an aryl group, and a heterocyclic ring group, with an aryl group and a heterocyclic ring group being more preferable. The specific examples of these substituents are as mentioned above.

As the halogen atom of R¹ to R⁸ and R¹¹, fluorine, chlorine, bromine, iodine and the like can be given.

The anthracene derivative of the invention is preferably the anthracene derivative in which a substituent consists only of an aryl group and/or a heterocyclic ring group. Most preferable is the anthracene derivative in which a substituent consists only of an aryl group.

The hydrogen atom bonded to the anthracene derivative of the invention may be a deuterium atom.

The specific examples of the anthracene derivative represented by formula (2) of the invention are as follows:

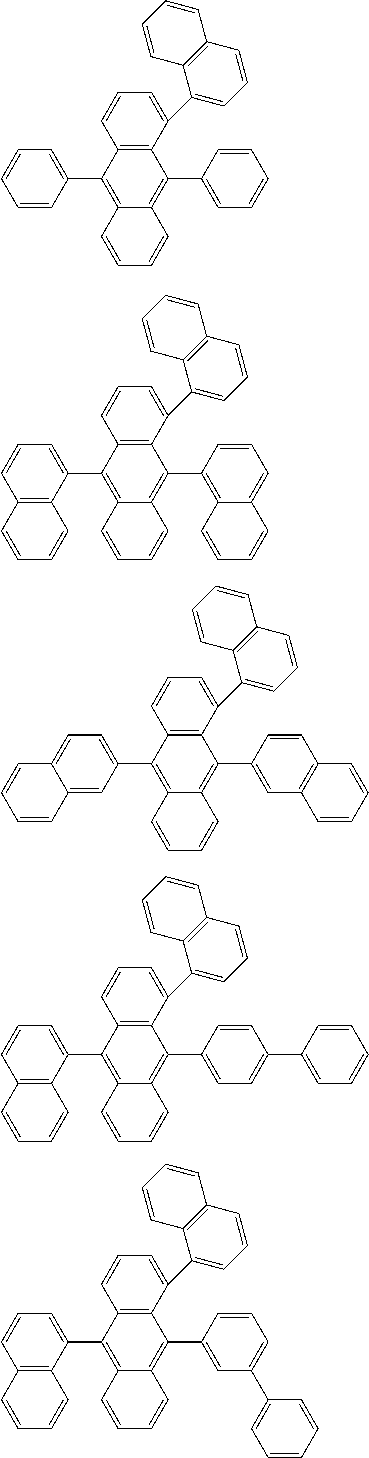

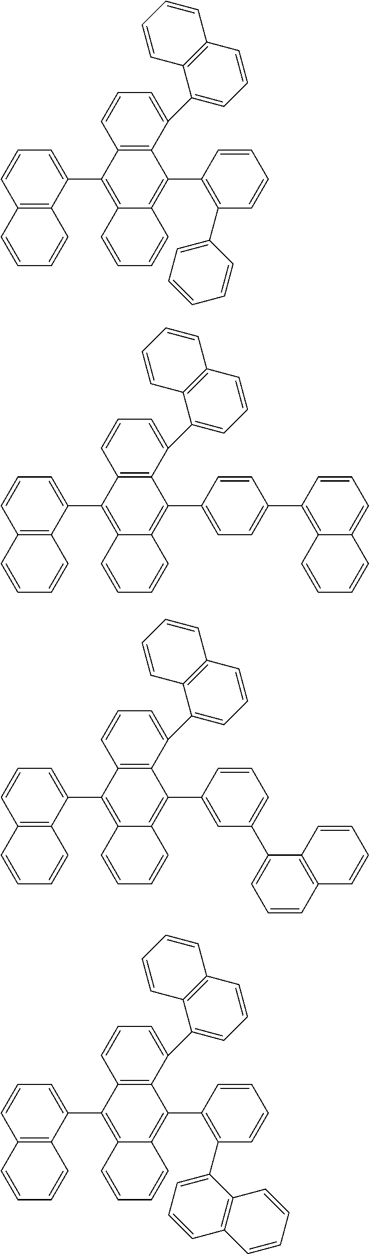

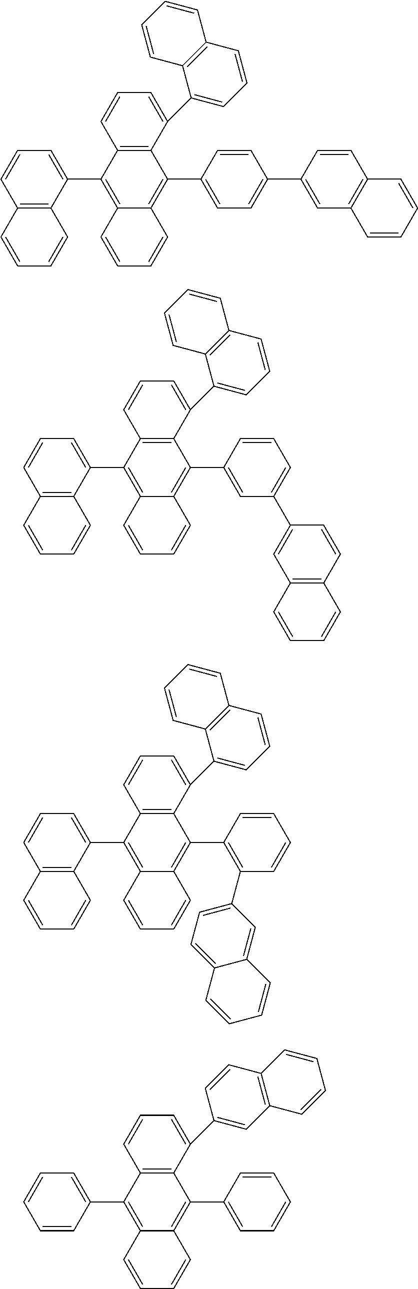

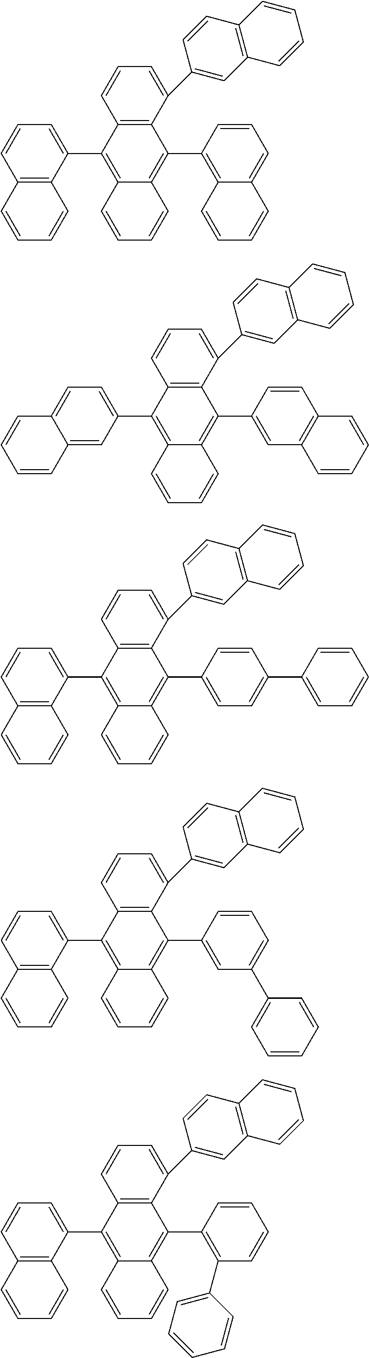

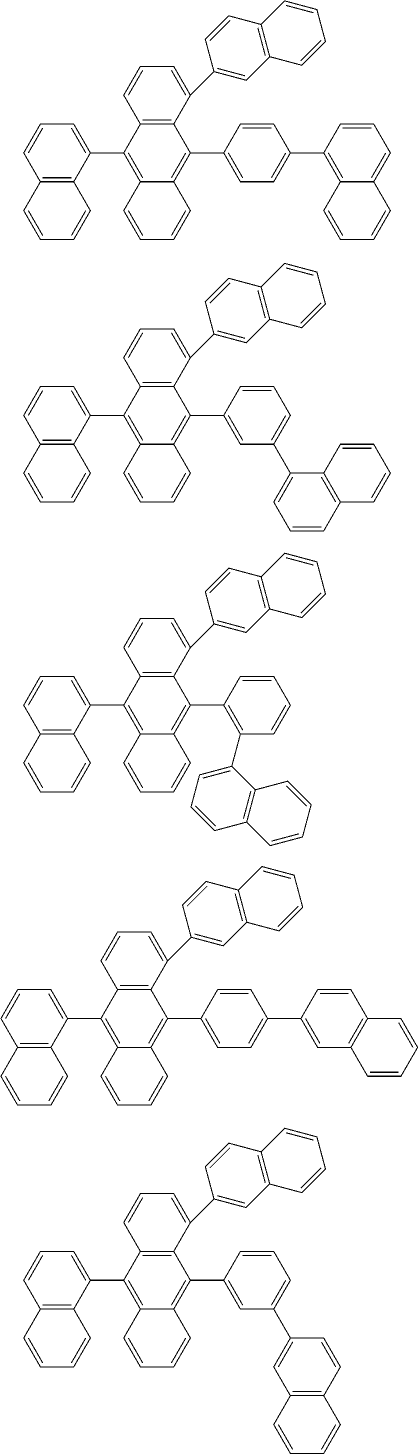

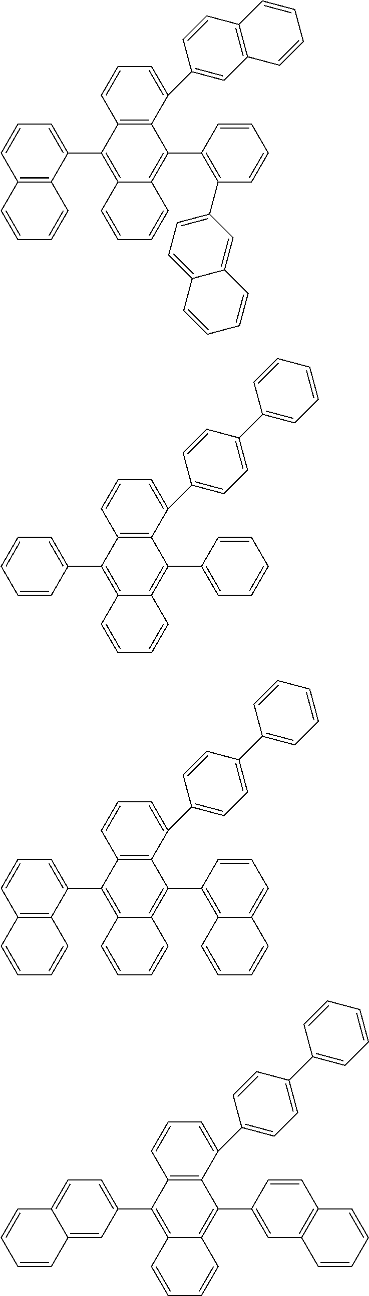

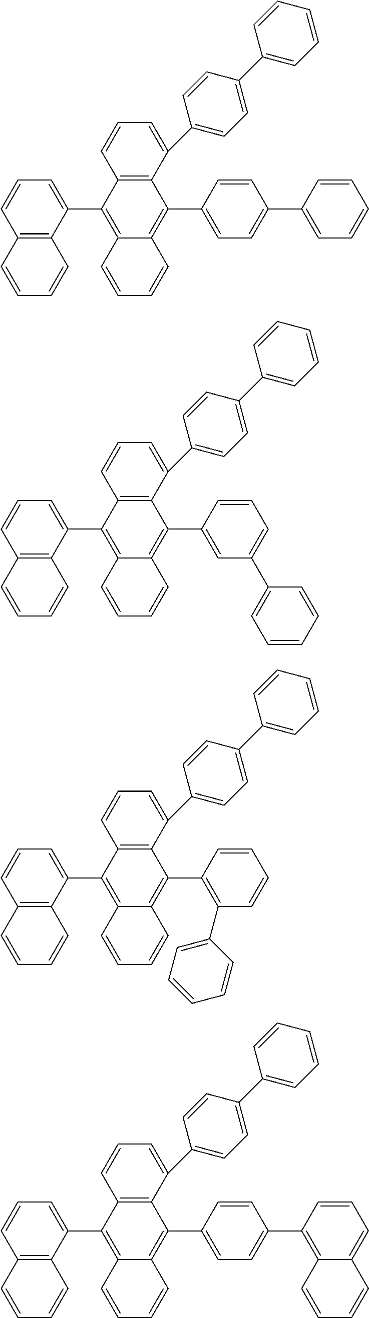

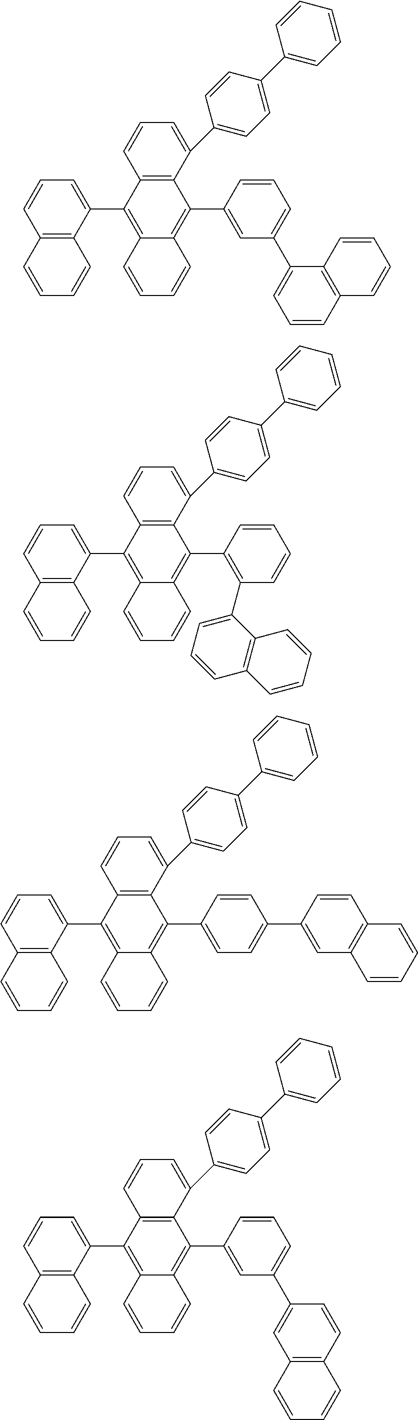

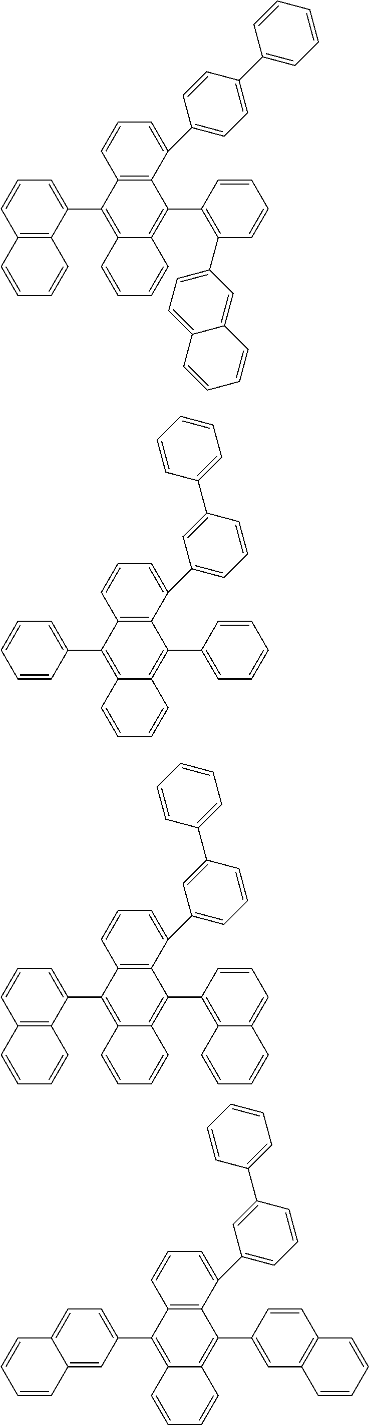

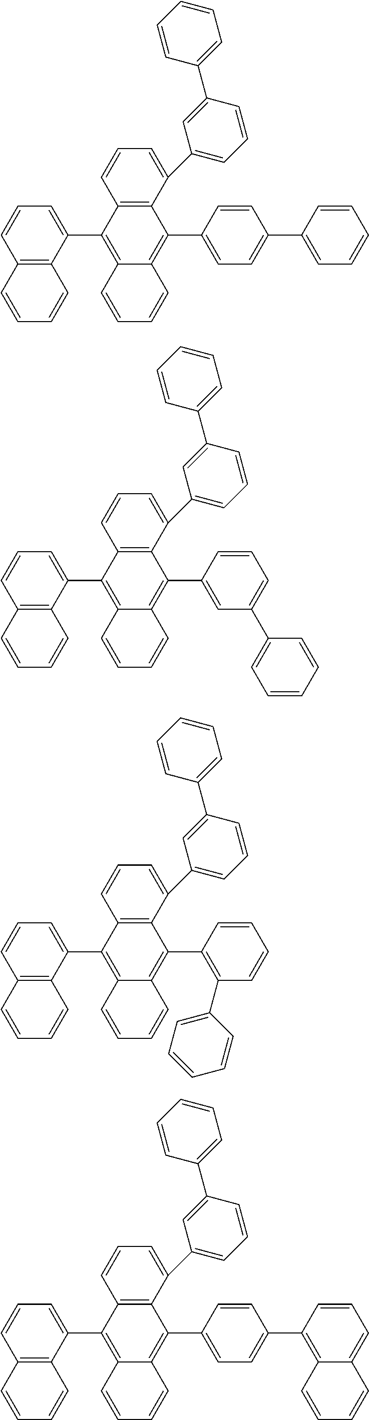

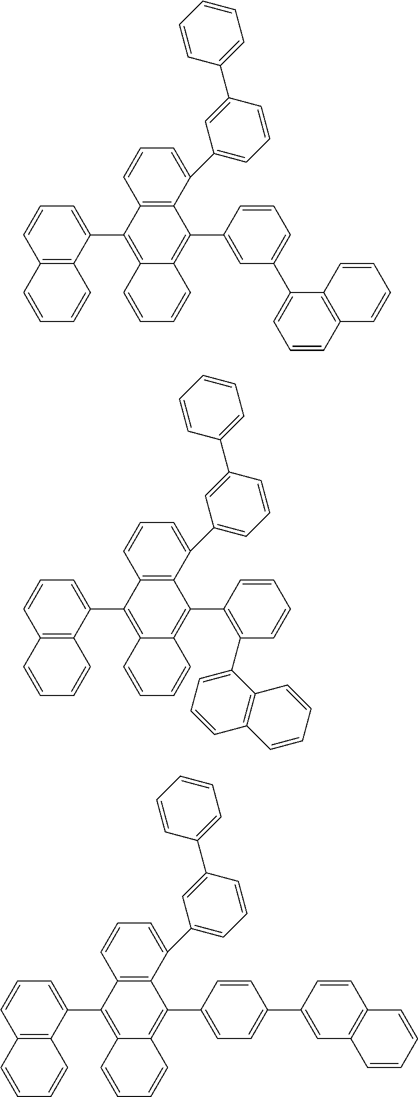

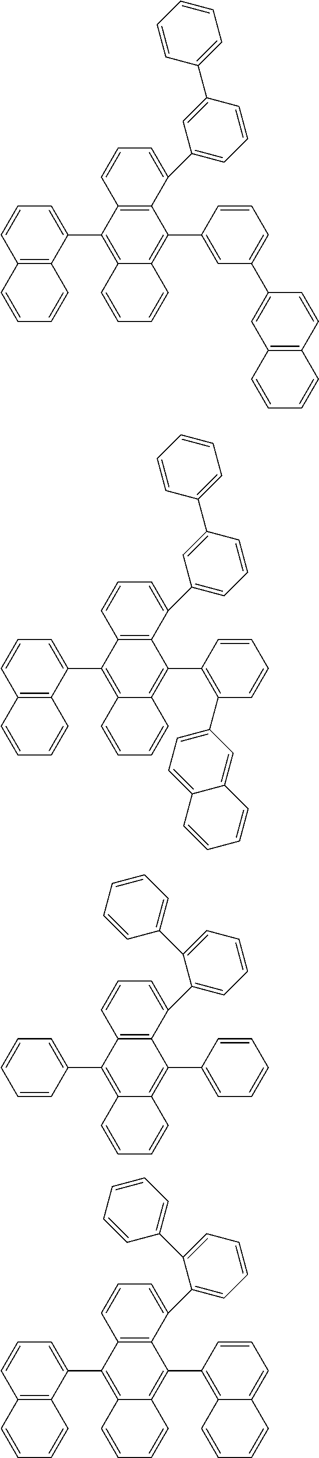

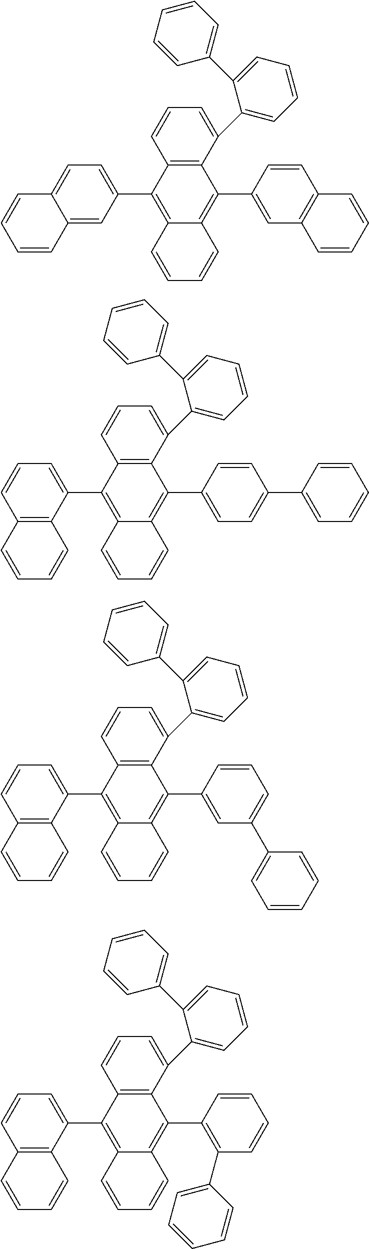

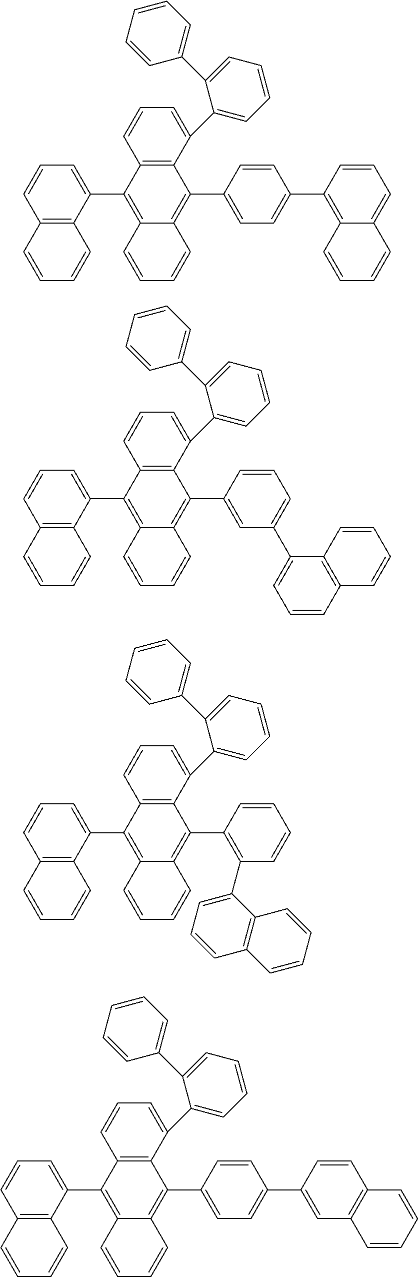

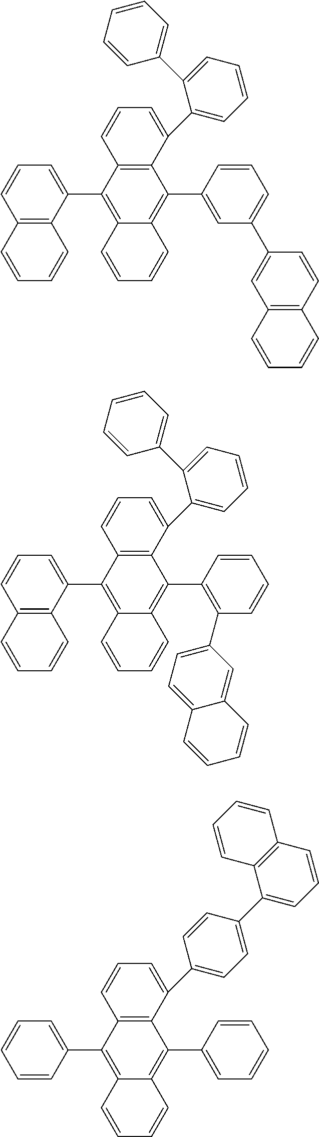

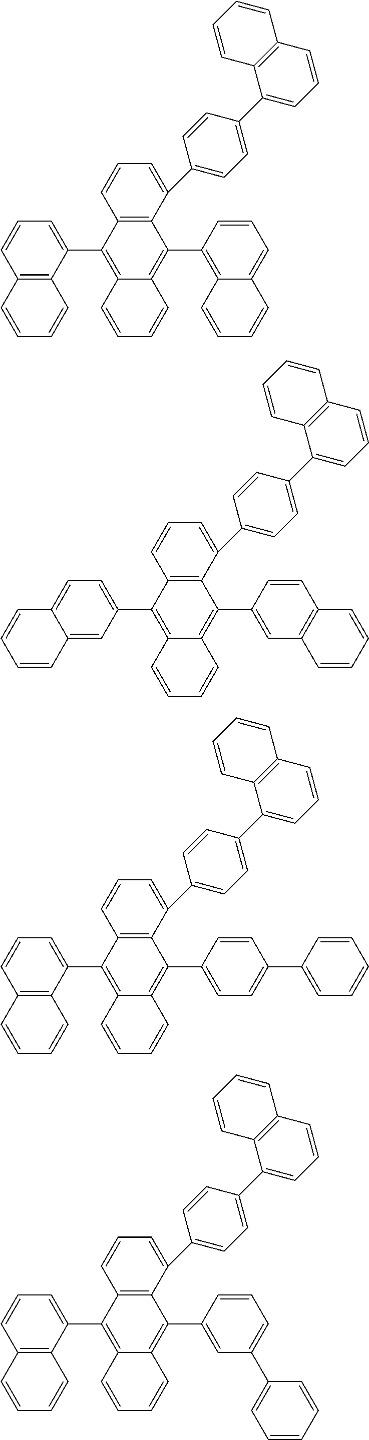

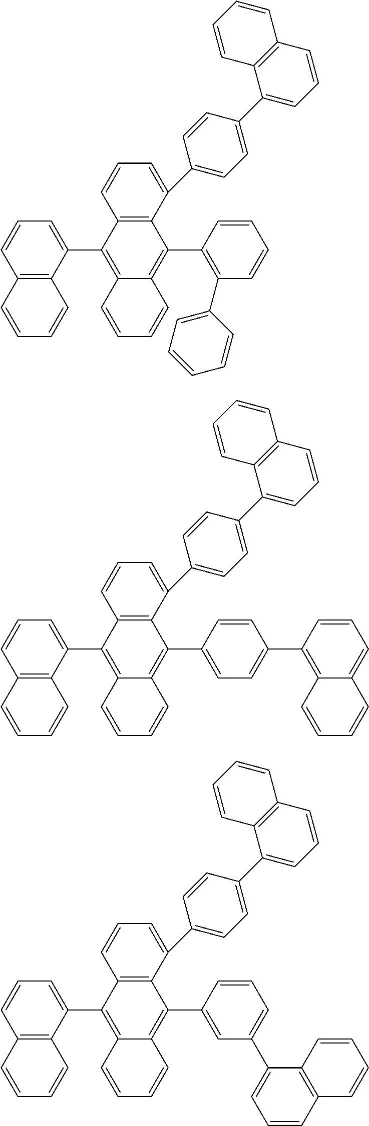

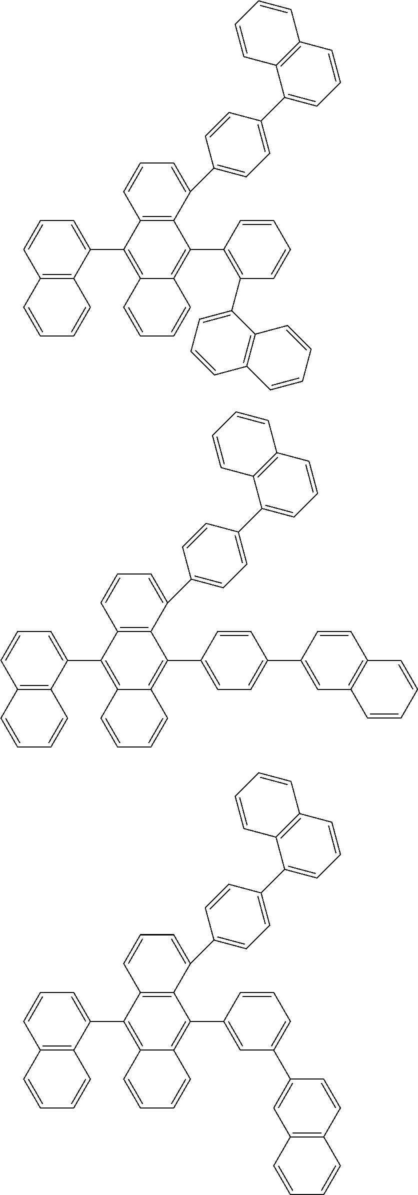

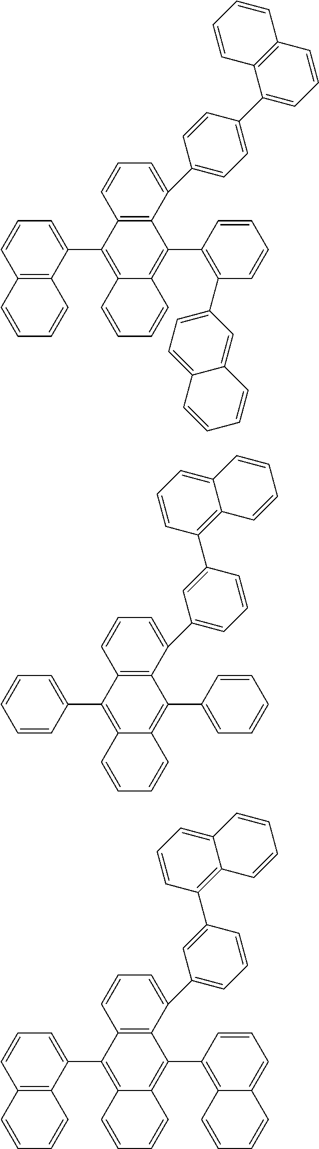

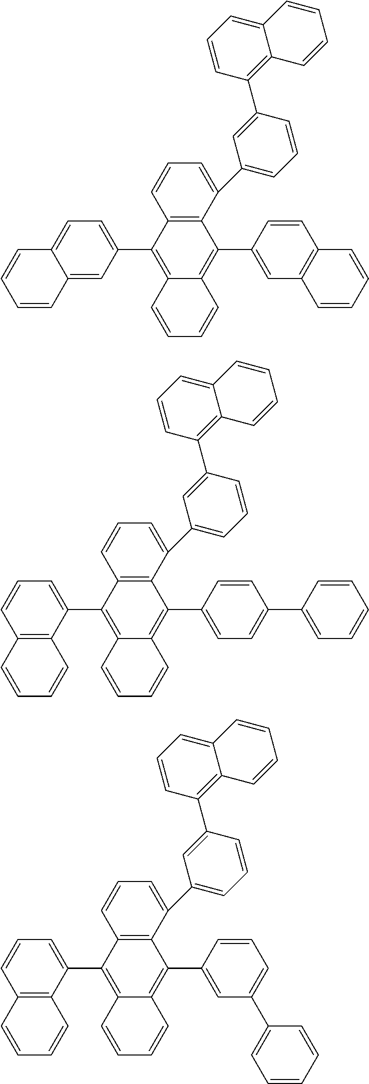

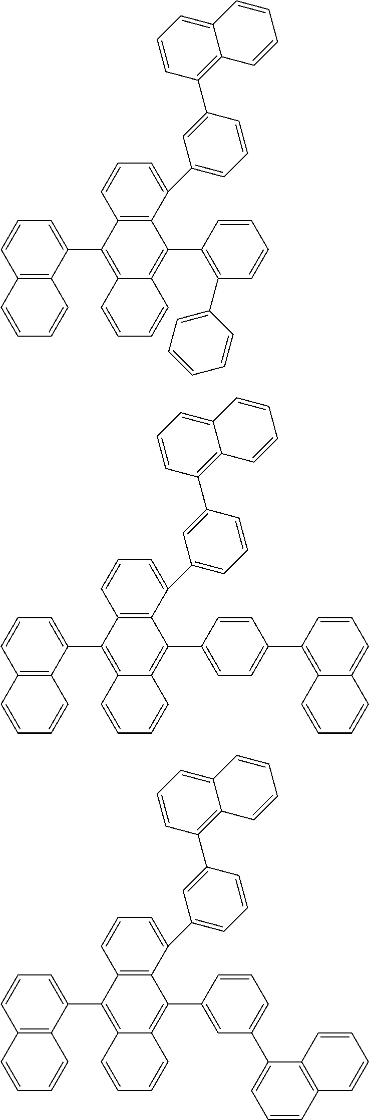

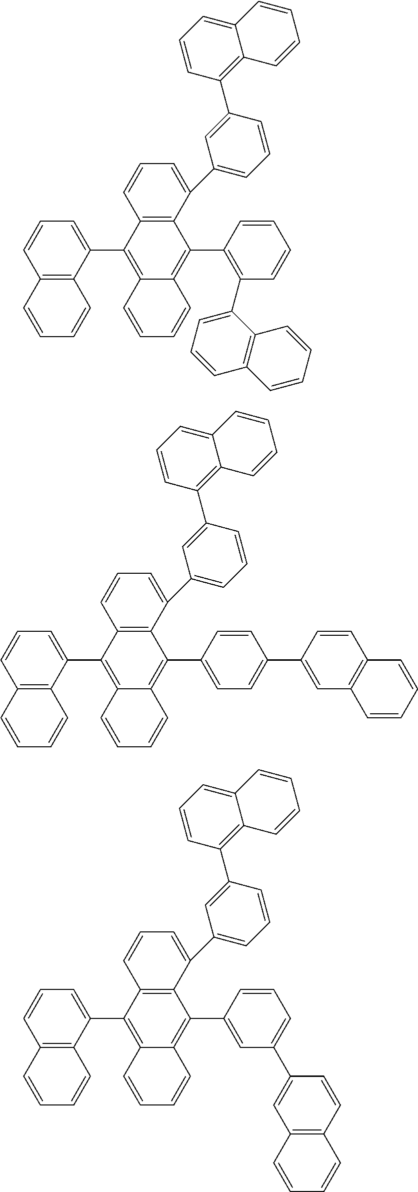

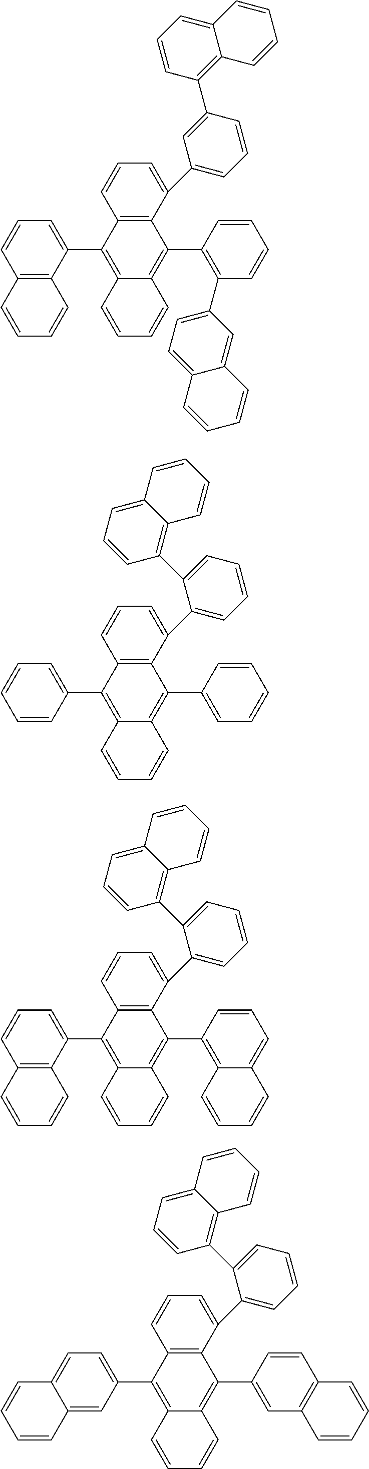

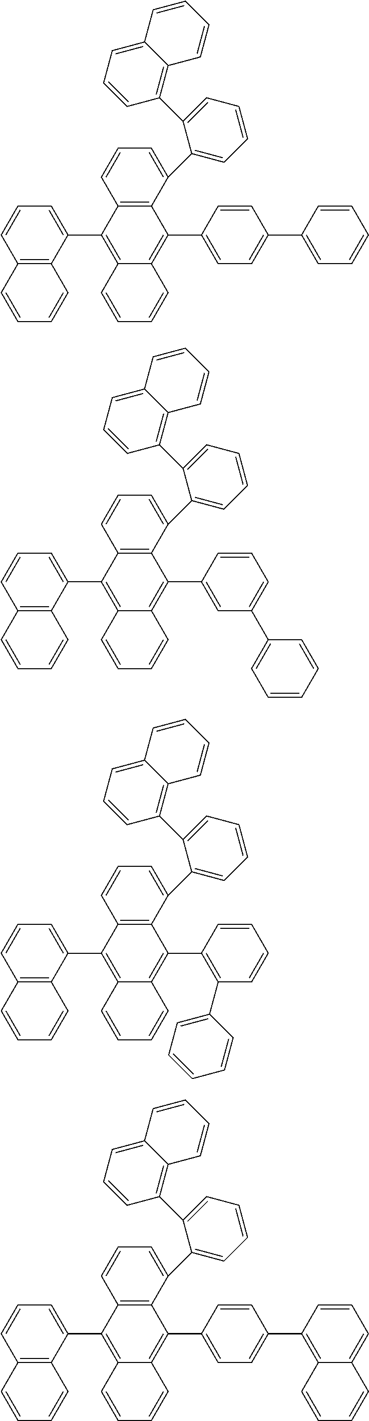

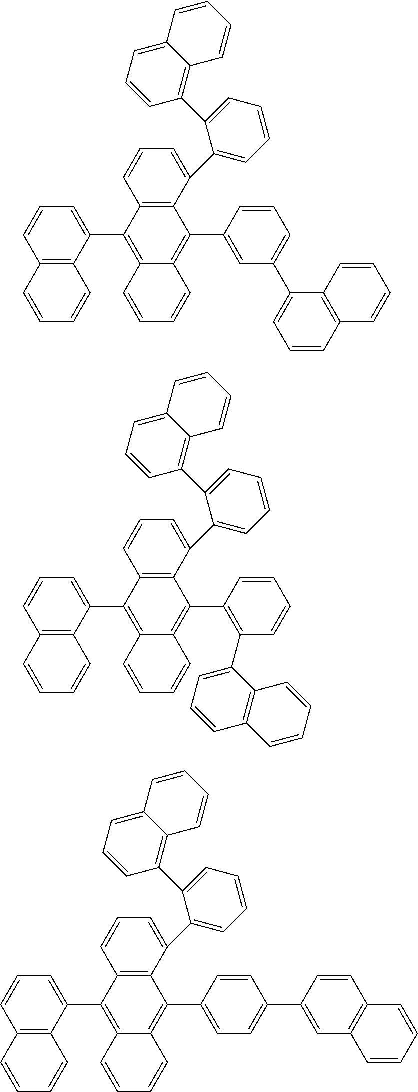

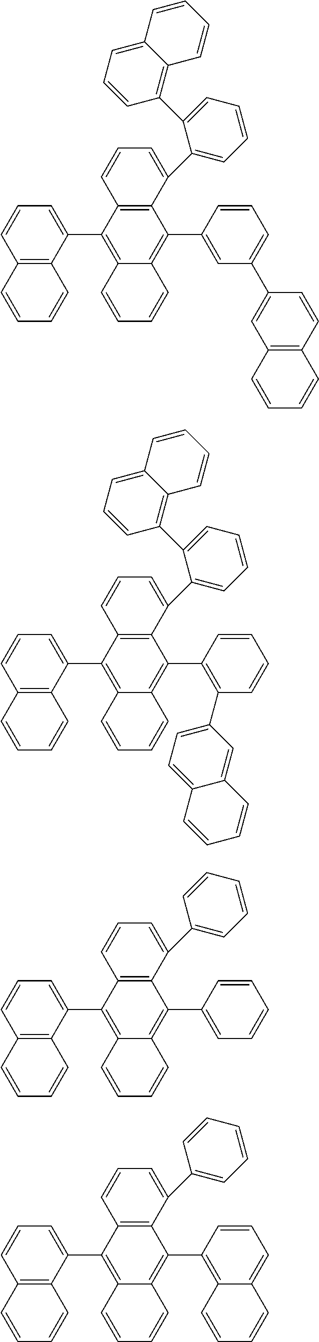

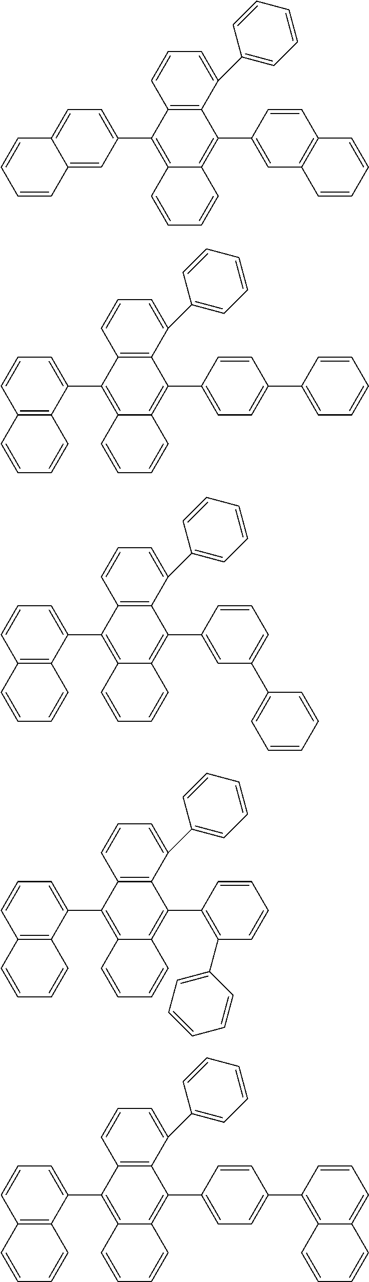

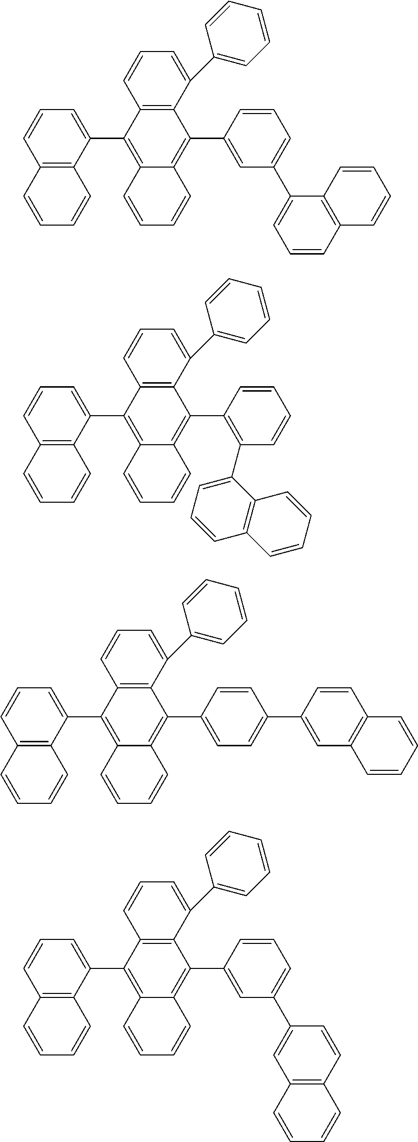

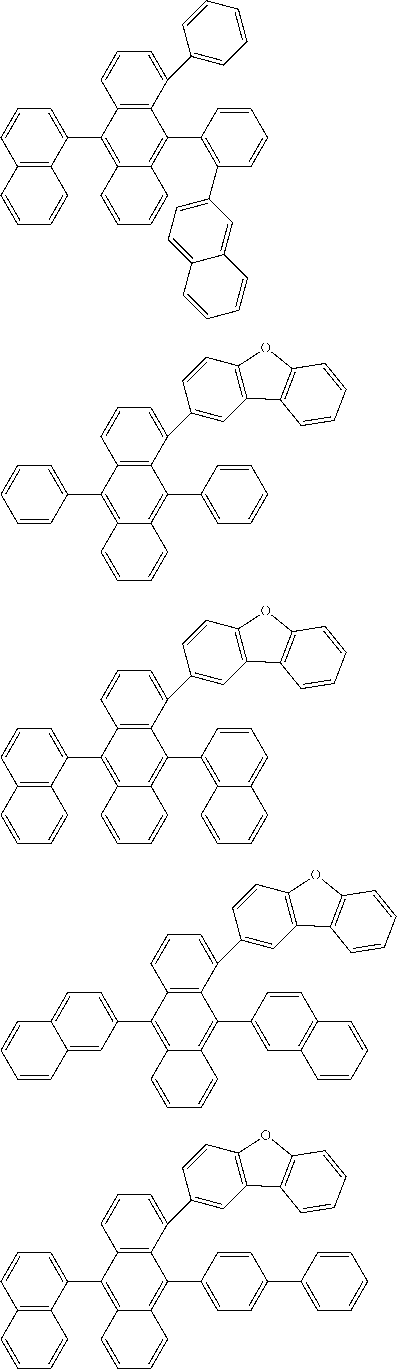

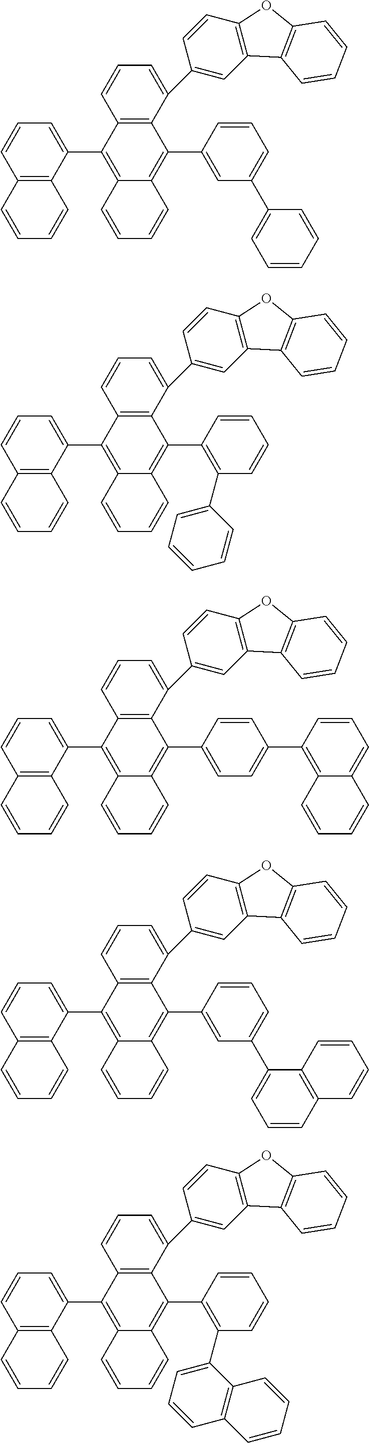

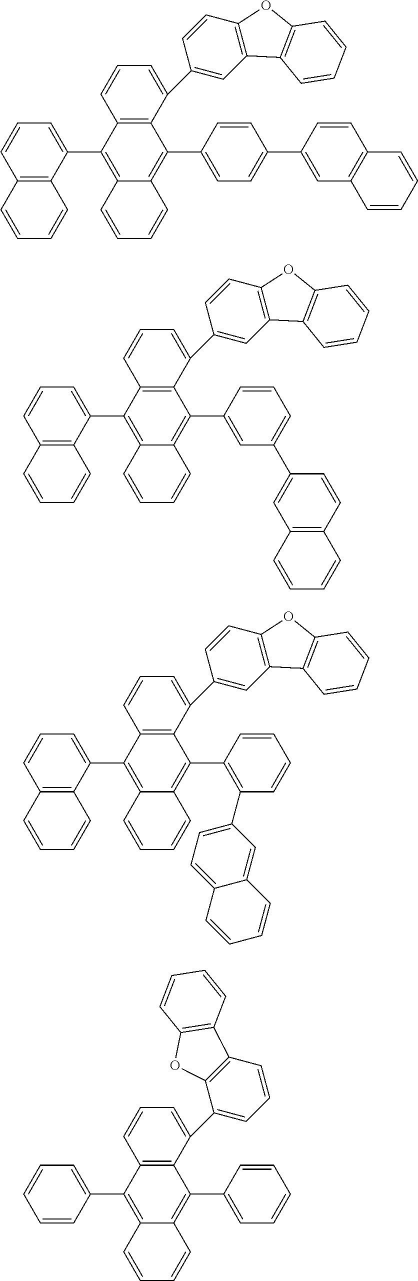

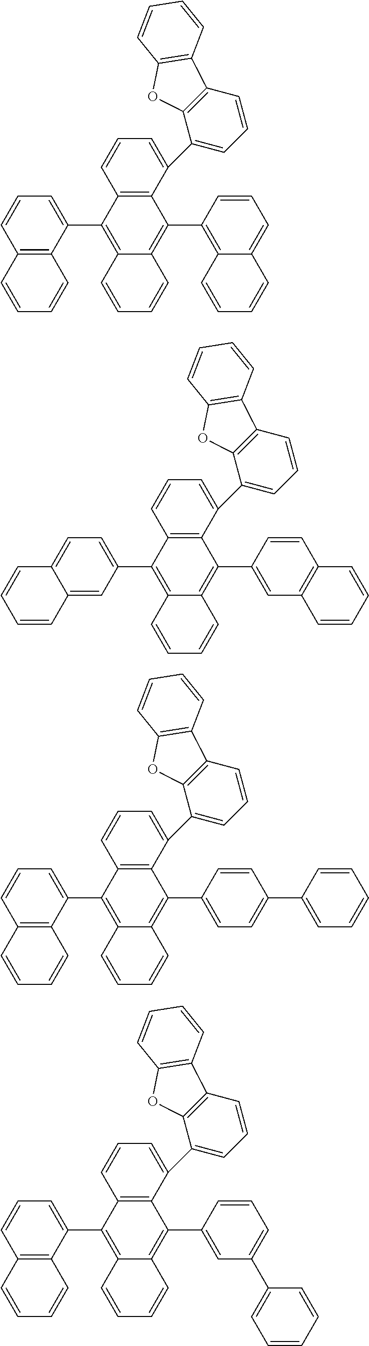

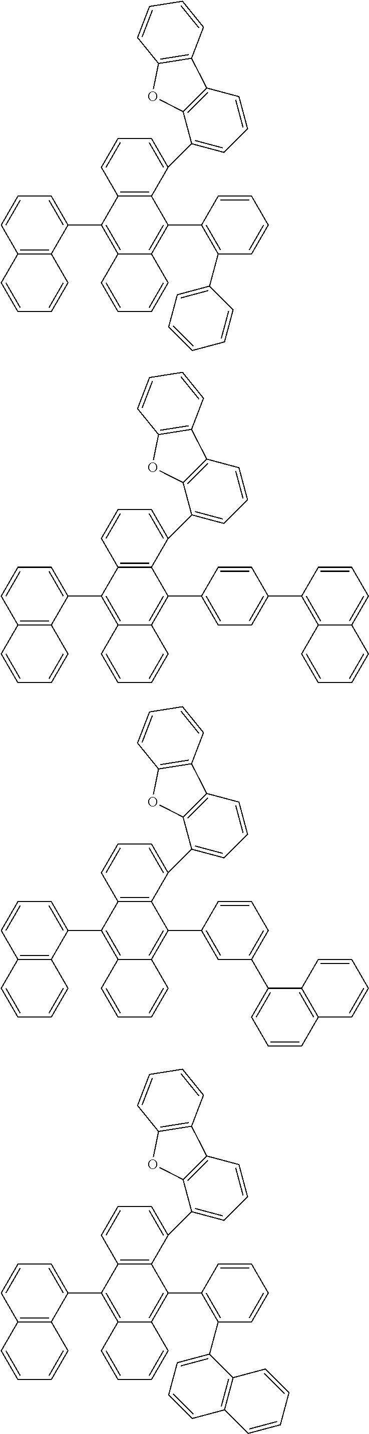

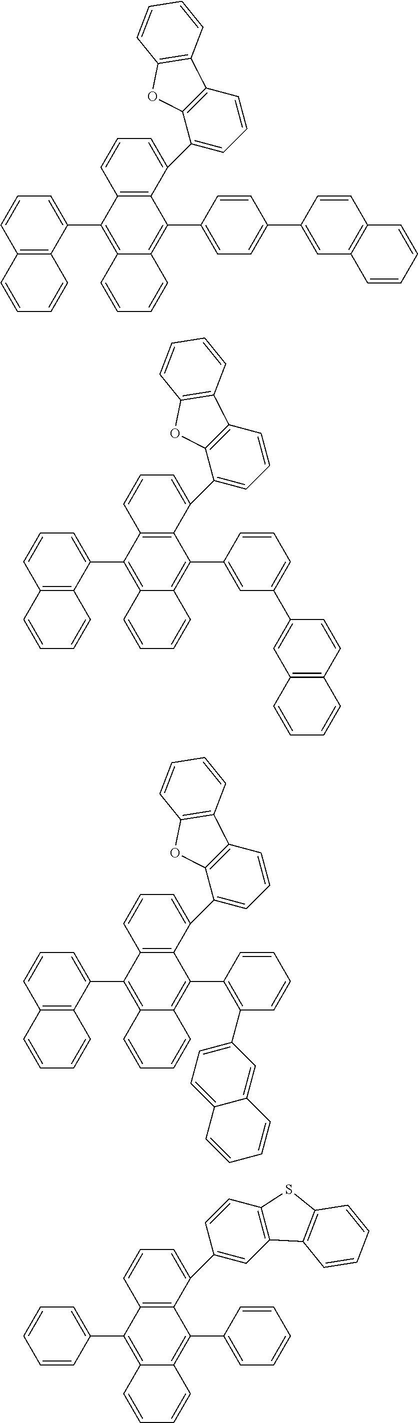

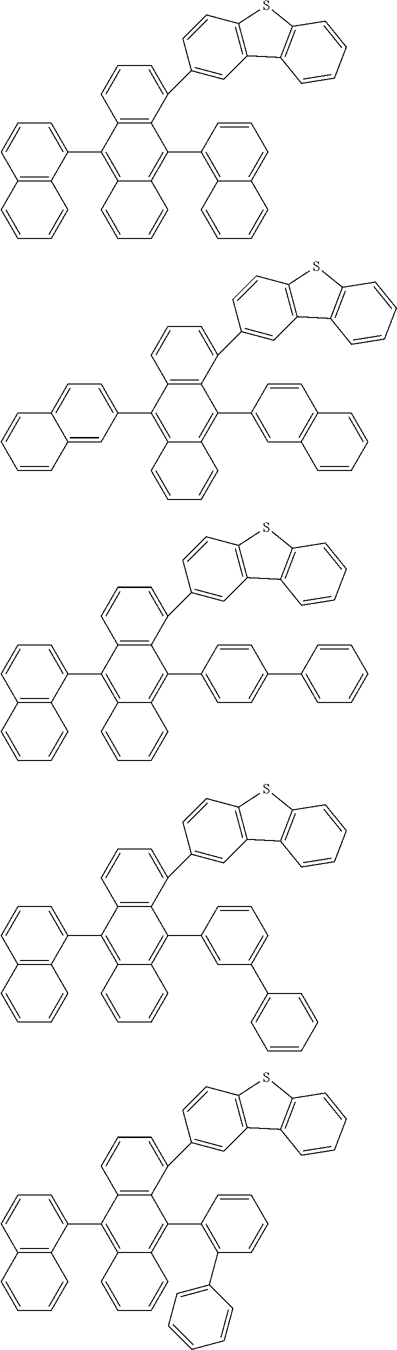

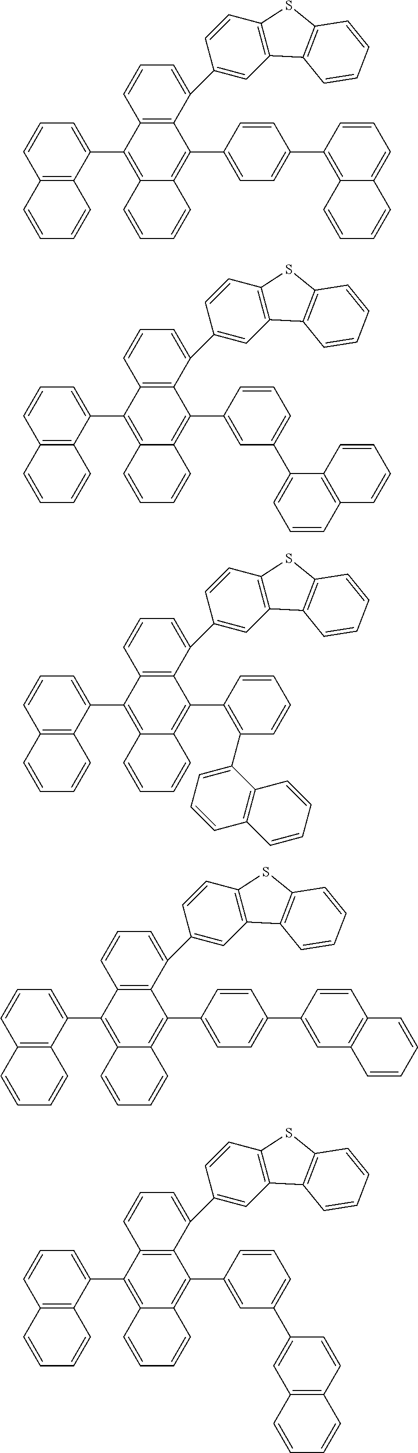

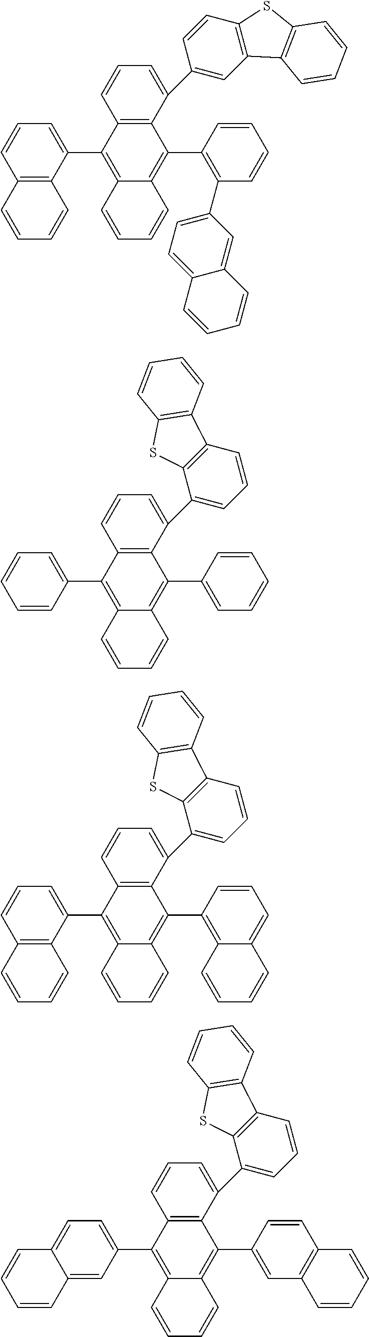

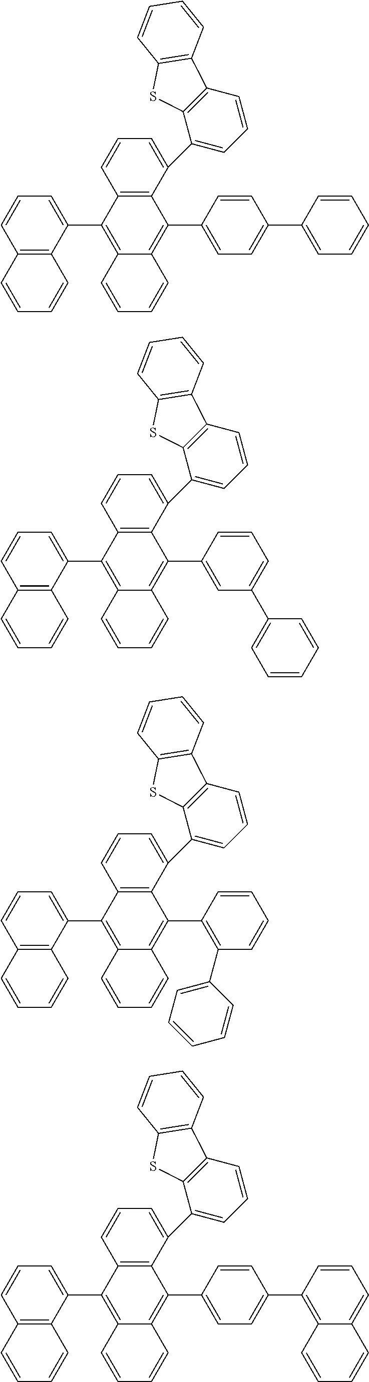

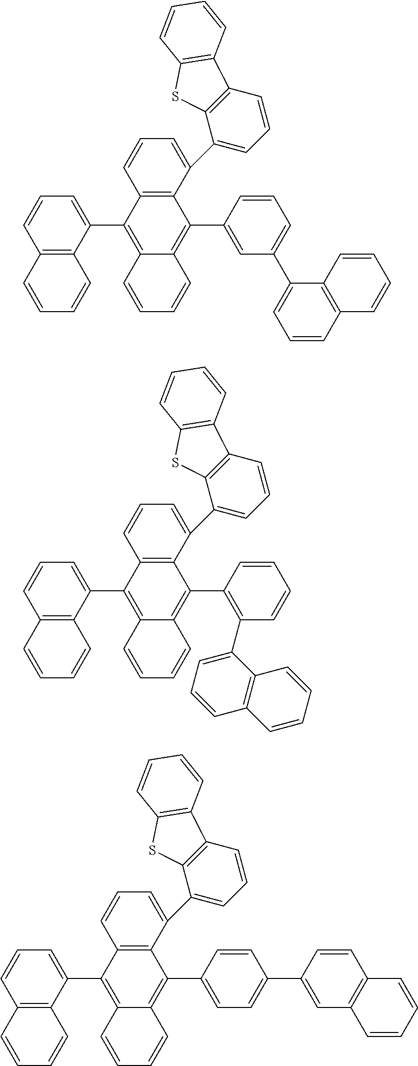

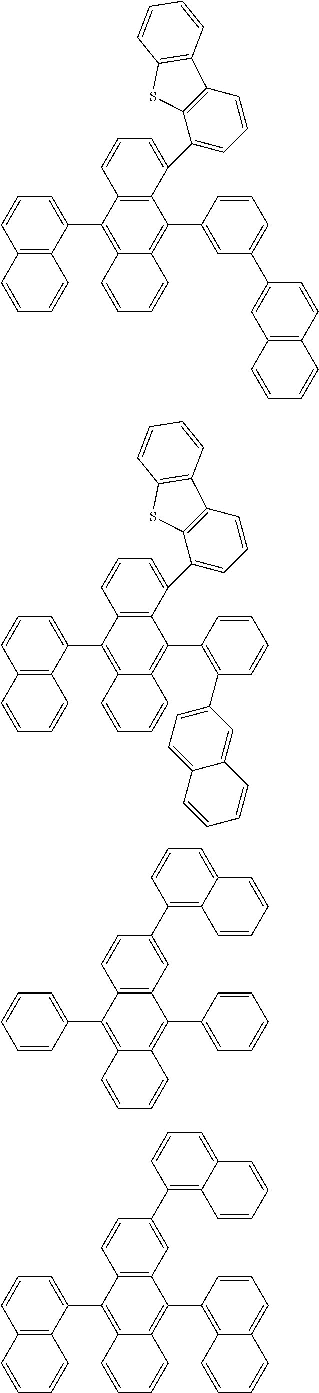

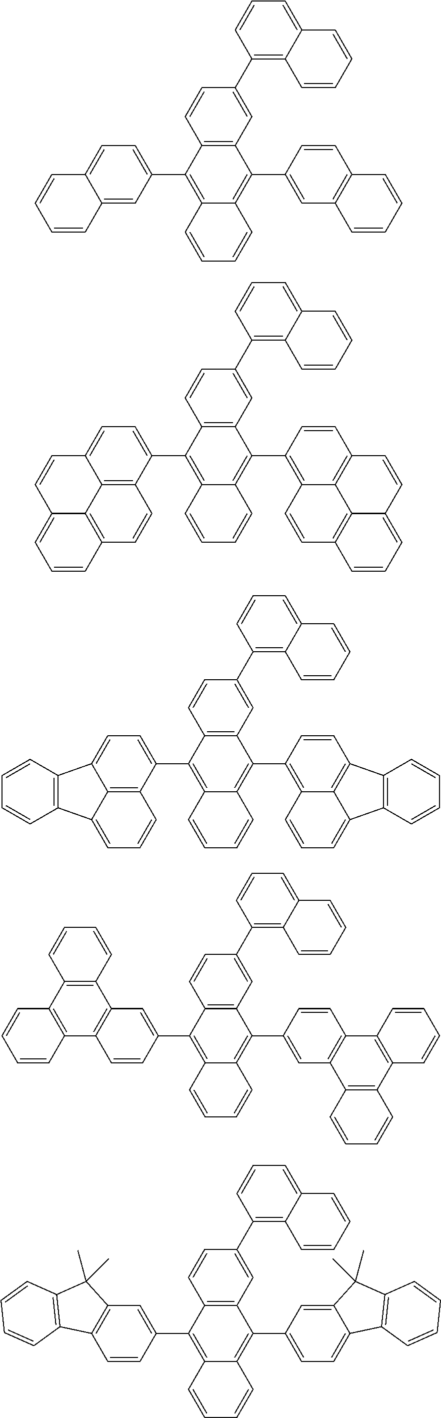

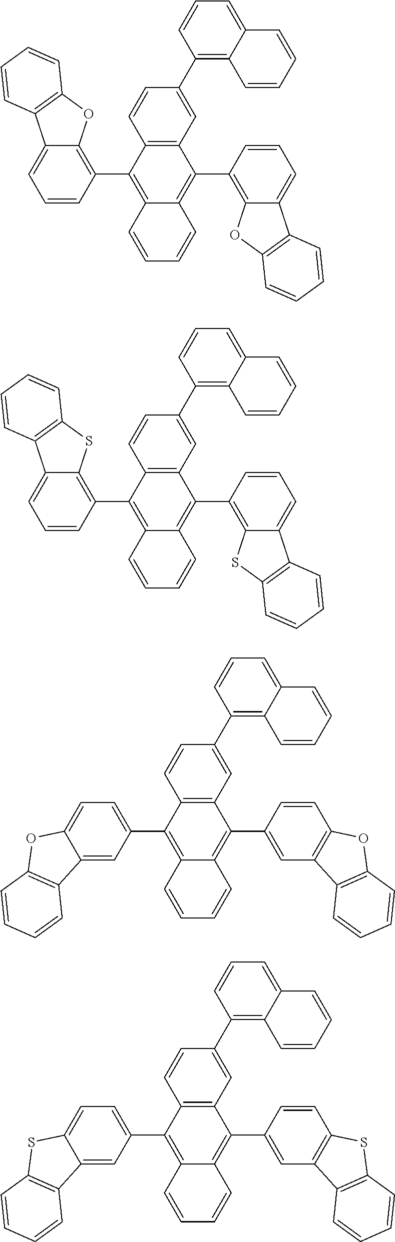

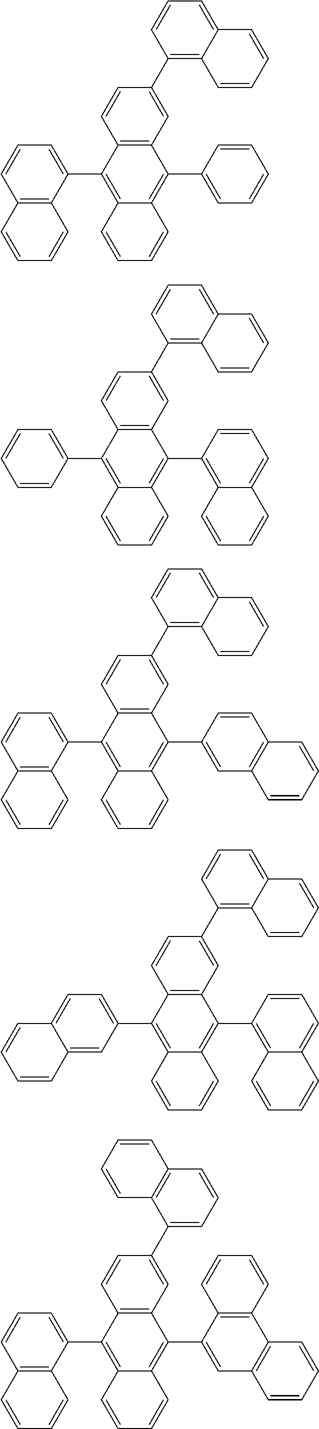

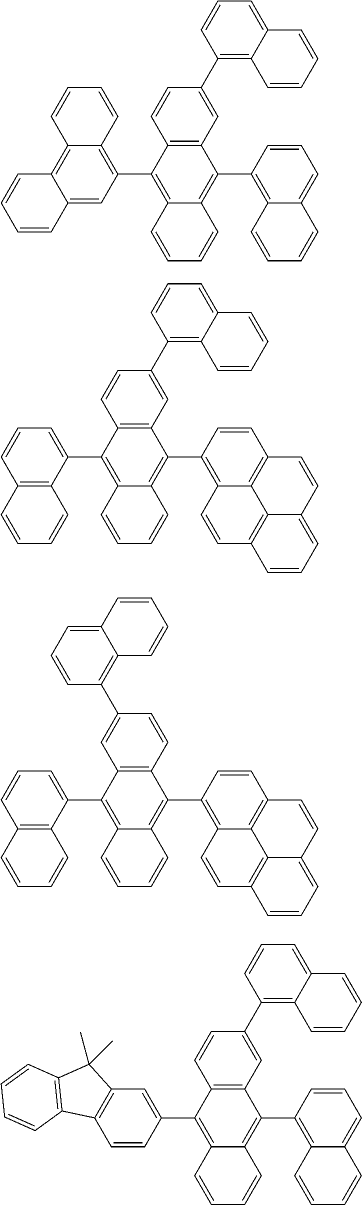

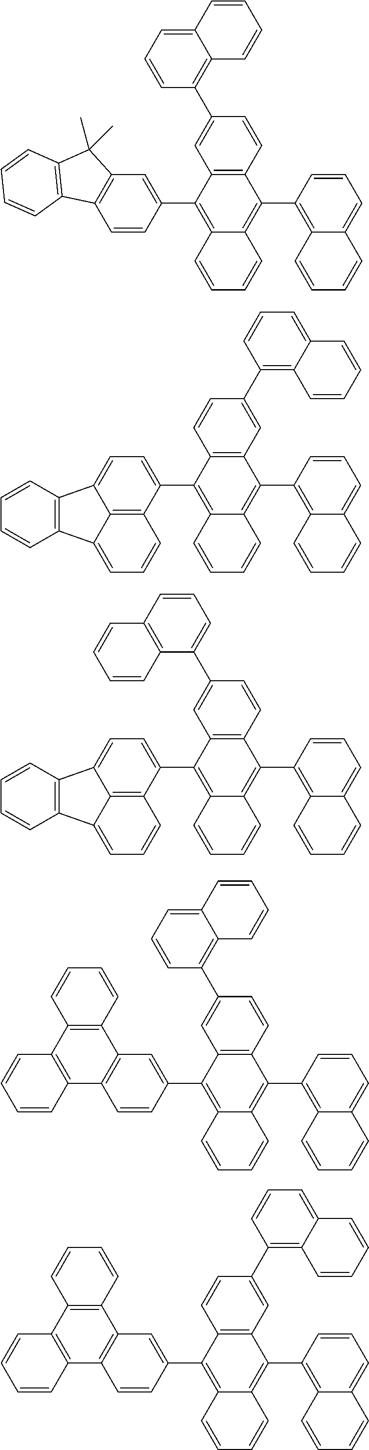

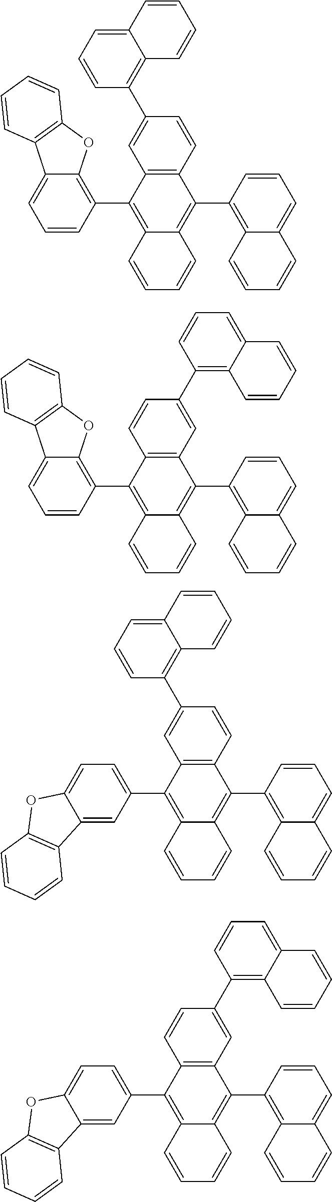

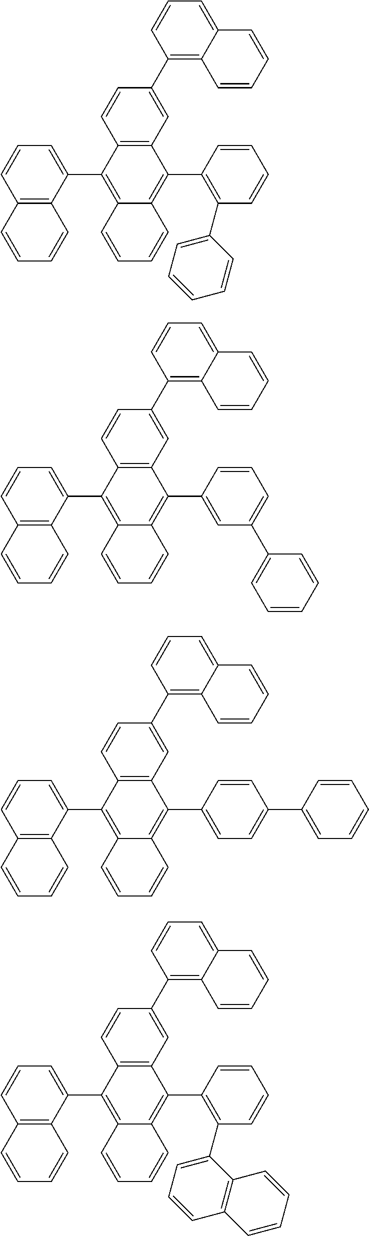

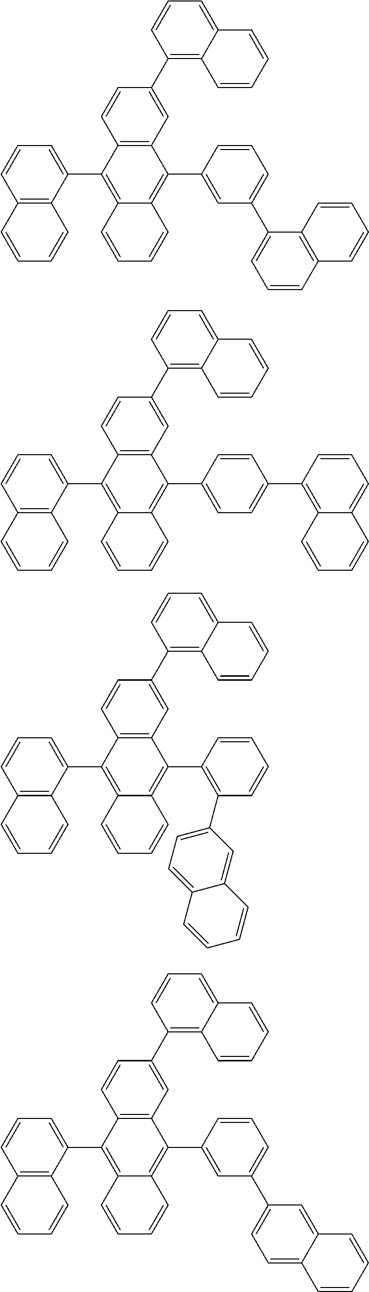

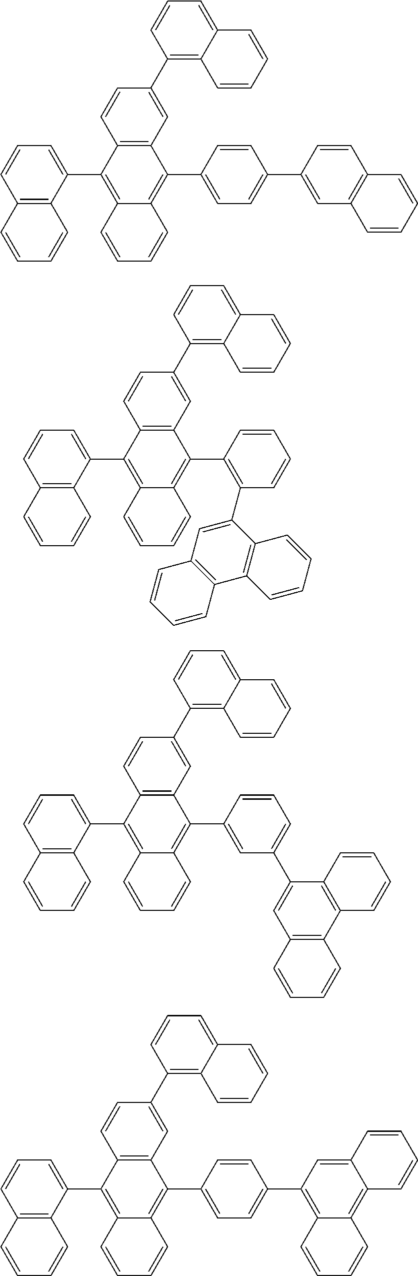

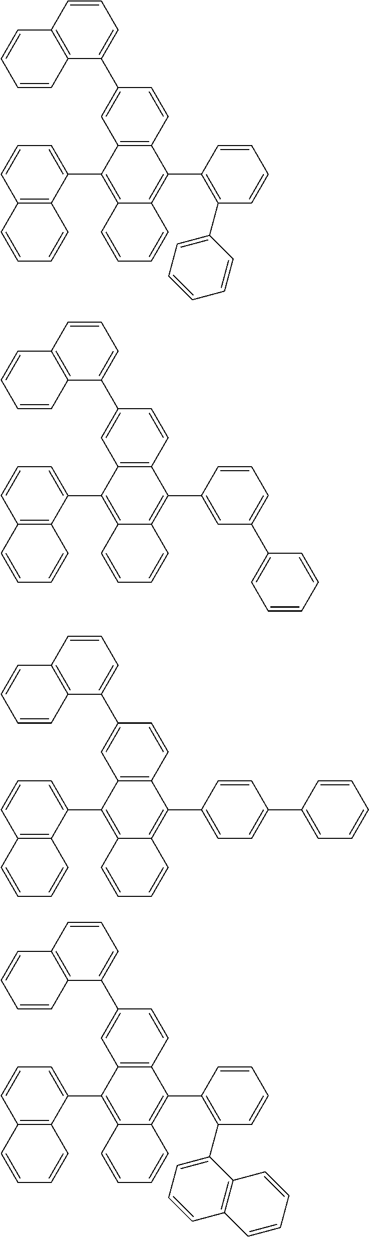

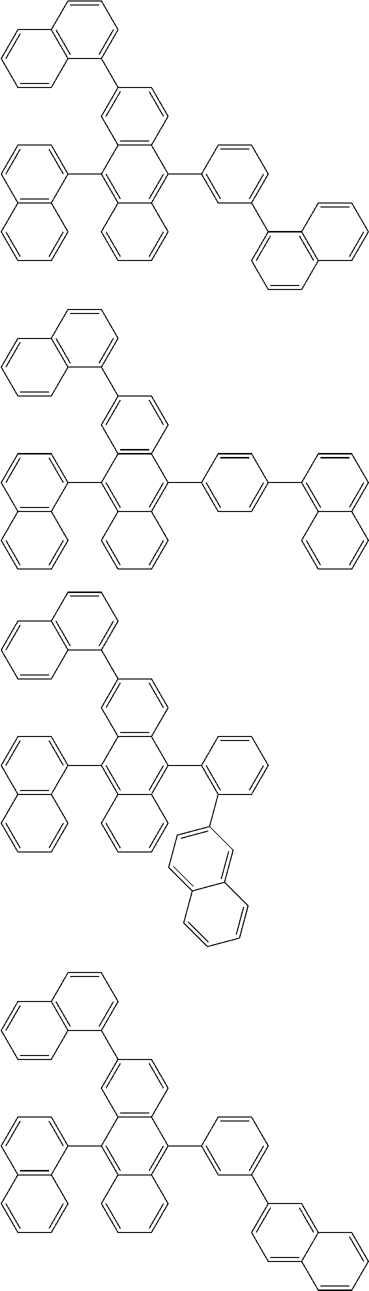

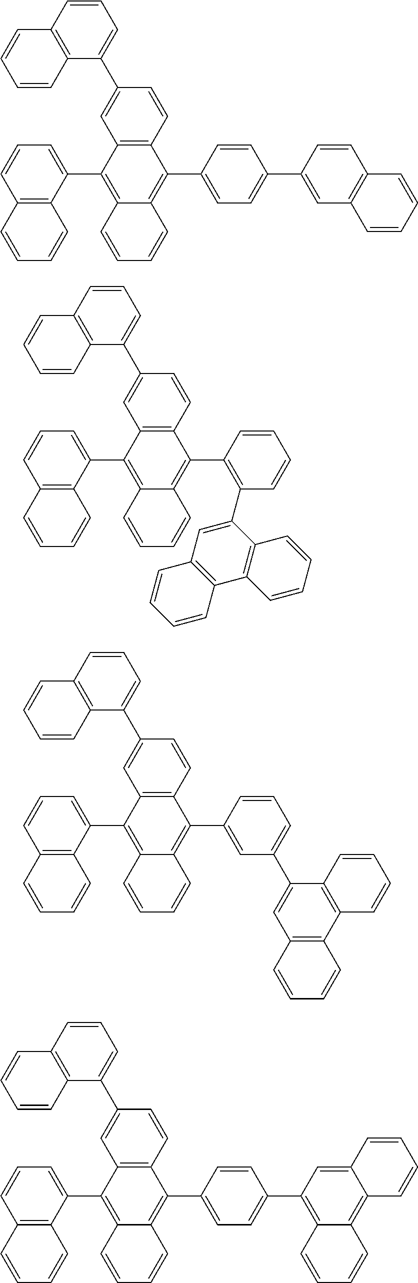

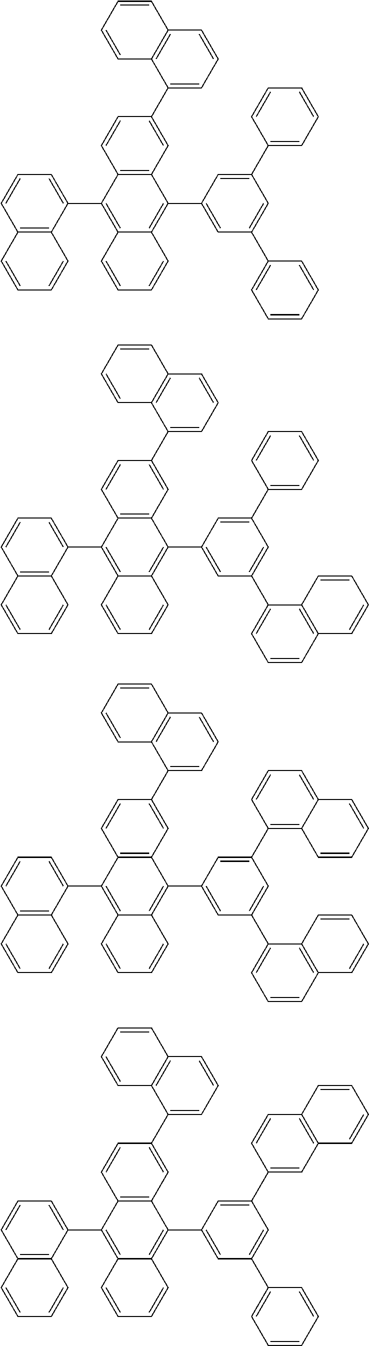

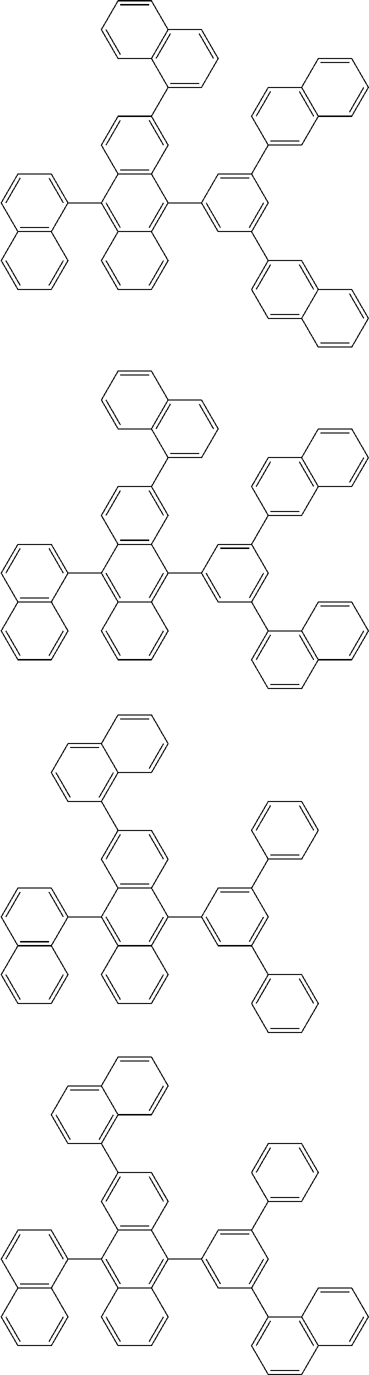

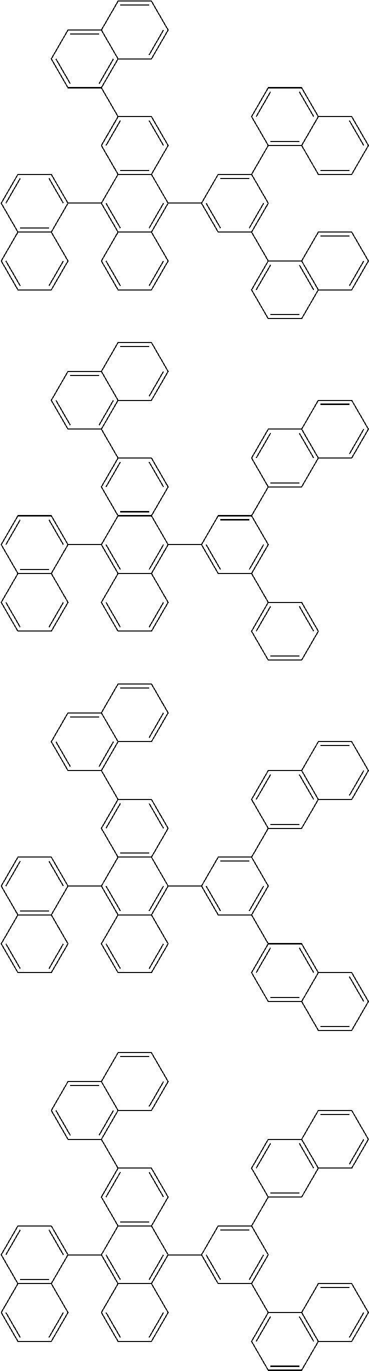

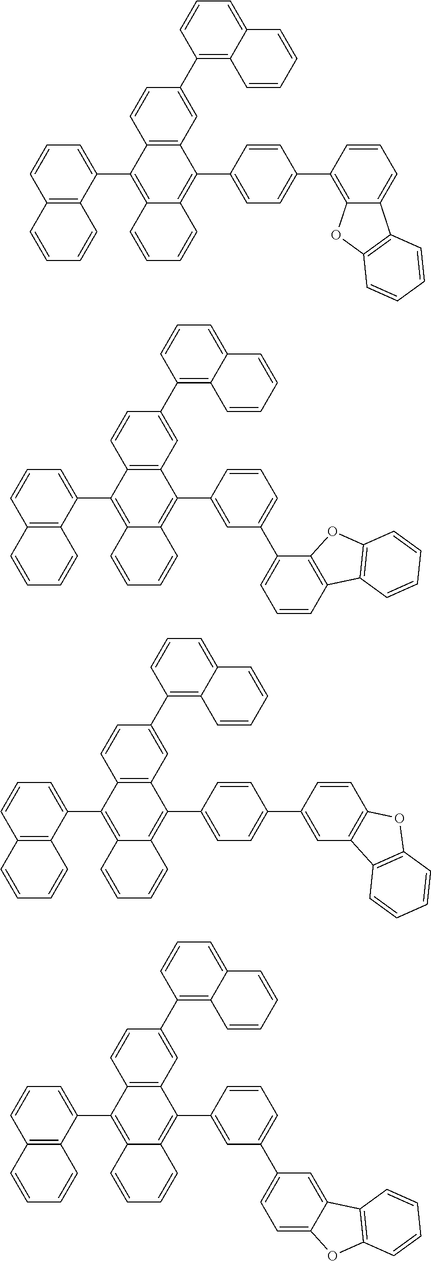

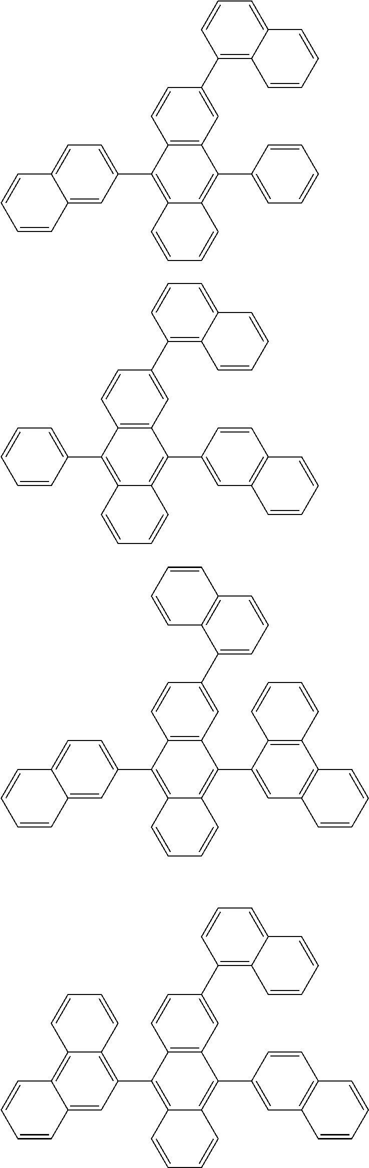

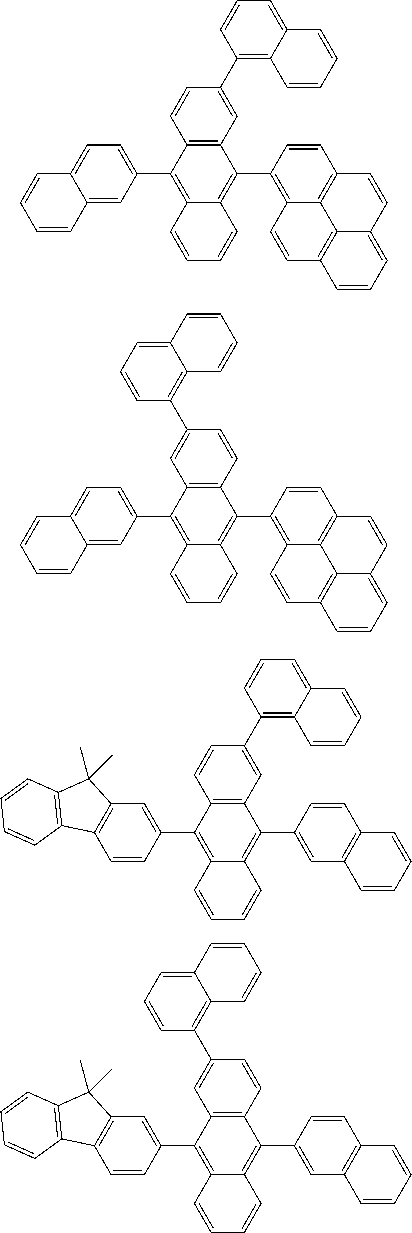

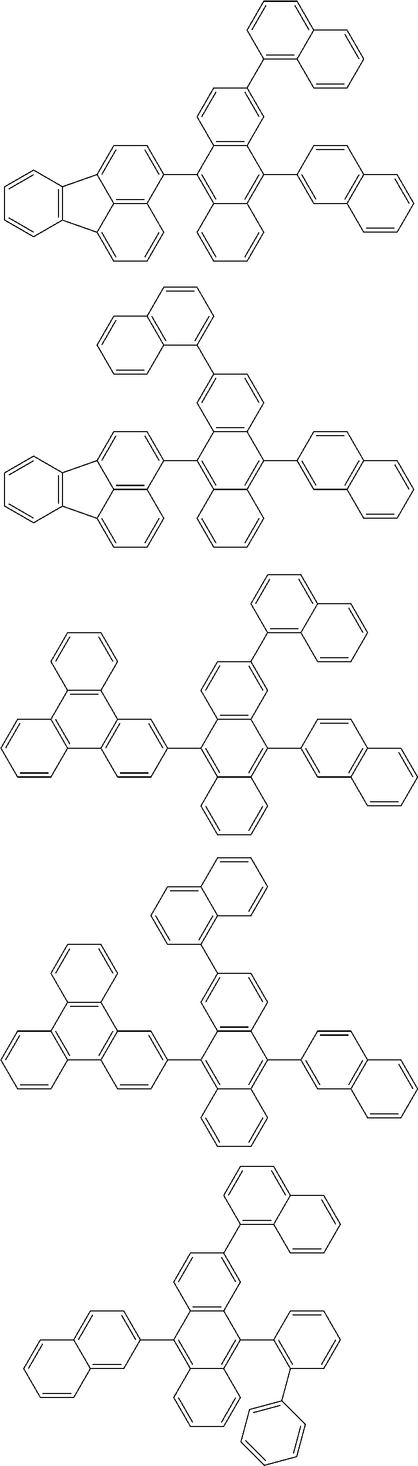

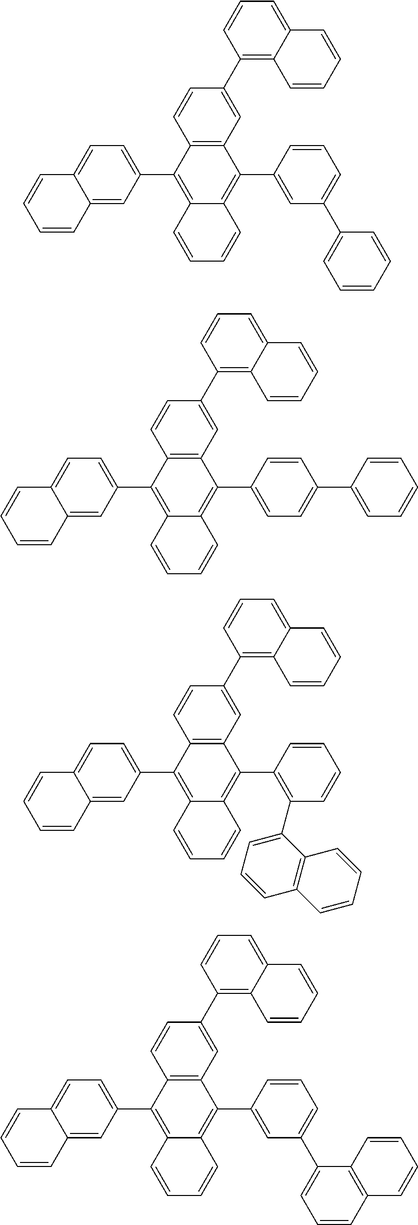

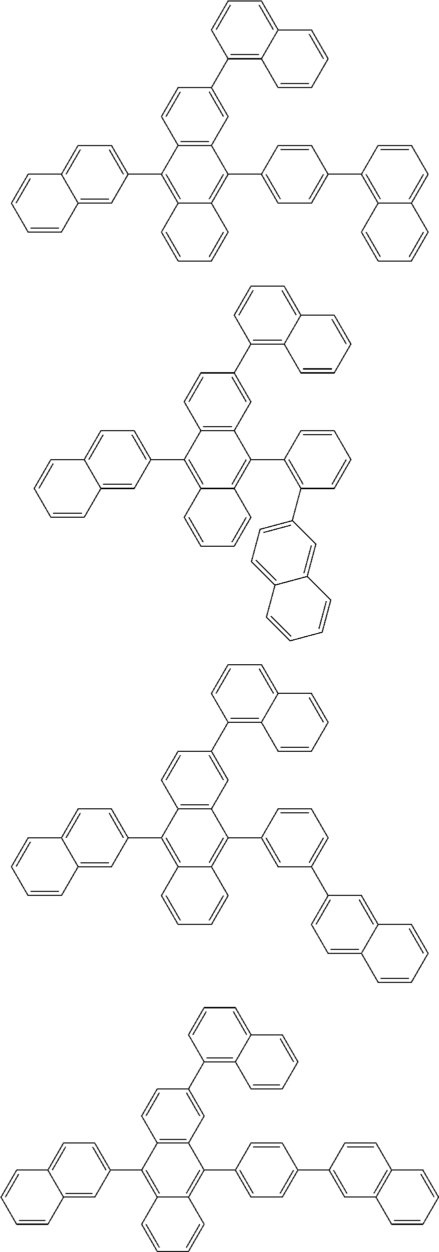

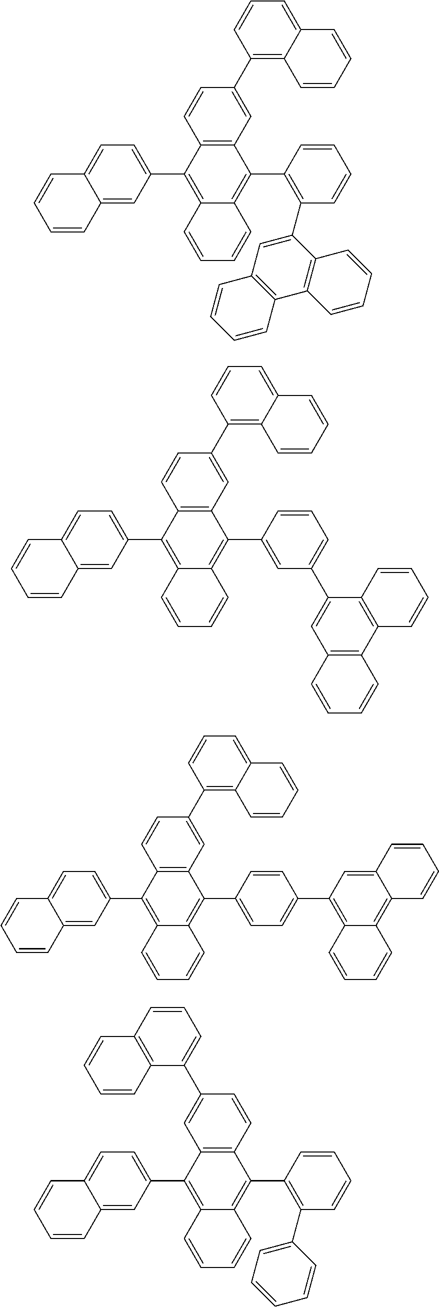

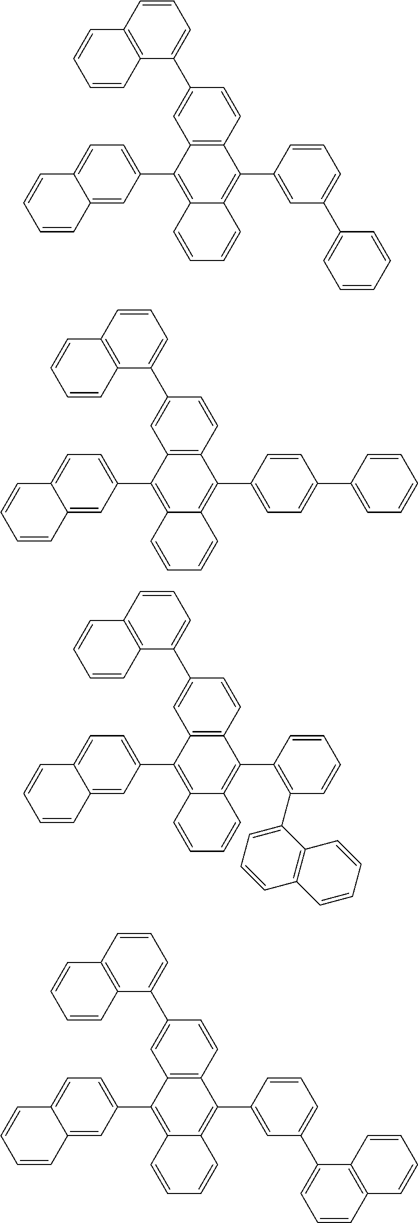

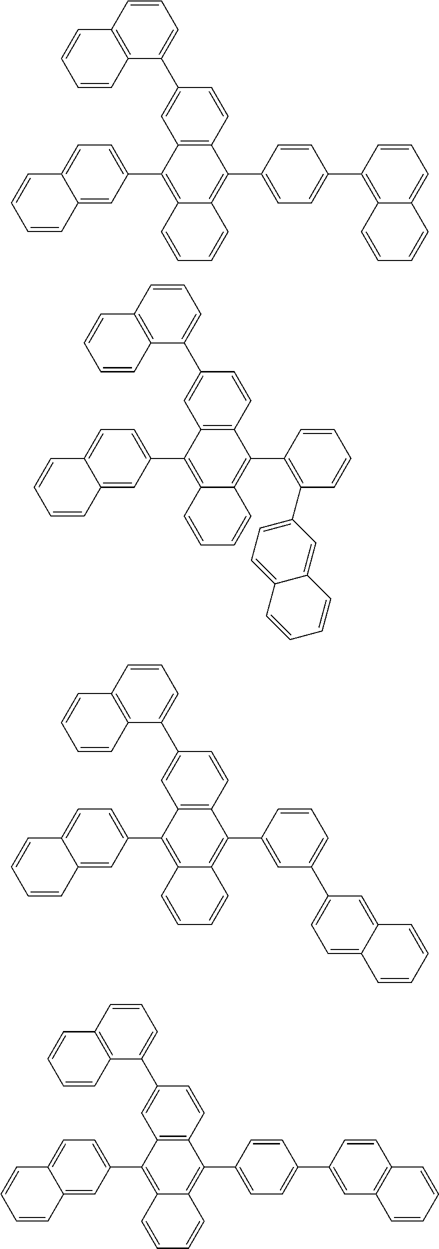

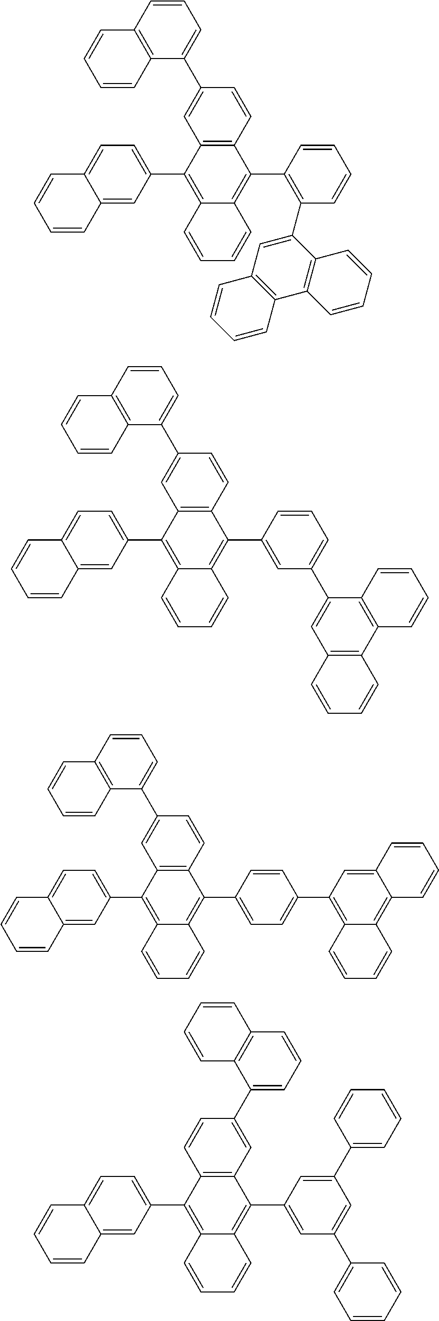

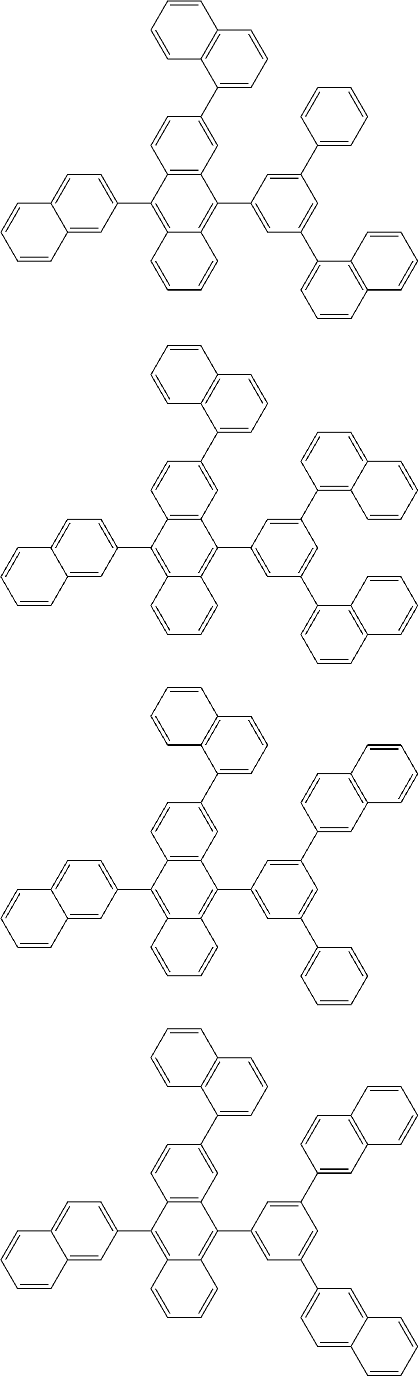

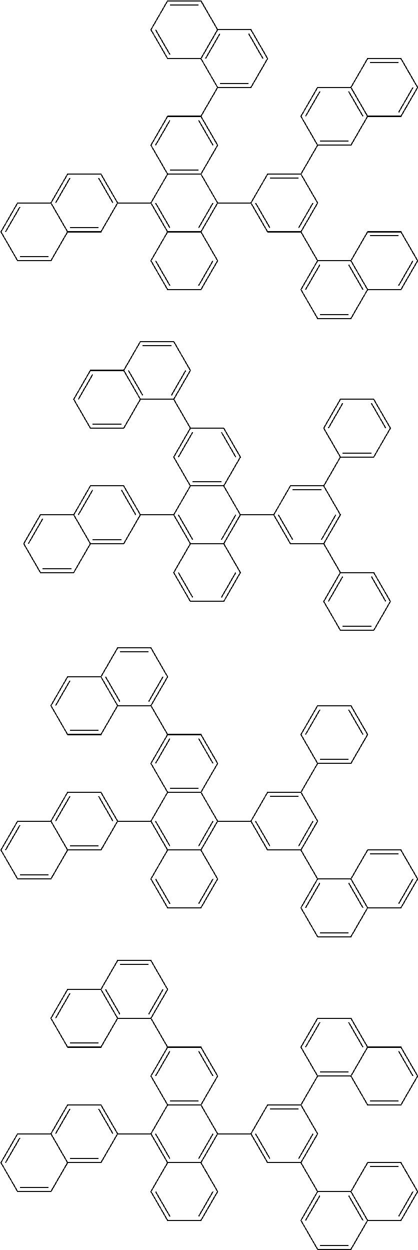

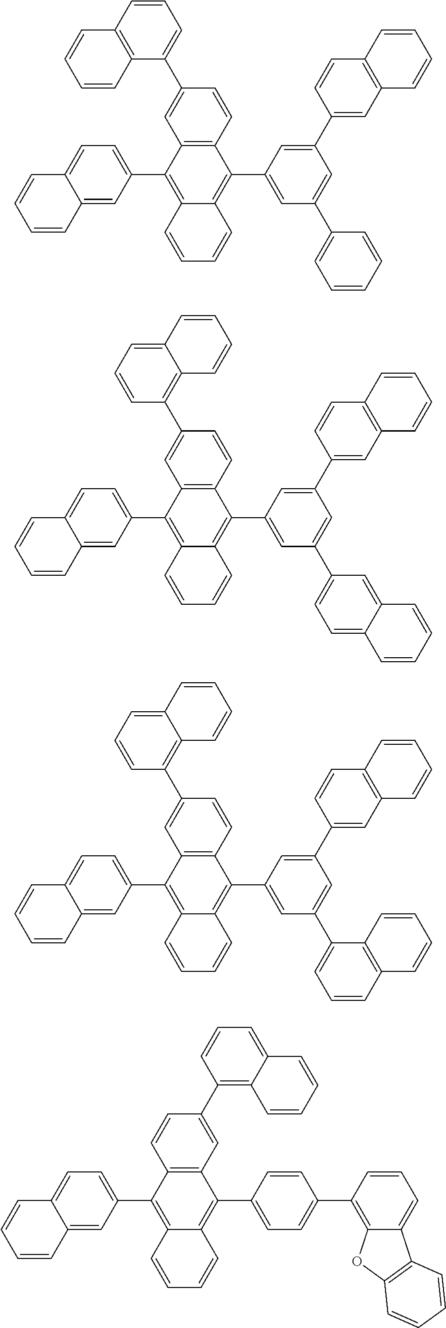

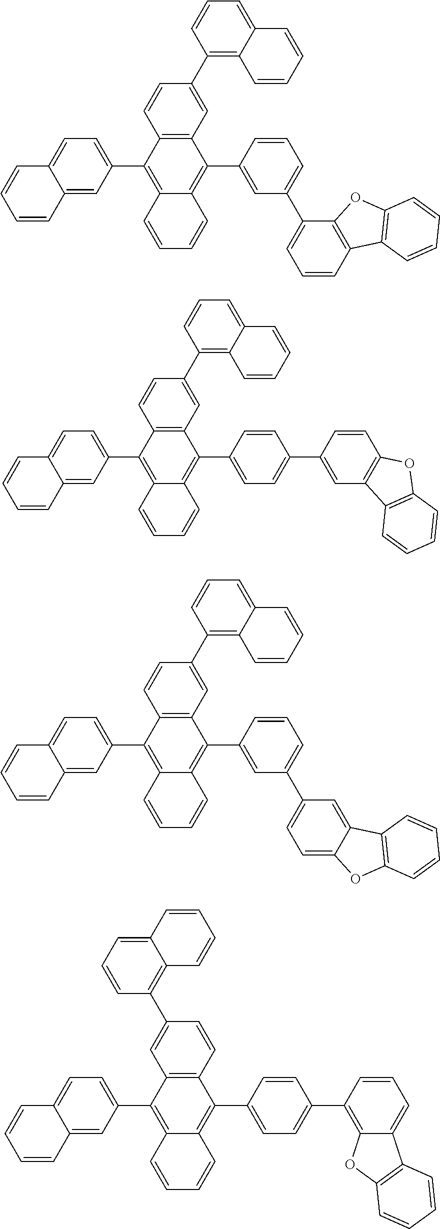

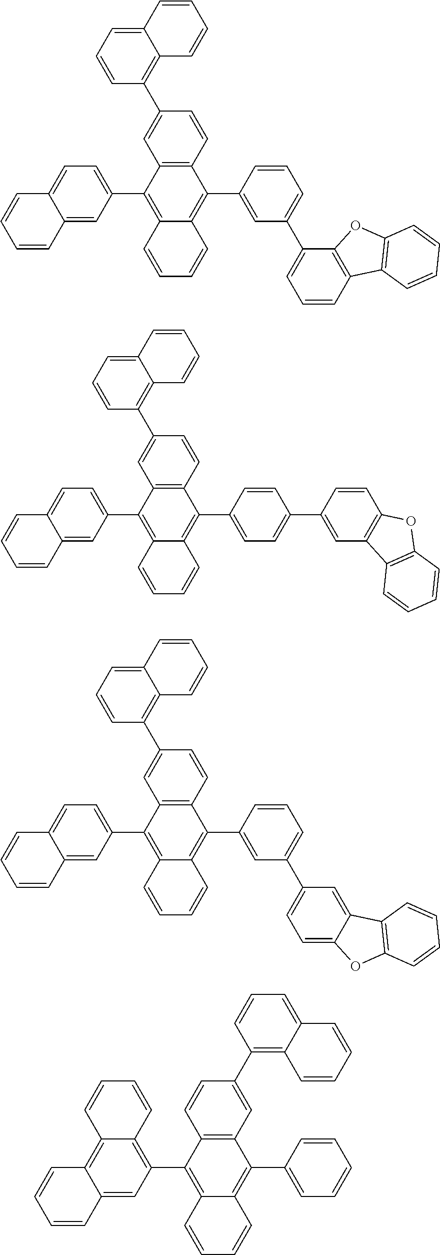

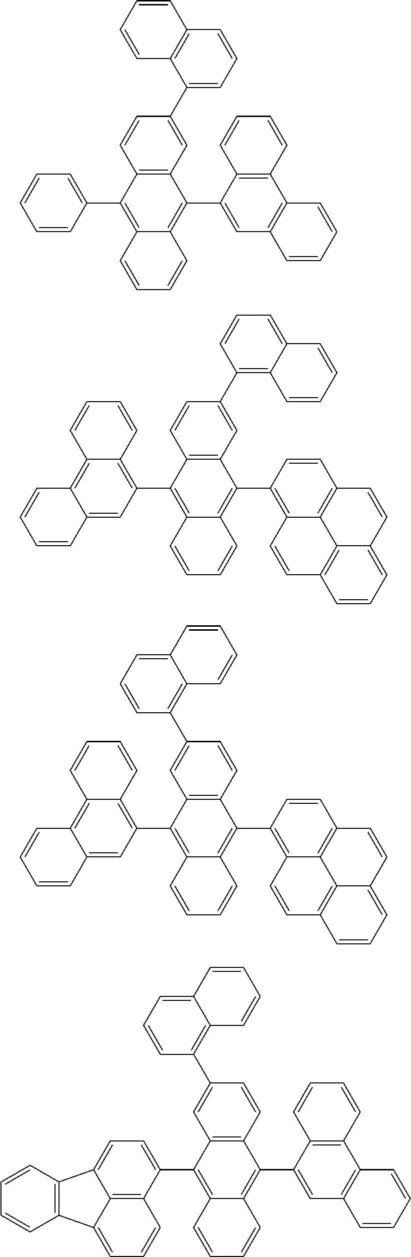

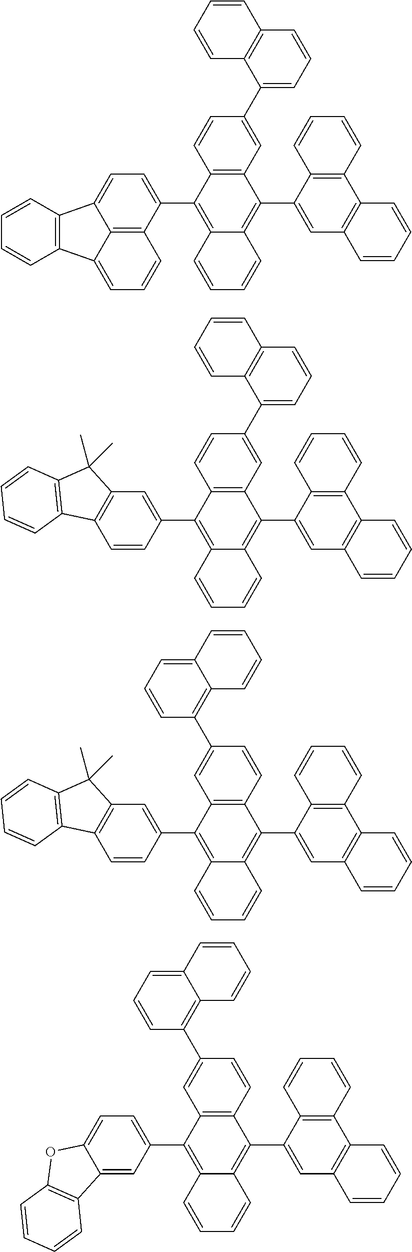

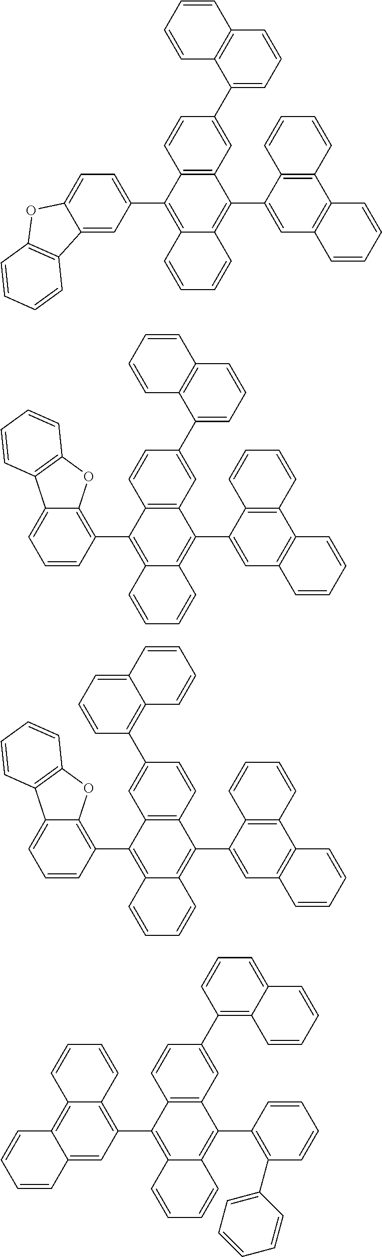

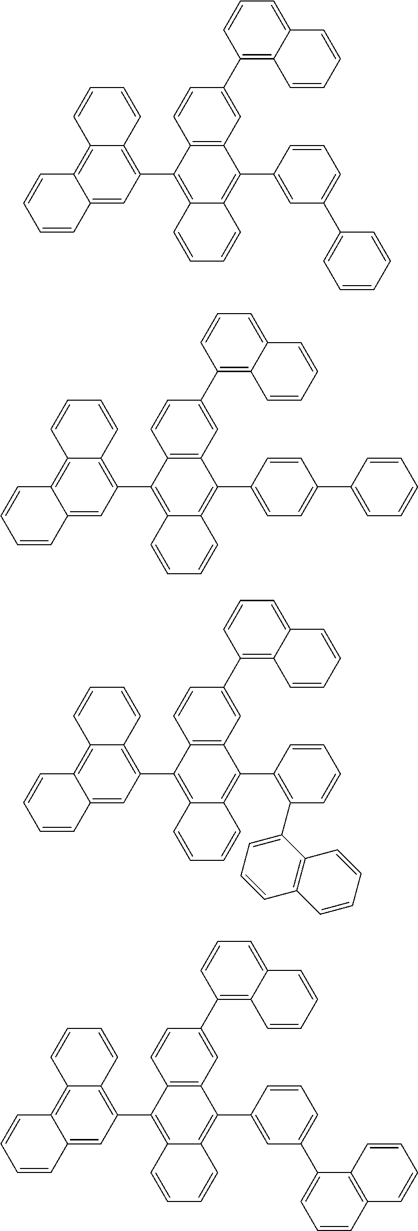

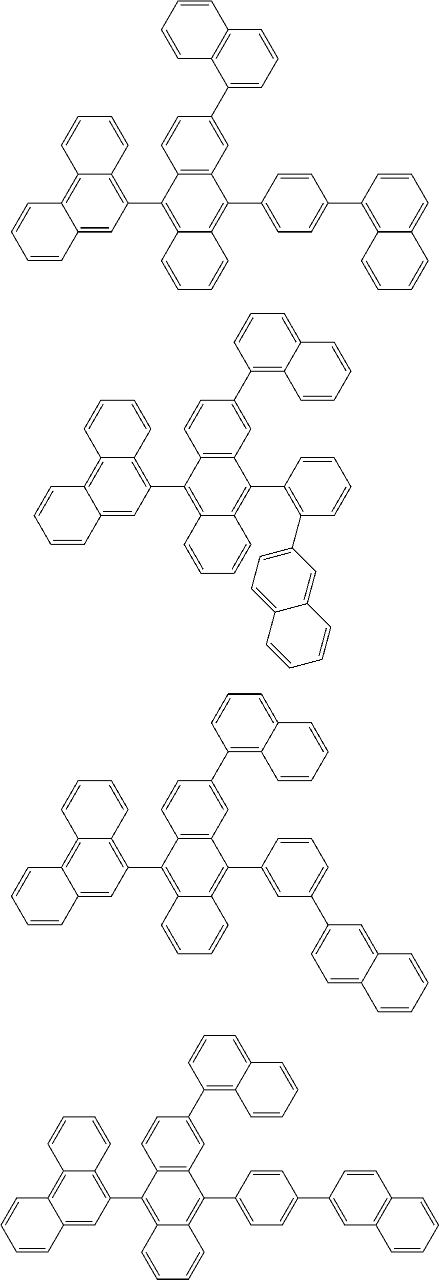

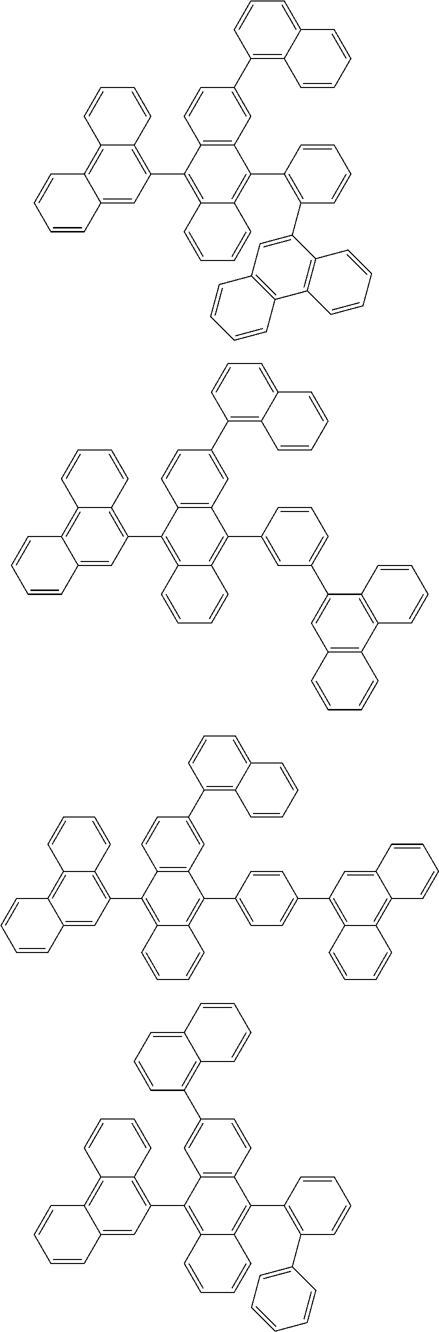

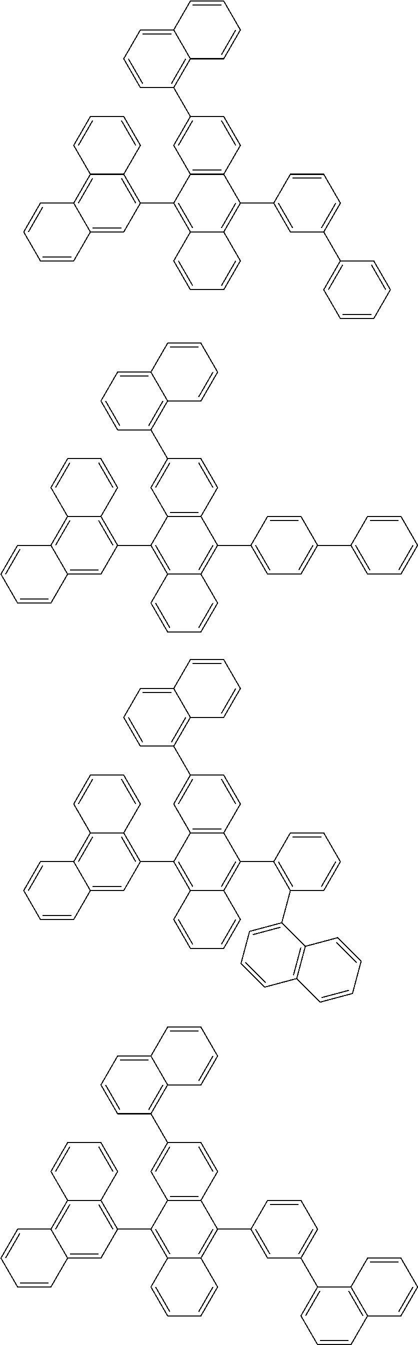

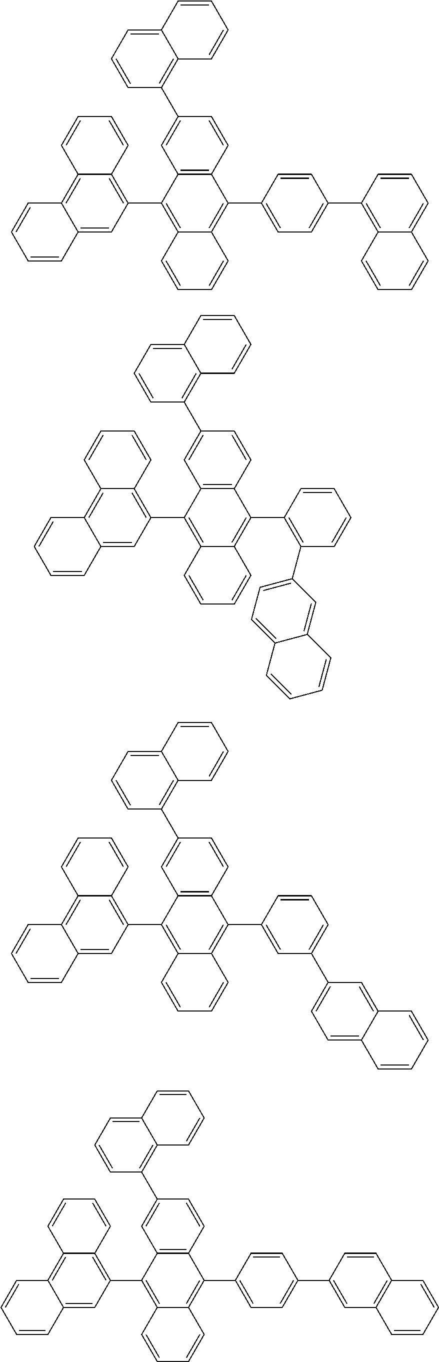

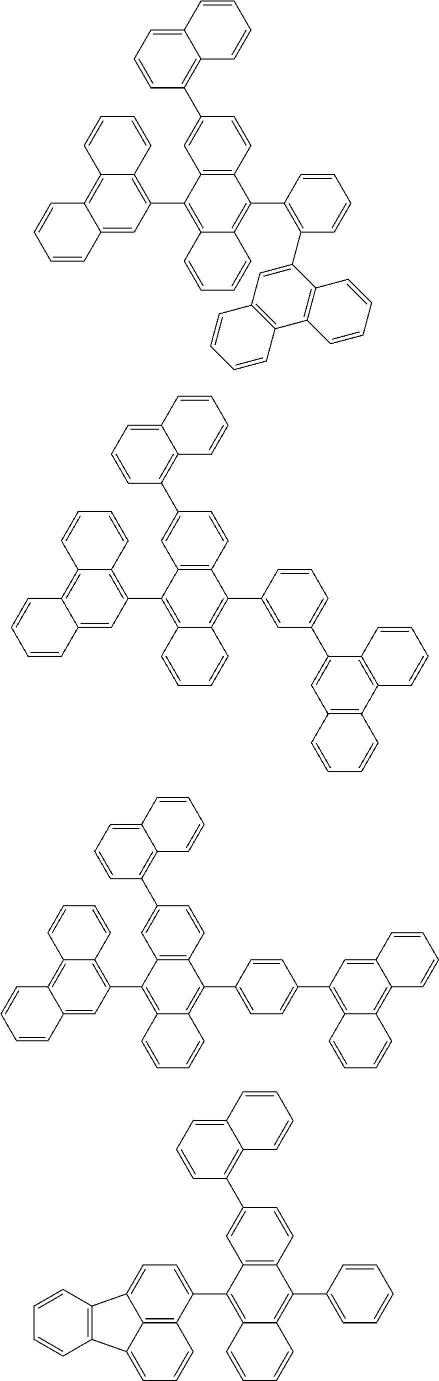

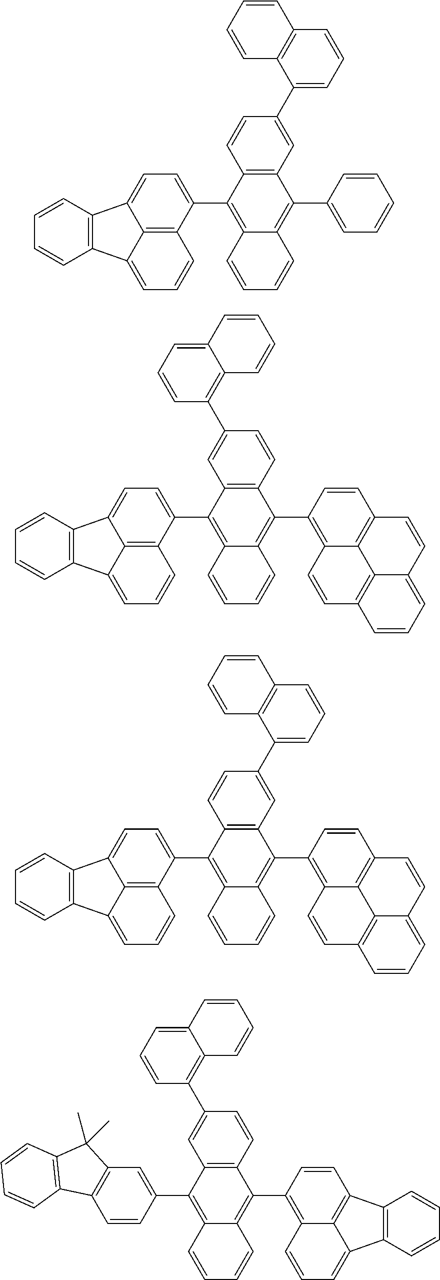

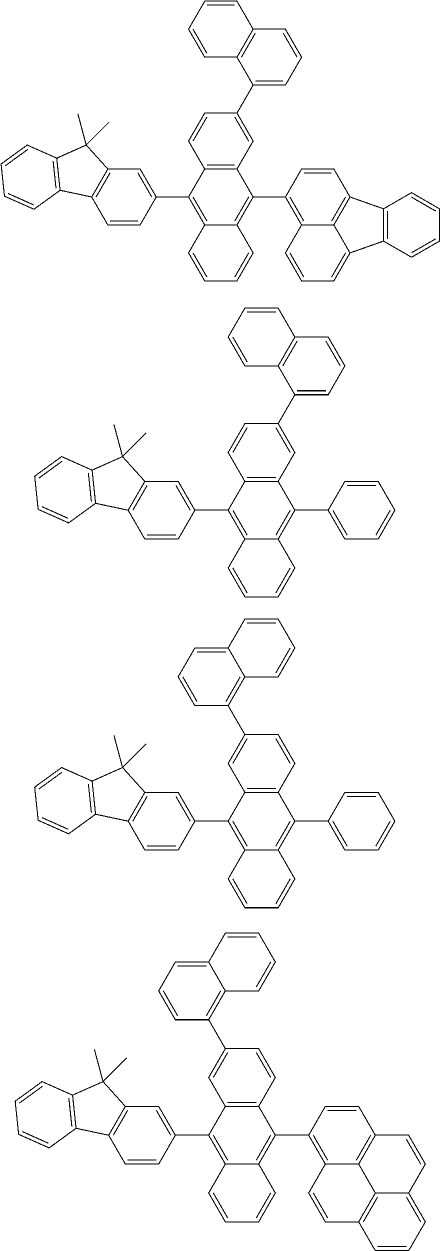

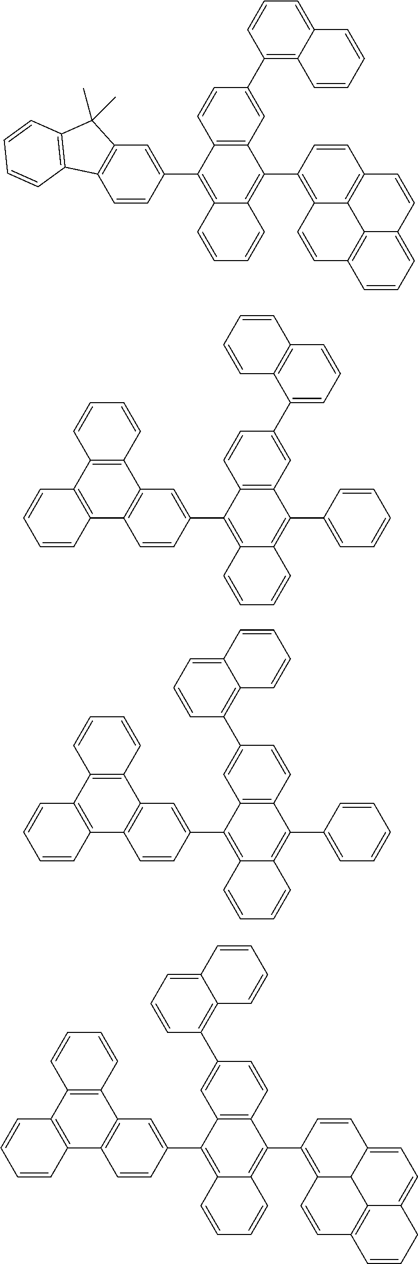

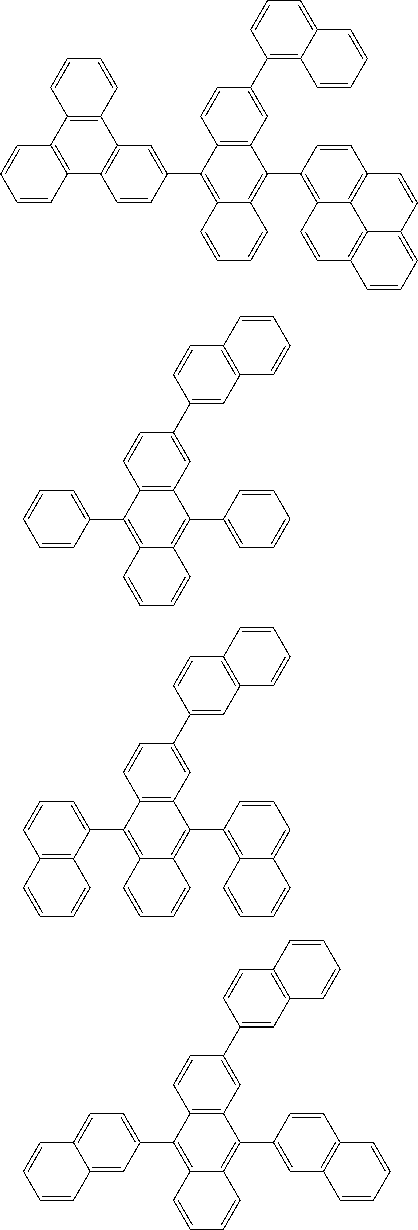

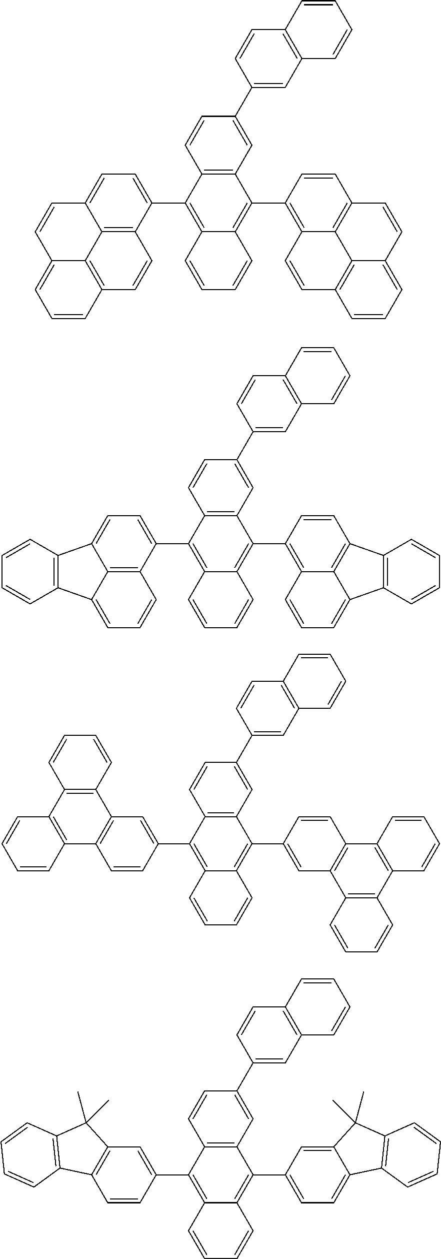

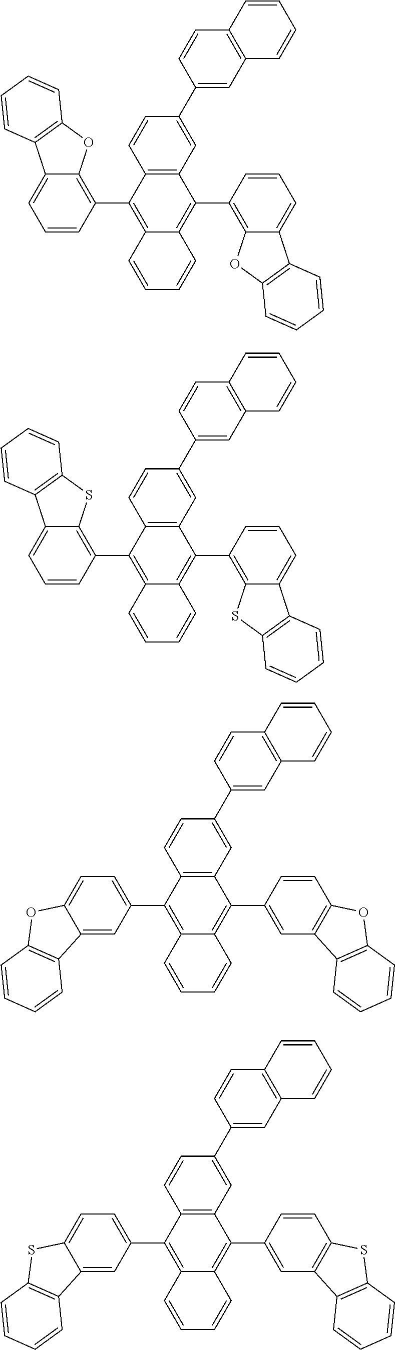

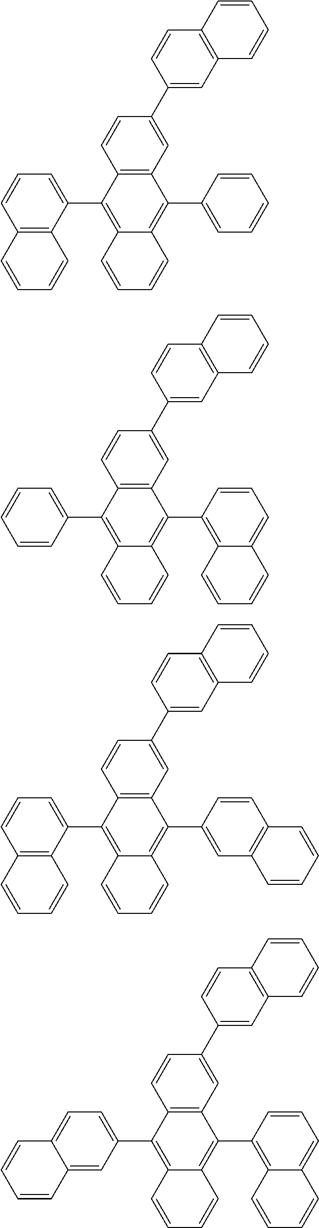

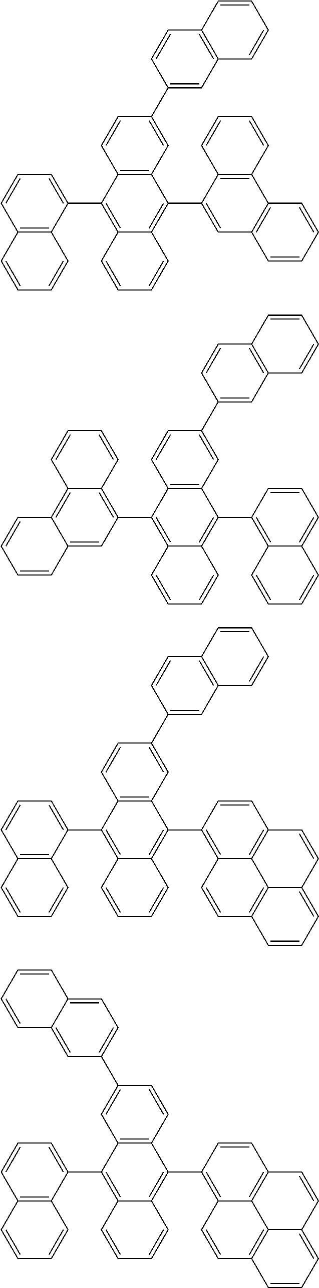

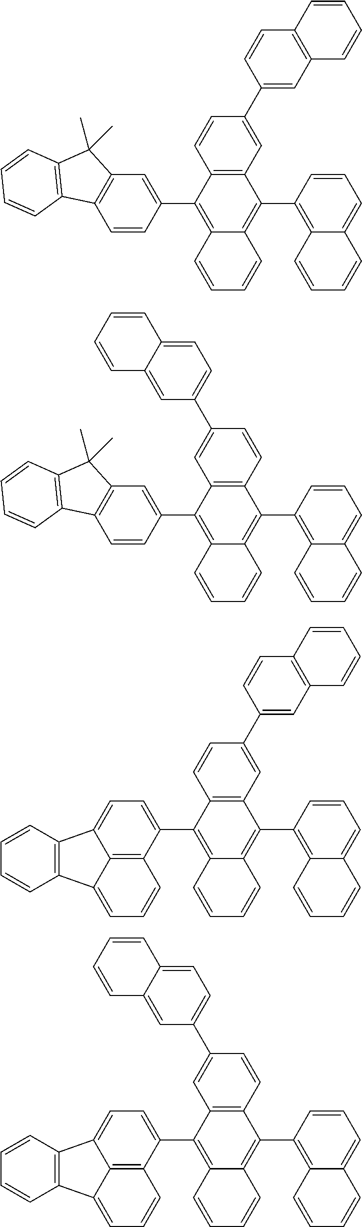

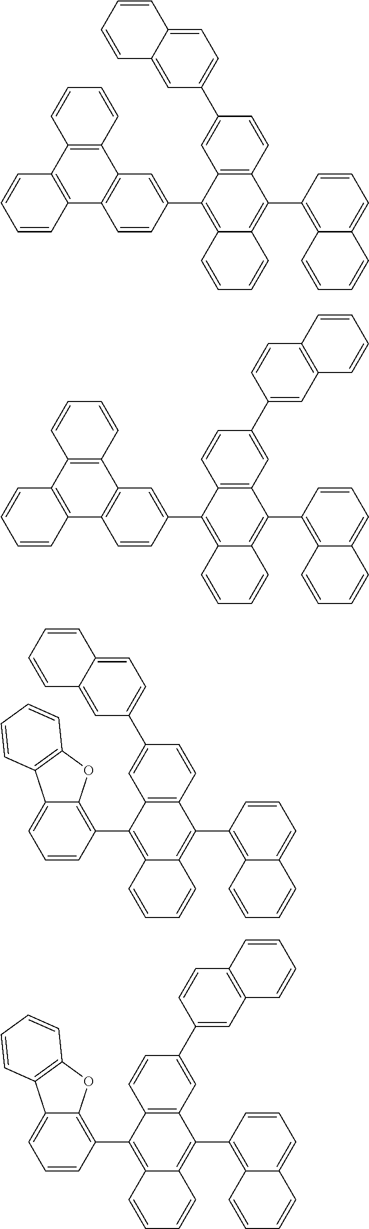

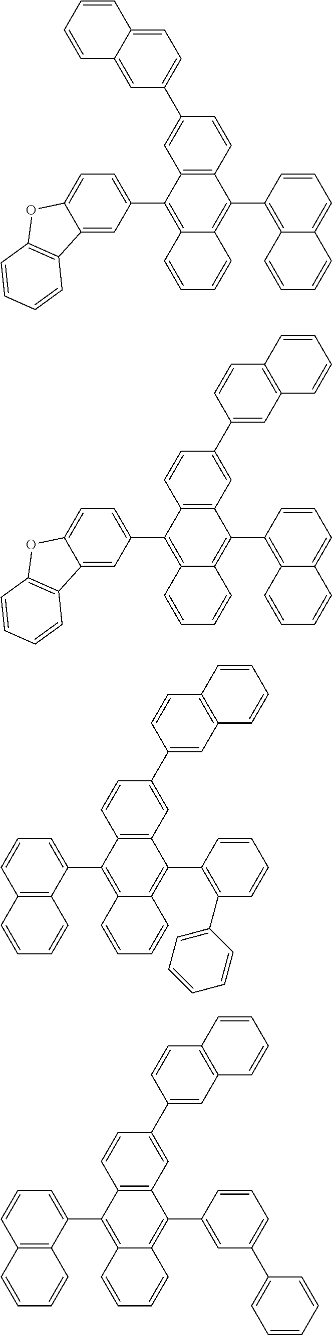

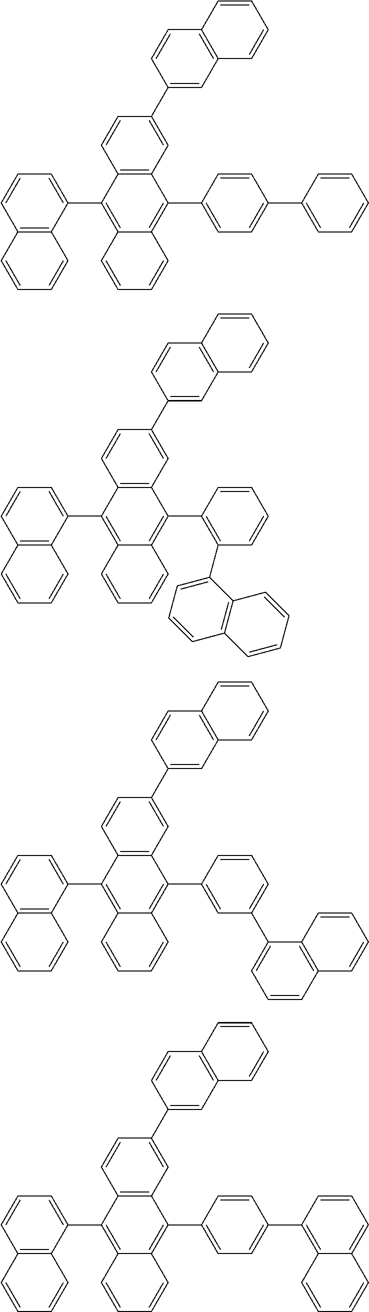

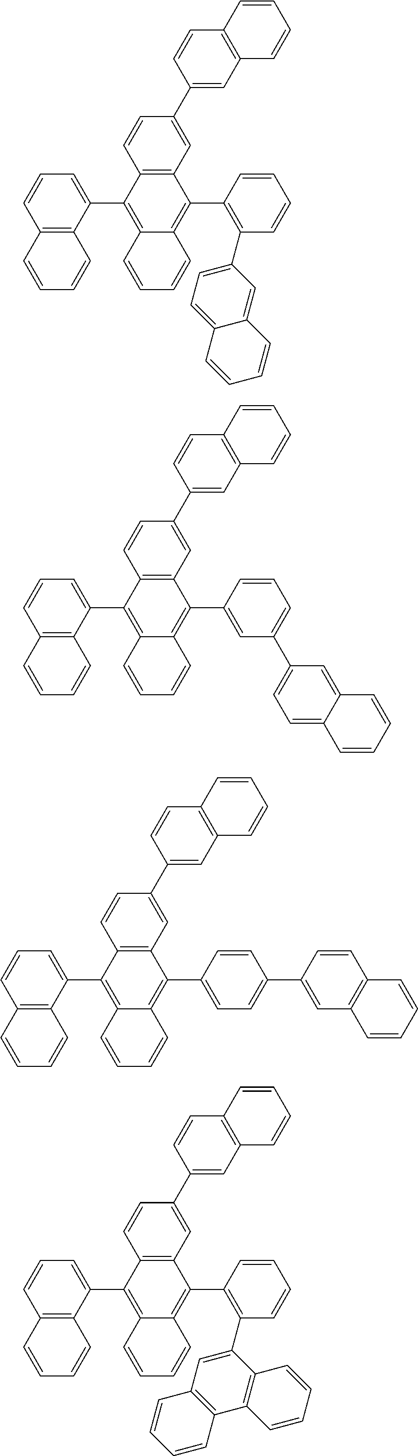

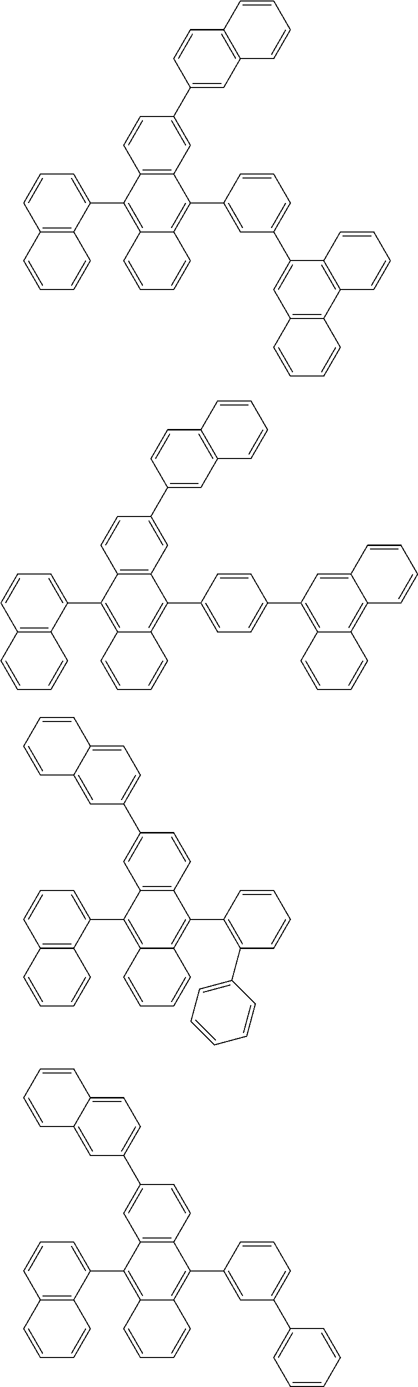

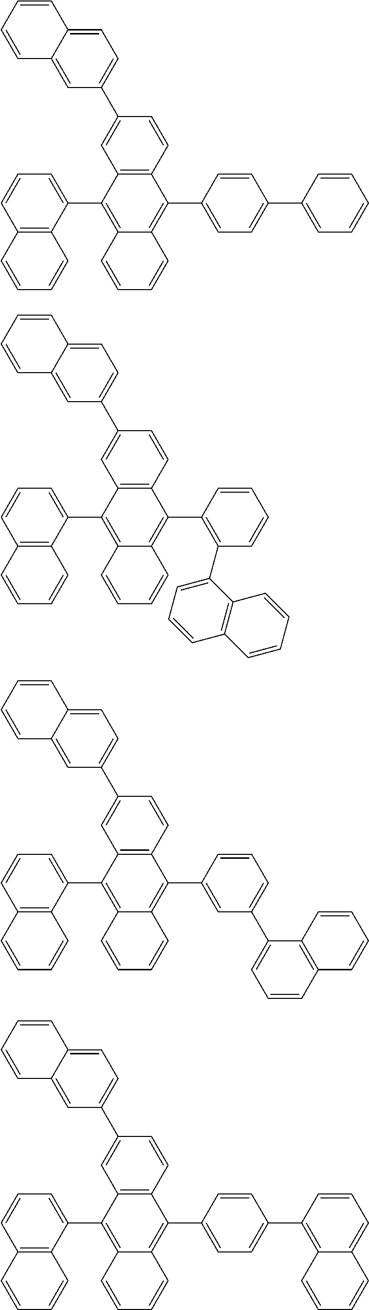

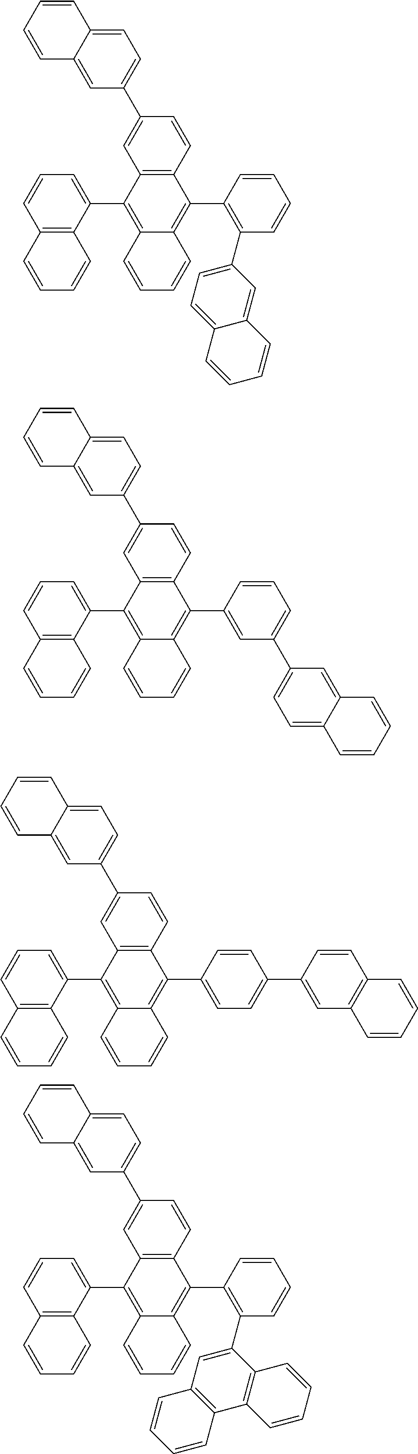

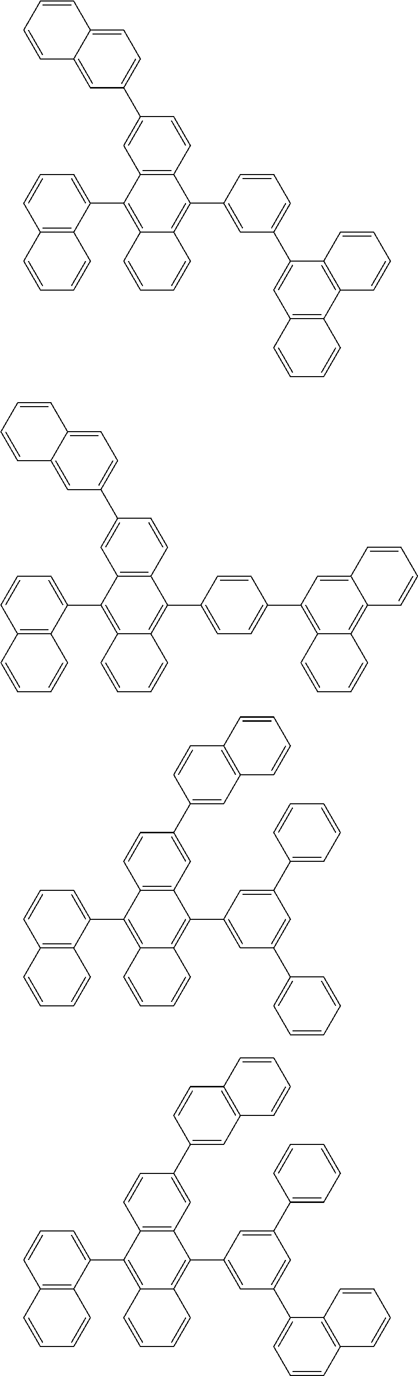

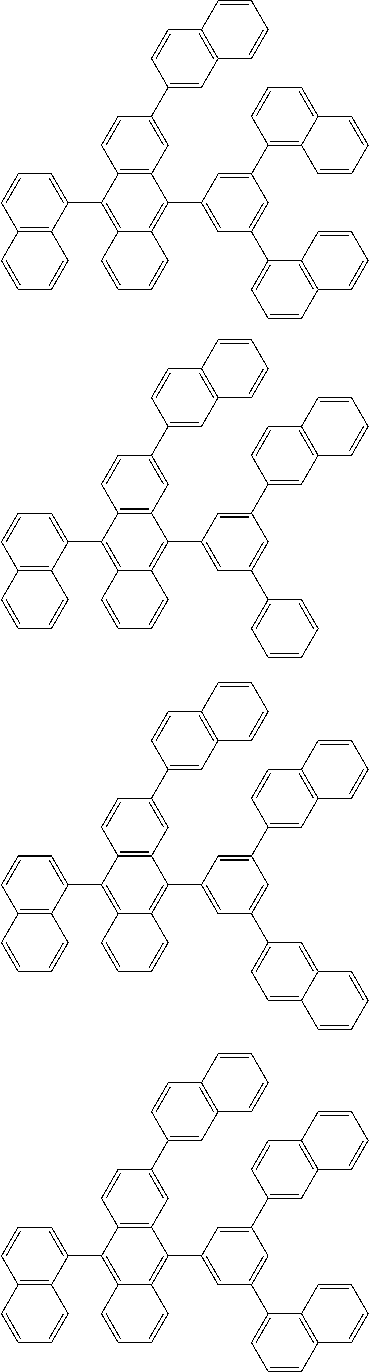

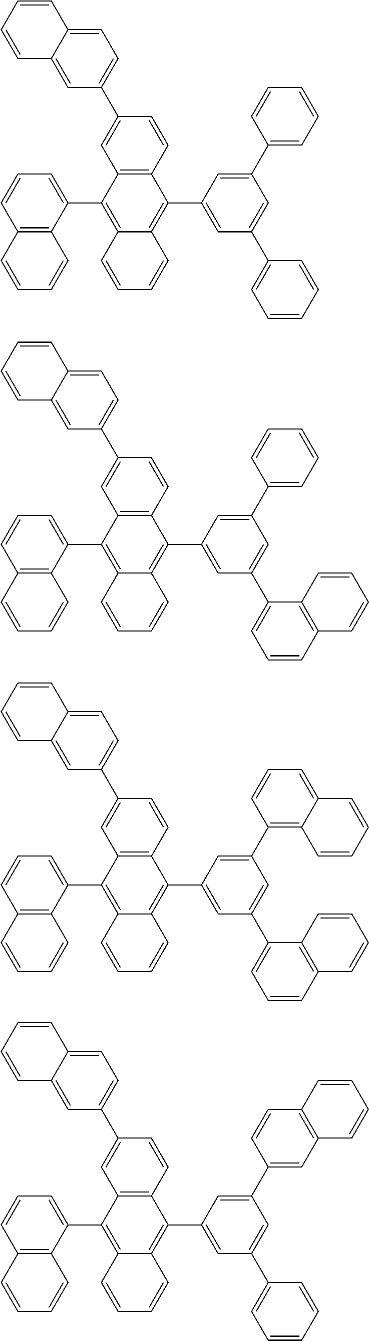

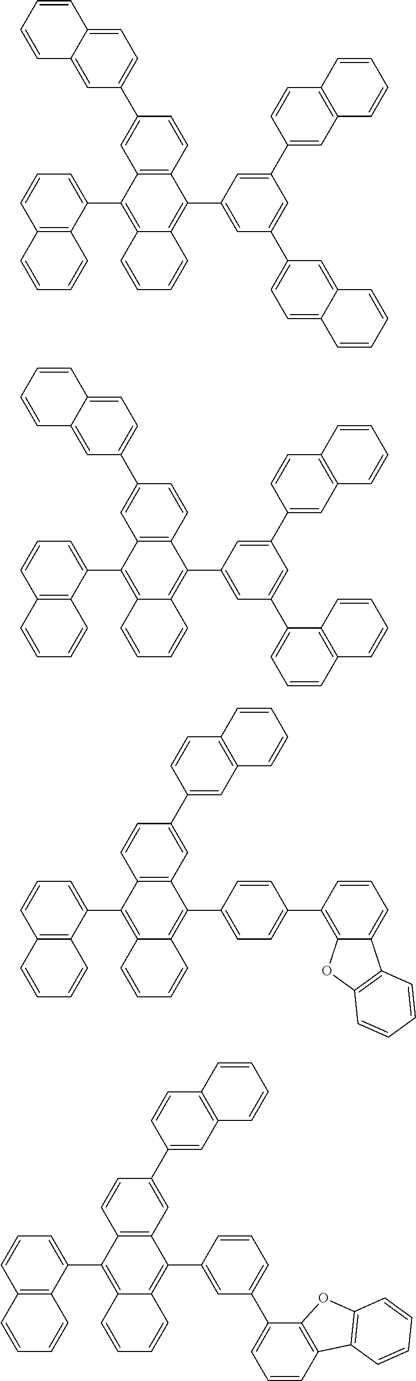

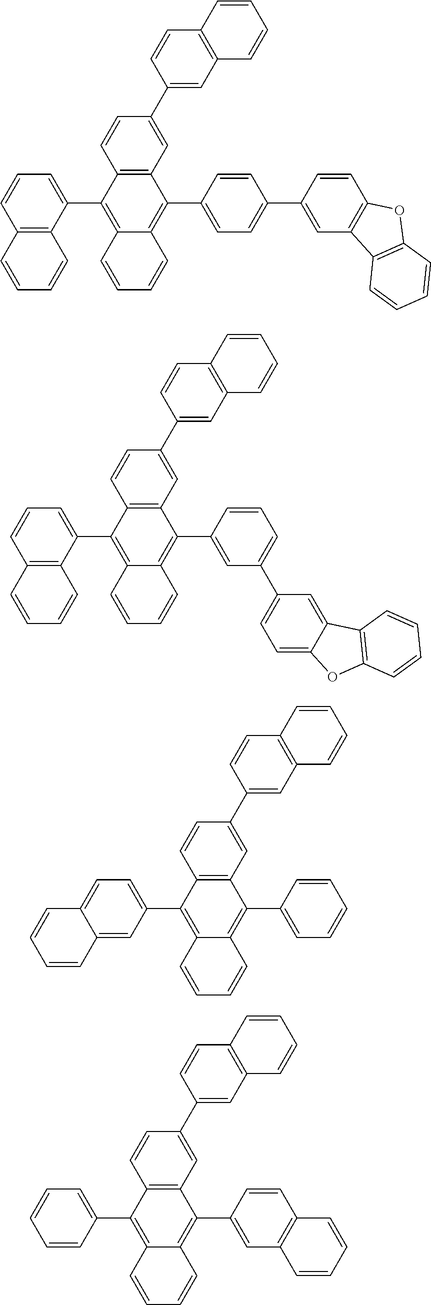

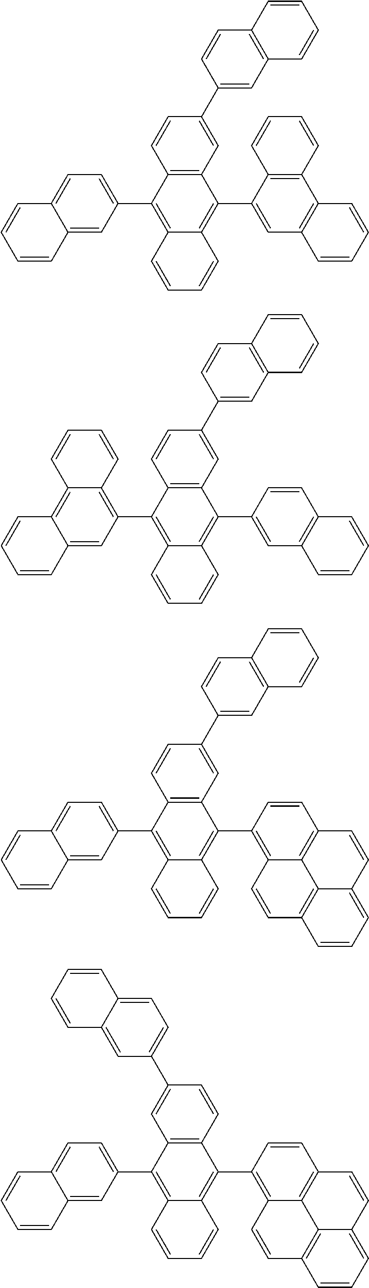

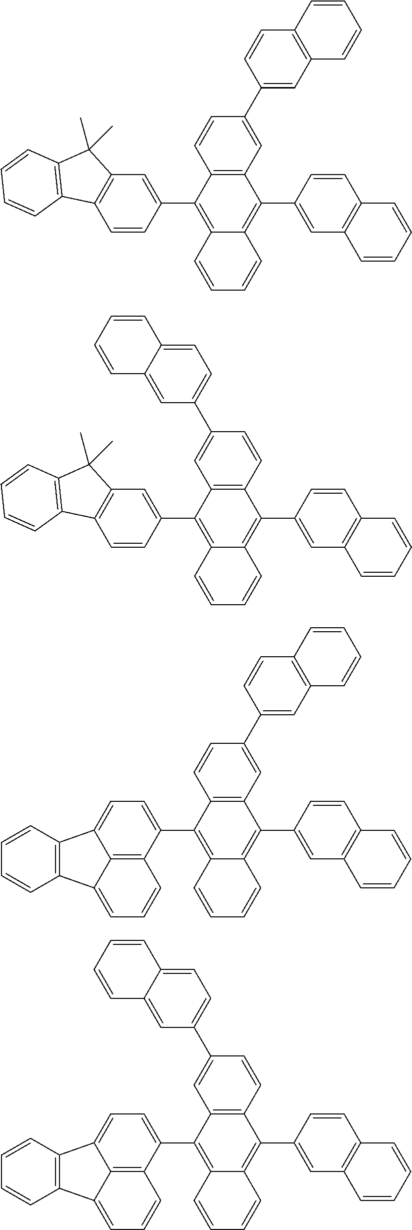

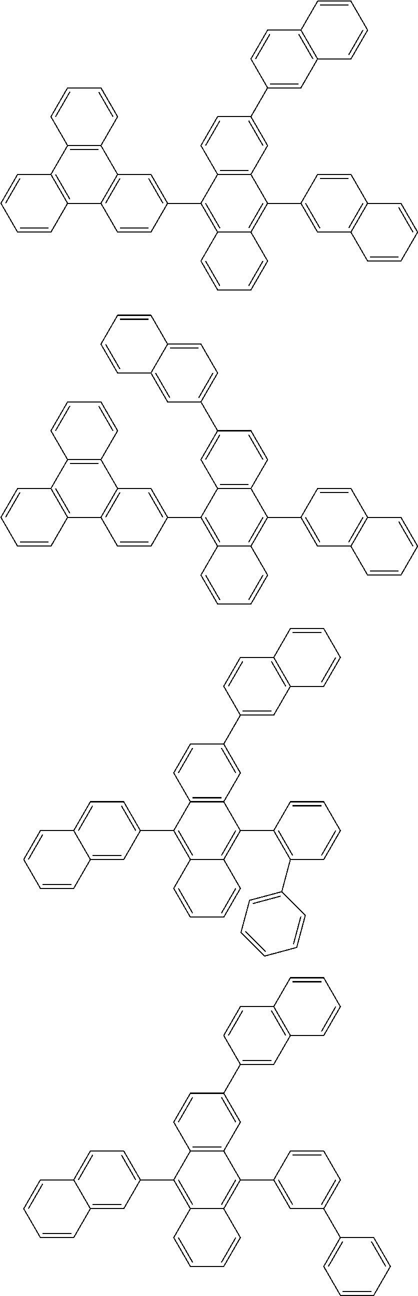

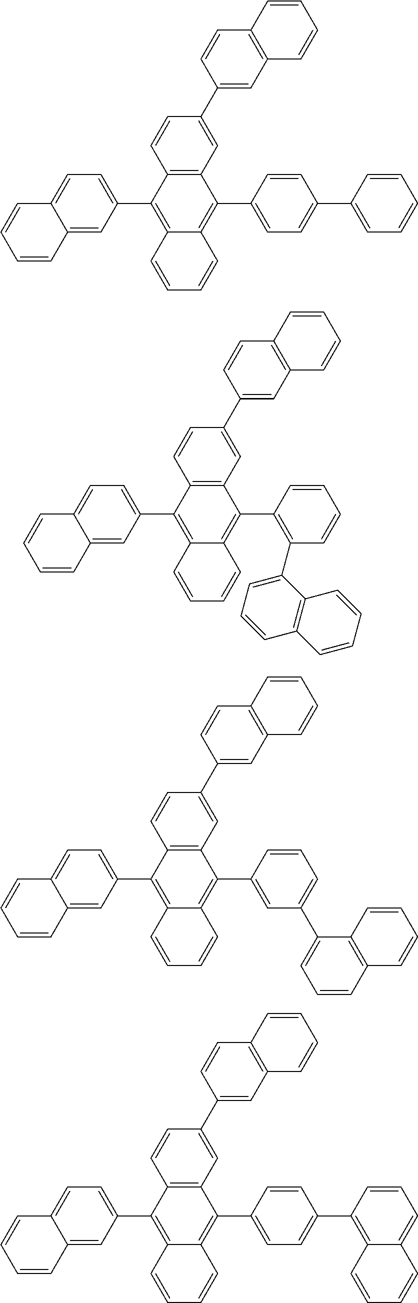

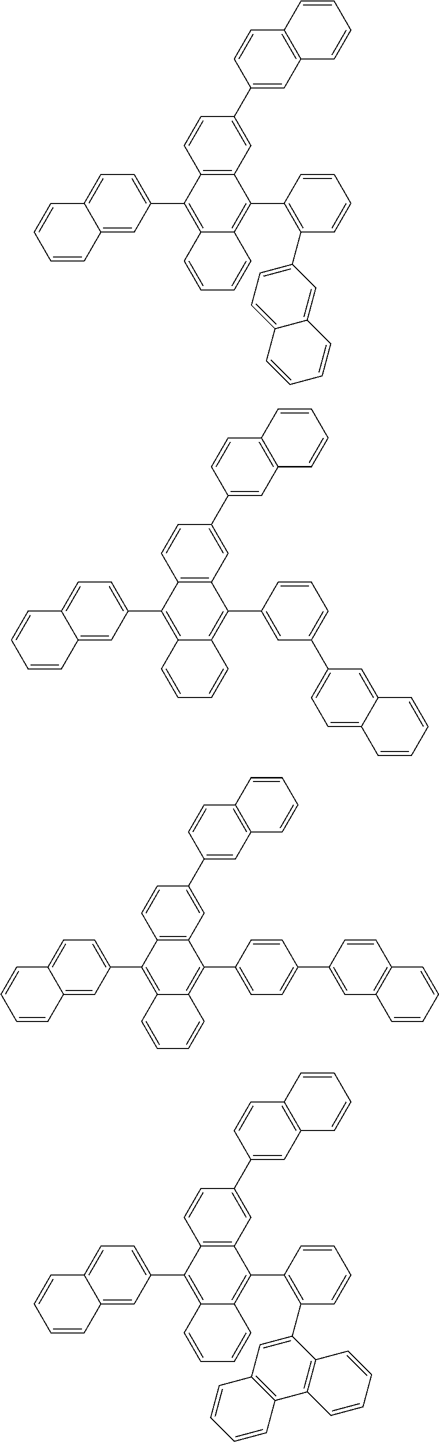

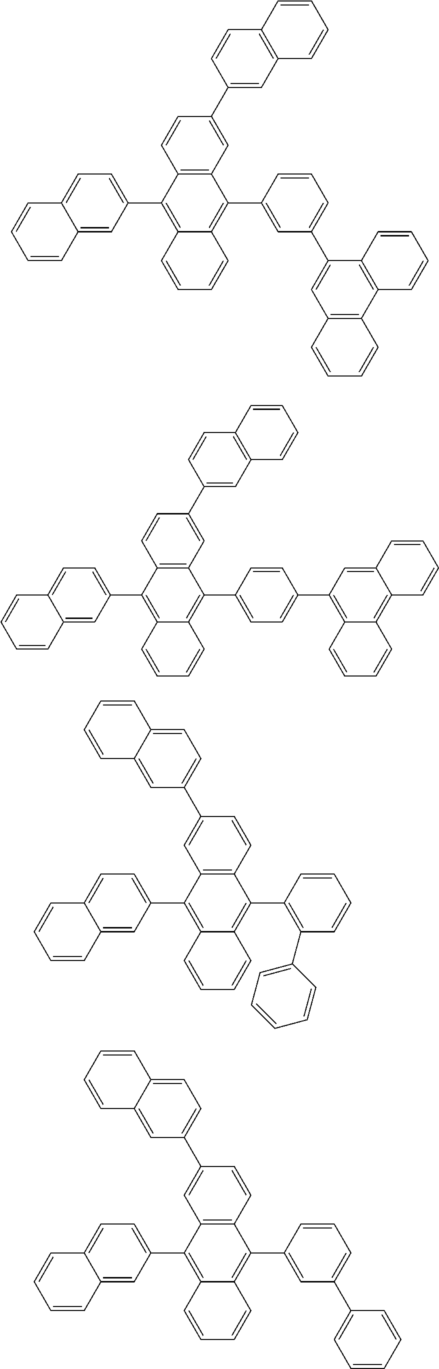

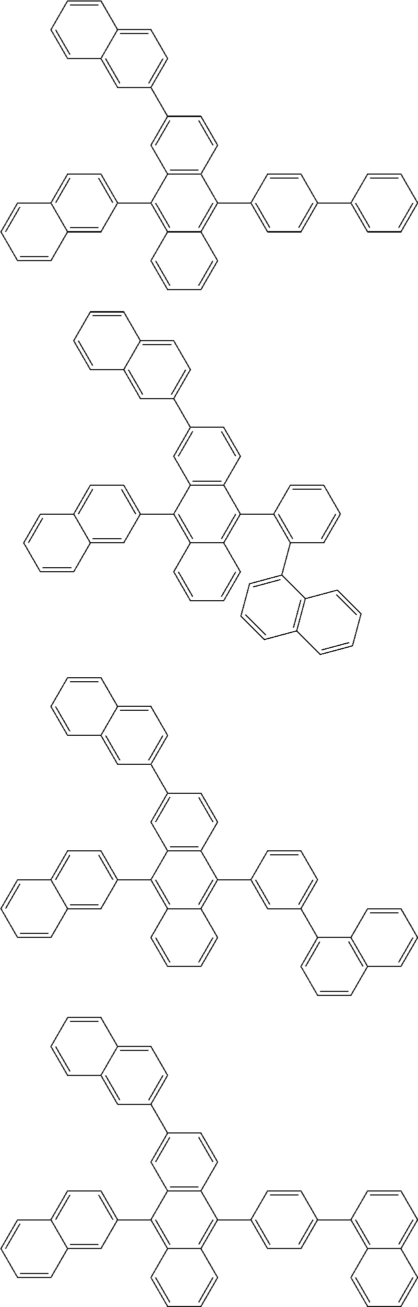

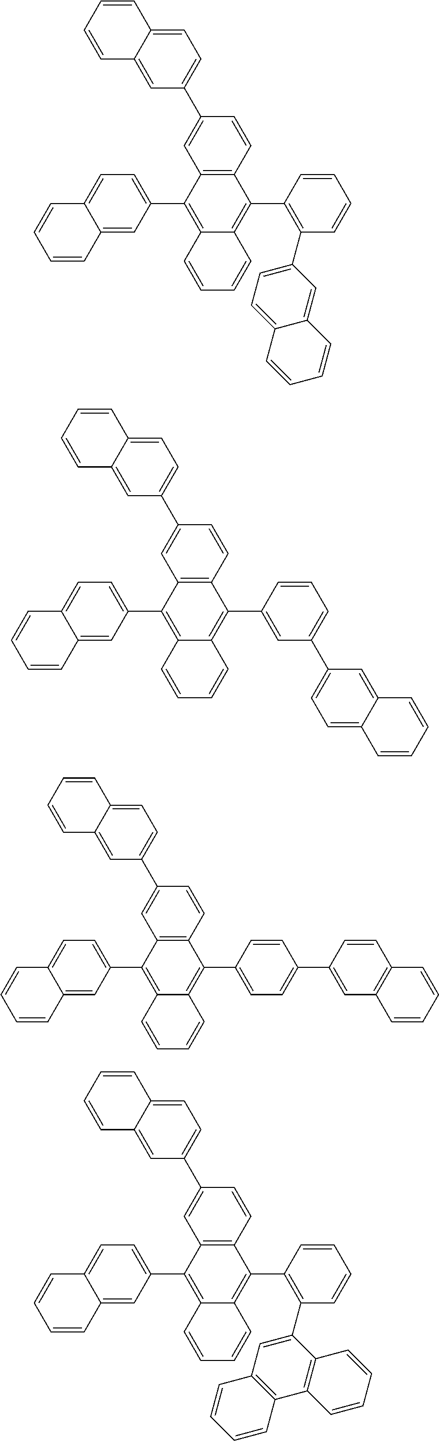

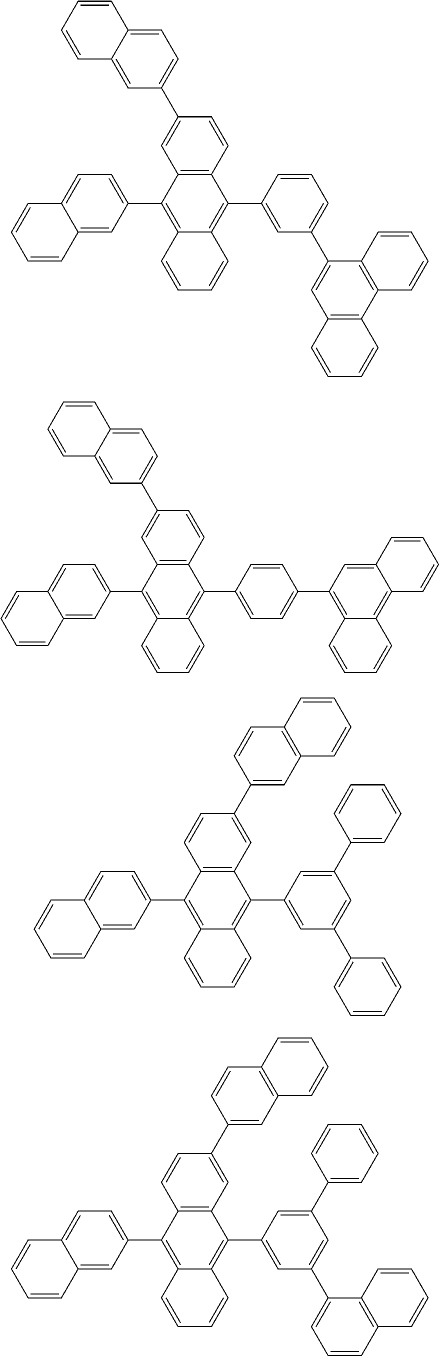

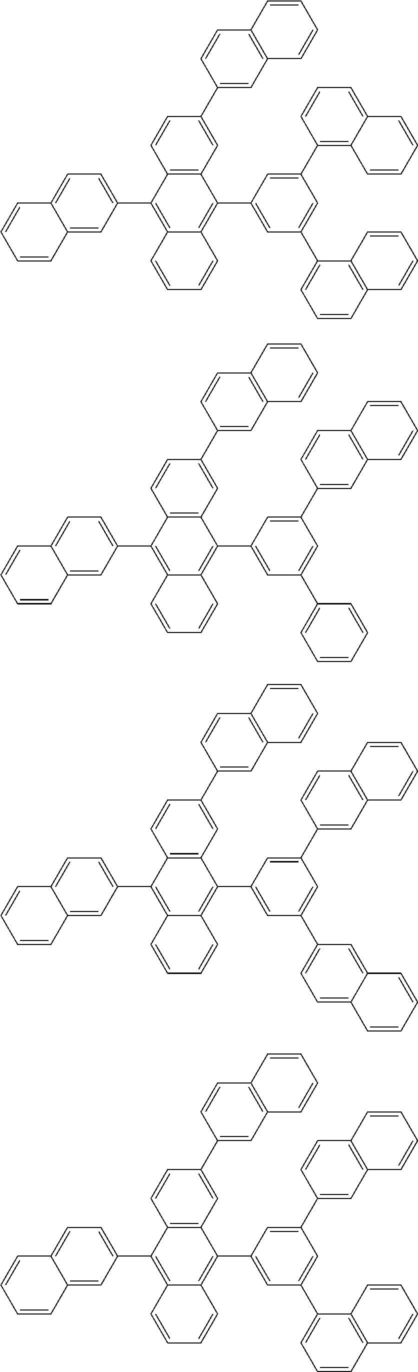

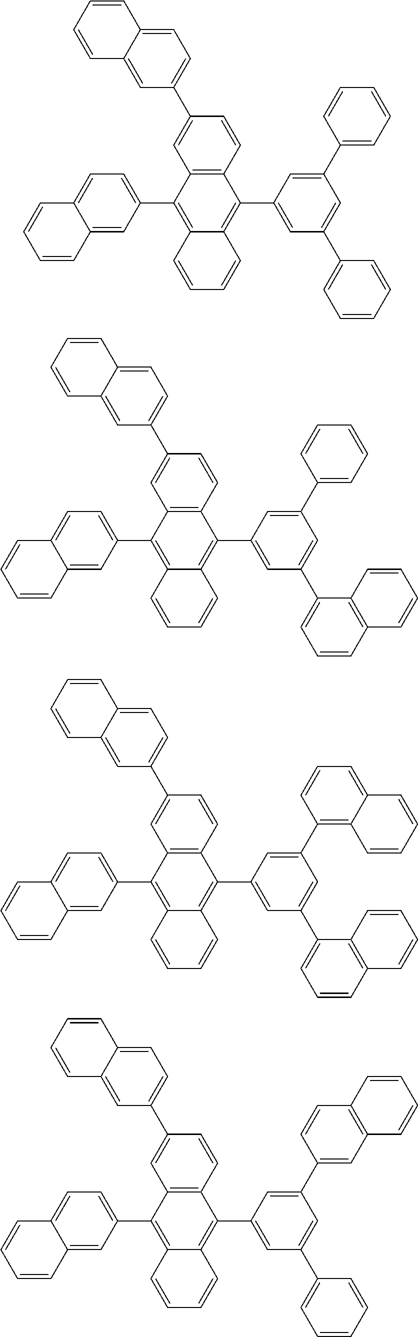

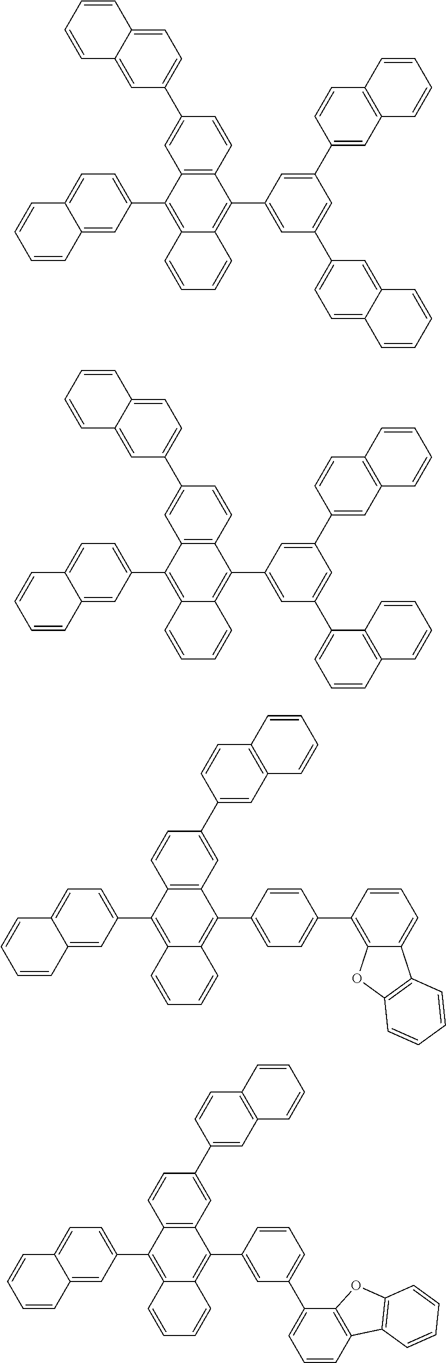

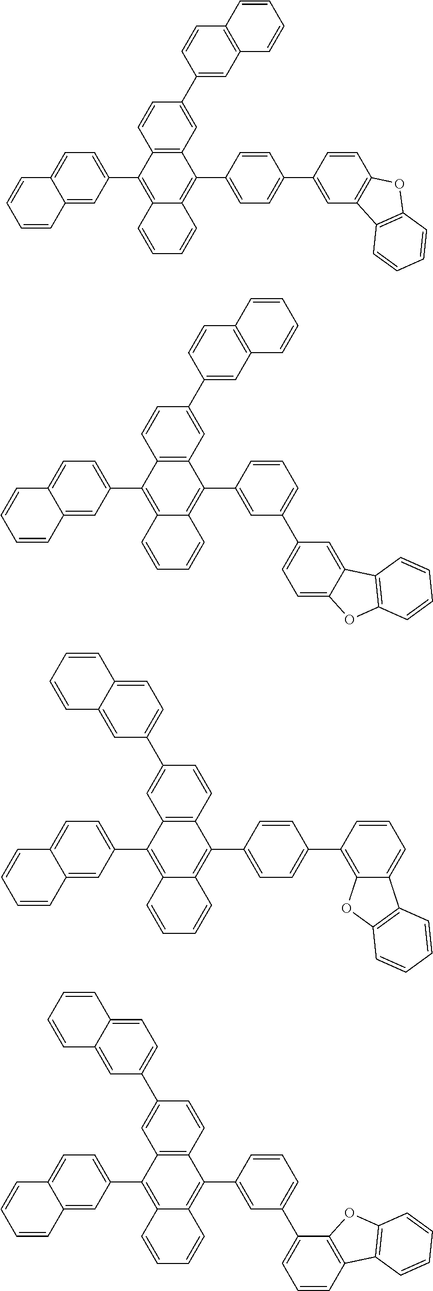

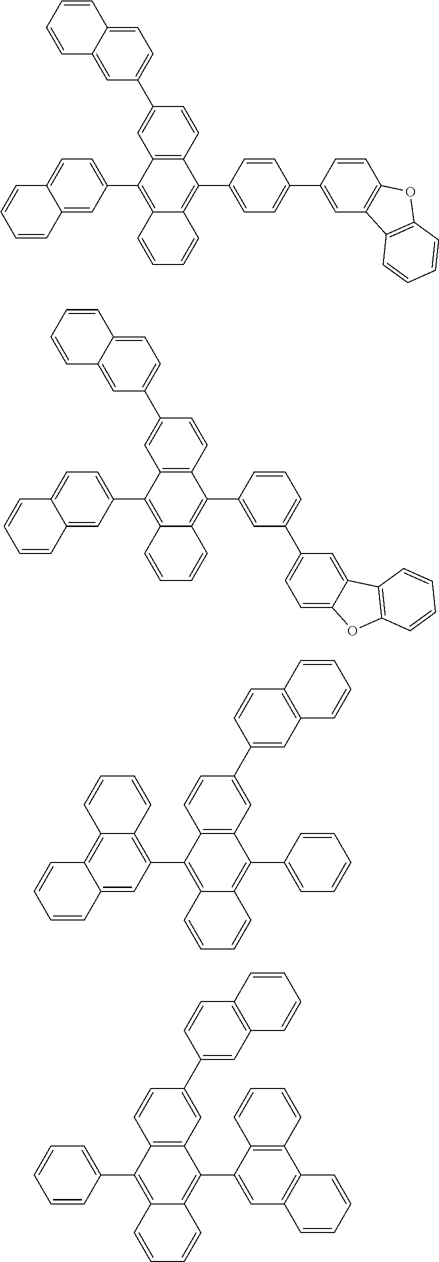

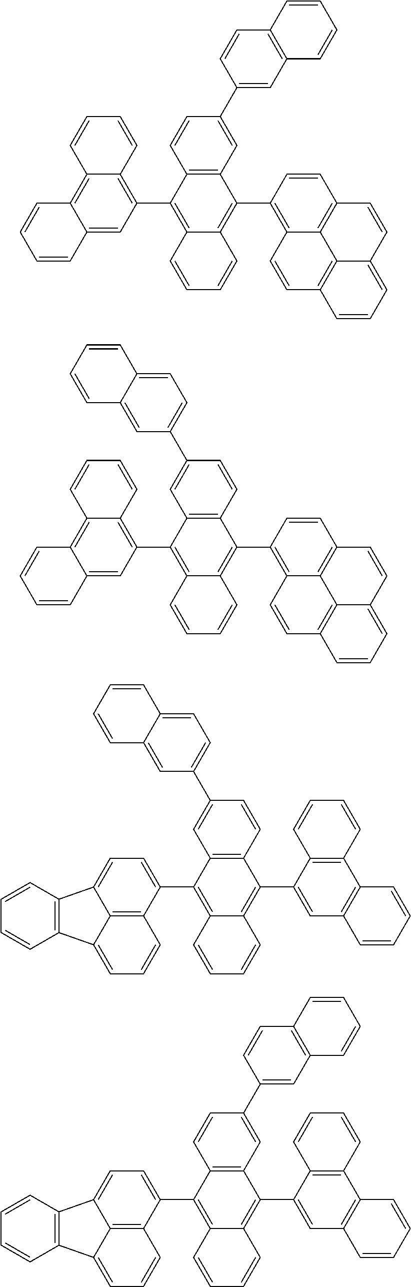

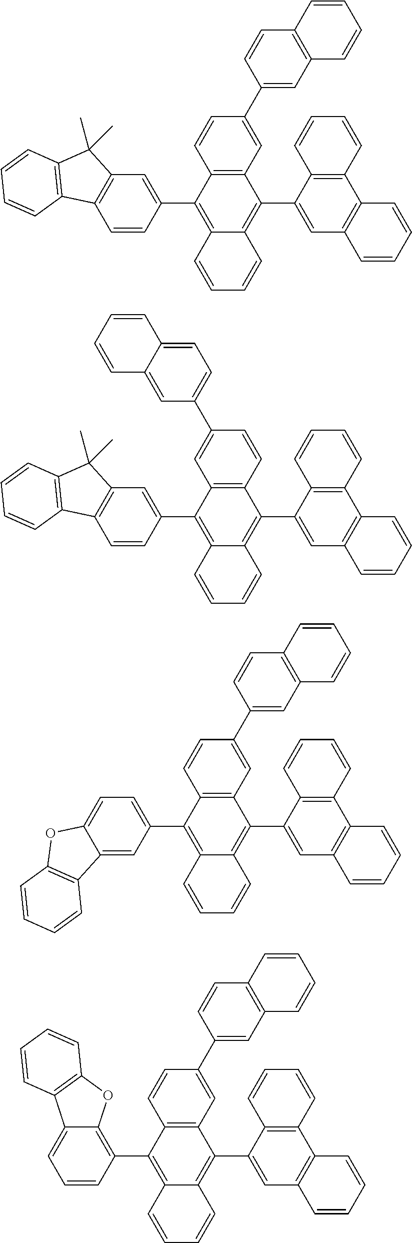

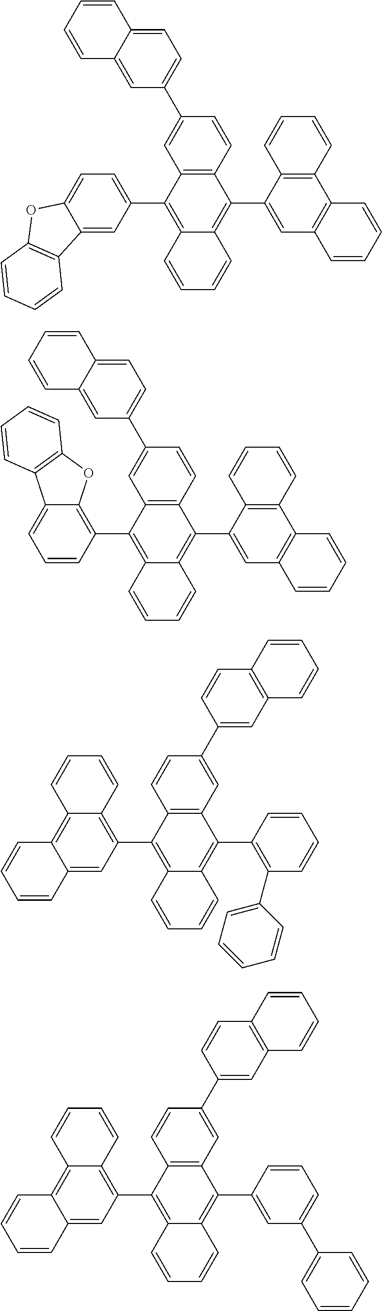

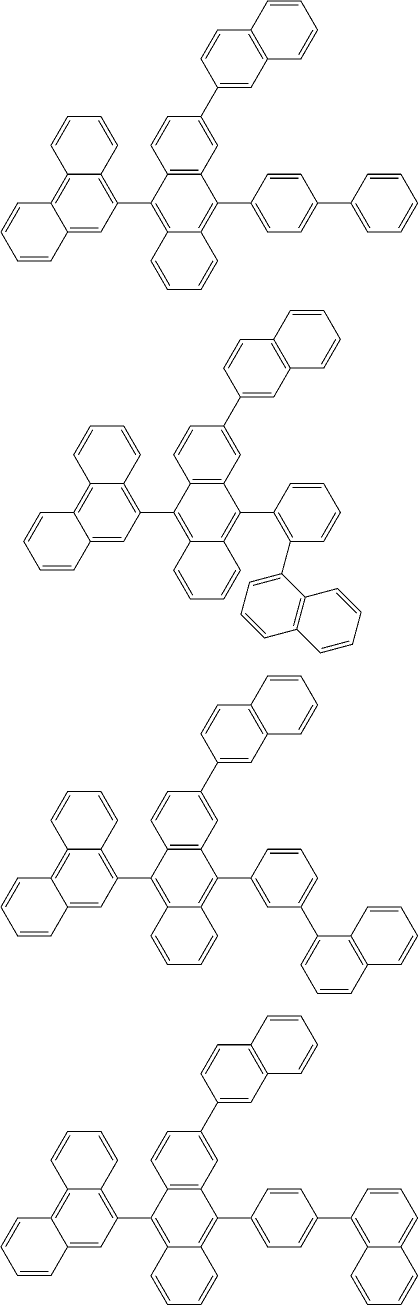

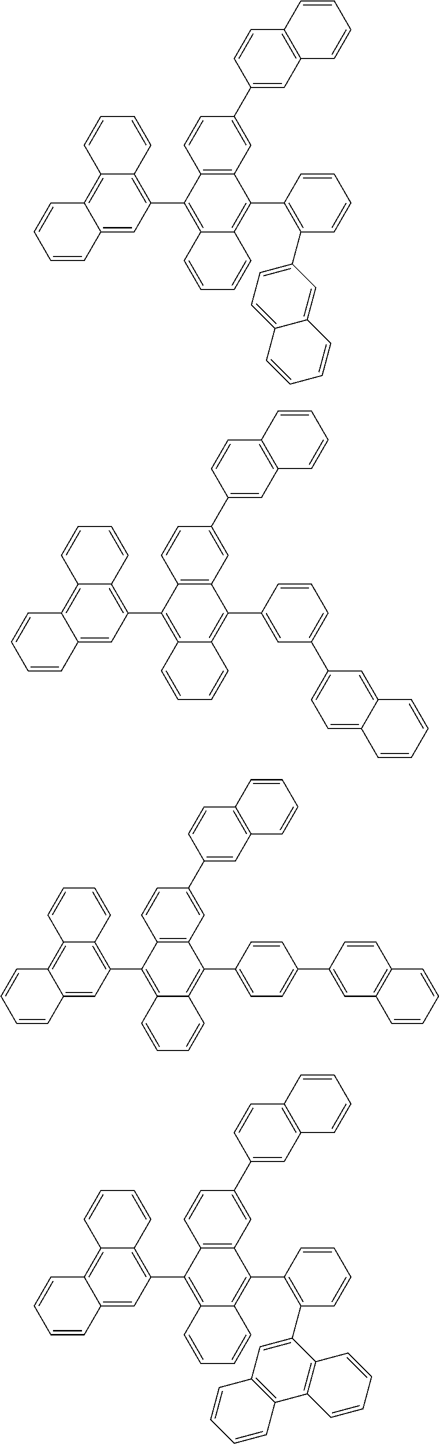

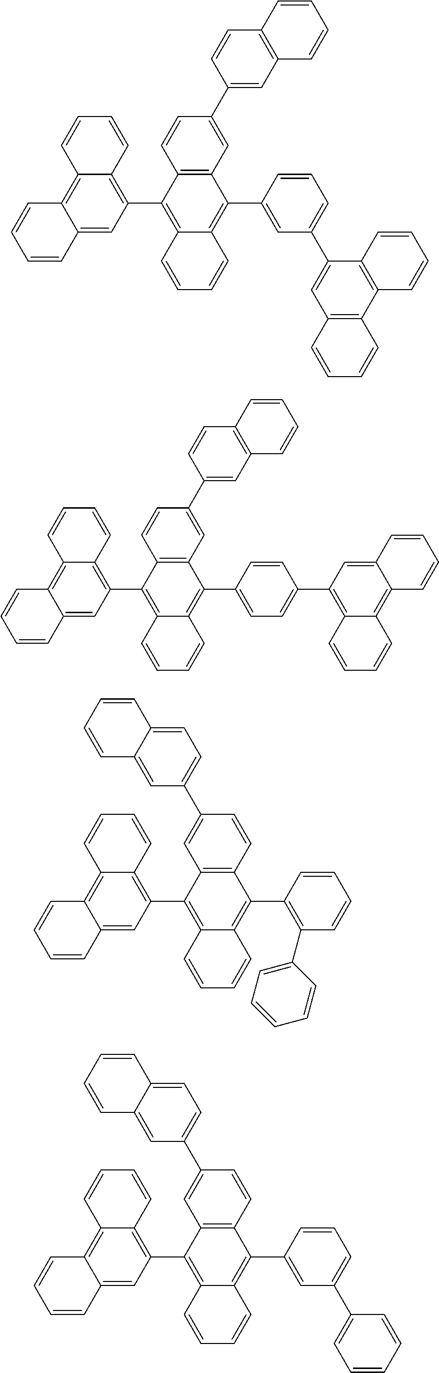

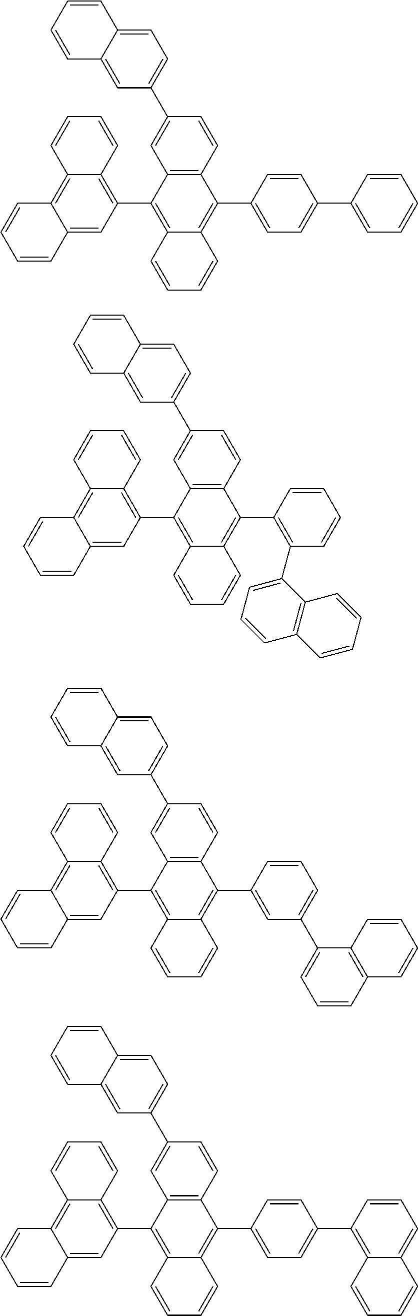

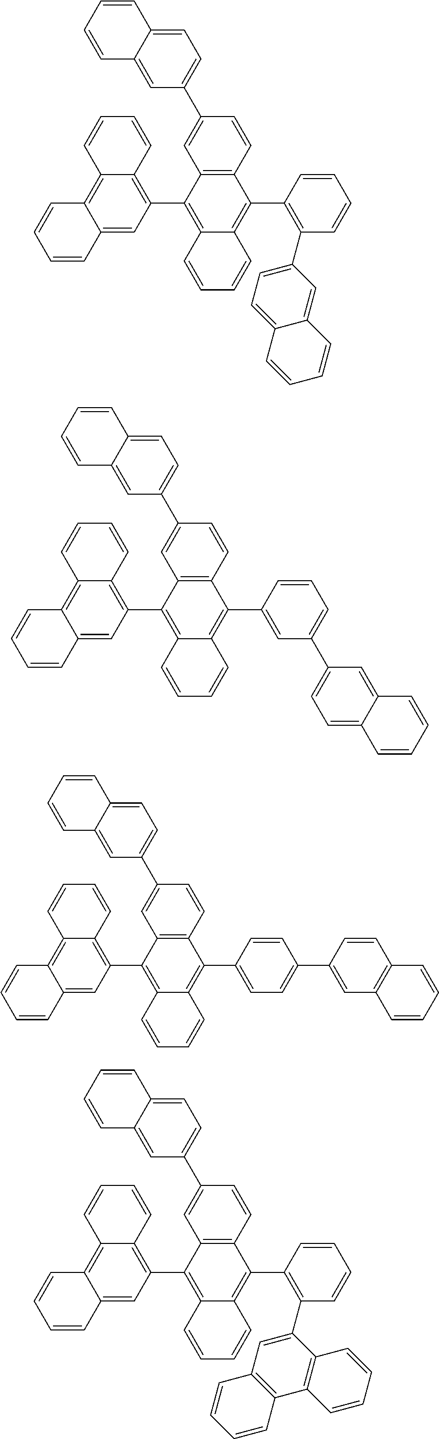

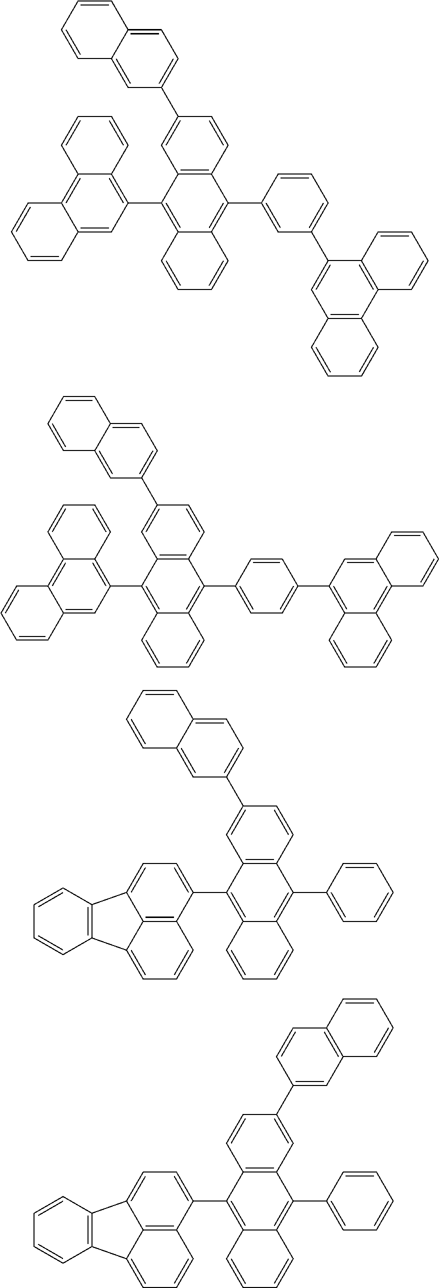

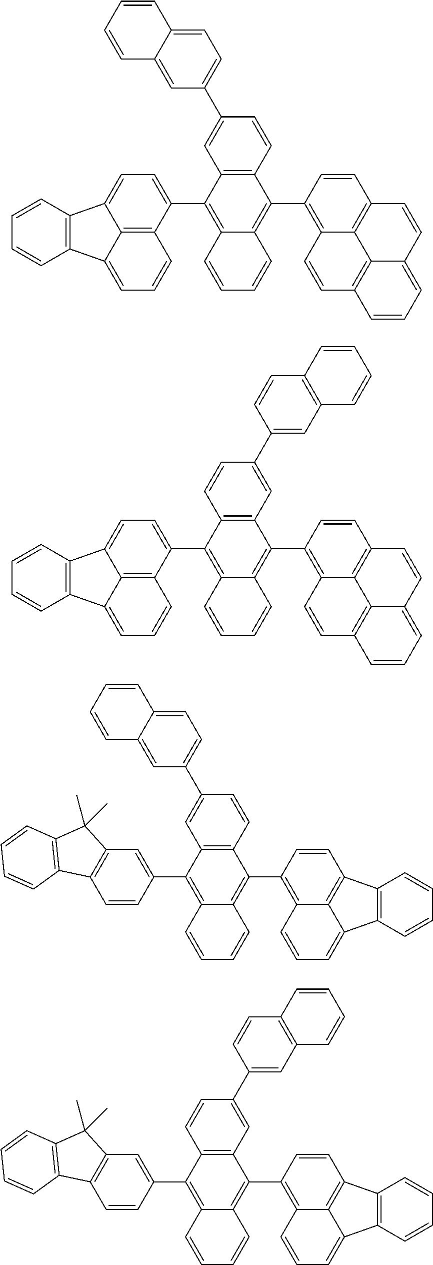

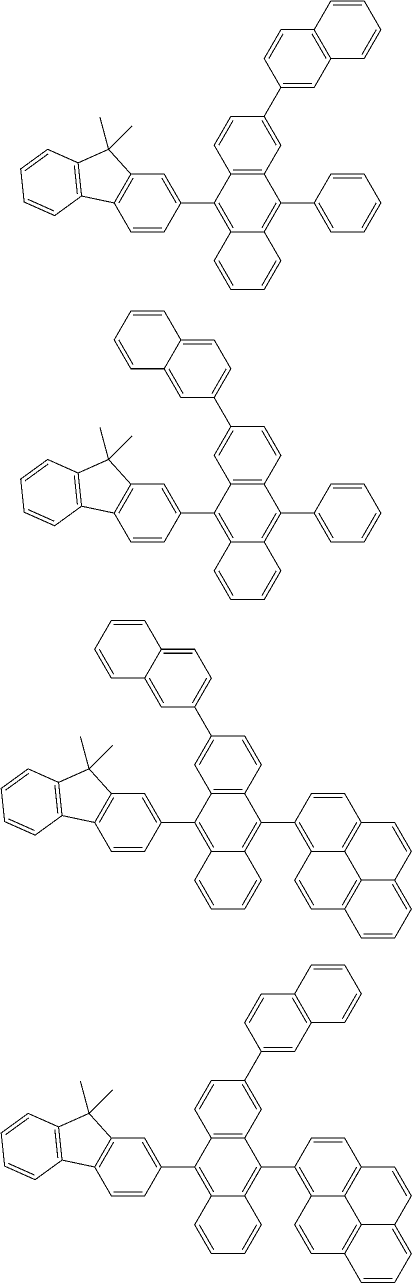

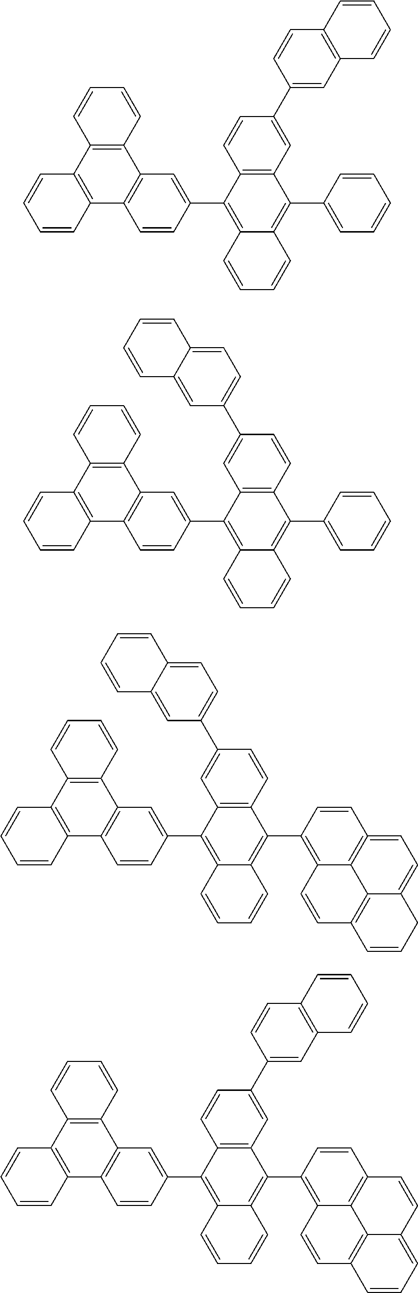

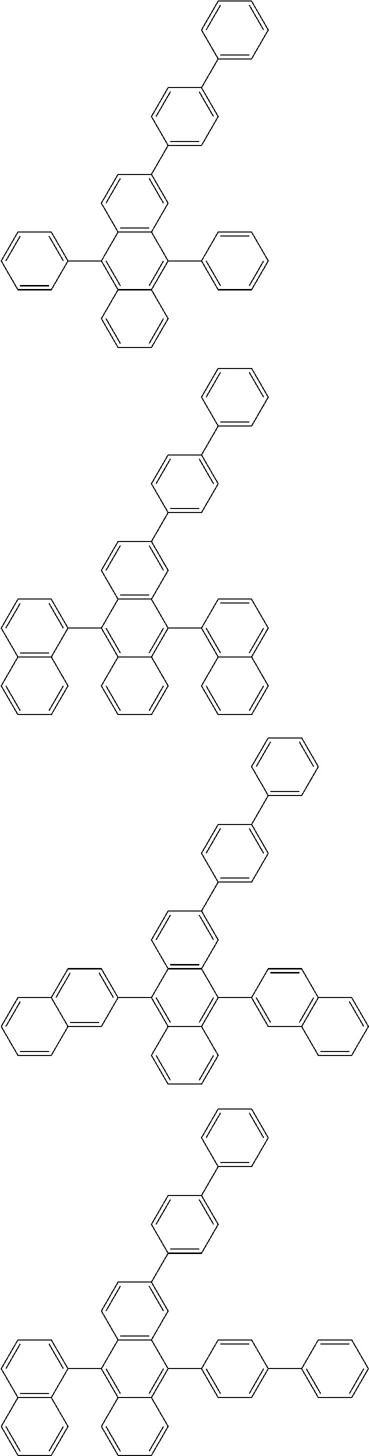

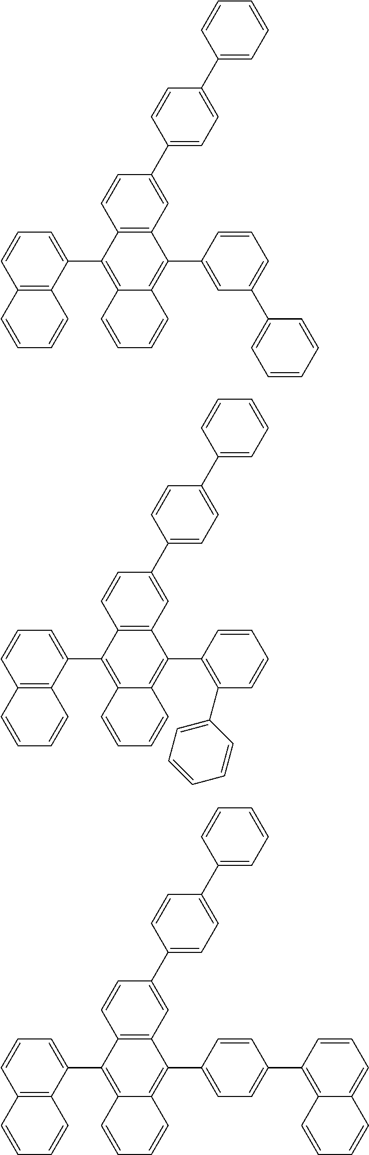

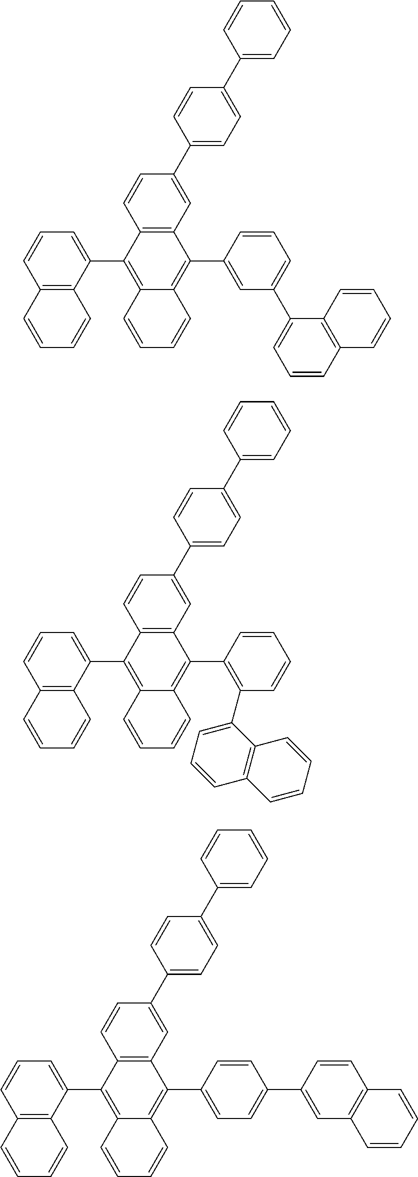

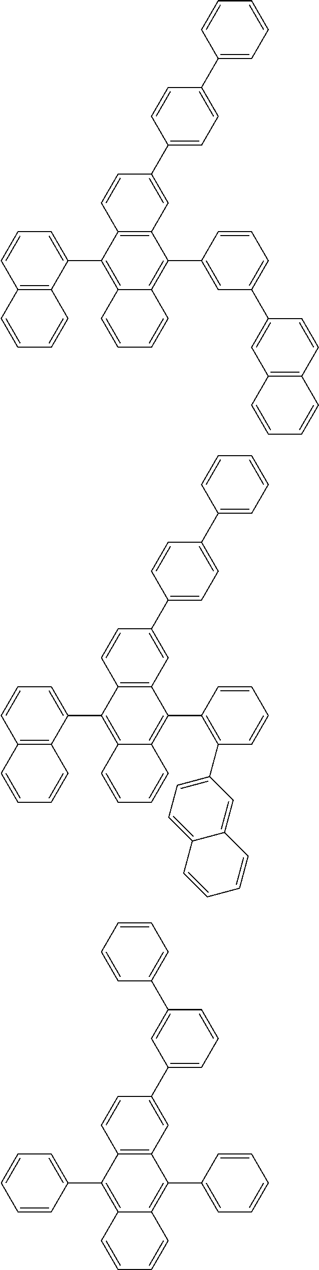

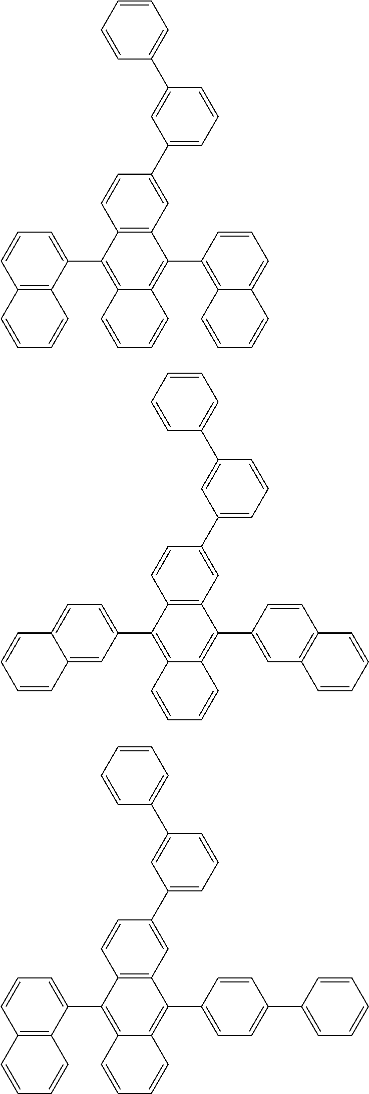

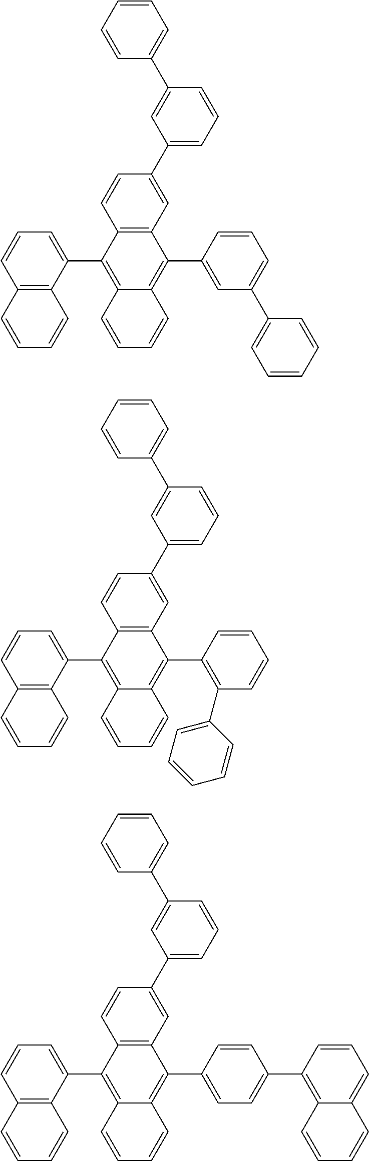

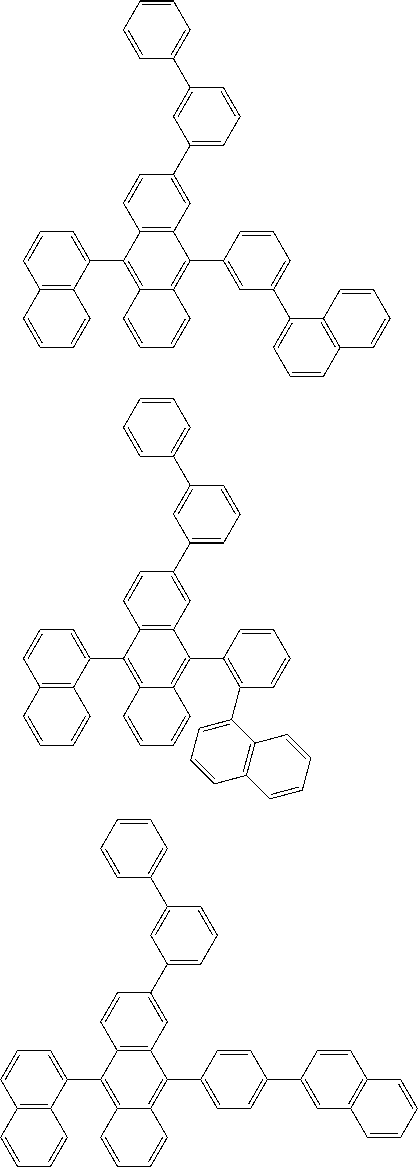

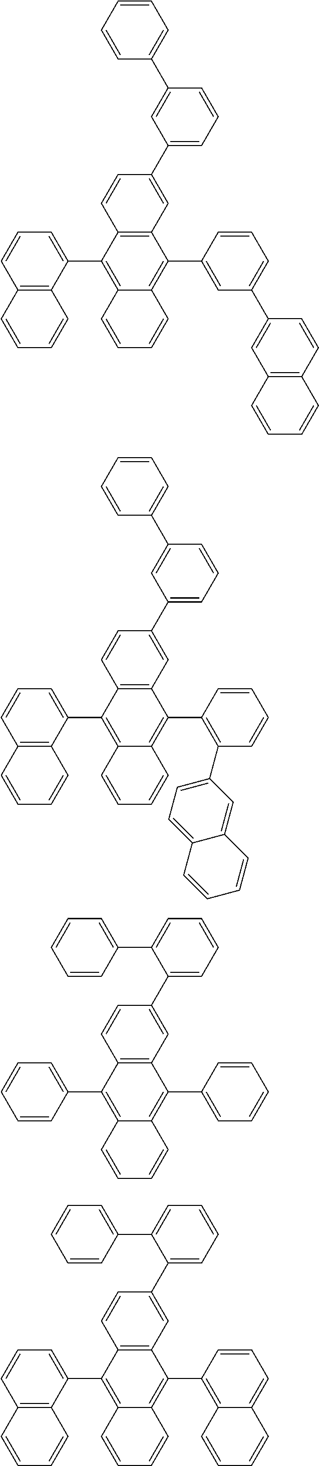

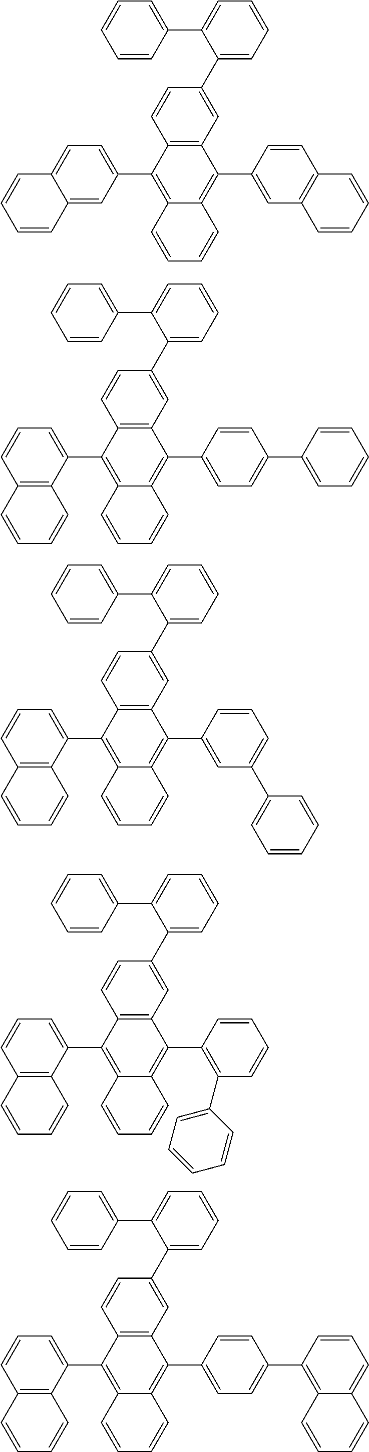

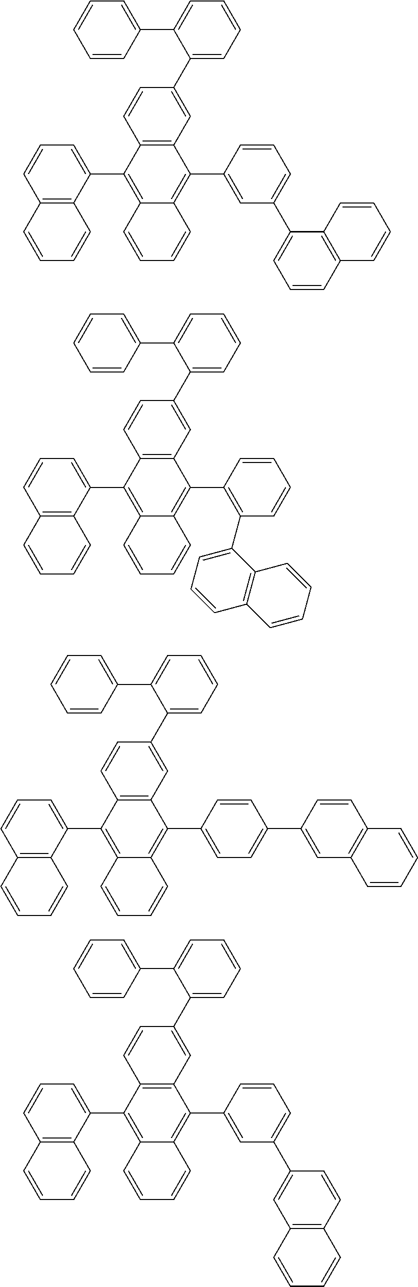

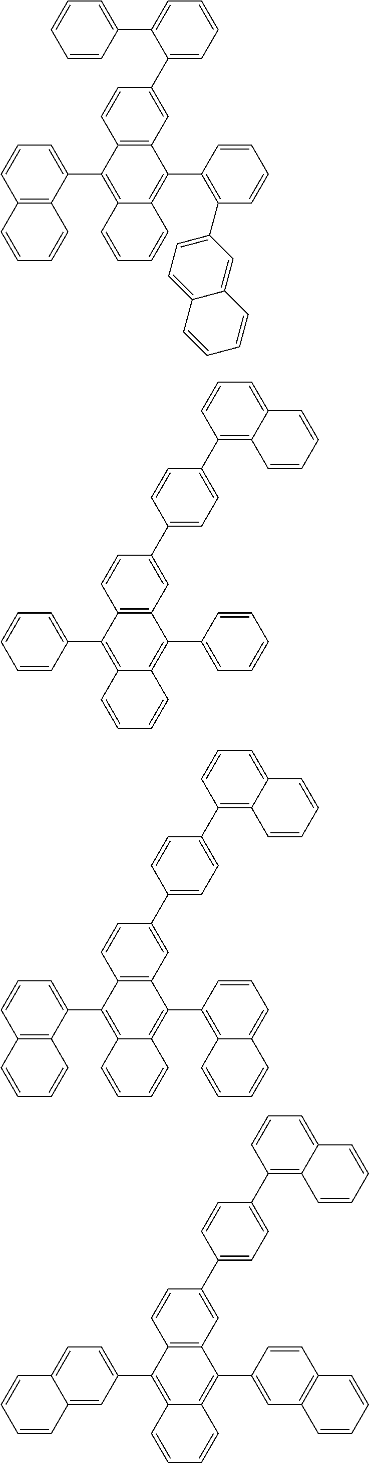

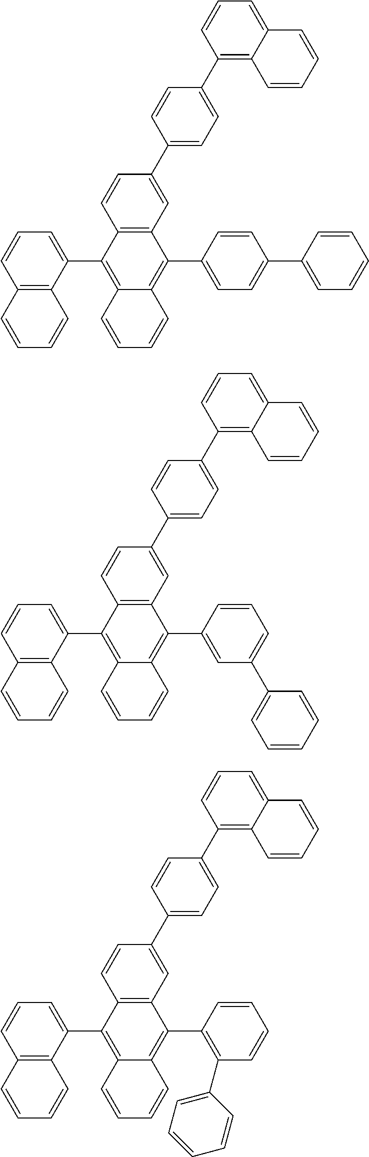

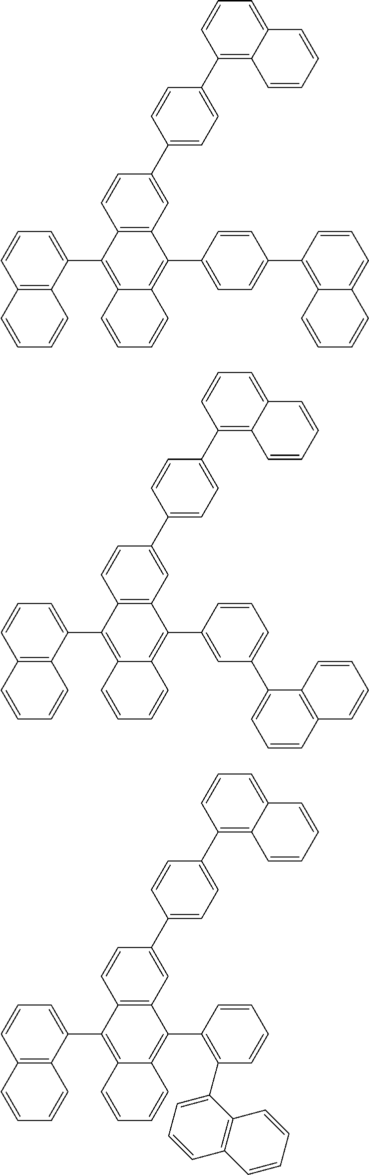

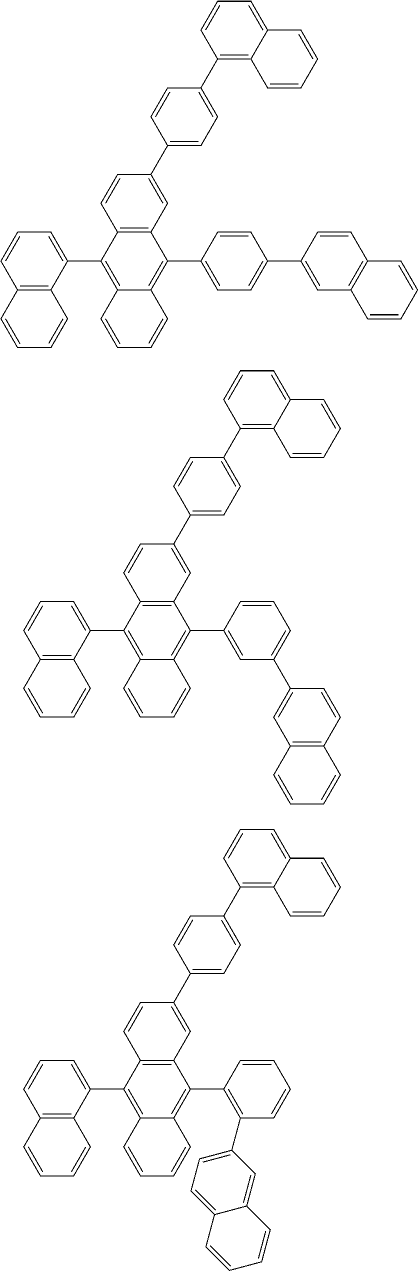

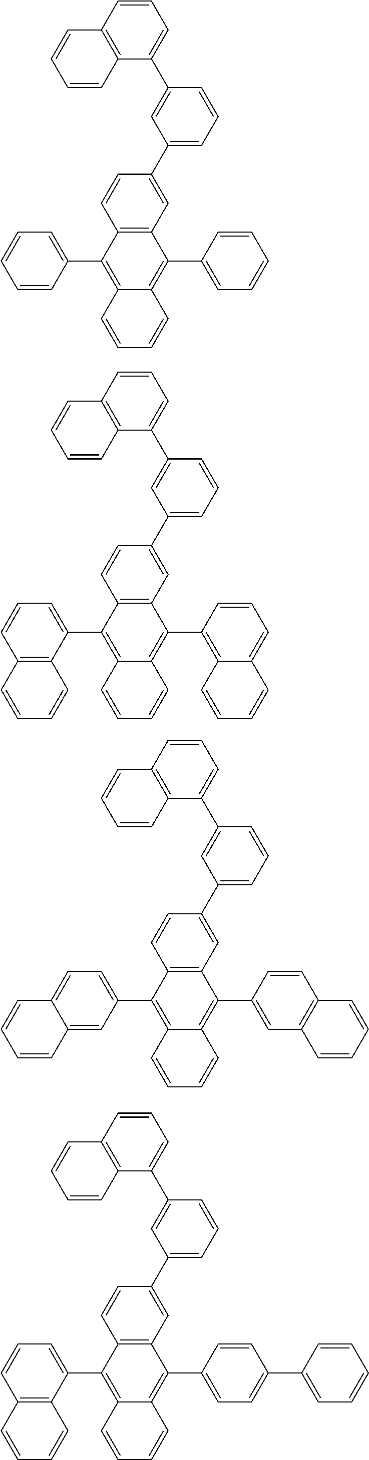

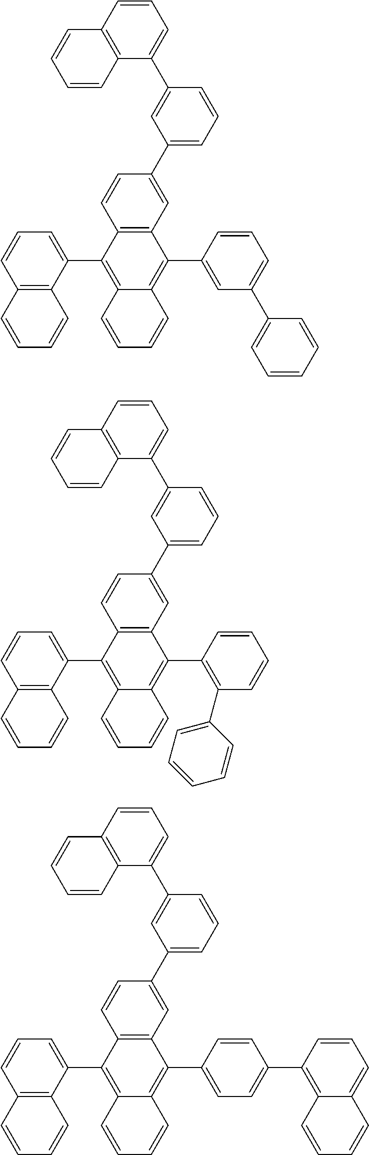

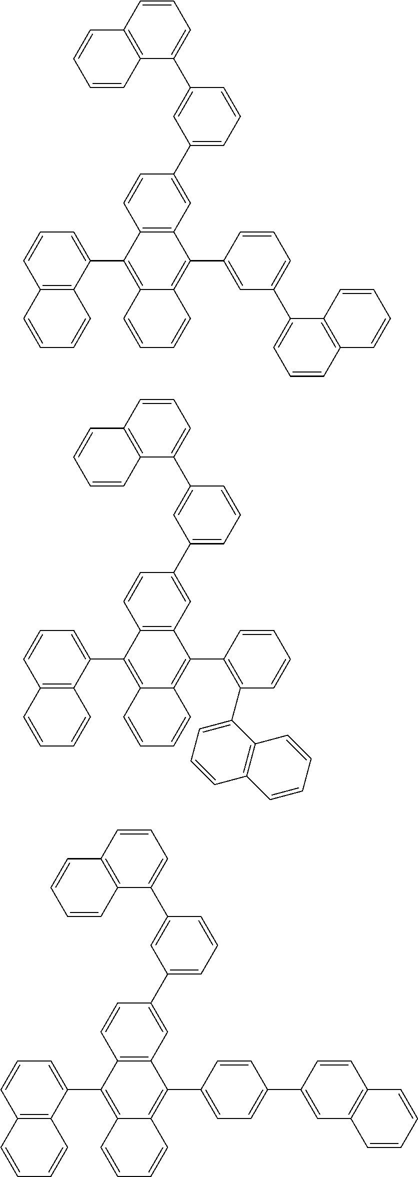

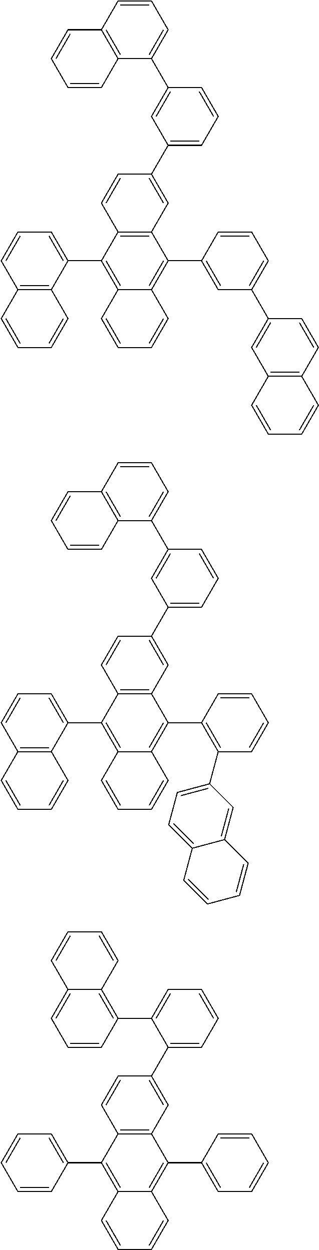

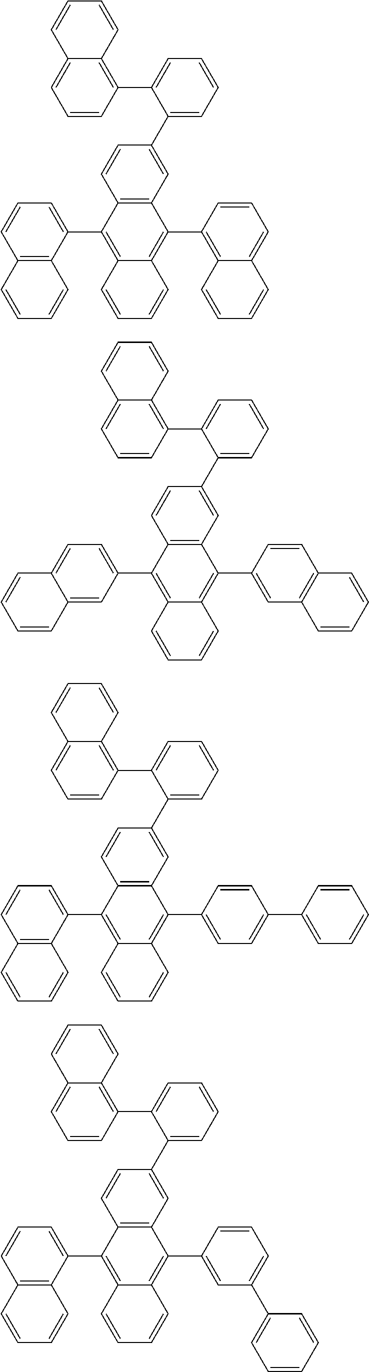

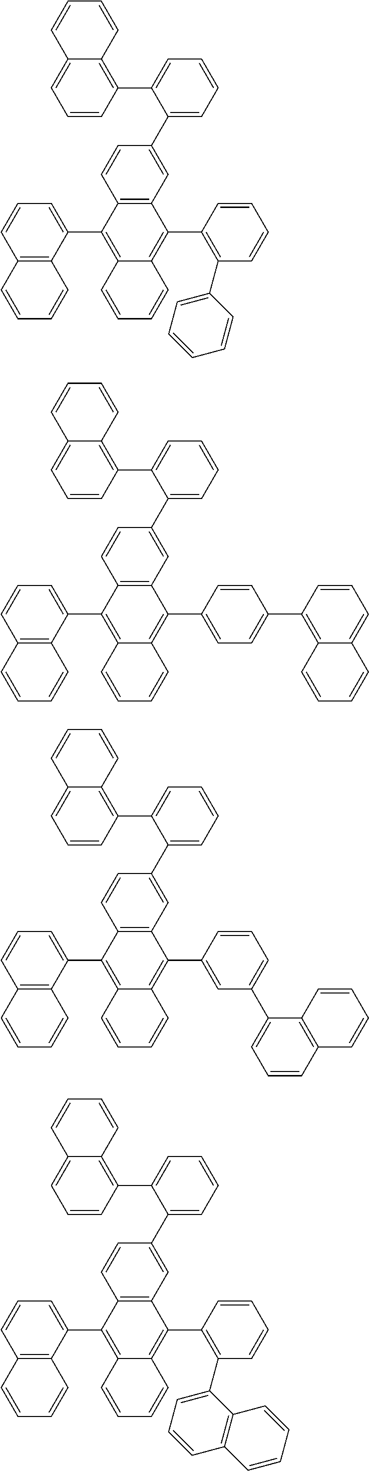

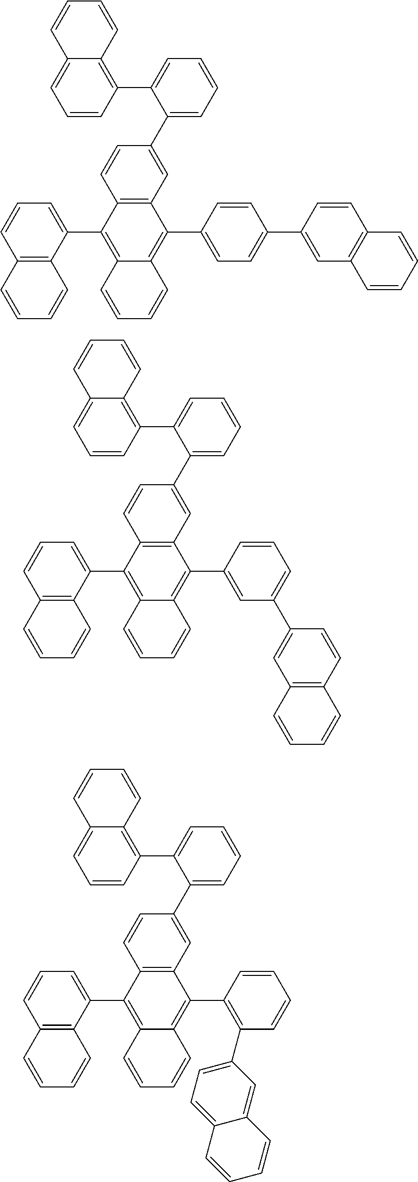

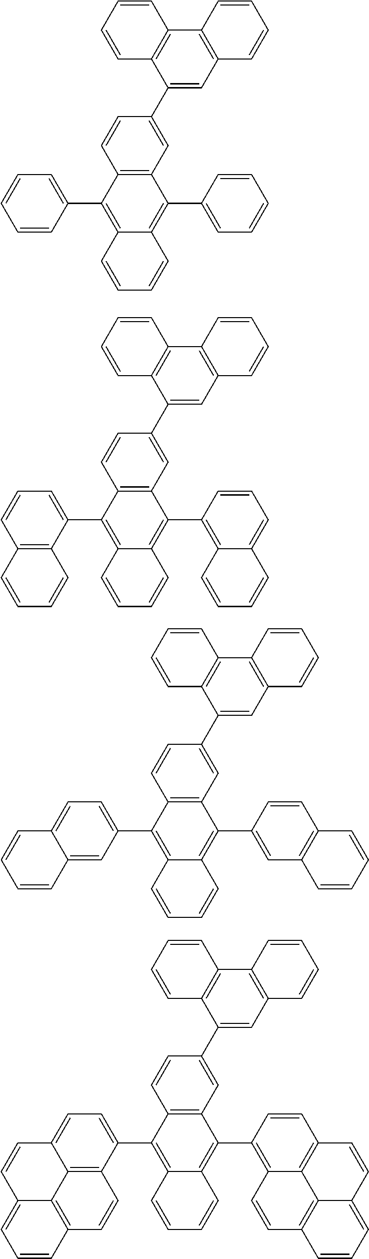

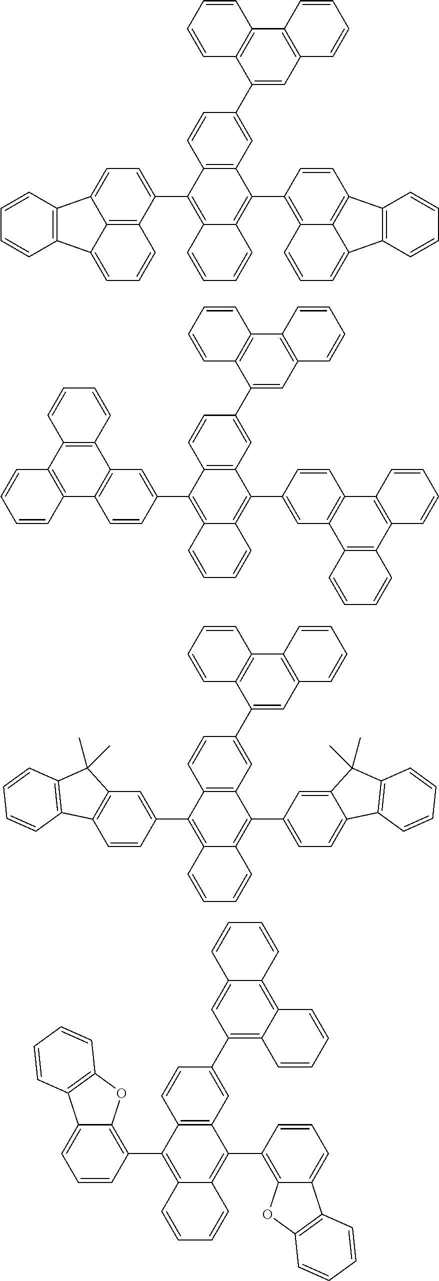

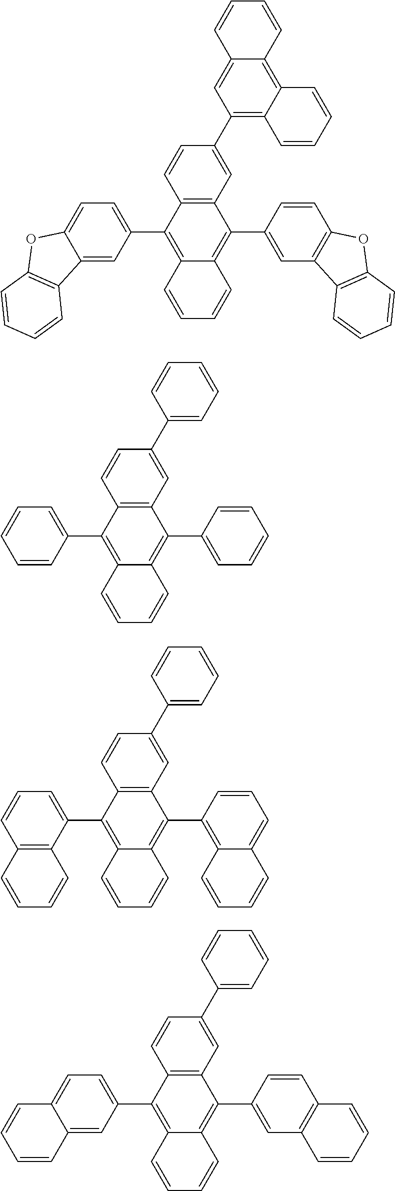

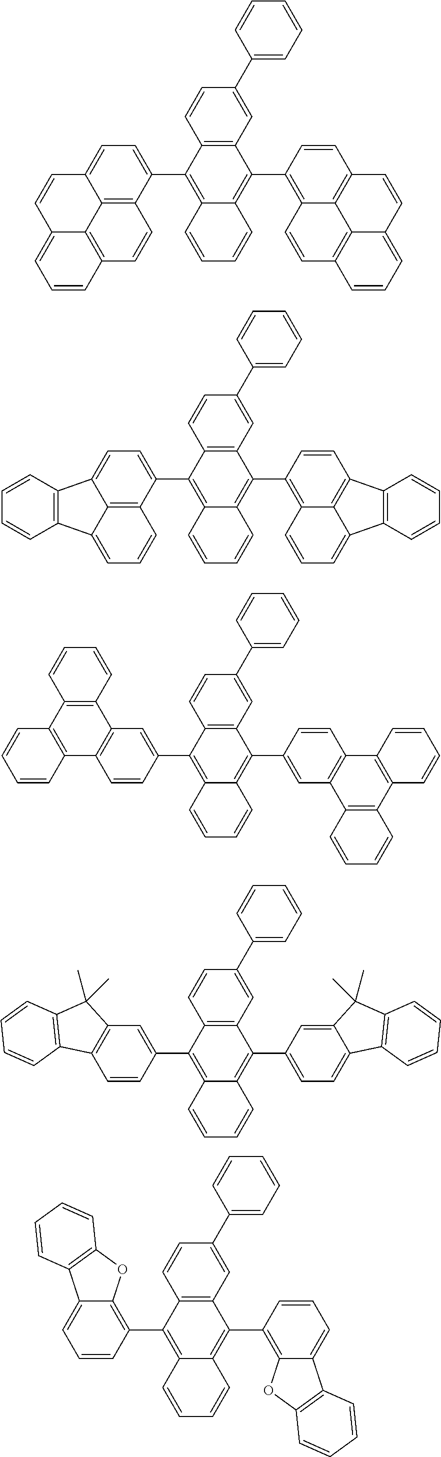

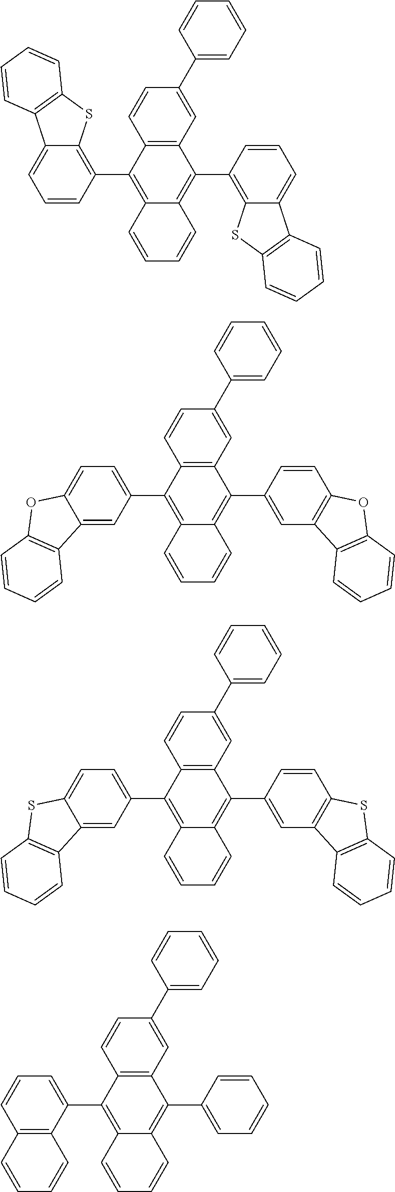

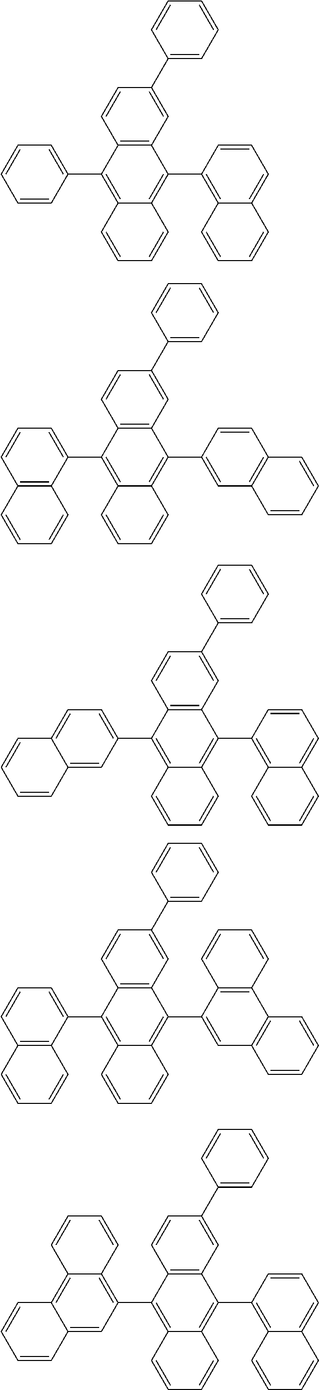

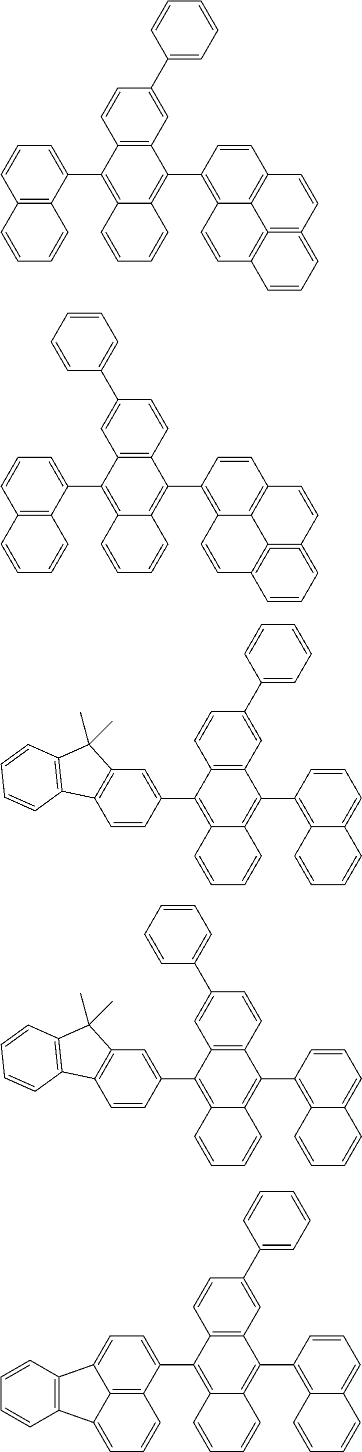

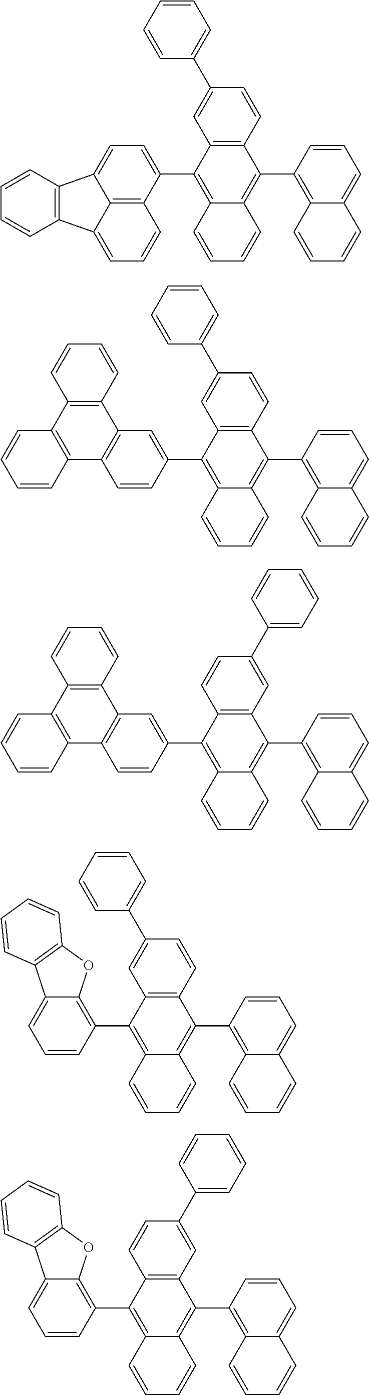

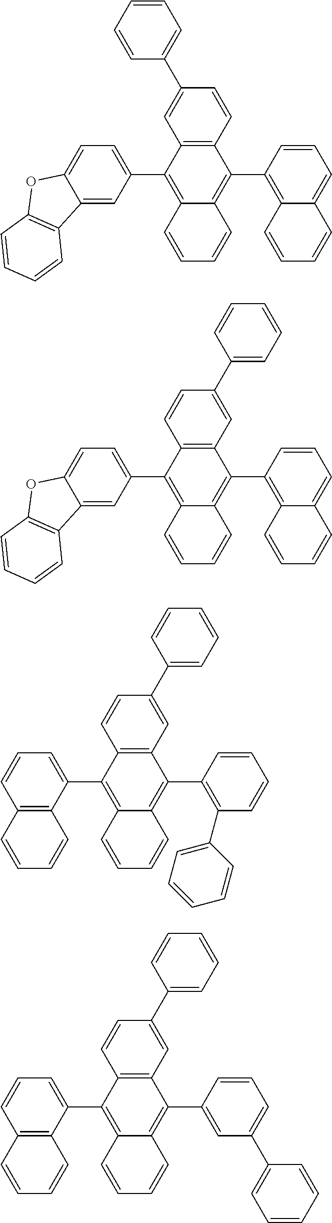

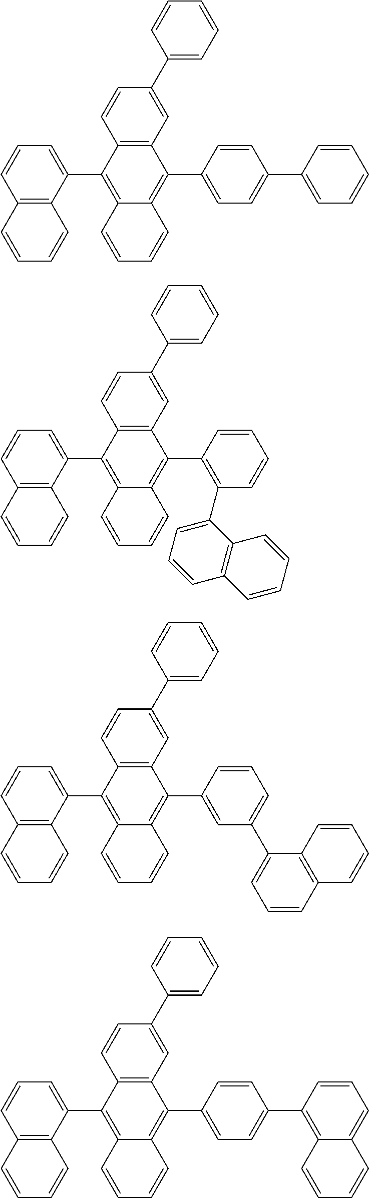

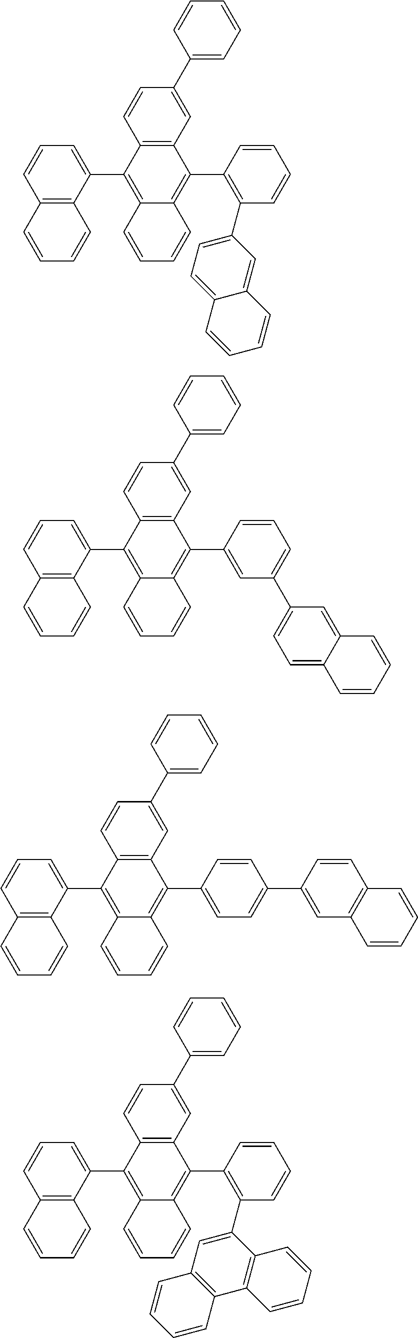

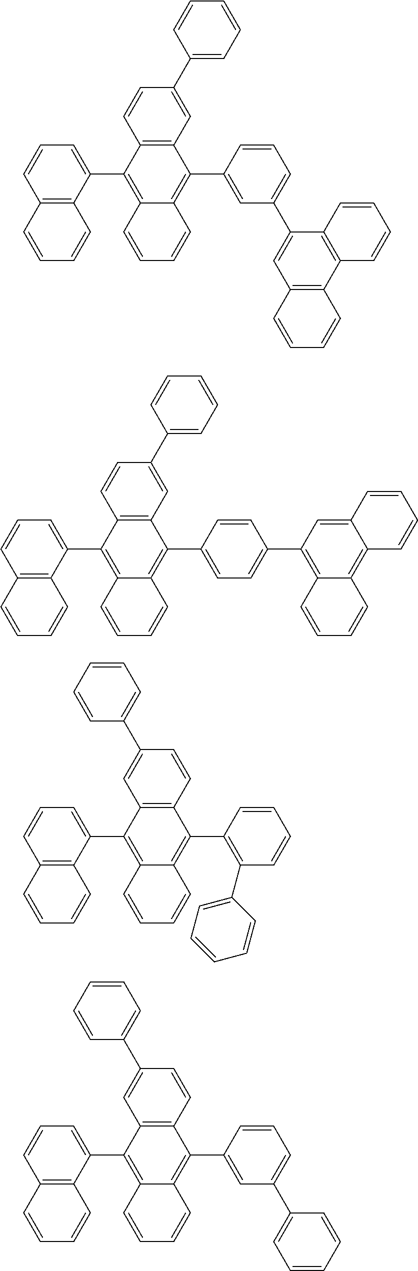

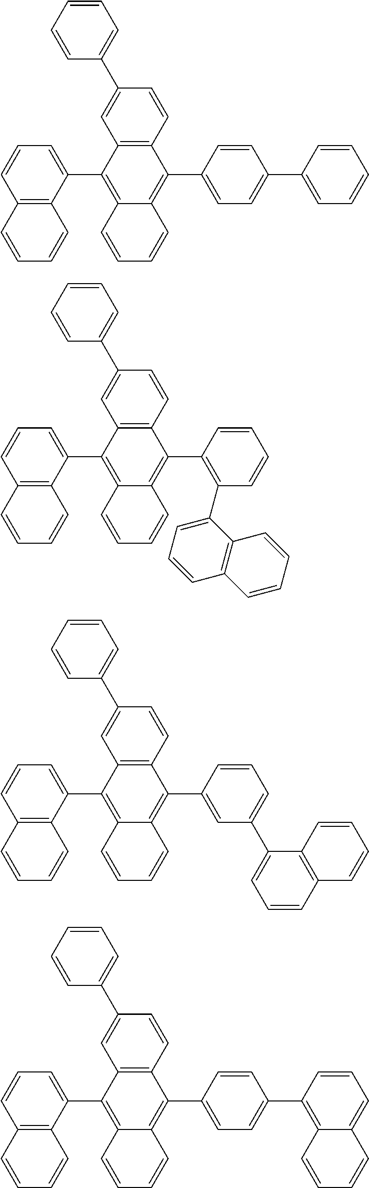

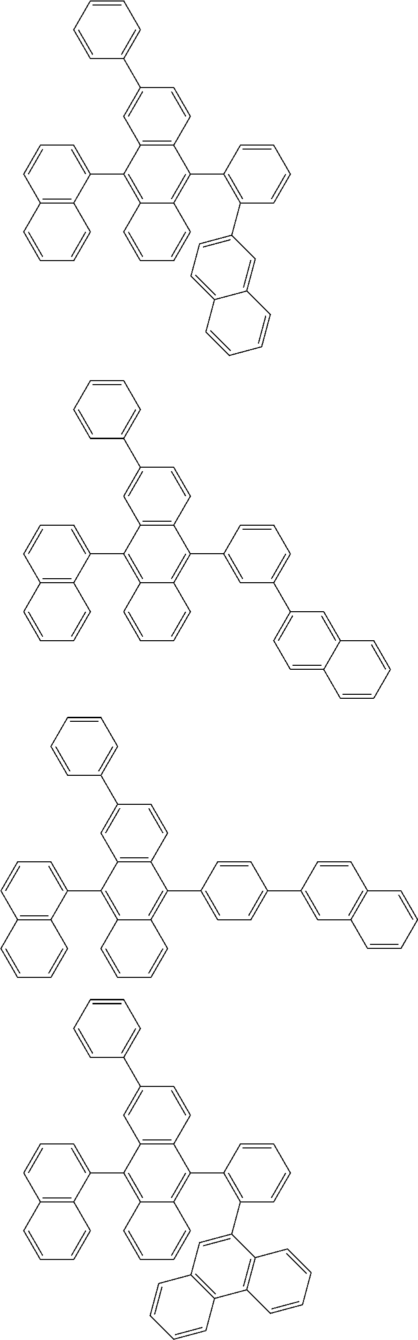

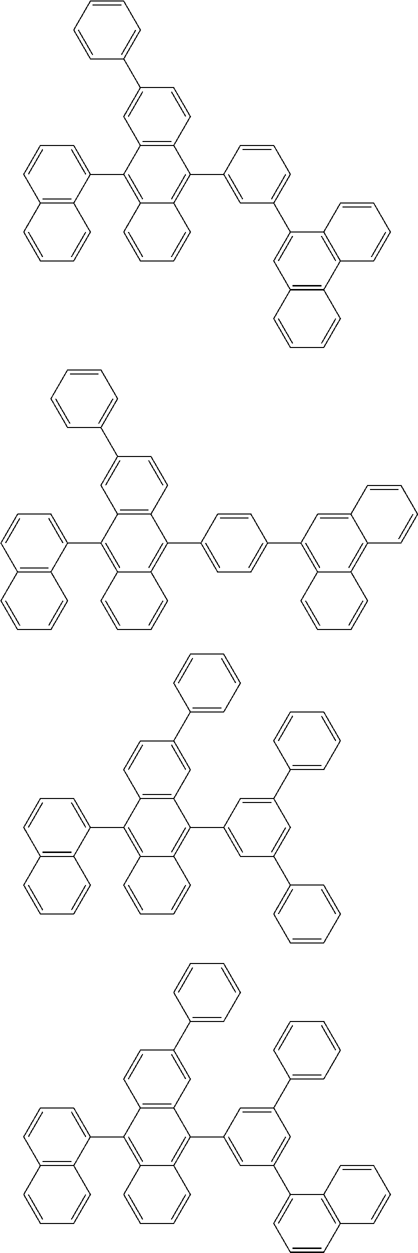

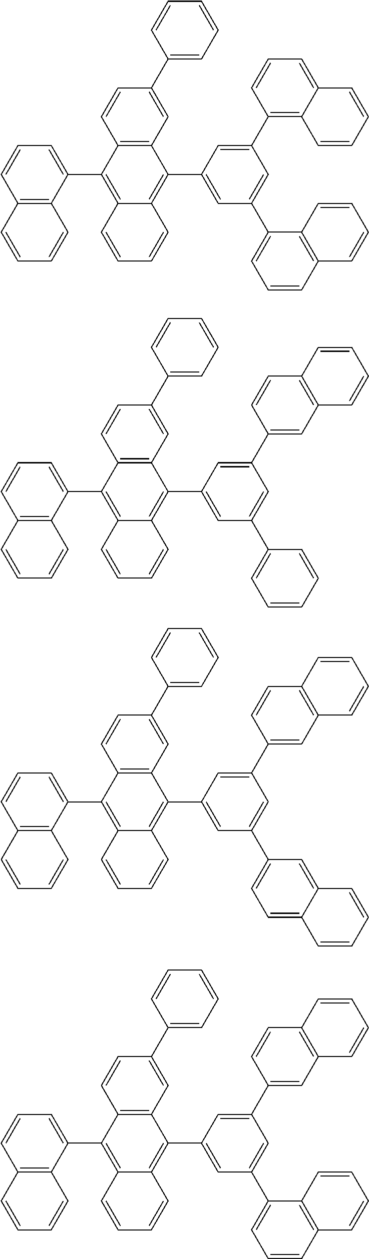

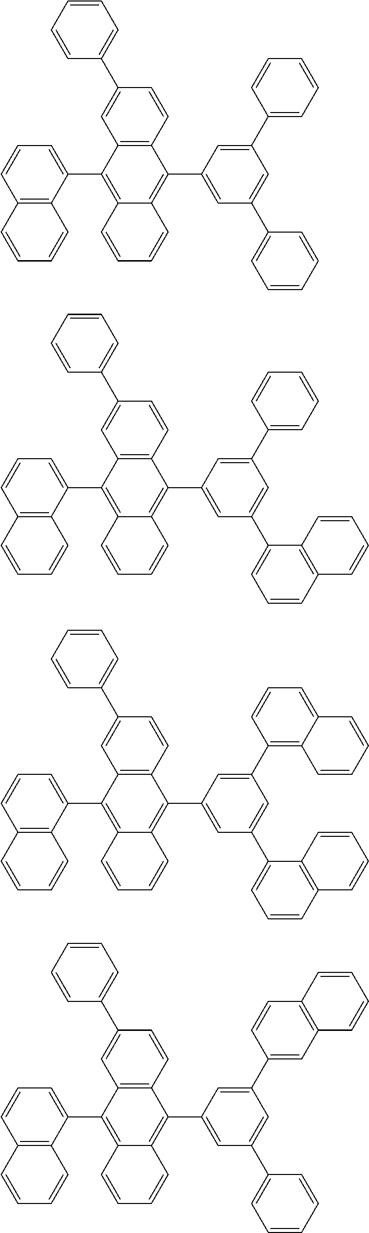

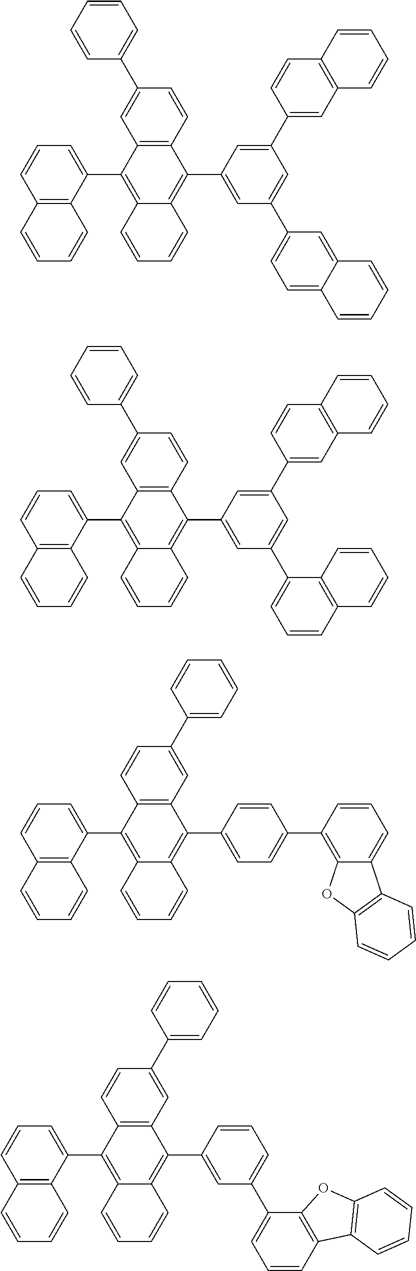

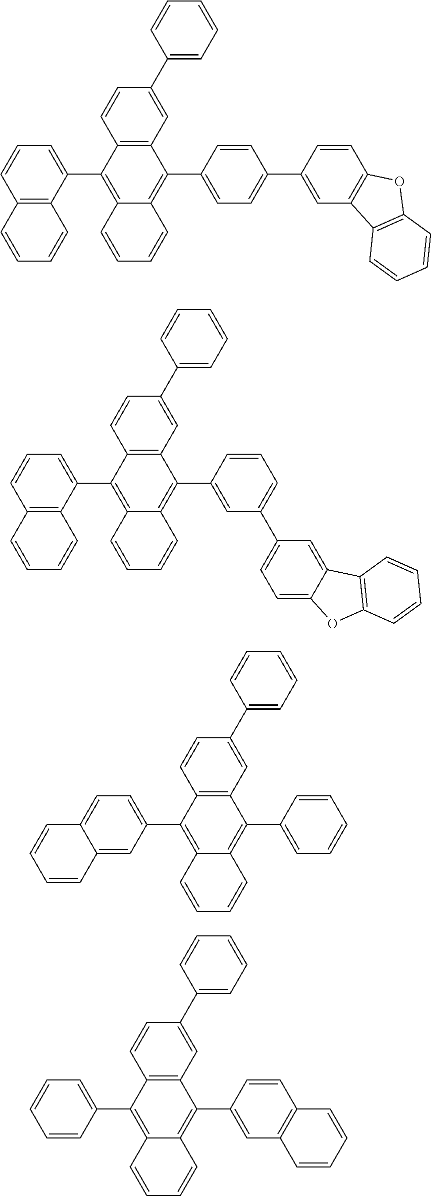

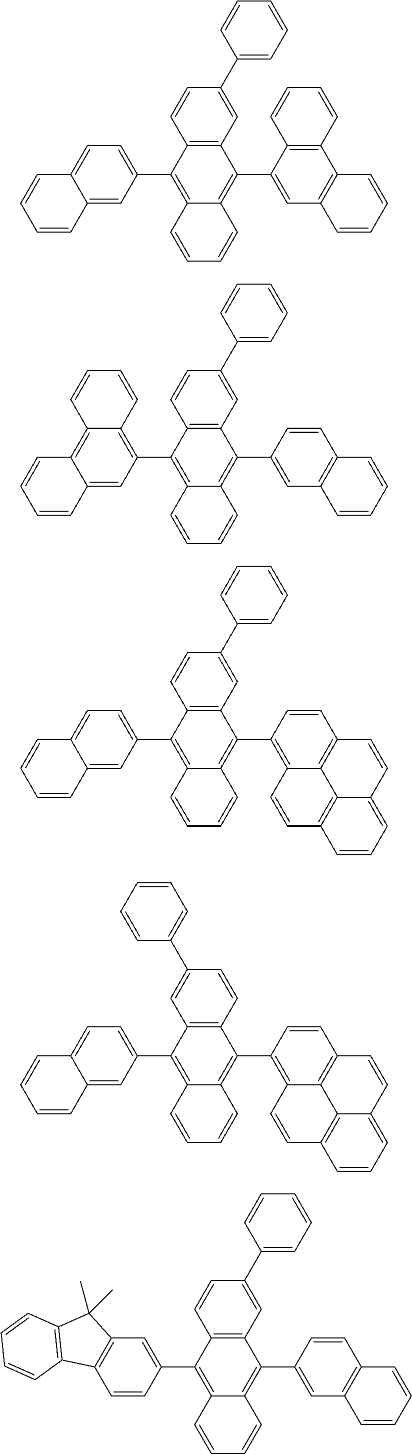

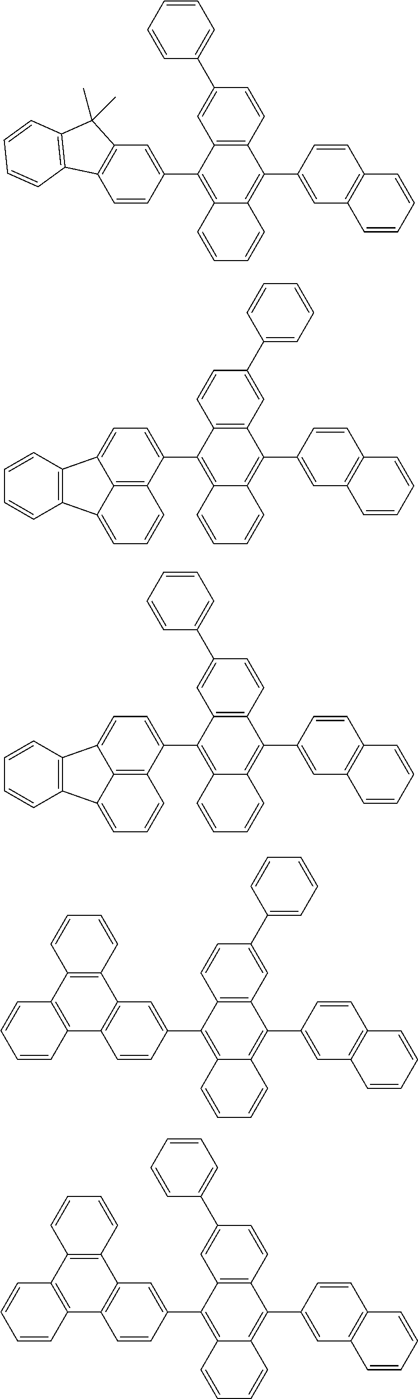

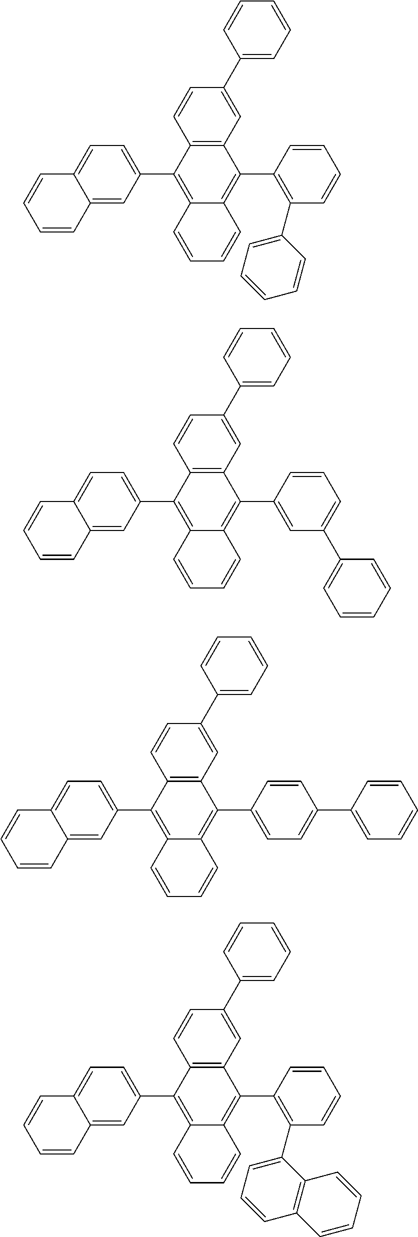

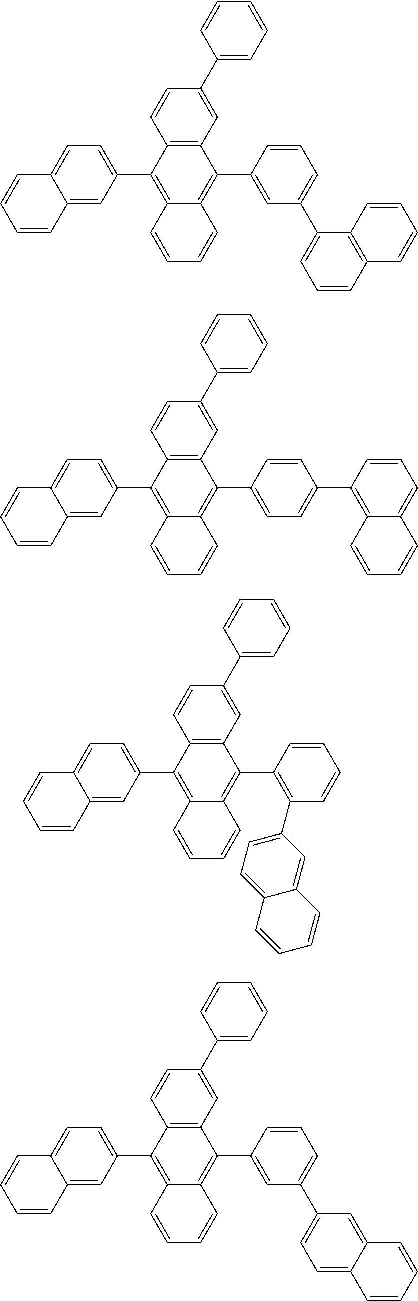

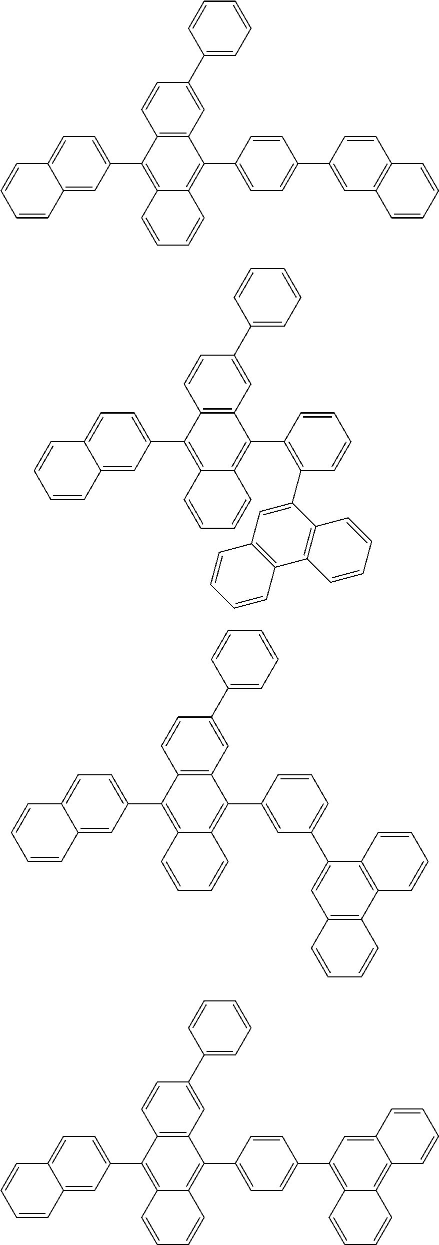

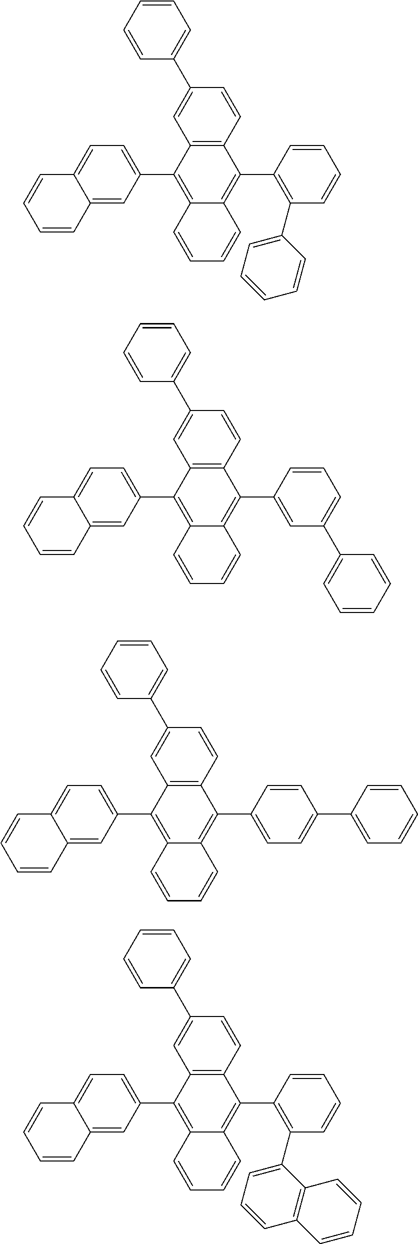

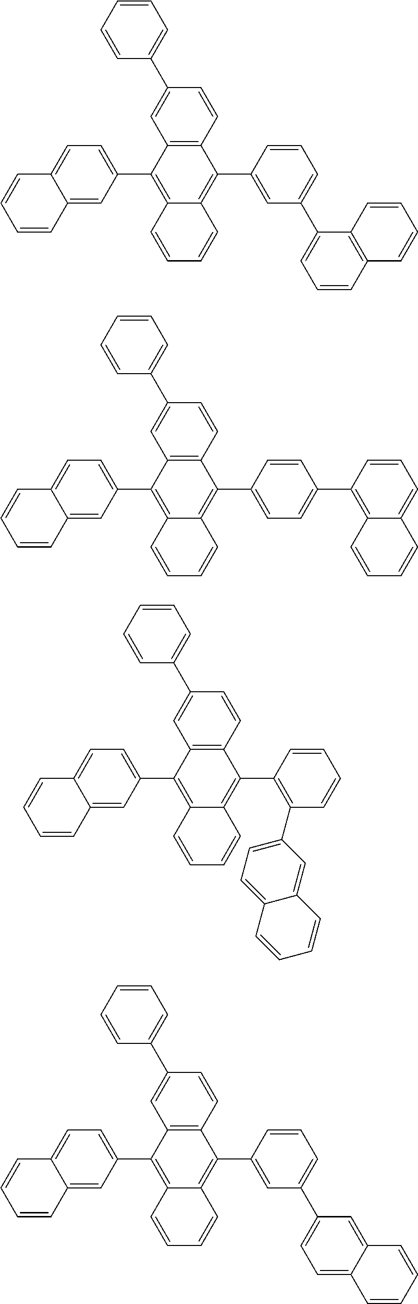

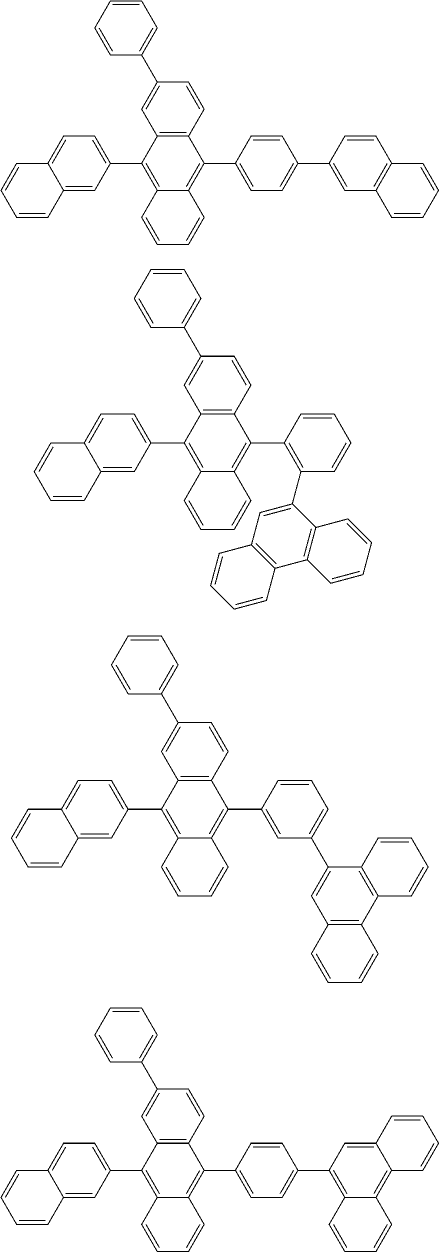

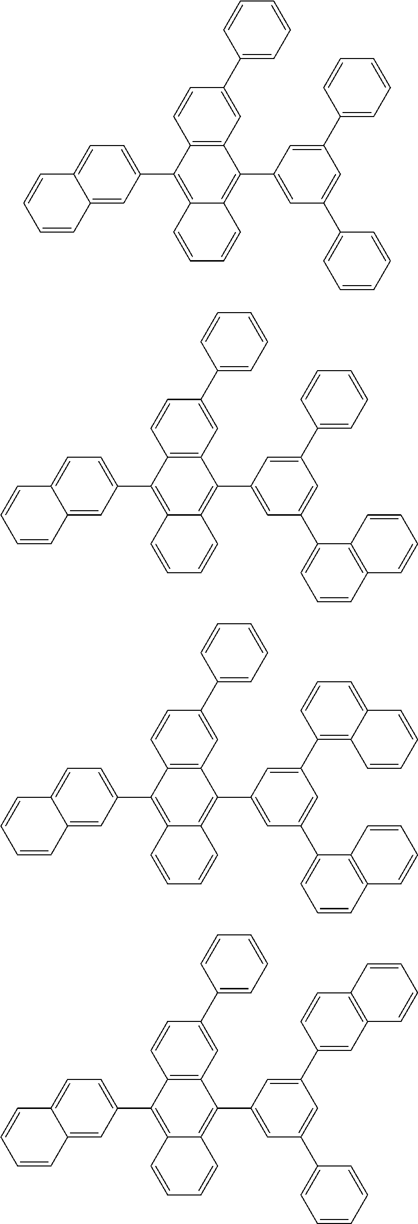

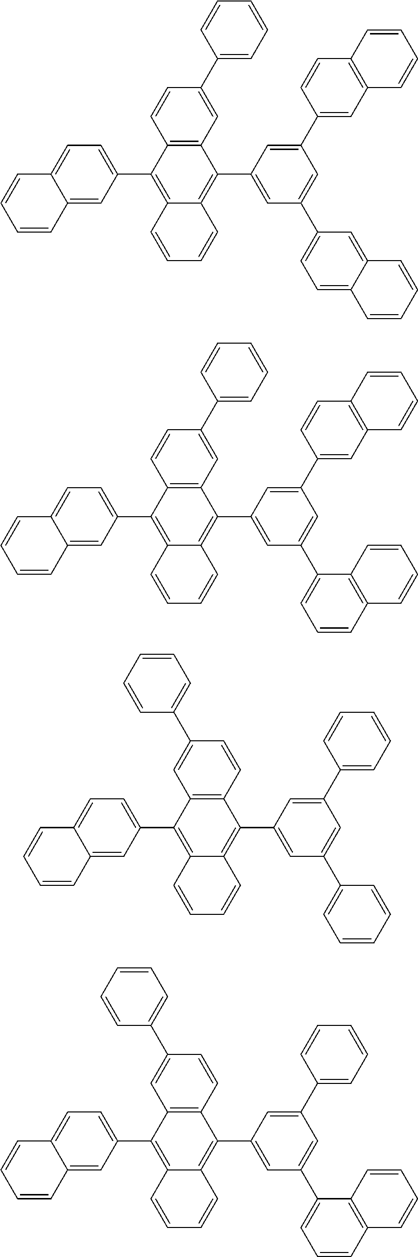

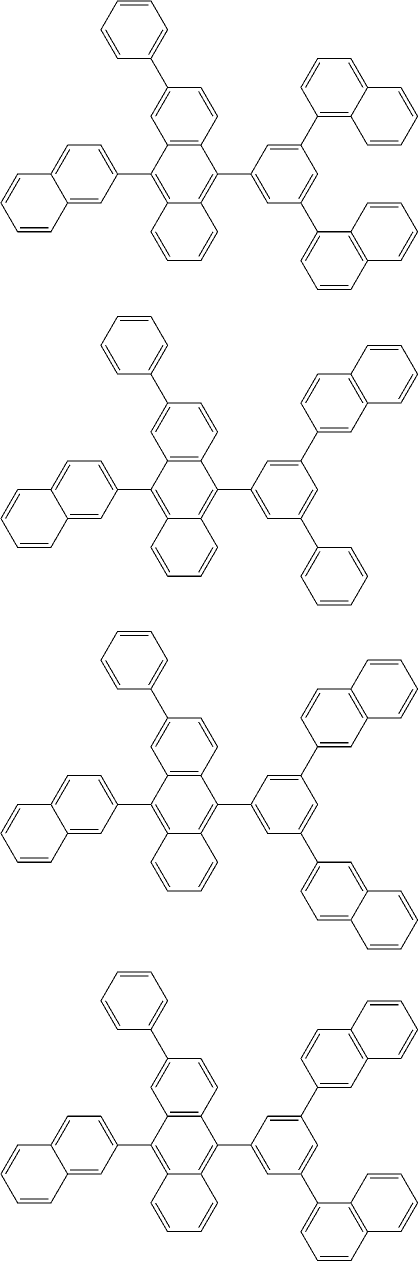

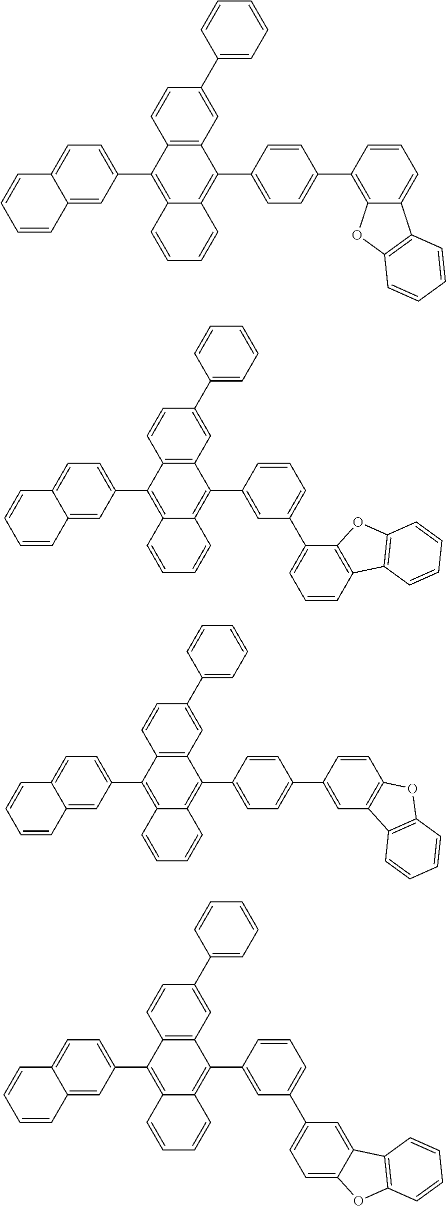

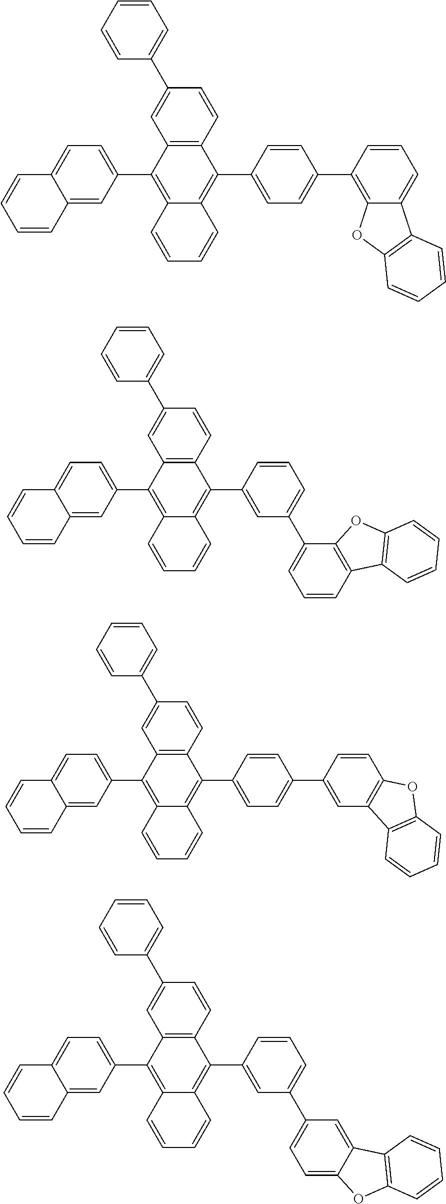

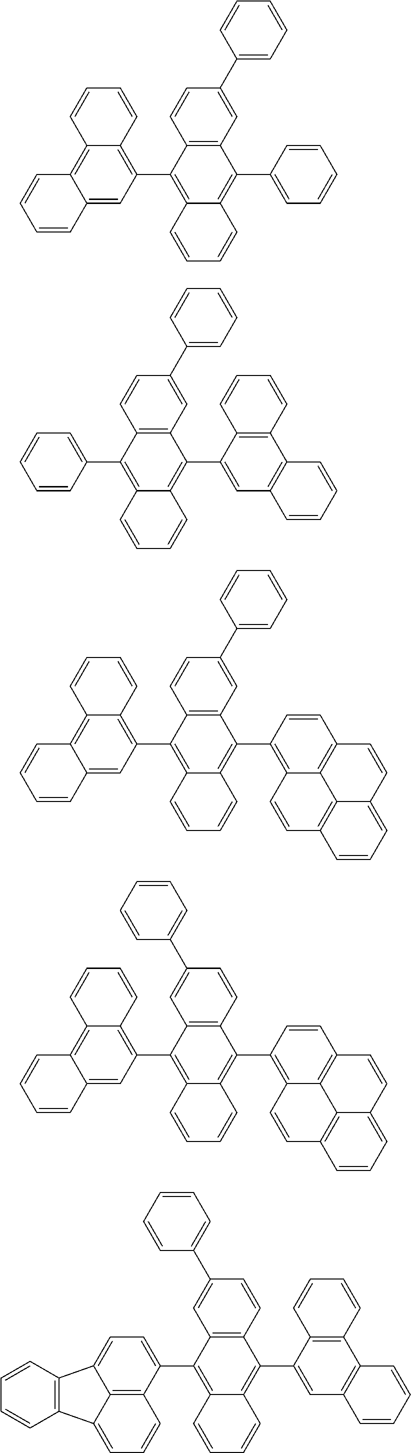

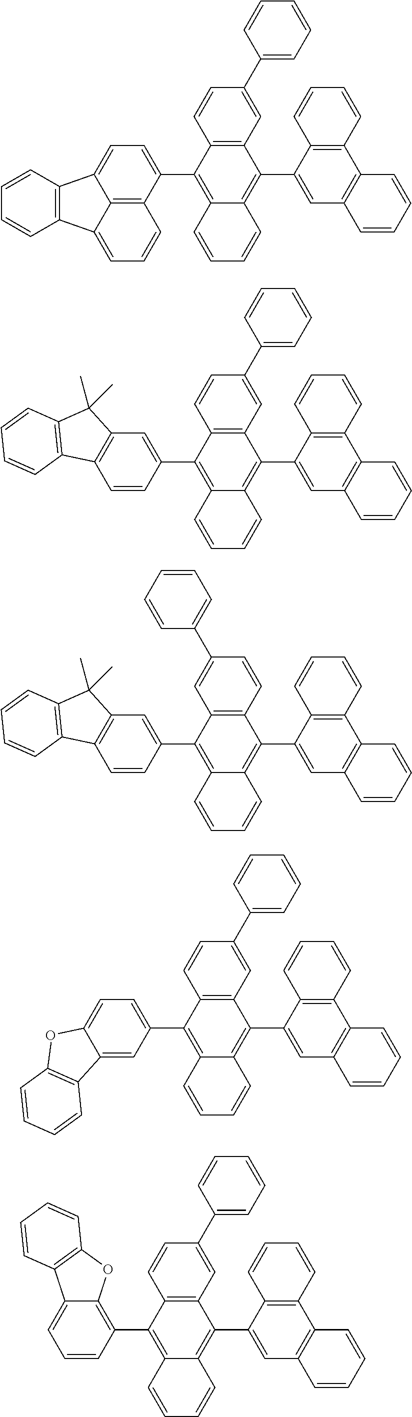

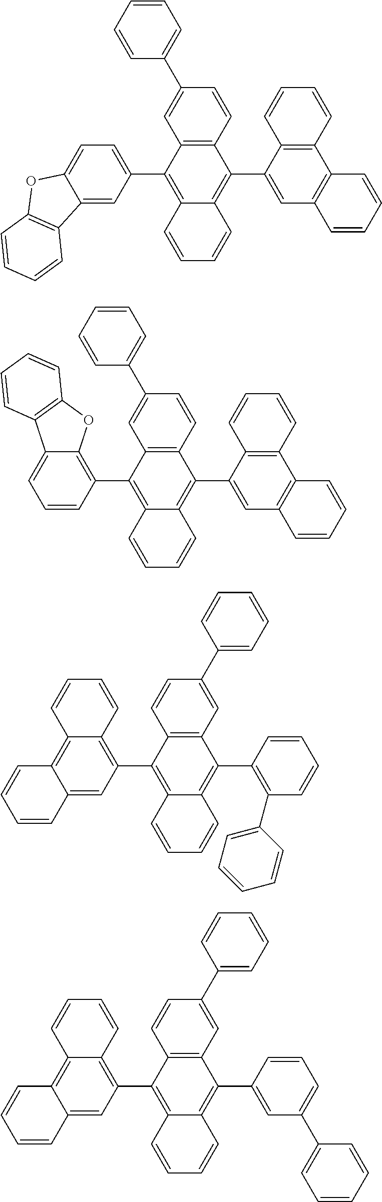

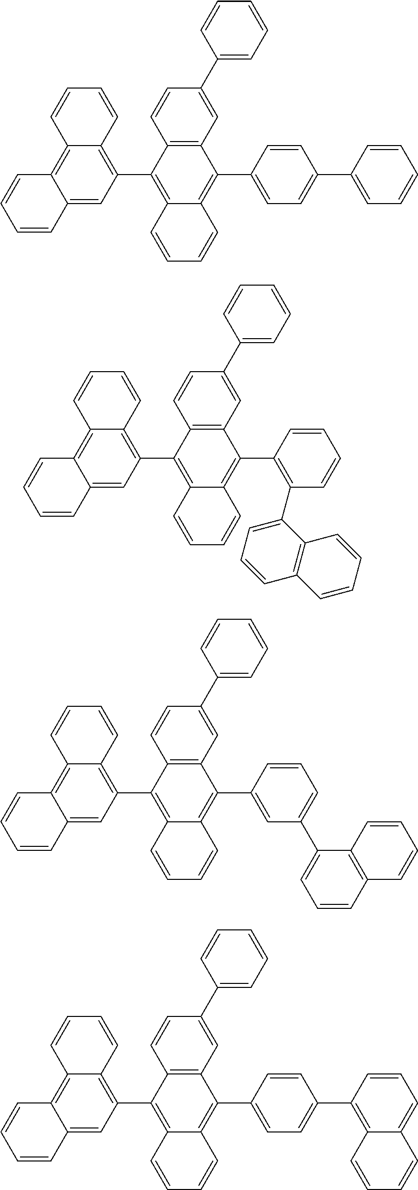

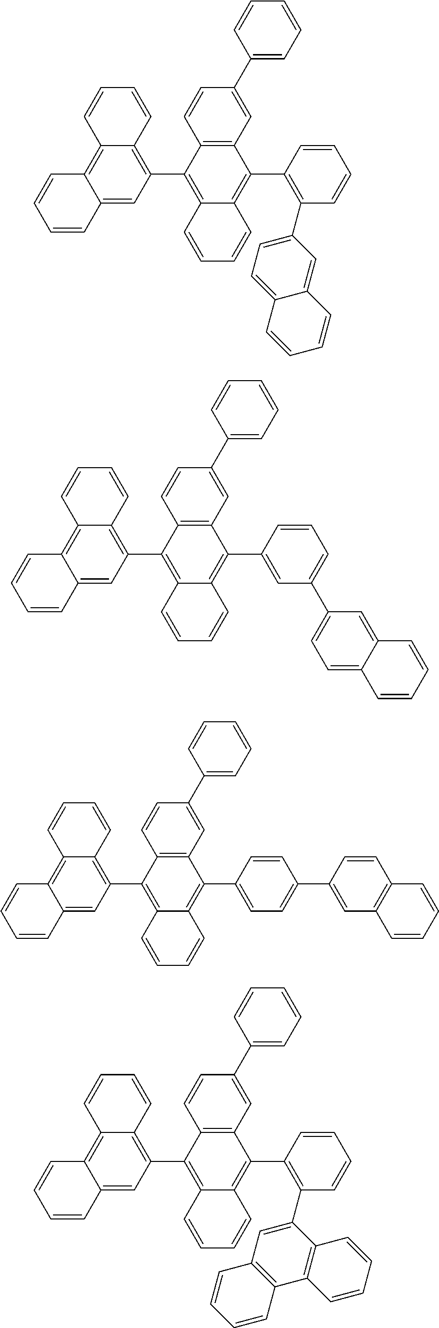

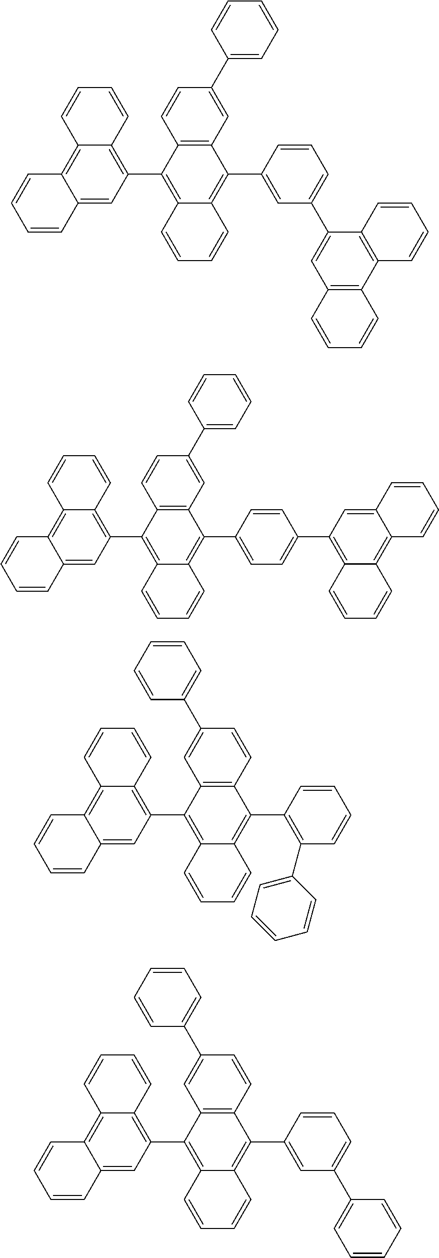

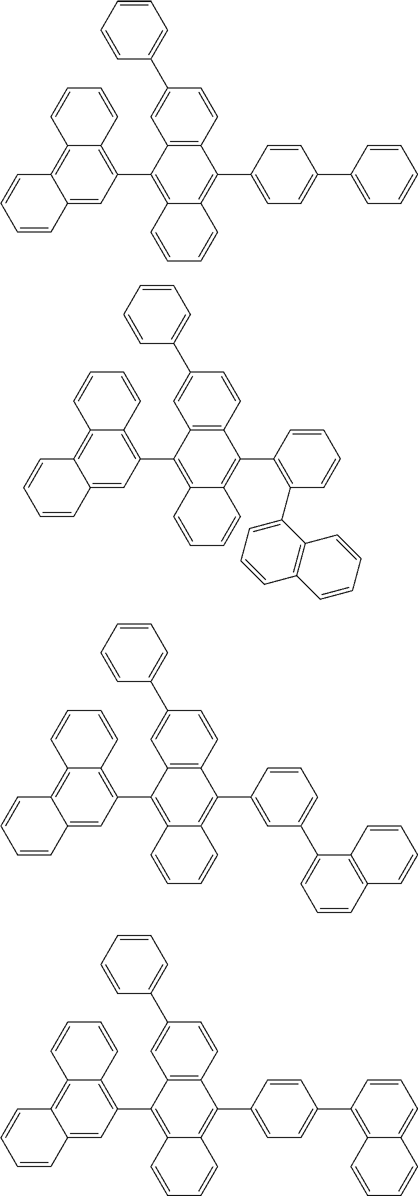

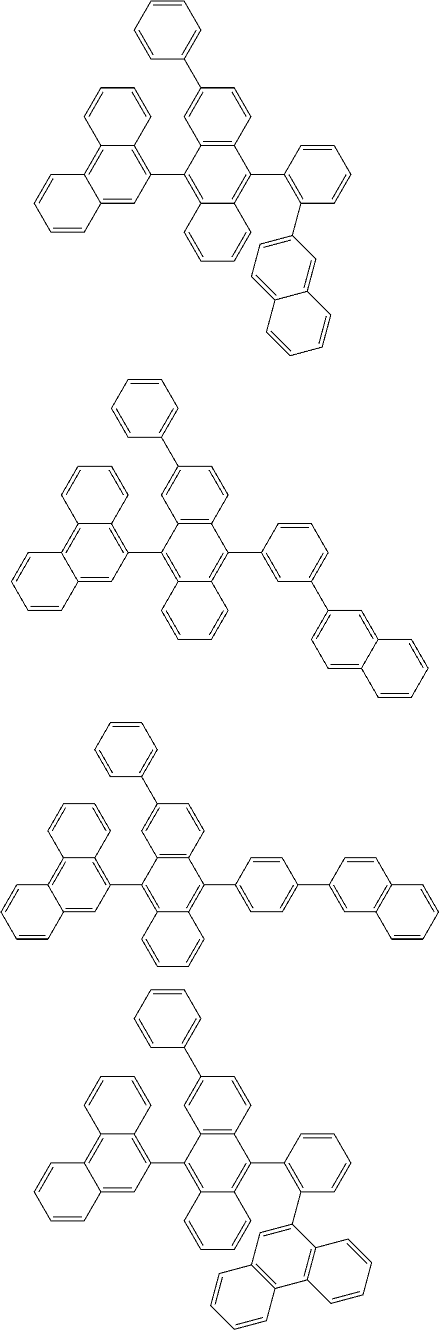

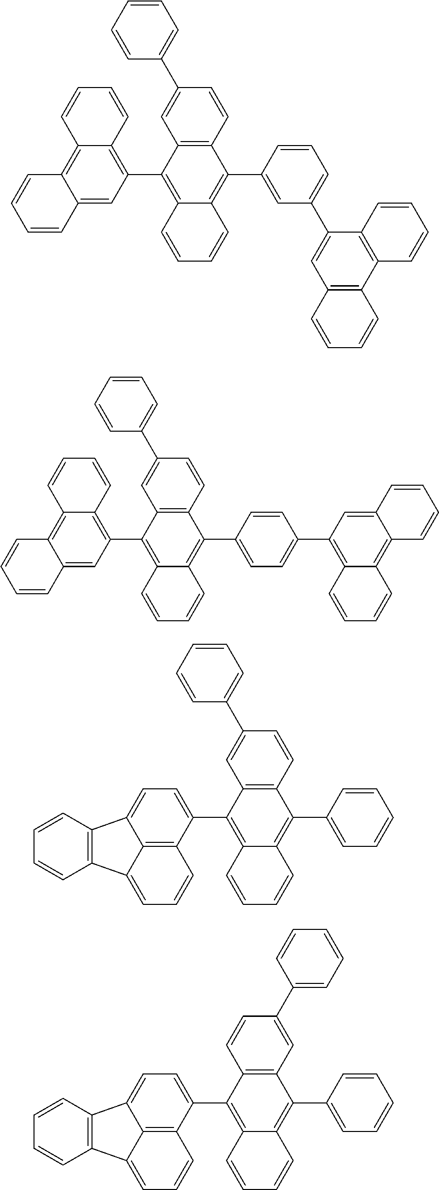

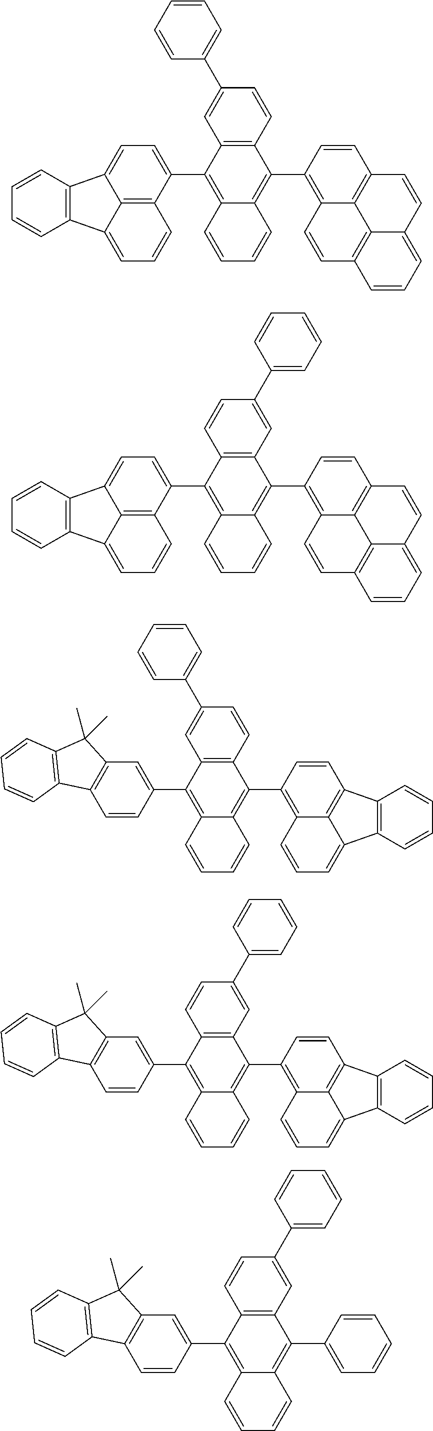

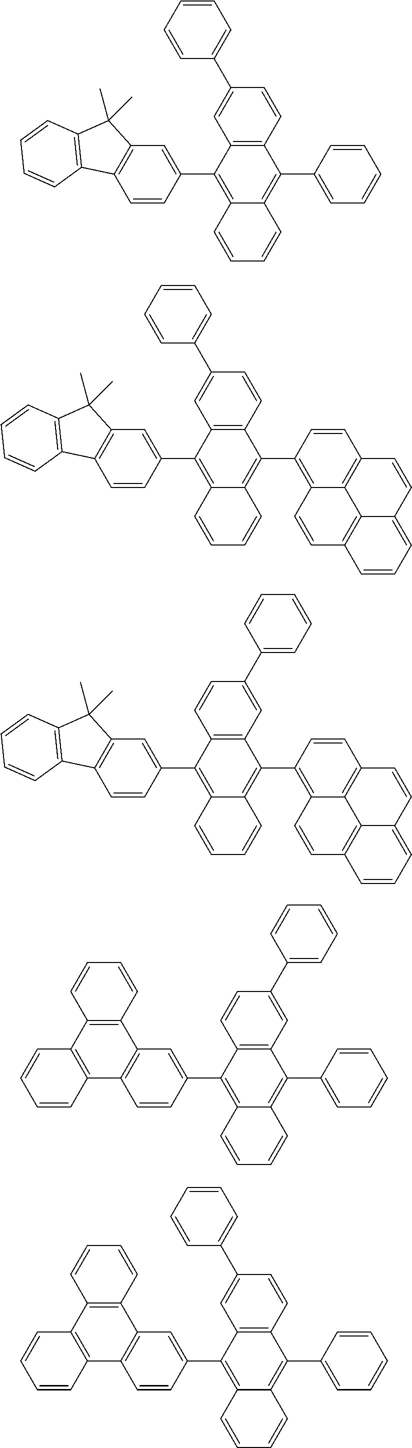

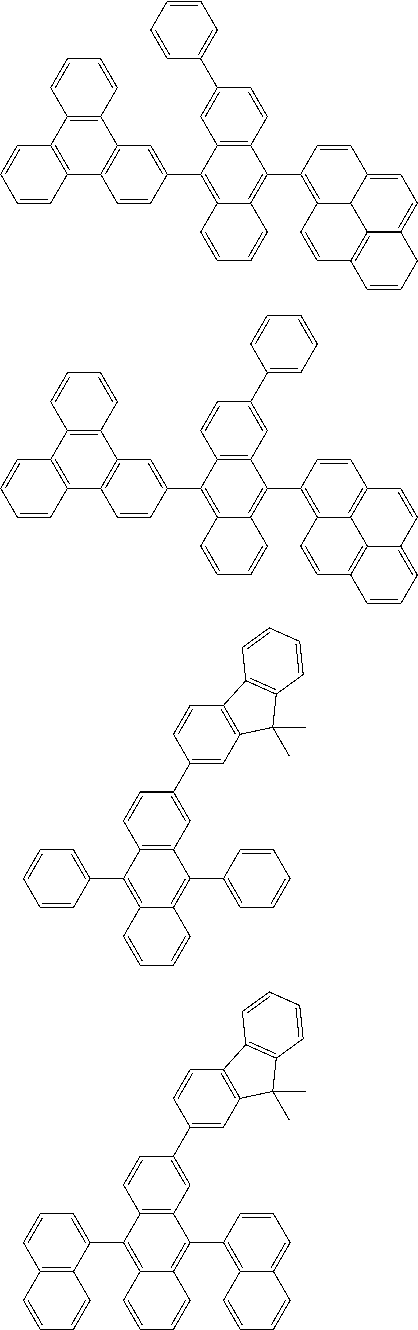

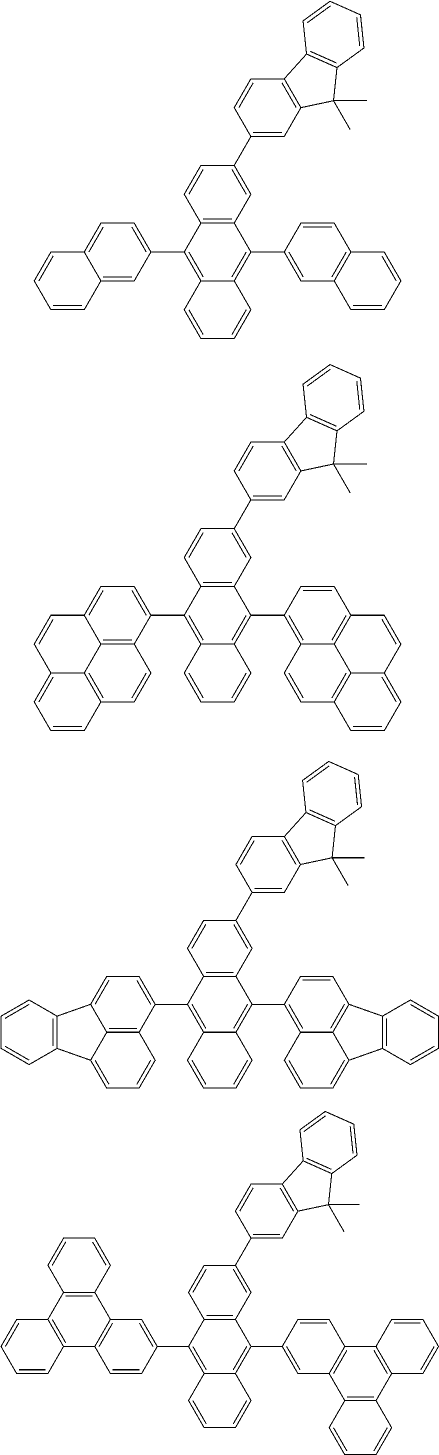

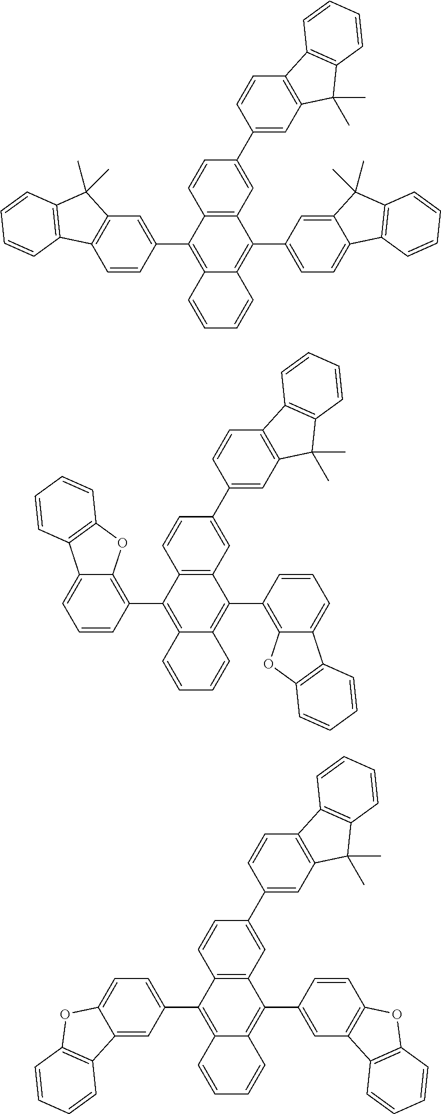

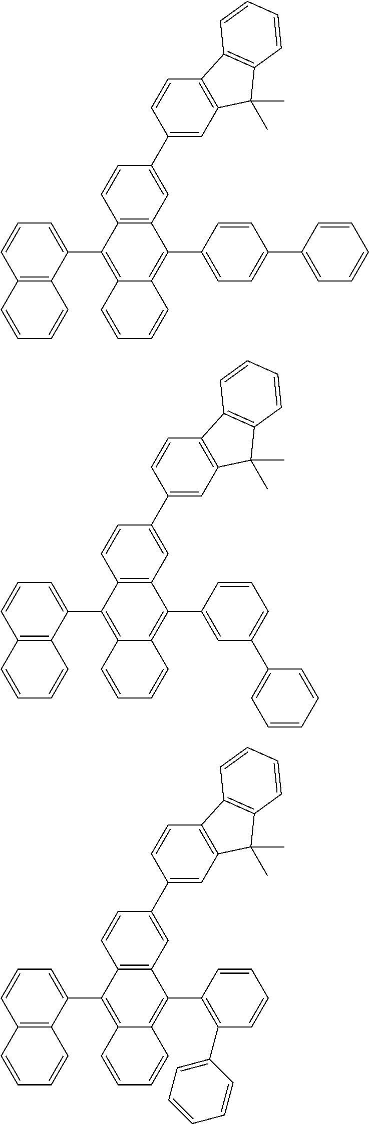

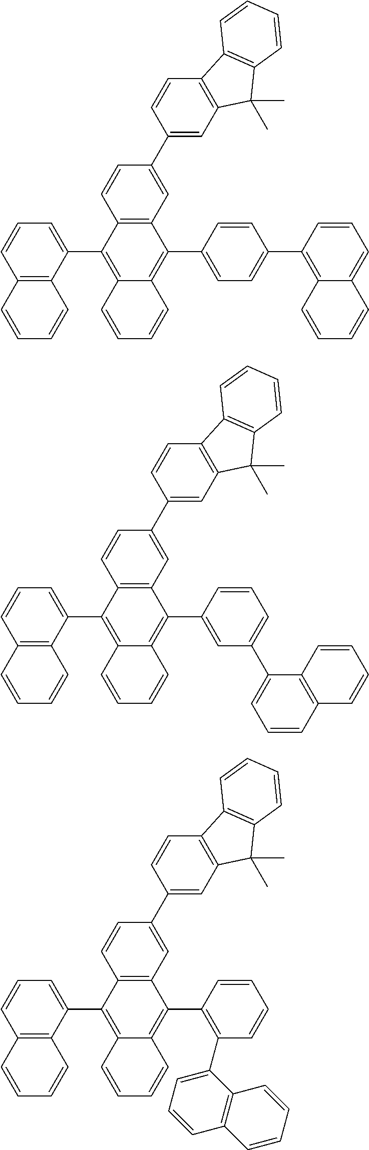

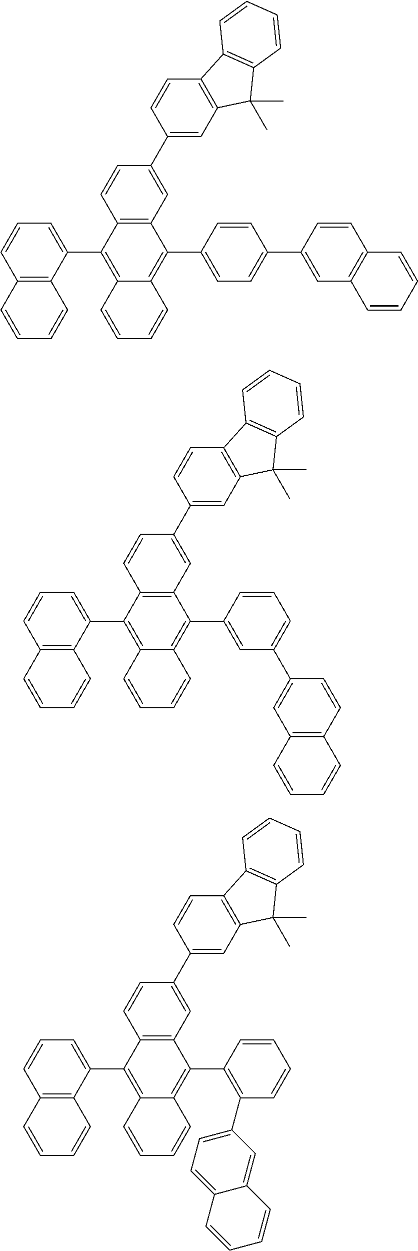

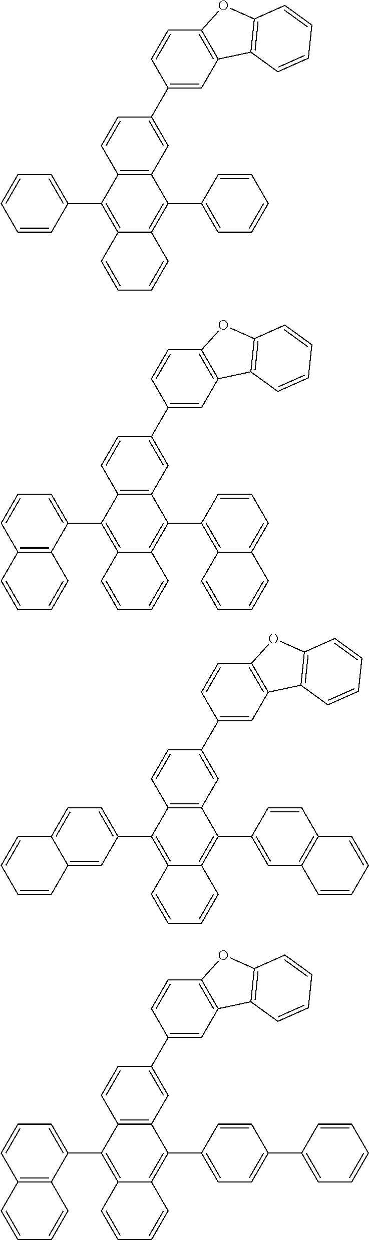

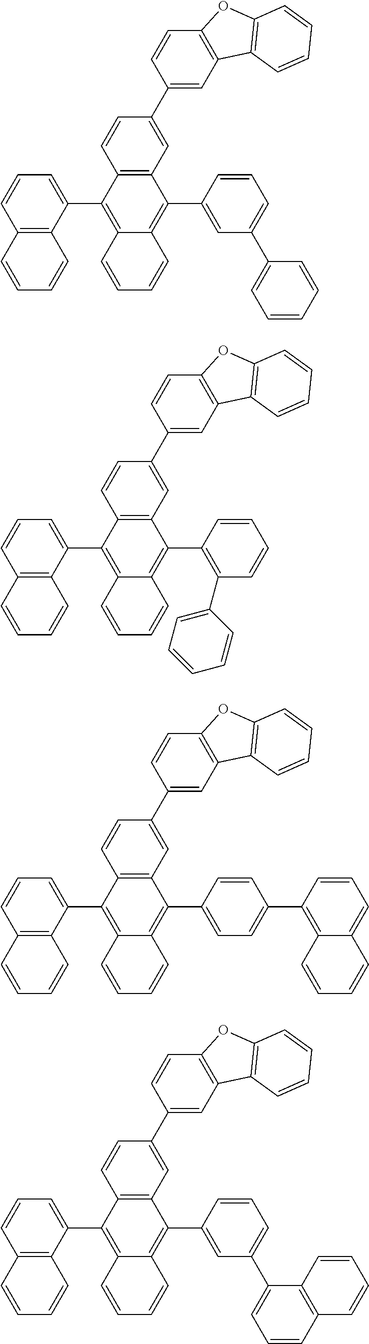

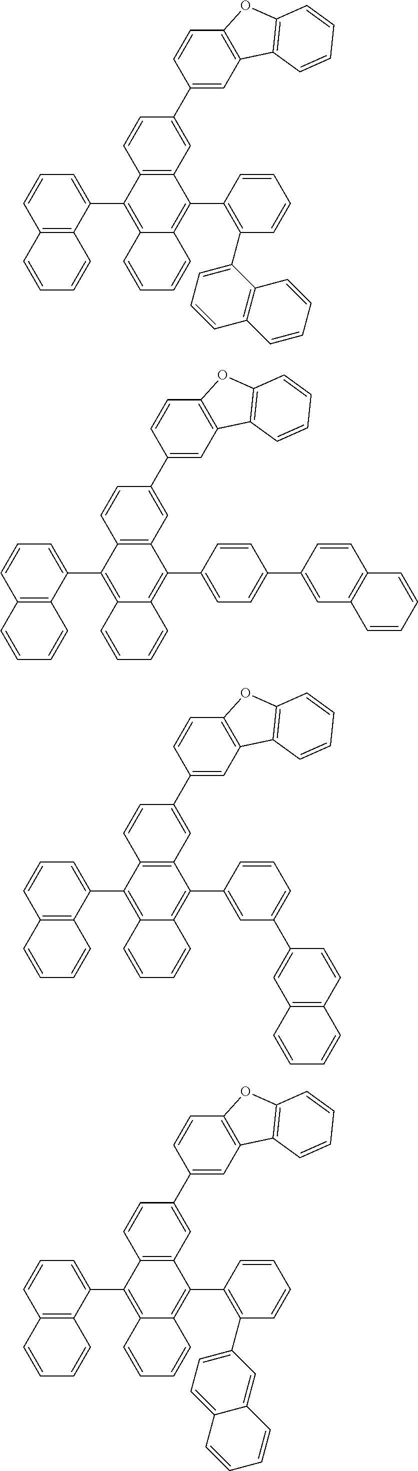

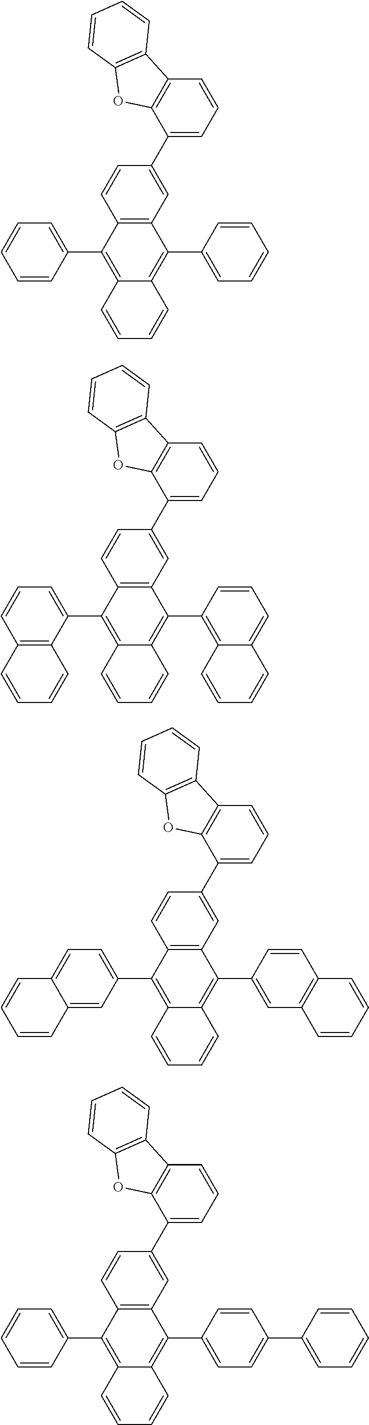

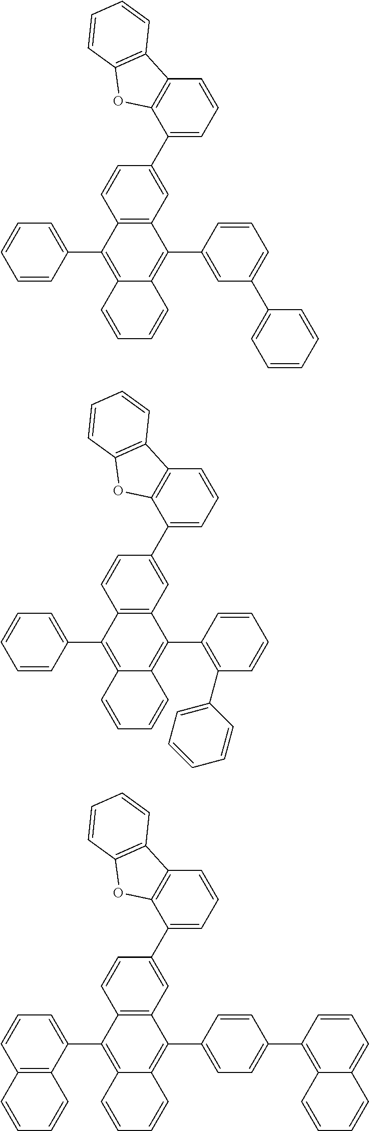

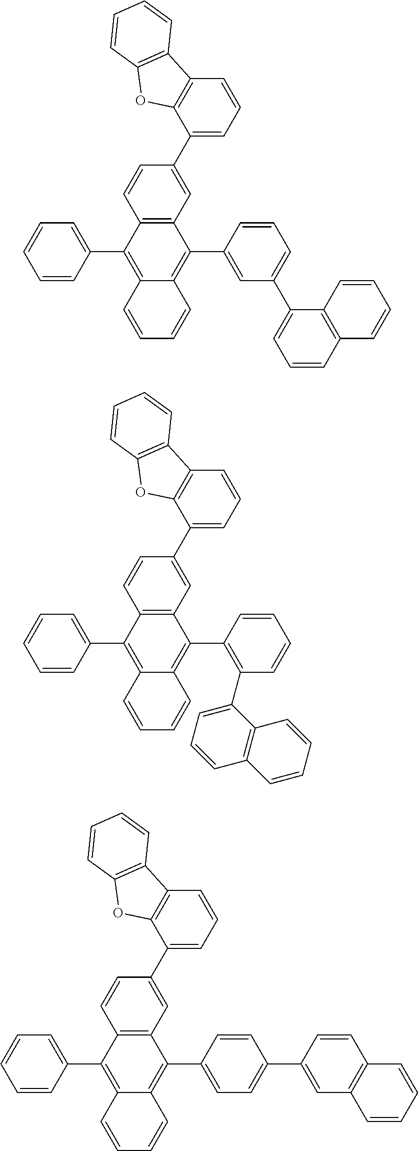

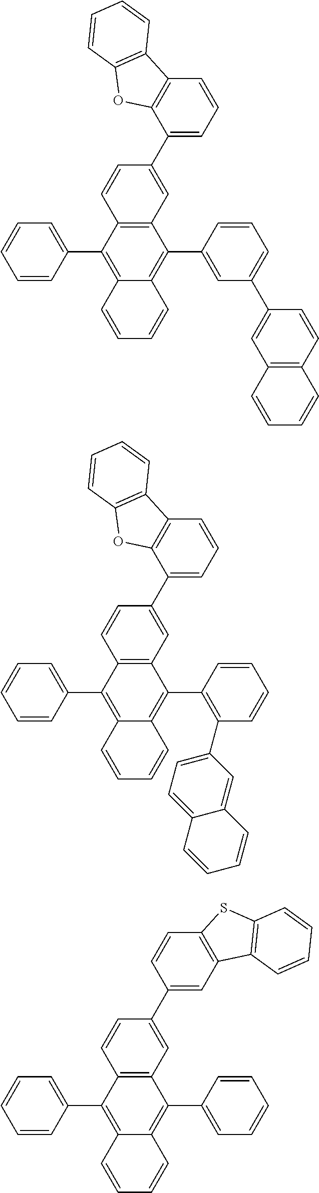

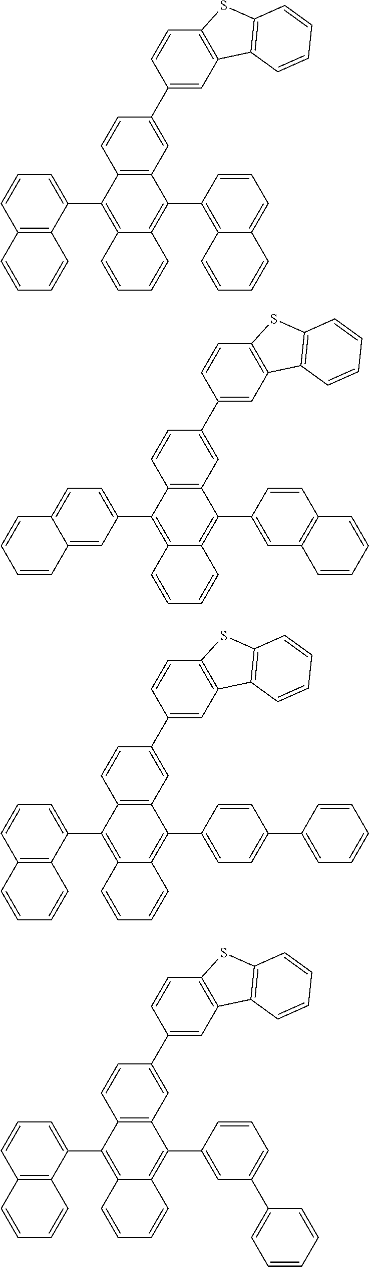

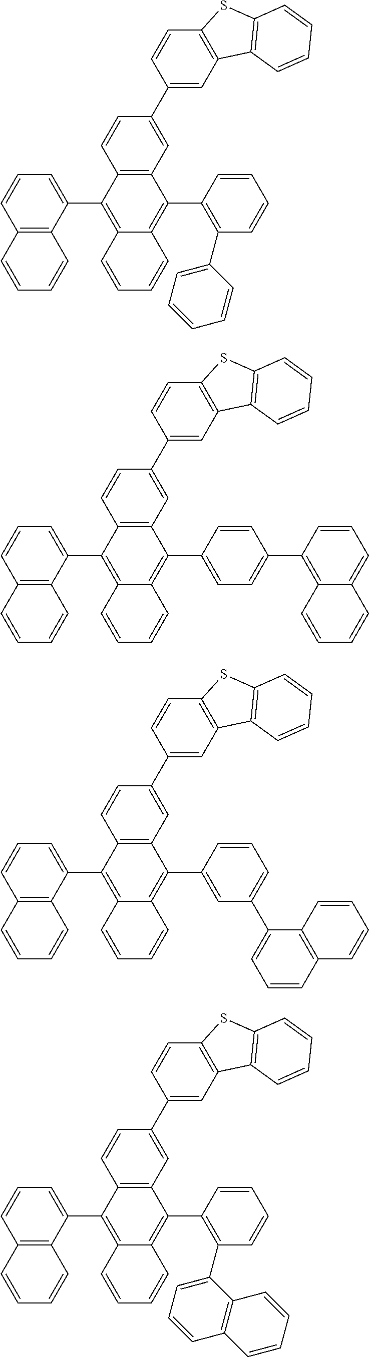

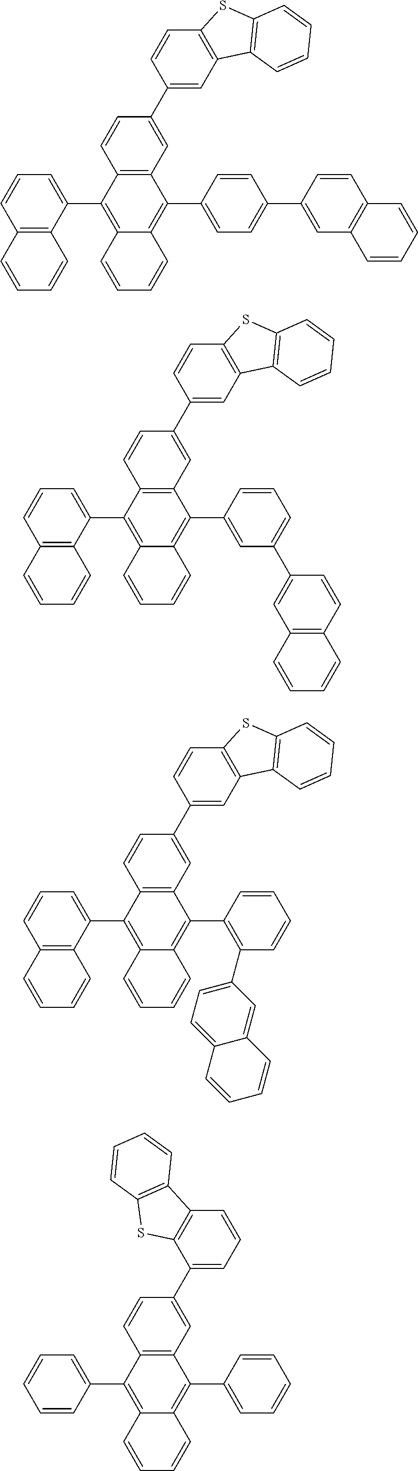

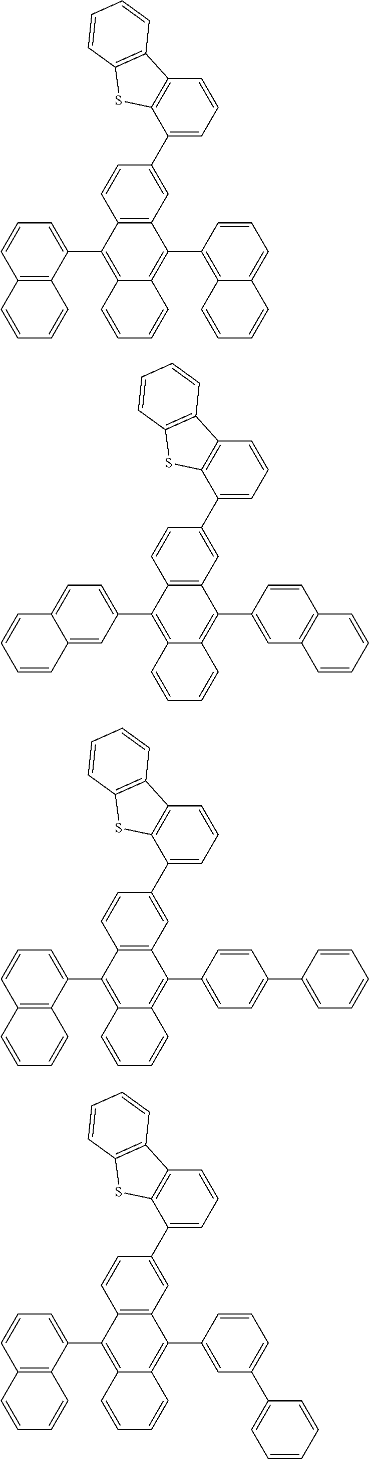

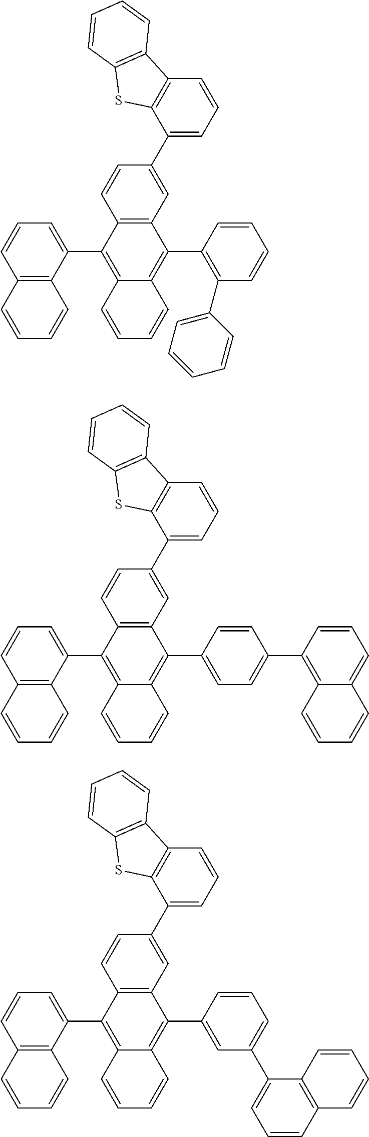

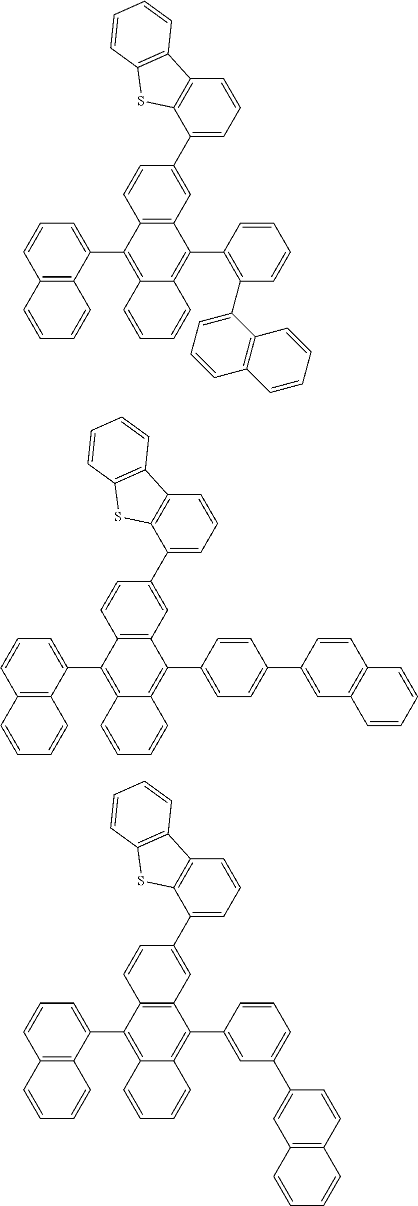

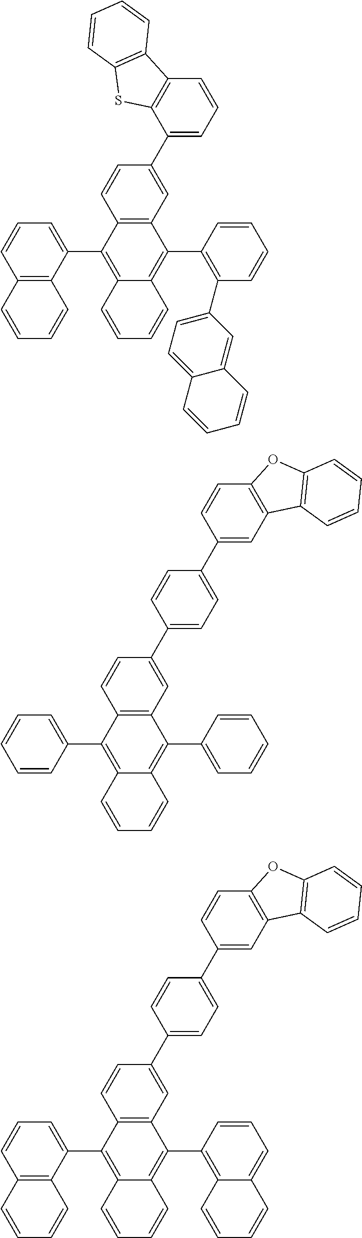

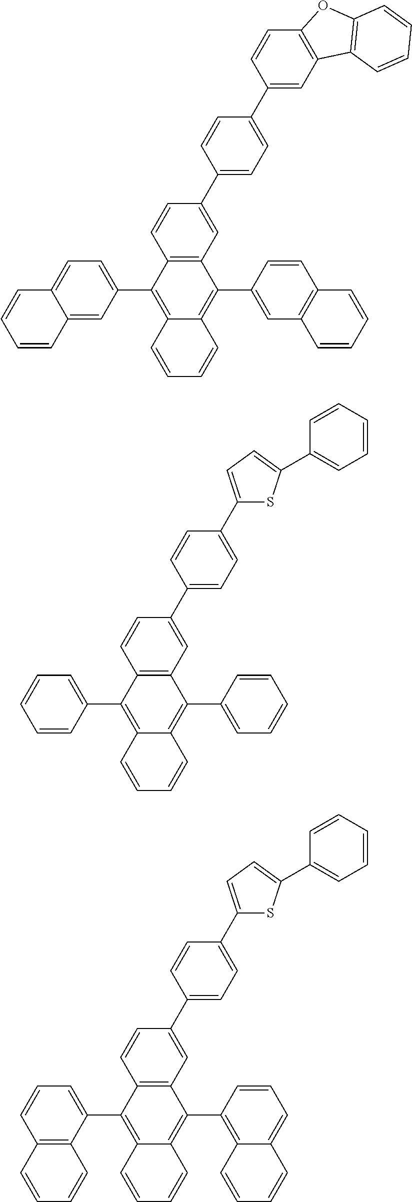

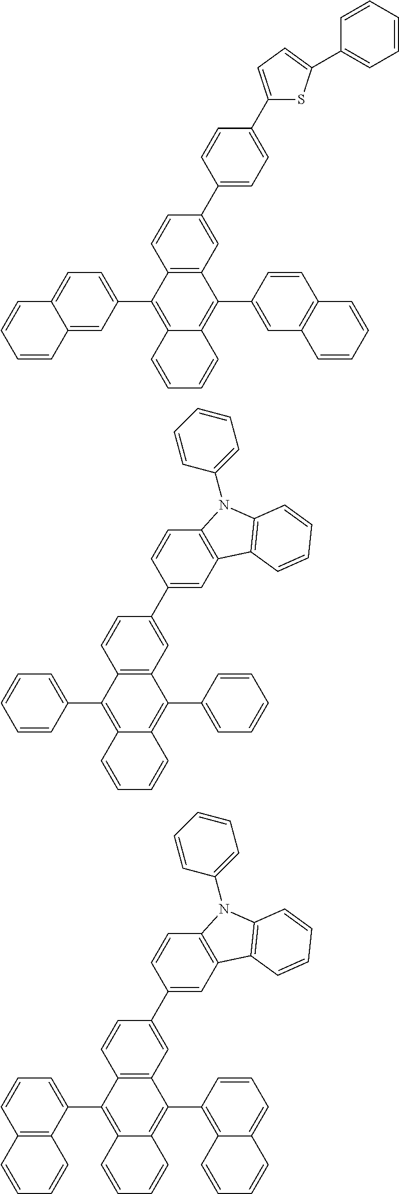

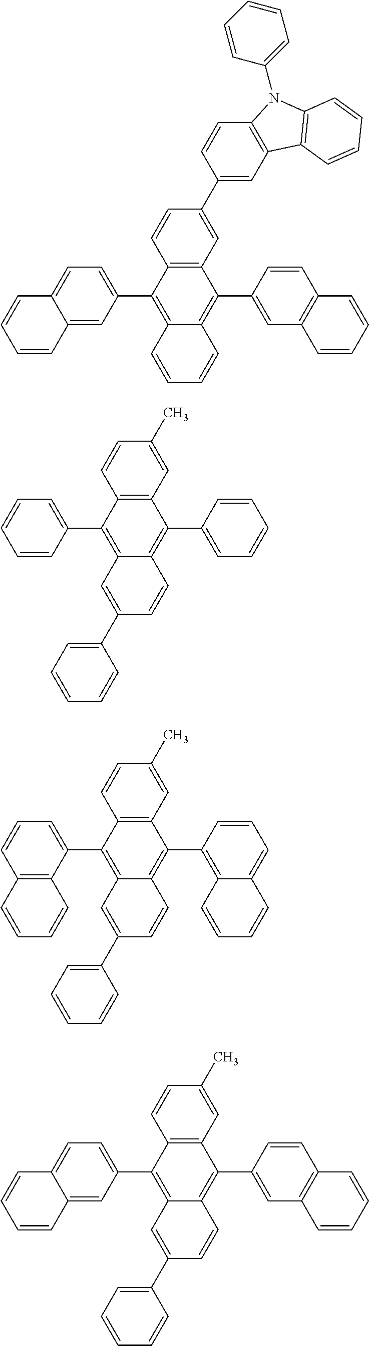

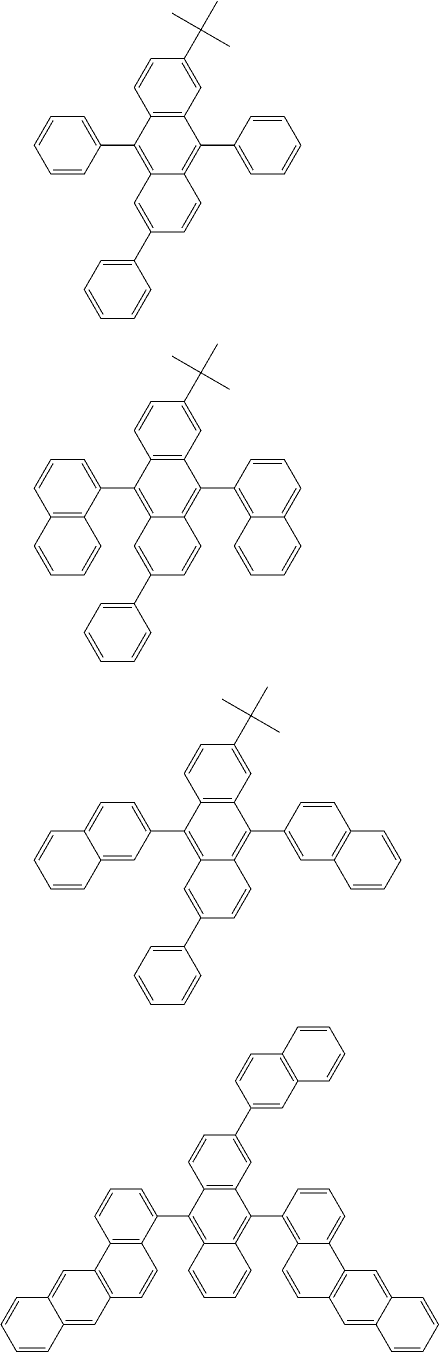

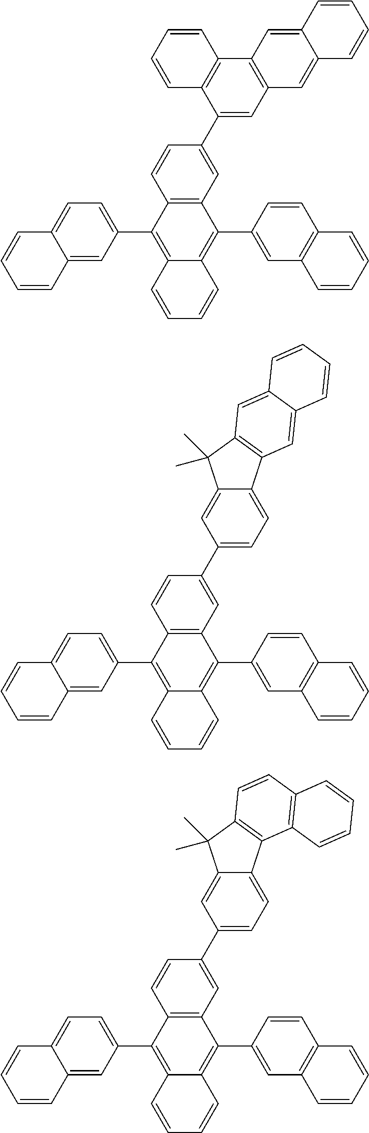

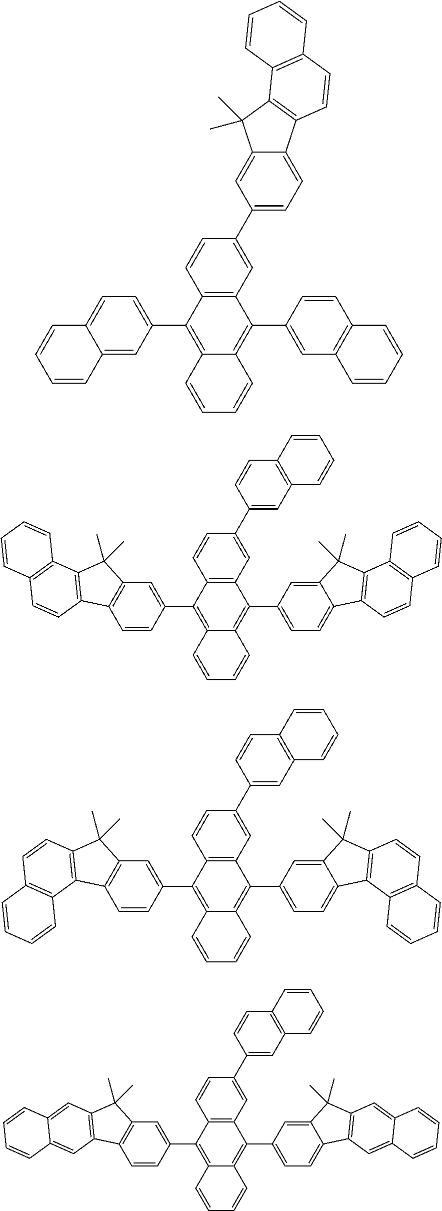

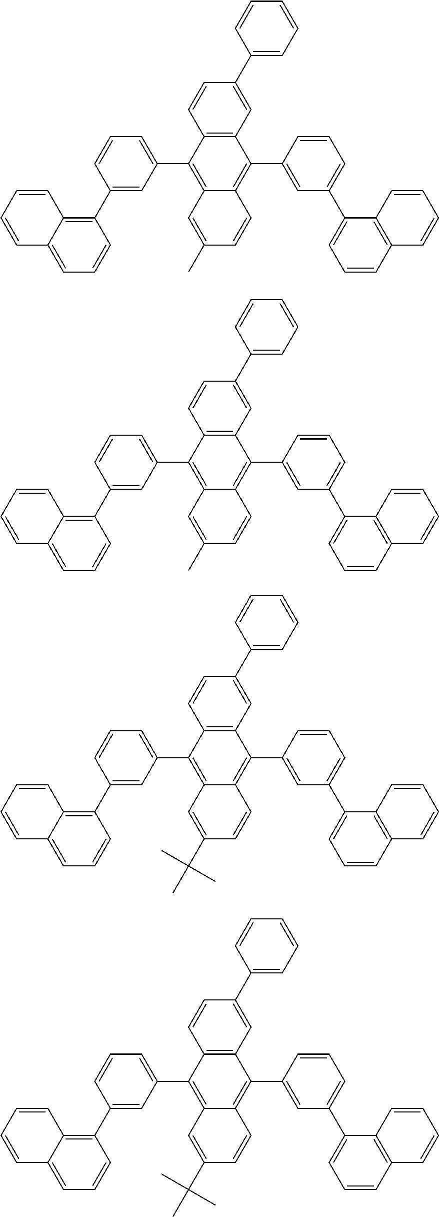

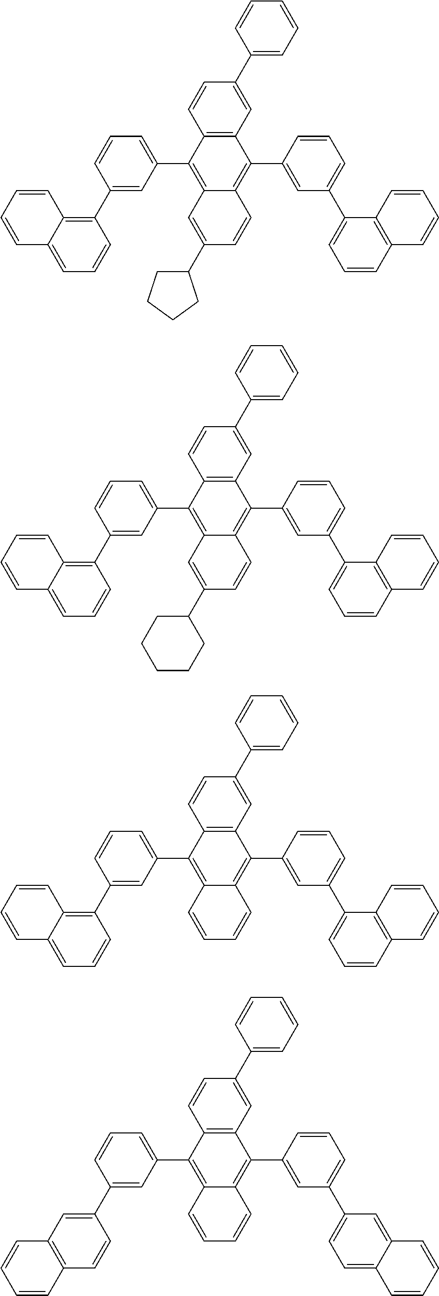

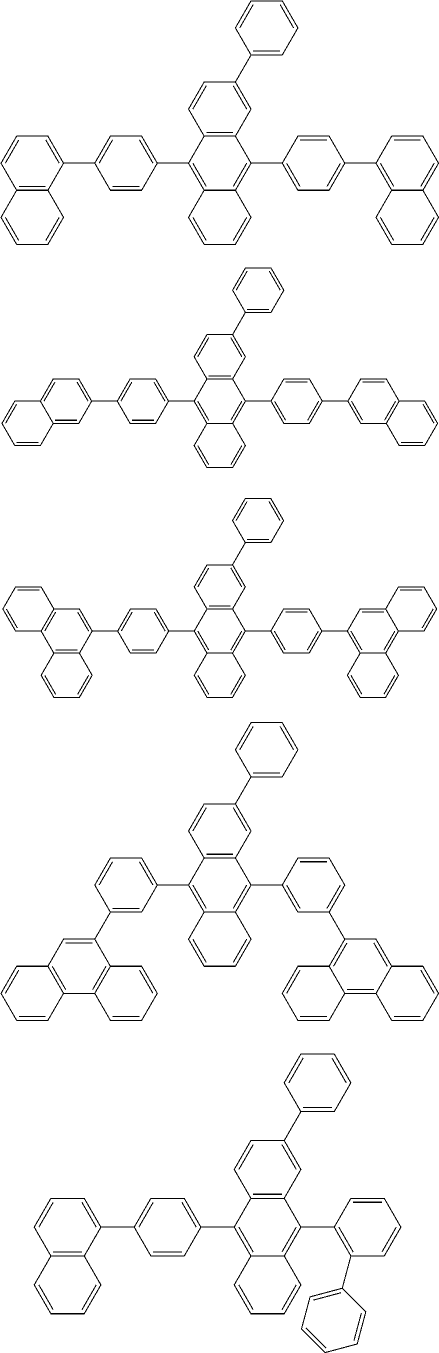

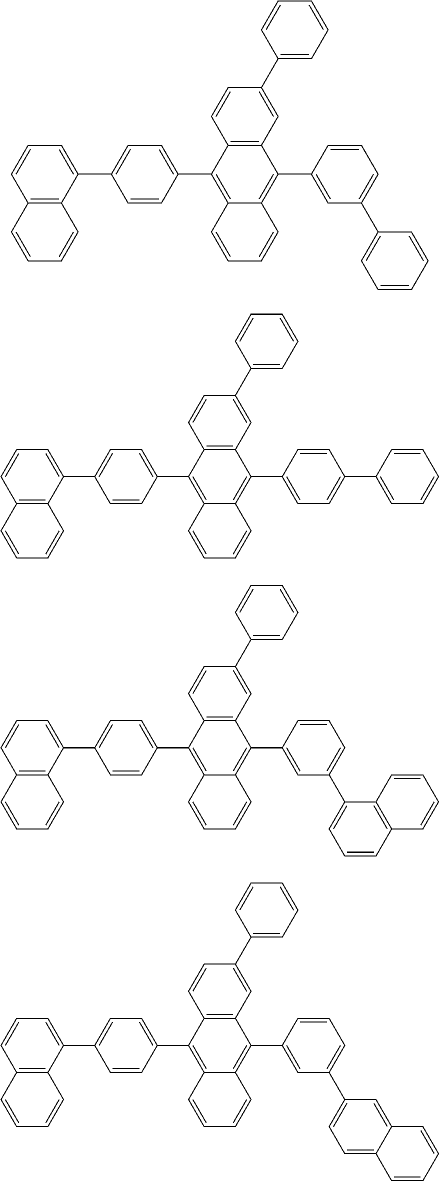

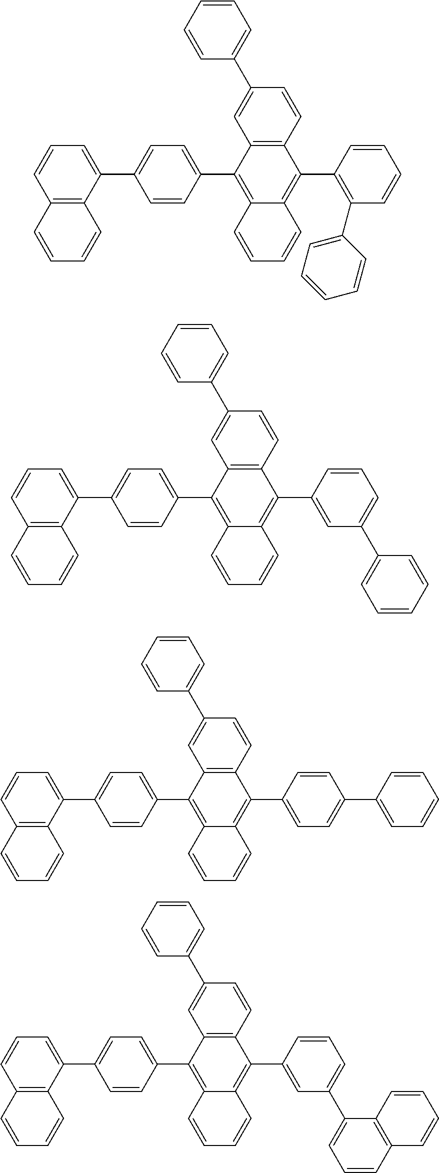

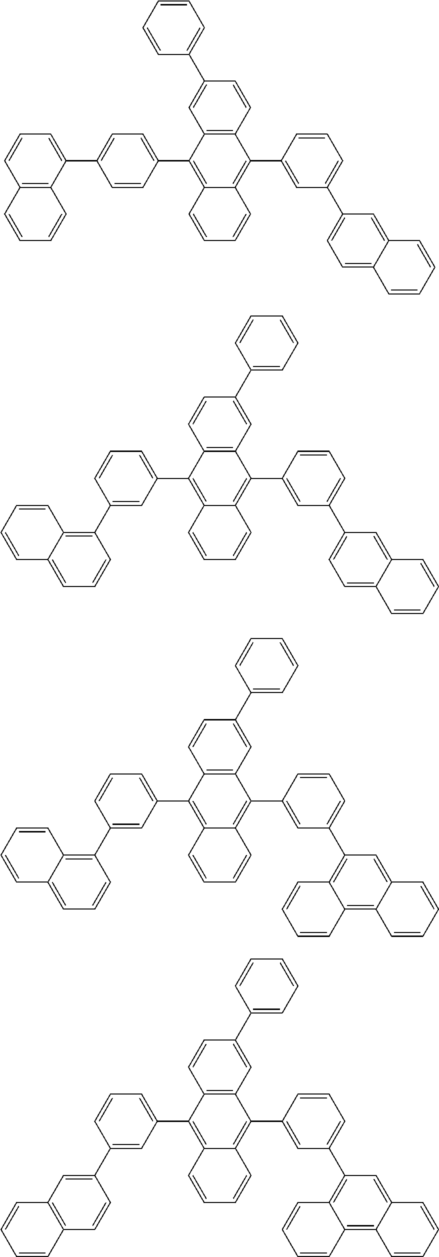

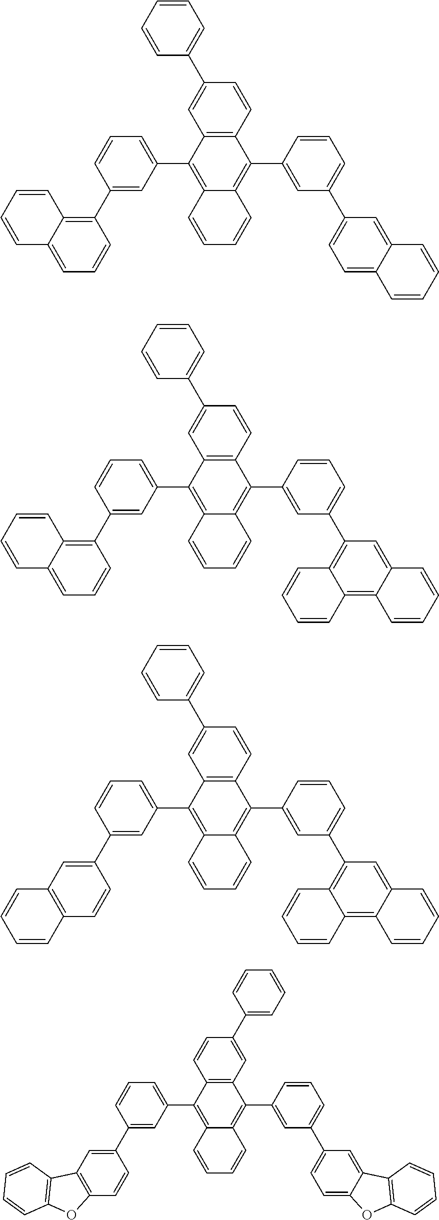

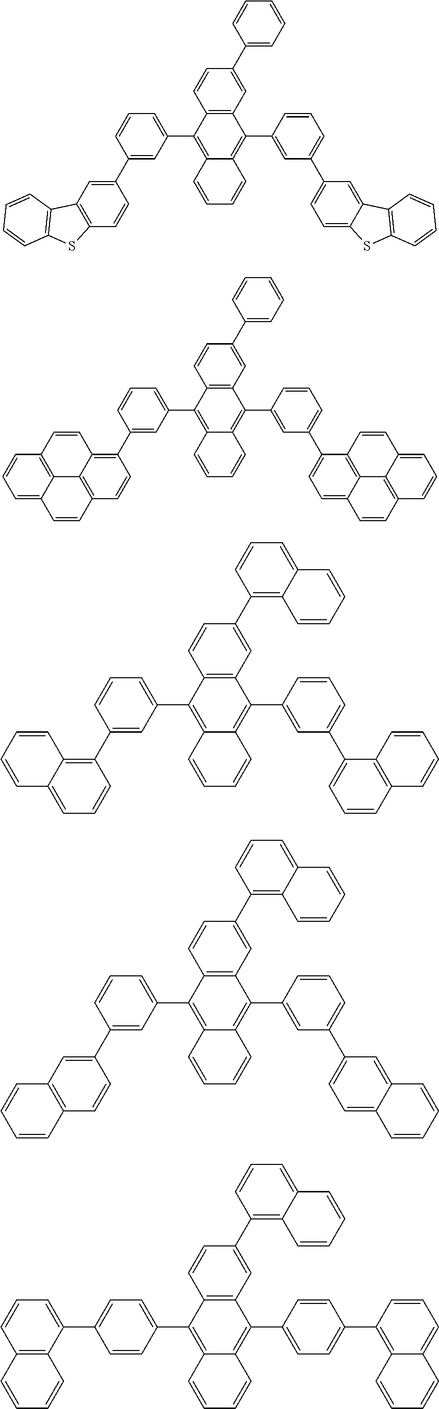

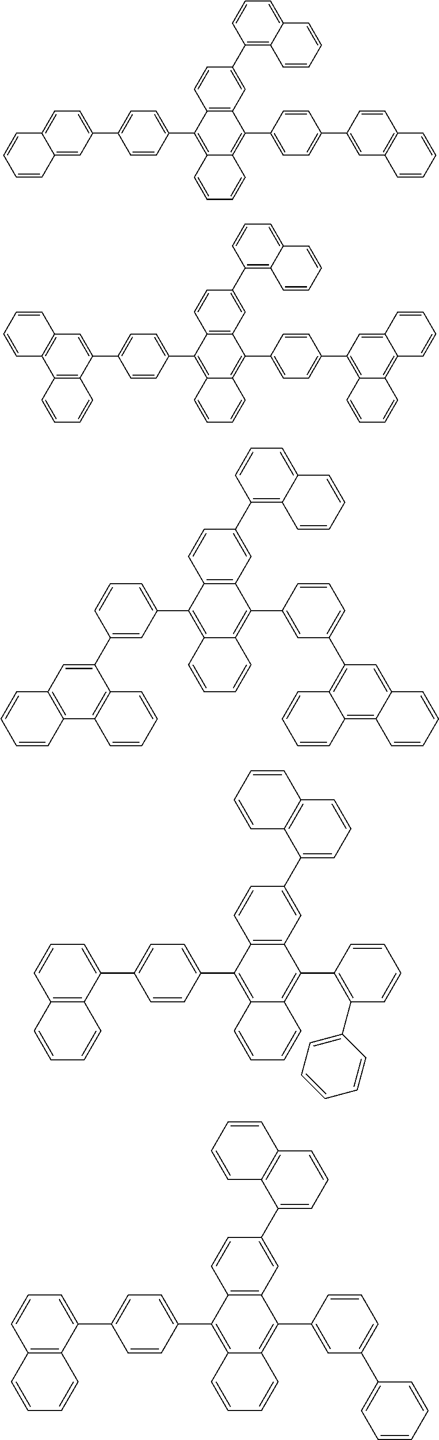

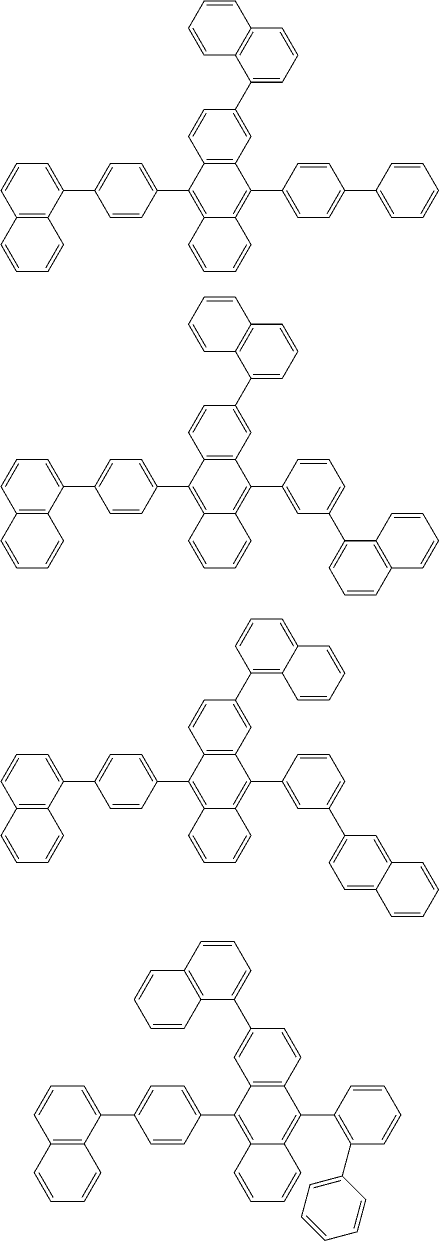

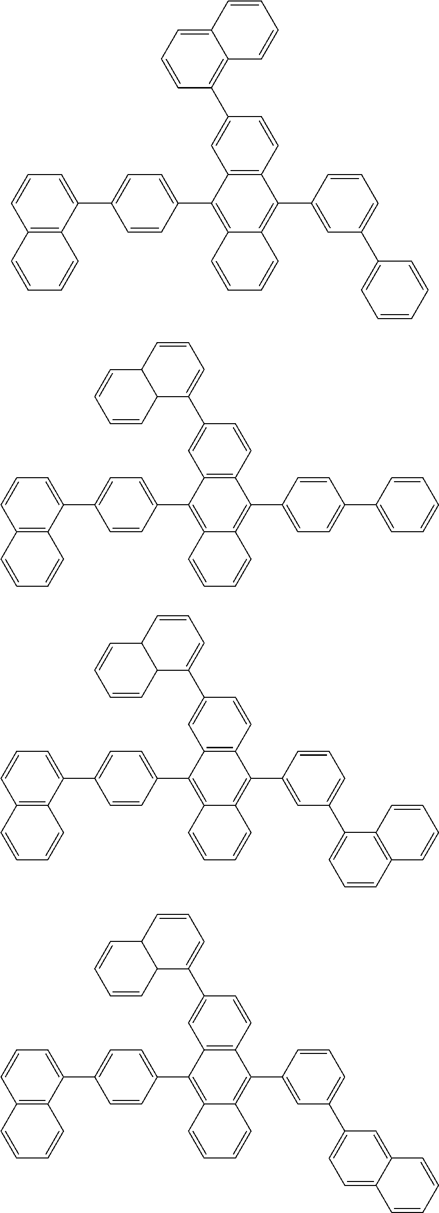

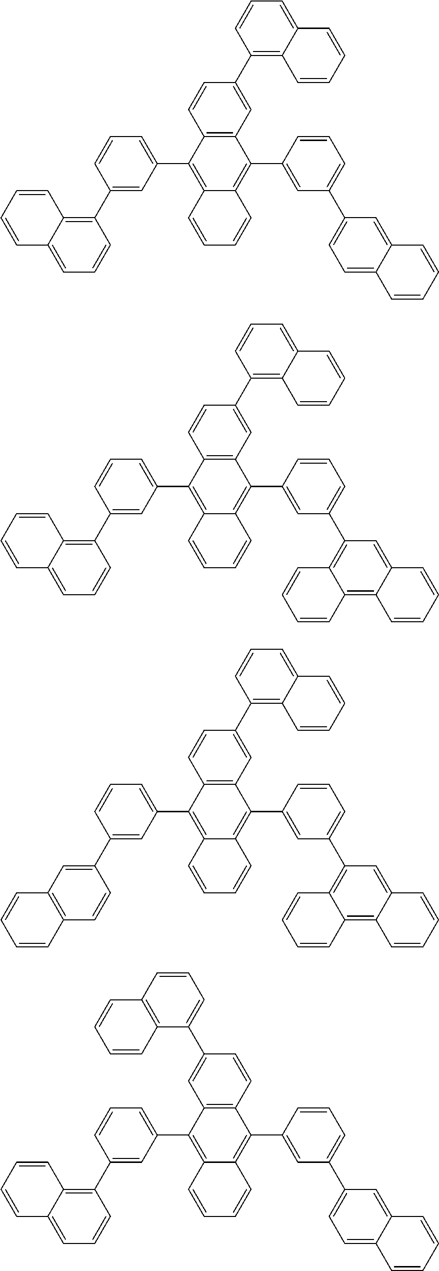

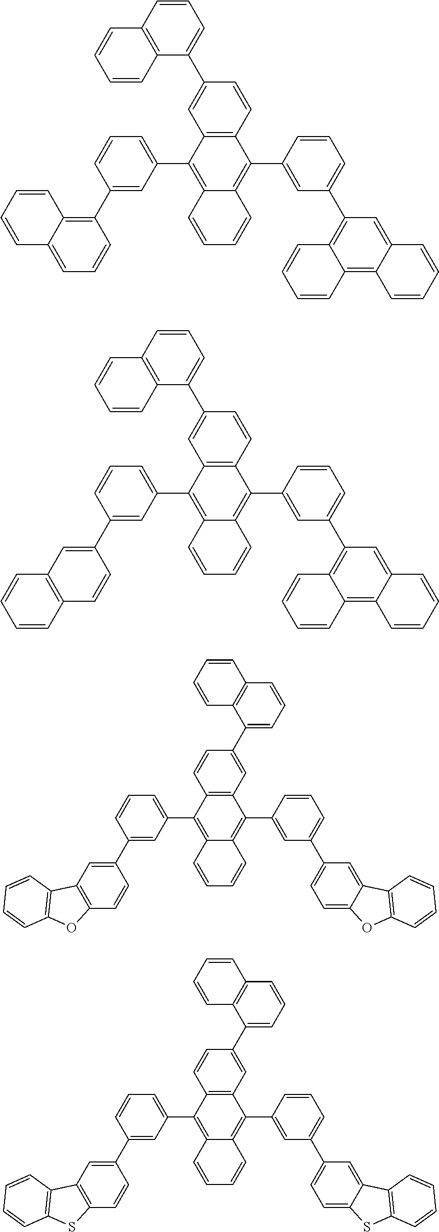

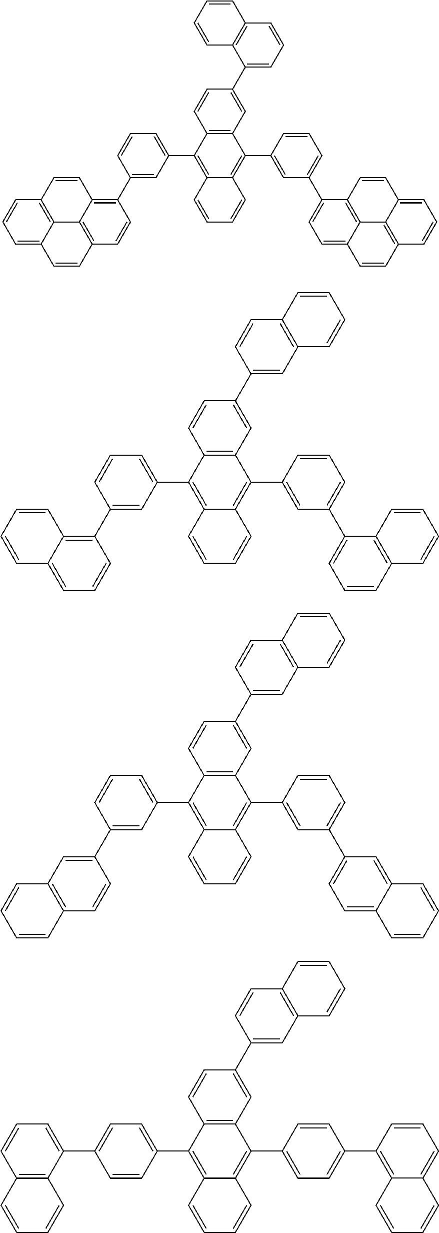

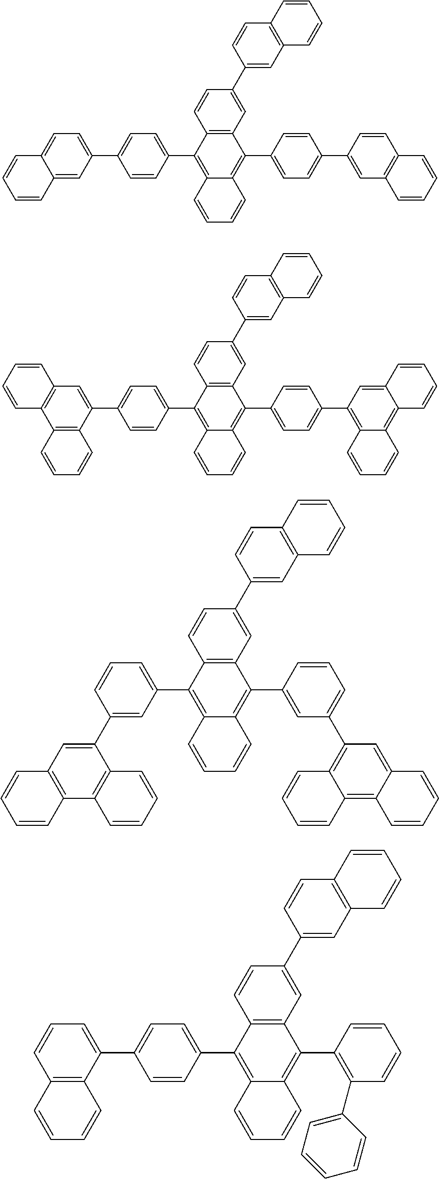

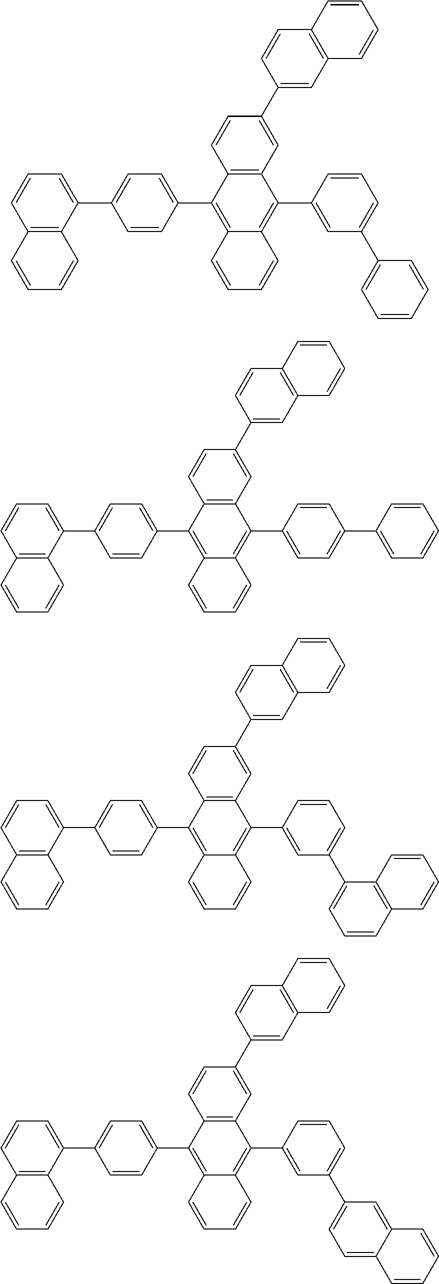

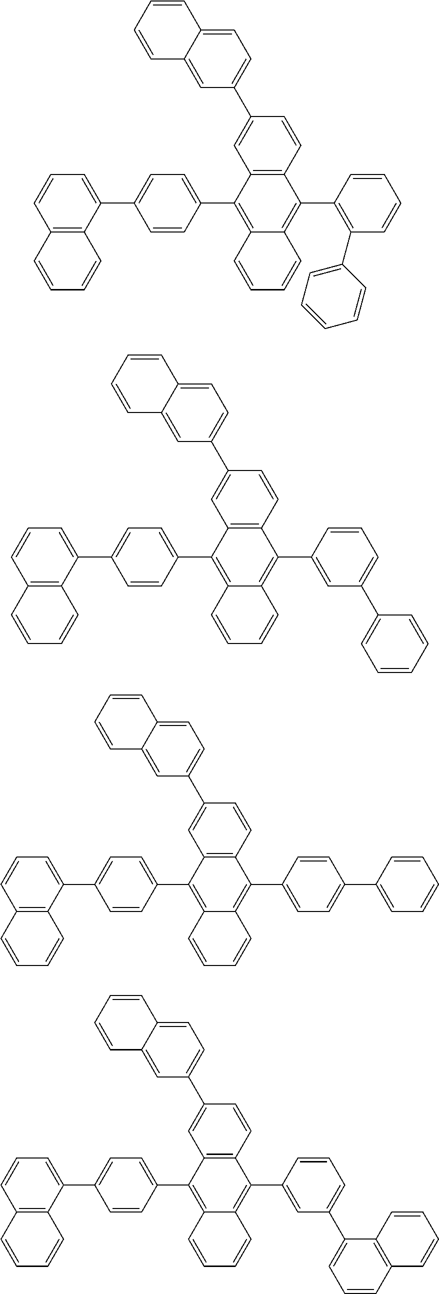

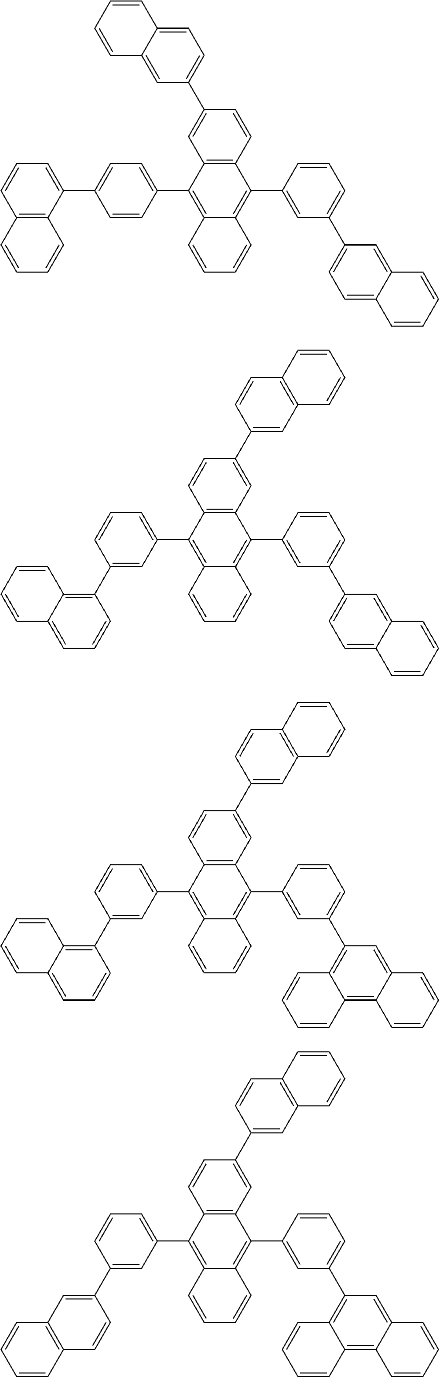

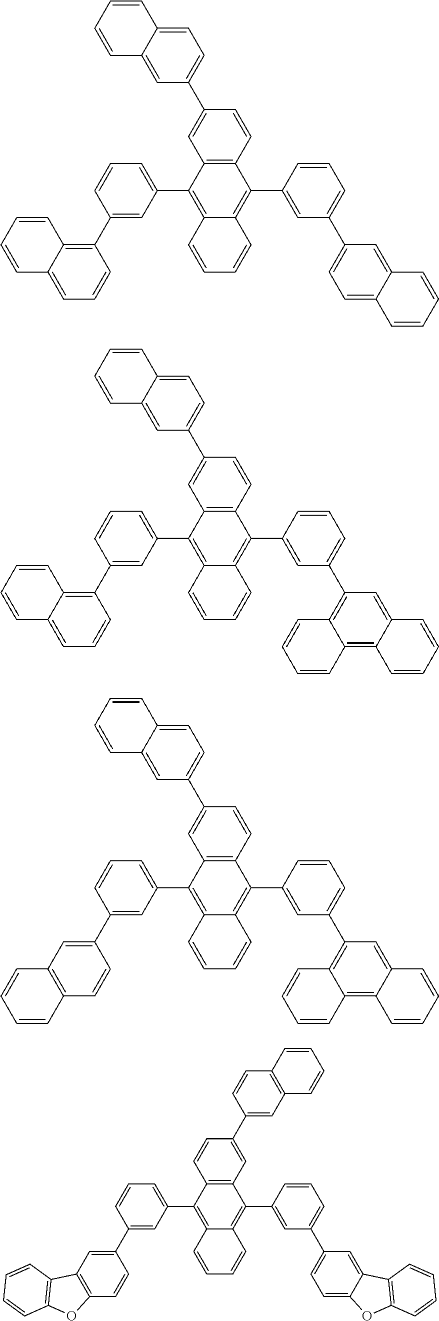

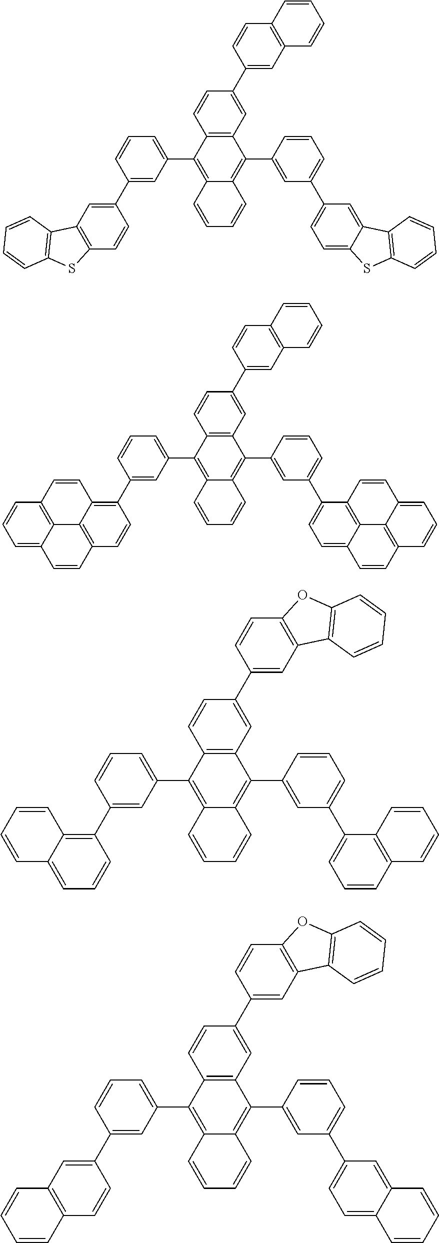

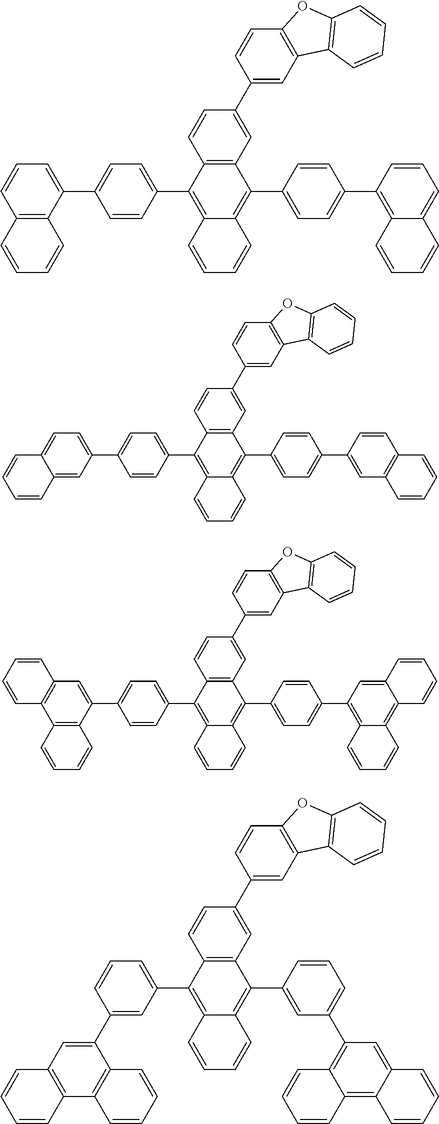

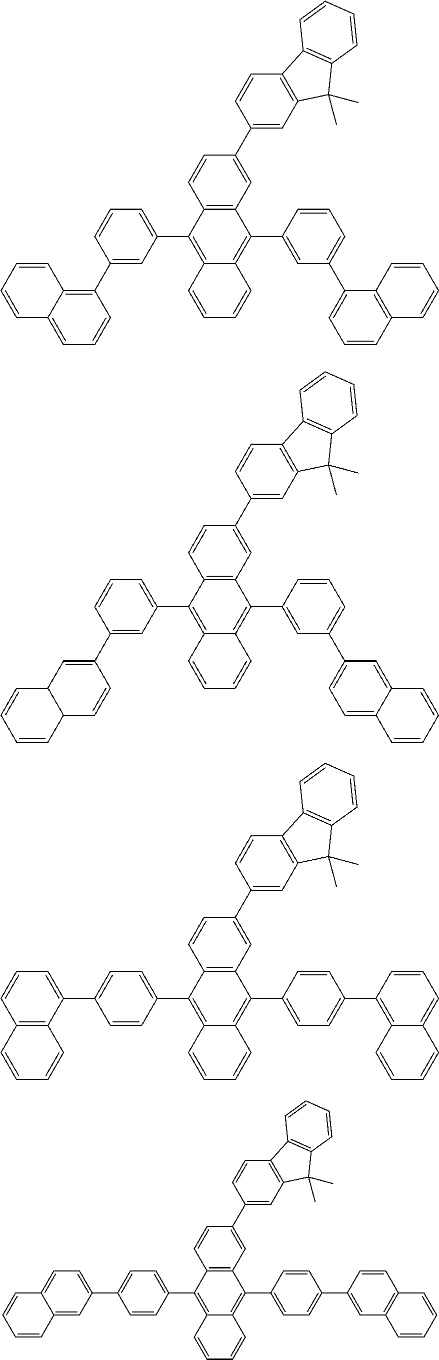

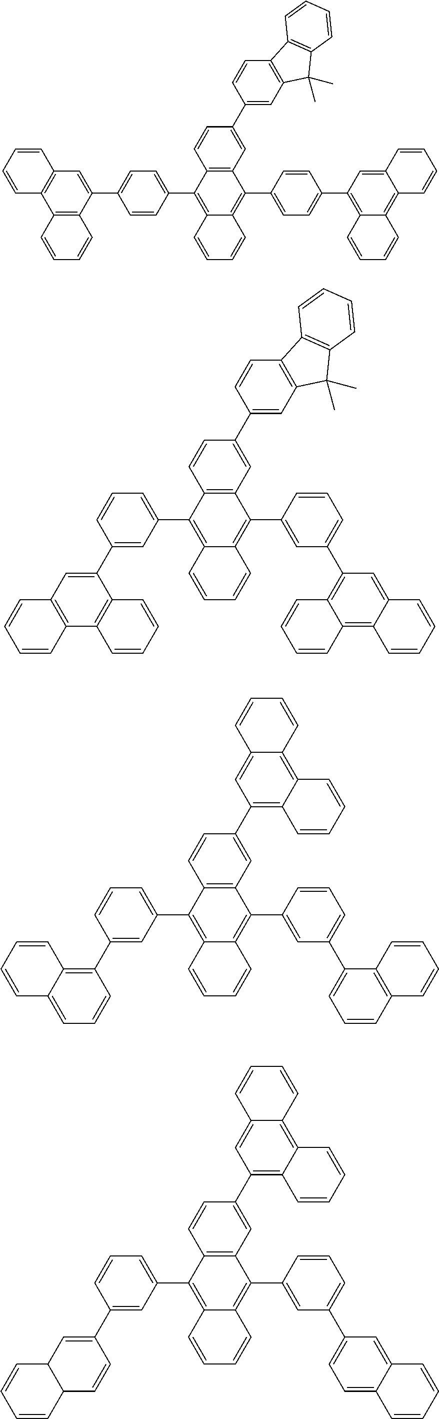

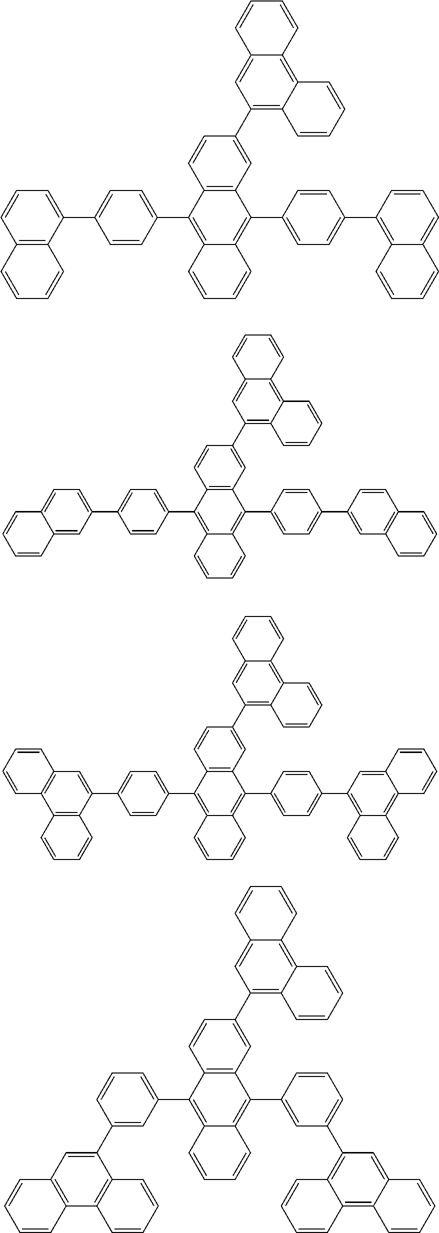

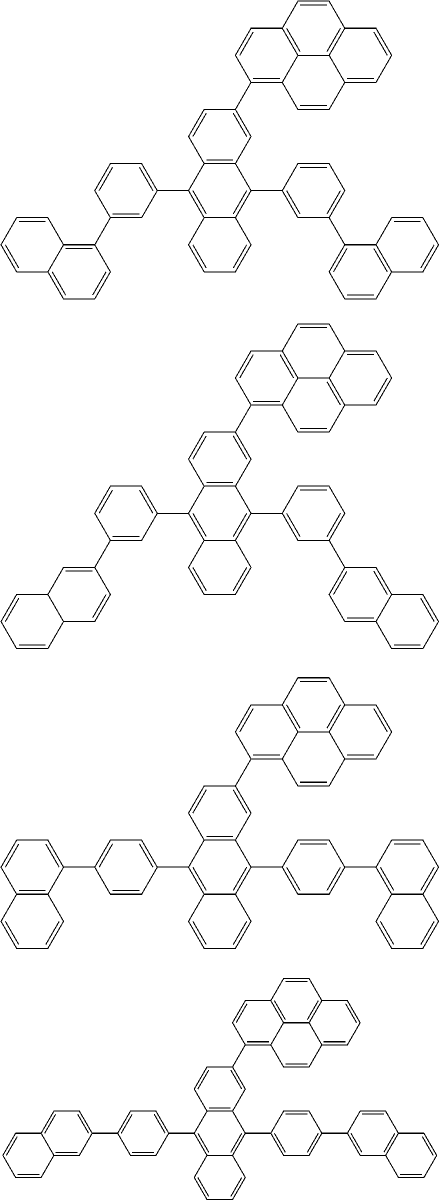

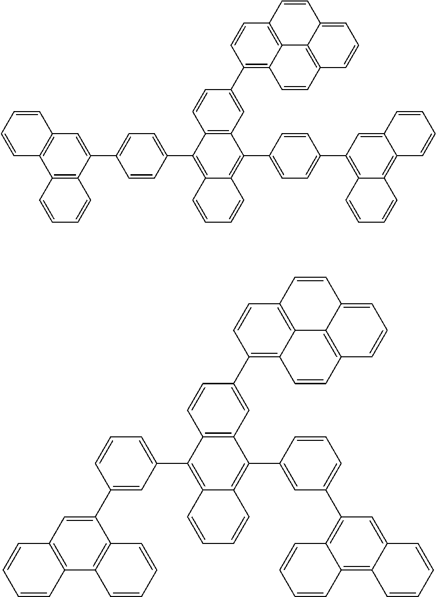

The diaminopyrene derivatives represented by formula (1), for example, can be synthesized as follows. Commercial pyrene is brominated to obtain dibromopyrene. After introducing a substituent by a known method, the dibromopyrene is re-brominated and reacted with the corresponding secondary amino compound in the presence of a metal catalyst, whereby the diaminopyrene derivative can be obtained. Moreover, the anthracene derivative represented by formula (2) can be synthesized using the method described in WO2004/018587.

The organic light-emitting medium is in the state where the diaminopyrene derivative represented by formula (1) and the anthracene derivative represented by formula (2) co-exist.

The mass rate of the diaminopyrene derivative represented by formula (1) and the anthracene derivative represented by formula (2) preferably ranges from 50:50 to 0.1:99.9, and more preferably from 20:80 to 1:99.

### [Organic EL Device]

The organic EL device of the invention is a device in which one or plural organic thin film layers are formed between an anode and a cathode. When there are plural organic thin film layers, one of them is an emitting layer. When there is one organic thin film layer, an emitting layer as the organic thin film layer is formed between the anode and the cathode. At least one layer of the organic thin film layers (preferably an emitting layer) contains the organic light-emitting medium of the invention, and further may contain a hole-injecting material or an electron-injecting material in order to transport holes injected from the anode or electrons injected from the cathode to an emitting material. The organic light-emitting medium of the invention has excellent emitting property.

Furthermore, the organic EL device of the invention, which comprises an organic thin film layer consisting of two or more layers including at least an emitting layer between a cathode and an anode, preferably comprises between a cathode and an anode an organic layer containing the organic light-emitting medium of the invention as a main component. For the organic layer, a hole-injecting layer, a hole-transporting layer and the like can be given.

In the invention, as the organic EL device in which a plurality of organic thin film layers is stacked, one with the following configurations can be given:

Anode/hole-injecting layer/emitting layer/cathode

Anode/emitting layer/electron-injecting layer/cathode

Anode/hole-injecting layer/emitting layer/electron-injecting layer, etc.

For the plural layers, if necessary, in addition to the organic light-emitting medium of the invention, further known emitting materials, doping materials, hole-injecting materials and electron-injecting materials can be used. Forming the organic thin film layer as a plural-layered structure can prevent a decrease in luminance and life time due to quenching. If necessary, emitting materials, doping materials, hole-injecting materials and electron-injecting materials can be used in combination. By using doping materials, the luminance and luminous efficiency can be improved and red or blue light emitting can be obtained. The hole-injecting layer, emitting layer, and electron-injecting layer each can be formed in the configuration having two or more layers. When the hole-injecting layer has two or more layers, the layer to which holes injected from the electrode is referred as a hole-injecting layer, and the layer which receives holes from the hole-injecting layer and transports the holes to the emitting layer is referred as a hole-transporting layer. Similarly, when the electron-injecting layer has two or more layers, the layer to which electrons are injected from the electrode is referred as an electron-injecting layer, and the layer which receives electrons from the electron-injecting layer and transports the electrons to the emitting layer is referred as an electron-transporting layer. Each of these layers are selected and used based on each factors such as energy levels of materials, heat resistance, and adhesion to the organic layer or the metal electrode.

Examples of the host material or doping material which can be used in the emitting layer together with the organic light-emitting medium of the invention include, though not limited thereto, fused multimeric aromatic compounds such as naphthalene, phenanthrene, rubrene, anthracene, tetracene, pyrene, perylene, chrysene, decacyclene, coronene, tetraphenylcyclopentadiene, pentaphenylcyclopentadiene, fluorene, spirofluorene, 9,10-diphenylanthracene, 9,10-bis(phenylethynyl)anthracene and 1,4-bis(9′-ethynylanthracenyl)benzene and derivatives thereof, organometallic complexes such as tris(8-quinolinolate)aluminum and bis-(2-methyl-8-quinolinolate)-4-(phenylphenolinate)aluminum, triarylamine derivatives, styrylamine derivatives, stilbene derivatives, coumarin derivatives, pyrane derivatives, oxazone derivatives, benzothiazole derivatives, benzoxazole derivatives, benzimidazole derivatives, pyrazine derivatives, cinnamate derivatives, diketo-pyrrolo-pyrrole derivatives, acridone derivatives, and quinacridone derivatives.

As the hole-injecting material, preferred is a compound which has ability for transporting holes, has an effect of injecting holes from the anode and an excellent effect of injecting holes to an emitting layer or organic light-emitting medium, prevents excitons generated in the emitting layer from moving to the electron-injecting layer or electron-injecting material, and has excellent ability for being formed into a thin film. Specific Examples include, though not limited thereto, phthalocyanine derivatives, naphthalocyanine derivatives, porphyrin derivatives, oxazole, oxadiazole, triazole, imidazole, imidazolone, imidazolthione, pyrazoline, pyrazolone, tetrahydroimidazole, oxazole, oxadiazole, hydrazone, acylhydrazone, polyarylalkane, stilbene, butadiene, benzidine-type triphenylamine, styrylamine-type triphenylamine and diamine-type triphenylamine, and derivatives thereof, and polymer materials such as polyvinylcarbazole, polysilane and conductive polymer.

Of the hole-injecting materials which can be used in the organic EL device of the invention, more effective materials are aromatic tertiary amine derivatives and phthalocyanine derivatives.

Examples of the aromatic tertiary amine derivative include, though not limited thereto, triphenylamine, tritolylamine, tolyldiphenylamine, N,N′-diphenyl-N,N′-(3-methylphenyl)-1,1′-biphenyl-4,4′-diamine, N,N,N′,N′-(4-methylphenyl)-1,1-phenyl-4,4′-diamine, N,N,N′,N′-(4-methylphenyl)-1,1′-biphenyl-4,4′-diamine, N,N′-diphenyl-N,N′-dinaphthyl-1,1′-biphenyl-4,4′-diamine, N,N′-(methylphenyl)-N,N′-(4-n-butylphenyl)-phenanthrene-9,10-diamine, and N-bis(4-di-4-tolylaminophenyl)-4-phenyl-cyclohexan, and oligomers or polymers having an aromatic tertiary amine skeleton thereof.

Examples of the phthalocyanine (Pc) derivative include, though not limited thereto, phthalocyanine derivatives such as H₂Pc, CuPc, CoPc, NiPc, ZnPc, PdPc, FePc, MnPc, ClAlPc, ClGaPc, ClInPc, ClSnPc, Cl₂SiPC, (HO)AlPc, (HO)GaPc, VOPc, TiOPc, MoOPc, and GaPc-O—GaPc, and naphthalocyanine derivatives.

In the organic EL device of the invention, it is preferred that a layer containing these aromatic tertiary amine derivative and/or phthalocyanine derivative be formed as the hole-transporting layer or hole-injecting layer between the emitting layer and the anode.

As the electron-injecting material, preferred is a compound which has ability for transporting electrons, has an effect of injecting electrons from the cathode and an excellent effect of injecting electrons to an emitting layer or light-emitting material, prevents excitons generated in the emitting layer from moving to the hole-injecting layer, and has excellent ability for being formed into a thin film. The material used in the electron-transporting layer is preferably a metal complex of 8-hydroxyquinoline or a derivative thereof, or an oxadiazole derivative. As specific examples of the metal complex of 8-hydroxyquinoline and derivative thereof, metal chelate oxynoid compounds including a chelate of oxine (generally, 8-quinolinol or 8-hydroxyquinoline), e.g. tris(8-quinolinolato)aluminum, can be used as an electron-injecting material.

An electron-transporting compound of the following formula can be given as the oxadiazole derivative.

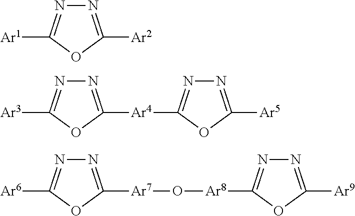

wherein Ar¹, Ar², Ar³, Ar⁵, Ar⁶ and Ar⁹ are independently substituted or unsubstituted aryl groups and may be the same or different.

Ar⁴, Ar⁷ and Ar⁸ are independently substituted or unsubstituted arylene groups and may be the same or different.

Furthermore, as the electron-injecting material, the compounds represented by the following formulas (A) to (F) may be used.

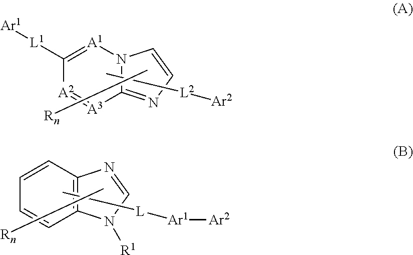

Nitrogen-containing heterocyclic derivatives represented by the formulas (A) and (B) wherein Ar¹ to Ar³ are each independently a nitrogen atom or a carbon atom;

Ar¹ is a substituted or unsubstituted aryl group having 6 to 60 ring carbon atoms or a substituted or unsubstituted heterocyclic group having 5 to 60 ring atoms,

Ar² is a hydrogen atom, a substituted or unsubstituted aryl group having 6 to 60 ring carbon atoms, a substituted or unsubstituted heterocyclic group having 5 to 60 ring atoms, a substituted or unsubstituted alkyl group having 1 to 20 carbon atoms, a substituted or unsubstituted alkoxy group having 1 to 20 carbon atoms, or a divalent group thereof, provided that one of Ar¹ and Ar² is a substituted or unsubstituted fused ring group having 10 to 60 ring carbon atoms or a substituted or unsubstituted monohetero fused ring group having 5 to 60 ring atoms,

L¹, L² and L are independently a single bond, a substituted or unsubstituted arylene group having 6 to 60 ring carbon atoms, a substituted or unsubstituted heteroarylene group having 5 to 60 ring atoms, or a substituted or unsubstituted fluorenylene group,

Rs are independently a hydrogen atom, a substituted or unsubstituted aryl group having 6 to 60 ring carbon atoms, a substituted or unsubstituted heterocyclic ring group having 5 to 60 ring atoms, a substituted or unsubstituted alkyl group having 1 to 20 carbon atoms, or a substituted or unsubstituted alkoxy group having 1 to 20 carbon atoms, and n is an integer of 0 to 5, provided that, when n is 2 or more, a plurality of Rs may be the same or different, and adjacent Rs may be bonded to each other to form a carbocyclic aliphatic ring or a carbocyclic aromatic ring;

R¹ is a hydrogen atom, a substituted or unsubstituted aryl group having 6 to 60 ring carbon atoms, a substituted or unsubstituted heteroaryl group having 3 to 60 ring carbon atoms, a substituted or unsubstituted alkyl group having 1 to 20 carbon atoms, a substituted or unsubstituted alkoxy group having 1 to 20 carbon atoms or -L¹-Ar¹—Ar².

HAr-L-Ar¹—Ar² (C)

Nitrogen-containing heterocyclic derivatives shown by the formula (C):
wherein HAr is a nitrogen-containing heterocyclic ring having 3 to 40 carbon atoms, which may have a substituent,

L is a single bond, an arylene group having 6 to 60 ring carbon atoms, which may have a substituent, an heteroarylene group having 5 to 60 ring atoms, which may have a substituent, or a fluorenylene group which may have a substituent,

Ar¹ is a divalent aromatic hydrocarbon group having 6 to 60 ring carbon atoms, which may have a substituent, and

Ar² is an aryl group having 6 to 60 ring carbon atoms, which may have a substituent or a heterocyclic group having 5 to 60 ring atoms, which may have a substituent.

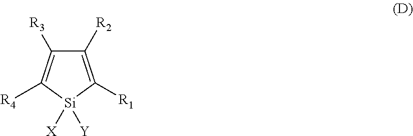

Silacyclopentadiene derivatives shown by the formula (D) wherein X and Y are independently a saturated or unsaturated hydrocarbon group having 1 to 6 carbon atoms, an alkoxy group, an alkenyloxy group, an alkynyloxy group, a hydroxyl group, a substituted or unsubstituted aryl group, or a substituted or unsubstituted hetero ring, or X and Y are bonded to form a saturated or unsaturated ring, and

R₁ to R₄ are independently hydrogen, a halogen atom, a substituted or unsubstituted aryl group having 1 to 6 carbon atoms, an alkoxy group, an aryloxy group, a perfluoroalkyl group, a perfluoroalkoxy group, an amino group, an alkylcarbonyl group, an arylcarbonyl group, an alkoxycarbonyl group, an aryloxycarbonyl group, an azo group, an alkylcarbonyloxy group, an arylcarbonyloxy group, an alkoxycarbonyloxy group, an aryloxycarbonyloxy group, a sulfinyl group, a sulfonyl group, a sulfanyl group, a silyl group, a carbamoyl group, an aryl group, a heterocyclic group, an alkenyl group, an alkynyl group, a nitro group, a formyl group, a nitroso group, a formyloxy group, an isocyano group, a cyanate group, an isocyanate group, a thiocyanate group, an isothiocyanate group, or a cyano group, or the structure including fused substituted or unsubstituted rings when X and Y are adjacent to each other.

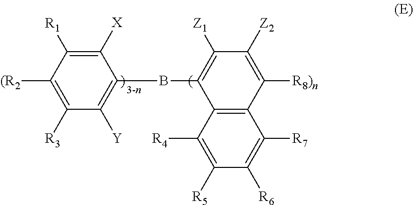

Borane derivatives shown by the formula (E) wherein R₁ to R₈ and Z₂ are independently a hydrogen atom, a saturated or unsaturated hydrocarbon group, an aromatic hydrocarbon group, a heterocyclic group, a substituted amino group, a substituted boryl group, an alkoxy group, or an aryloxy group,

X, Y, and Z are independently a saturated or unsaturated hydrocarbon group, an aromatic hydrocarbon group, a heterocyclic group, a substituted amino group, an alkoxy group, or an aryloxy group,

Z₁ and Z₂ may be bonded to form a fused ring, and n is an integer of 1 to 3, provided that when n is 2 or more, Z₁s may be the same or different,

provided that compounds where n is 1, X, Y, and R₂ are methyl groups, and R₈ is a hydrogen atom or a substituted boryl group, and compounds where n is 3 and Z₁ is a methyl group are excluded.

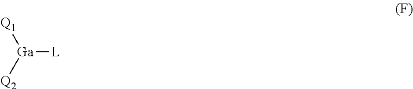

Gallium complexes shown by the formula (F) wherein Q¹ and Q² are independently ligands represented by the following formula (G) and

L is a halogen atom, a substituted or unsubstituted alkyl group, a substituted or unsubstituted cycloalkyl group, a substituted or unsubstituted aryl group, a substituted or unsubstituted heterocyclic group, —OR¹ (R¹ is a hydrogen atom, a substituted or unsubstituted alkyl group, a substituted or unsubstituted cycloalkyl group, a substituted or unsubstituted aryl group, or a substituted or unsubstituted heterocyclic group) or a ligand represented by —O—Ga-Q³(Q⁴) wherein Q³ and Q⁴ are the same as Q¹ and

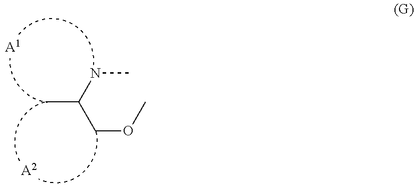

wherein rings A¹ and A² are independently a 6-membered aryl ring structure which may have a substituent and they are fused to each other.

The metal complexes have the strong nature of an n-type semiconductor and large ability of injecting electrons. Further, the energy generated at the time of forming a complex is small so that a metal is then strongly bonded to ligands in the complex formed and the fluorescent quantum efficiency becomes large as the emitting material.

As for the alkyl group, the aryl group, the heterocyclic group or the like mentioned in the hole-injecting materials, the hole-transporting materials and the electron-injecting materials in the invention, the groups shown by R²¹ to R²⁴ in the formula (1) given above or the groups shown by R¹ to R⁸ in the formula (2) given above can be applied.

A preferred embodiment of the invention is a device containing a reducing dopant in an electron-transferring region or in an interfacial region between the cathode and the organic layer. The reducing dopant is defined as a substance which can reduce an electron-transferring compound. Accordingly, various substances which have given reducing properties can be used. For example, at least one substance can be preferably used which is selected from the group consisting of alkali metals, alkaline earth metals, rare earth metals, alkali metal oxides, alkali metal halides, alkaline earth metal oxides, alkaline earth metal halides, rare earth metal oxides, rare earth metal halides, alkali metal carbonates, alkaline earth metal carbonates, alkali metal organic complexes, alkaline earth metal organic complexes, and rare earth metal organic complexes.

More specific examples of the preferred reducing dopants include at least one alkali metal selected from the group consisting of Na (work function: 2.36 eV), K (work function: 2.28 eV), Rb (work function: 2.16 eV) and Cs (work function: 1.95 eV), and at least one alkaline earth metal selected from the group consisting of Ca (work function: 2.9 eV), Sr (work function: 2.0 to 2.5 eV), and Ba (work function: 2.52 eV). Metals having a work function of 2.9 eV or less are particularly preferred. Among these, a more preferable reducing dopant is at least one alkali metal selected from the group consisting of K, Rb and Cs. Even more preferable is Rb or Cs. Most preferable is Cs. These alkali metals are particularly high in reducing ability. Thus, the addition of a relatively small amount thereof to an electron-injecting zone improves the luminance of the organic EL device and make the lifetime thereof long. As a reducing dopant having a work function of 2.9 eV or less, combinations of two or more alkali metals are preferable, and particularly combinations including Cs, such as Cs and Na, Cs and K, Cs and Rb, or Cs, Na and K, are preferable. The combination containing Cs makes it possible to exhibit the reducing ability efficiently. The luminance of the organic EL device can be improved and the lifetime thereof can be made long by the addition thereof to its electron-injecting zone.

In the invention, an electron-injecting layer made of an insulator or a semiconductor may further be provided between a cathode and an organic layer. By forming the electron-injecting layer, a current leakage can be effectively prevented and electron-injecting properties can be improved. As the insulator, at least one metal compound selected from the group consisting of alkali metal calcogenides, alkaline earth metal calcogenides, halides of alkali metals and halides of alkaline earth metals can be preferably used. When the electron-injecting layer is formed of the alkali metal calcogenide or the like, the injection of electrons can be preferably further improved.

Specifically preferable alkali metal calcogenides include Li₂O, K₂O, Na₂S, Na₂Se and Na₂O and preferable alkaline earth metal calcogenides include CaO, BaO, SrO, BeO, BaS and CaSe. Preferable halides of alkali metals include LiF, NaF, KF, CsF, LiCl, KCl and NaCl. Preferable halides of alkaline earth metals include fluorides such as CaF₂, BaF₂, SrF₂, MgF₂ and BeF₂ and halides other than fluorides.

Semiconductors forming an electron-transporting layer include one or combinations of two or more of oxides, nitrides, and oxidized nitrides containing at least one element of Ba, Ca, Sr, Yb, Al, Ga, In, Li, Na, Cd, Mg, Si, Ta, Sb and Zn. An inorganic compound forming an electron-injecting layer is preferably a microcrystalline or amorphous insulating thin film. When the electron-injecting layer is formed of the insulating thin films, more uniformed thin film is formed whereby pixel defects such as a dark spot can be decreased. Examples of such an inorganic compound include the above-mentioned alkali metal calcogenides, alkaline earth metal calcogenides, halides of alkali metals, and halides of alkaline earth metals.

For the cathode, the following may be used: an electrode substance made of a metal, an alloy or an electroconductive compound, or a mixture thereof which has a small work function (for example, 4 eV or less). Specific examples of the electrode substance include sodium, sodium-potassium alloy, magnesium, lithium, cesium, magnesium/silver alloy, aluminum/aluminum oxide, Al/LiO₂, Al/LiO, Al/LiF, aluminum/lithium alloy, indium, and rare earth metals.

This cathode can be formed by making the electrode substances into a thin film by vapor deposition, sputtering or some other method.

In the case where light is emitted from the emitting layer through the cathode, the cathode preferably has a light transmittance of larger than 10%. The sheet resistance of the cathode is preferably several hundreds Ω/□ to or less, and the film thickness thereof is usually from 10 nm to 1 μm, preferably from 50 to 200 nm.

In the organic EL device, pixel defects based on leakage or a short circuit are easily generated since an electric field is applied to the super thin film. In order to prevent this, an insulative thin film layer may be inserted between the pair of electrodes.

Examples of the material used in the insulating layer include aluminum oxide, lithium fluoride, lithium oxide, cesium fluoride, cesium oxide, magnesium oxide, magnesium fluoride, calcium oxide, calcium fluoride, aluminum nitride, titanium oxide, silicon oxide, germanium oxide, silicon nitride, boron nitride, molybdenum oxide, ruthenium oxide, and vanadium oxide. A mixture or laminate thereof may be used.

In order to enhance the stability to temperature, moisture, atmosphere or the like of the organic EL device obtained by the invention, it is possible to provide a protective layer on the device surface. The entire device can be protected by silicone oil, a resin or the like.

As the conductive material used for the anode of the organic EL device of the present invention, a conductive material having a work function larger than 4 eV is suitable. Examples thereof include carbon, aluminum, vanadium, iron, cobalt, nickel, tungsten, silver, gold, platinum, palladium, etc. and alloys thereof, tin oxides used in an ITO substrate and a NESA substrate, metal oxides such as indium oxide, and organic conductive resins such as polythiophene and polypyrrole. As the conductive material used for the cathode, a conductive material having a work function smaller than 4 eV is suitable. Examples thereof include magnesium, calcium, tin, lead, titanium, yttrium, lithium, ruthenium, manganese, aluminum, lithium fluoride and alloys thereof, but not limited thereto. Representative examples of the alloys include magnesium/silver alloys, magnesium/indium alloys and lithium/aluminum alloys, but not limited thereto. The amount ratio of the alloy is controlled by the temperature of a deposition source, atmosphere, degree of vacuum or the like, can be appropriately selected. If necessary, the anode and the cathode each may have a laminated structure of two or more layers.

In order to allow the organic EL device of the invention to emit light efficiently, it is desired that at least one surface be fully transparent in an emission wavelength region of the device. Further, it is desired that the substrate be also transparent. By using the above-mentioned conductive materials and by using the methods such as deposition and sputtering, the transparent electrode is provided such that predetermined transparency can be ensured. It is desired that the electrode on the light-emitting surface have a light transmission of 10% or higher. Although there are no restrictions on the substrate as long as it has mechanical and thermal strength and transparency, usable substrates include a glass substrate and a transparent resin film.

Examples of the transparent resin film include polyethylene, an ethylene-vinyl acetate copolymer, an ethylene-vinyl alcohol copolymer, polypropylene, polystyrene, polymethyl methacrylate, polyvinyl chloride, polyvinyl alcohol, polyvinyl butyral, nylon, polyetheretherketone, polysulfone, polyethersulfone, tetrafluoroethylene-perfluoroalkylvinylether copolymer, polyvinyl fluoride, a tetrafluoroethylene-ethylene copolymer, a tetrafluoroethylene-hexafluoropropylene copolymer, polychlorotrifluoroethylene, polyvinylidene fluoride, polyester, polycarbonate, polyurethane, polyimide, polyetherimide, polyimide and polypropylene.

Each layer of the organic EL device of the invention can be formed by any of dry film forming methods such as vacuum vapor deposition, sputtering, plasma coating and ion coating and wet film forming methods such as spin coating, dipping and flow coating. Although the film thickness is not particularly limited, each layer is required to be set to have an appropriate thickness. If the film thickness is too large, it is required to apply a large voltage in order to obtain a certain light output, resulting in a lowered efficiency. If the film thickness is too small, pinholes or the like are generated, and a sufficient luminance cannot be obtained even if an electric field is applied. Normally, a film thickness of 5 nm to 10 μm is appropriate, with 10 nm to 0.2 μm being further preferable.

In the case of wet film forming methods, a thin film is formed by dissolving or dispersing materials for forming each layer in an appropriate solvent such as ethanol, chloroform, tetrahydrofuran, dioxane or the like. Any of the above-mentioned solvents is usable. Further, in any of organic thin film layer, an appropriate resin or an additive may be used in order to improve film-forming properties, prevention of generation of pin holes in the film, or the like. Usable resins include insulating resins such as polystyrene, polycarbonate, polyarylate, polyesters, polyamides, polyurethane, polysulfone, polymethyl methacrylate, polymethyl acrylate and cellulose and copolymers thereof, photoconductive resins such as poly-N-vinylcarbazole and polysilane, and conductive resins such as polythiophene and polypyrrole. Examples of usable additives include an antioxidant, an UV absorber and a plasticizer.

The organic EL device of the invention can be suitably used as a planar emitting body such as a flat panel display of a wall hanging television, backlight of a copier, a printer, or a liquid crystal display, light sources for instruments, a display panel, a navigation light, and the like. Further, the materials of the invention can be used not only in organic EL devices, but also in the fields of electrophotographic photoreceptors, photoelectric conversion devices, solar cells, image sensors or the like.

Other embodiments of the invention will be described below.

1′. An organic light-emitting medium comprising a diaminopyrene derivative represented by the above formula (1) and an anthracene derivative represented by the above formula (2) (however, one shown by the following formula (2′) is excluded):

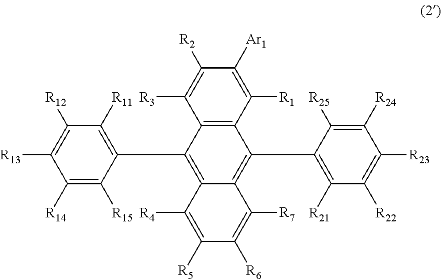

wherein R₁ to R₇ are independently a hydrogen atom, an alkyl group having 1 to 20 carbon atoms, a cycloalkyl group having 3 to 20 carbon atoms, a substituted or unsubstituted alkoxy group having 1 to 50 carbon atoms, a substituted or unsubstituted silyl group, a halogen atom, or a cyano group;

R₁₁ to R₁₅ and R₂₁ to R₂₅ are independently a hydrogen atom, an alkyl group having 1 to 20 carbon atoms, a cycloalkyl group having 3 to 20 carbon atoms, a substituted or unsubstituted alkoxy group having 1 to 50 carbon atoms, a substituted or unsubstituted aryl group having 6 to 50 ring carbon atoms, a substituted or unsubstituted fused aromatic group having 10 to 50 ring carbon atoms, a substituted or unsubstituted heterocyclic group having 5 to 50 ring atoms, a substituted or unsubstituted silyl group, a halogen atom or a cyano group;

provided that at least one of R₁₁ to R₁₅ and R₂₁ to R₂₅ is a substituted or unsubstituted fused aromatic group having 10 to 50 ring carbon atoms or a substituted or unsubstituted heterocylic group having 5 to 50 ring atoms;

Ar₁ is a substituted or unsubstituted aryl group having 6 to 50 ring carbon atoms or a substituted or unsubstituted heterocyclic group having 5 to 50 ring atoms, provided that Ar₁ does not contain an orthophenylene structure.

2′. The organic light-emitting medium according to 1′, wherein any one of R¹, R², R⁷ and R⁸ in the formula (2) is a substituted or unsubstituted aryl group having 6 to 50 ring carbon atoms or a substituted or unsubstituted heterocyclic group having 5 to 50 ring atoms.
3′. The organic light-emitting medium according to 2′, wherein any one of R¹ and R⁸ in the formula (2) is a substituted or unsubstituted aryl group having 6 to 50 ring carbon atoms or a substituted or unsubstituted heterocyclic group having 5 to 50 ring atoms, and the other is a hydrogen atom.
4′. The organic light-emitting medium according to 2′, wherein any one of R¹, R², R⁷ and R⁸ in the formula (2) is a substituted or unsubstituted aryl group having 6 to 50 ring carbon atoms.
5′. The organic light-emitting medium according to 4′, wherein one of R¹ and R⁸ in the formula (2) is a substituted or.
6′. The organic light-emitting medium according to 5′, wherein the substituted or unsubstituted aryl group having 6 to 50 ring carbon atoms is a substituted or unsubstituted phenyl group, a substituted or unsubstituted naphthyl group, a substituted or unsubstituted fluorenyl group or a substituted or unsubstituted phenanthryl group.
7′. The organic light-emitting medium according to any of 1′ to 6′, wherein Ar¹¹ in the above formula (2) is a substituted or unsubstituted heterocyclic group having 5 to 50 ring atoms.
8′. The organic light-emitting medium according to any of 1′ to 6′, wherein Ar¹¹ and Ar¹² in the above formula (2) are independently a substituted or unsubstituted fused aryl group having 10 to 50 ring carbon atoms.
9′. The organic light-emitting medium according to 8′, wherein Ar¹¹ and Ar¹² in the above formula (2) are the same groups.
10′. The organic light-emitting medium according to 9′, wherein Ar¹¹ and Ar¹² in the above formula (2) are each a substituted or unsubstituted 9-phenanthrenyl group.
11′. The organic light-emitting medium according to 9′, wherein Ar¹¹ and Ar¹² in the above formula (2) are a substituted or unsubstituted 2-naphthyl group.
12′. The organic light-emitting medium according to 9′, wherein Ar¹¹ and Ar¹² in the above formula (2) are a substituted or unsubstituted 1-naphthyl group.
13′. The organic light-emitting medium according to 8′, wherein Ar¹¹ and Ar¹² in the above formula (2) are different groups.
14′. The organic light-emitting medium according to any of 1′ to 9′ and 13′, wherein Ar¹¹ and Ar¹² in the above formula (2) are each a substituted or unsubstituted phenyl group.
15′. The organic light-emitting medium according to 14′, wherein Ar¹¹ and Ar¹² in the above formula (2) are each a substituted or unsubstituted aryl group having 6 to 30 carbon atoms or a phenyl group substituted with a substituted or unsubstituted heterocyclic group having 5 to 30 ring atoms.

16′. The organic light-emitting medium according to 13′, wherein Ar¹¹ and Ar¹² in the above formula (2) are independently any of a substituted or unsubstituted 9-phenanthrenyl group, a substituted or unsubstituted 1-naphthyl group, a substituted or unsubstituted 2-naphthyl group, a substituted or unsubstituted fluoranthenyl group and a substituted or unsubstituted pyrenyl group.

17′. The organic light-emitting medium according to 13′, wherein one of Ar¹¹ and Ar¹² in the above formula (2) is a substituted or unsubstituted phenyl group, and the other is a substituted or unsubstituted fused aryl group having 10 to 50 ring carbon atoms.
18′. The organic light-emitting medium according to 17′, wherein the substituted or unsubstituted fused aryl group having 10 to 50 ring carbon atoms is a substituted or unsubstituted 1-naphthyl group.
19′. The organic light-emitting medium according to 17′, wherein the substituted or unsubstituted fused aryl group having 10 to 50 ring carbon atoms is a substituted or unsubstituted 2-naphthyl group.
20′. The organic light-emitting medium according to 17′, wherein the substituted or unsubstituted fused aryl group having 10 to 50 ring carbon atoms is a substituted or unsubstituted fluoranthenyl group.
21′. The organic light-emitting medium according to 17′, wherein the substituted or unsubstituted fused aryl group having 10 to 50 ring carbon atoms is a substituted or unsubstituted pyrenyl group.

22′. An organic light-emitting medium comprising a diaminopyrene derivative represented by the above formula (1) and an anthracene derivative represented by the above formula (2′).

23′. An organic light-emitting medium according to any of 1′ to 22′, wherein R^{a} and R^{b} in the above formula (1) are independently a substituted or unsubstituted phenyl group, a substituted or unsubstituted naphthyl group or a substituted or unsubstituted fluorenyl group.
24′. The organic light-emitting medium according to any of 1′ to 23′, wherein Ar¹ to Ar⁴ in the above formula (1) are independently a group selected from a substituted or unsubstituted phenyl group, a substituted or unsubstituted naphthyl group, a substituted or unsubstituted fluorenyl group or a substituted and unsubstituted dibenzofuranyl group.
25′. The organic light-emitting medium according to 24′, wherein at least one of Ar¹ to Ar⁴ in the formula (1) is a substituted or unsubstituted fluorenyl group.
26′. The organic light-emitting medium according to any of 1′ to 25′, wherein R²¹ to R²⁴ in the above formula (1) are independently a substituted or unsubstituted phenyl group, a substituted or unsubstituted methyl group, a substituted or unsubstituted ethyl group, a substituted or unsubstituted isopropyl group, a substituted or unsubstituted t-butyl group, a substituted or unsubstituted cyclopropyl group, a substituted or unsubstituted cyclopentyl group, a substituted or unsubstituted cyclohexyl group, a substituted or unsubstituted trimethylsilyl group or a cyano group.
27′. An organic electroluminescence device comprising:

an anode, a cathode, and

one or more organic thin film layers between the anode and the cathode,

wherein at least one of the organic thin film layers comprises the organic light-emitting medium according to any of 1′ to 26′.

28′. The organic electroluminescence device according to 27′, wherein the organic thin film layer comprising the organic light-emitting medium is an emitting layer.

### EXAMPLES

The invention will be explained below in more detail with reference to Examples and Comparative Examples, which should not be construed as limiting the scope of the invention.

It is noted that Compounds 1 to 36 and Compounds 45 to 56 in the following Examples and Comparative examples is shown below. The following compounds were synthesized with reference to international publications WO2003/060956 and WO2006/025700.

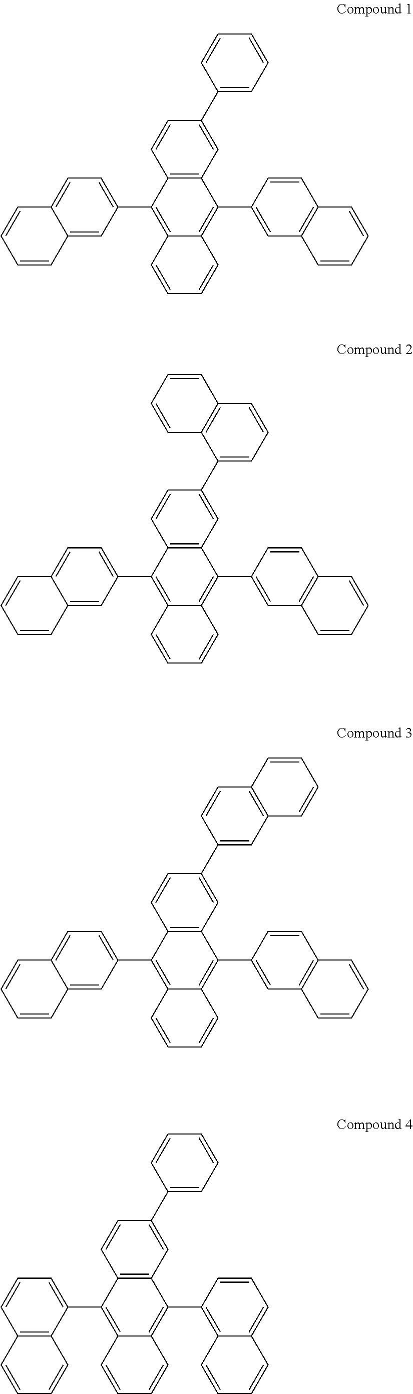

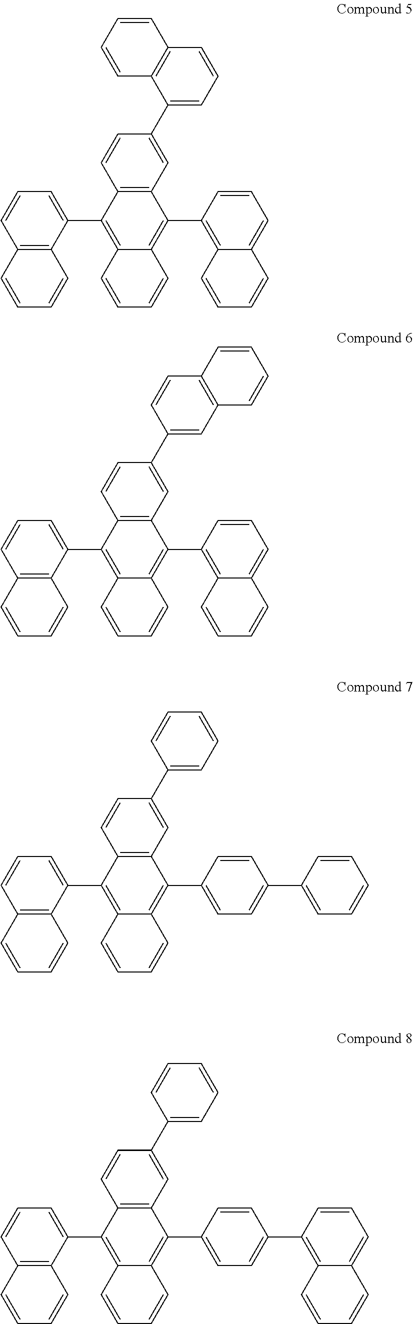

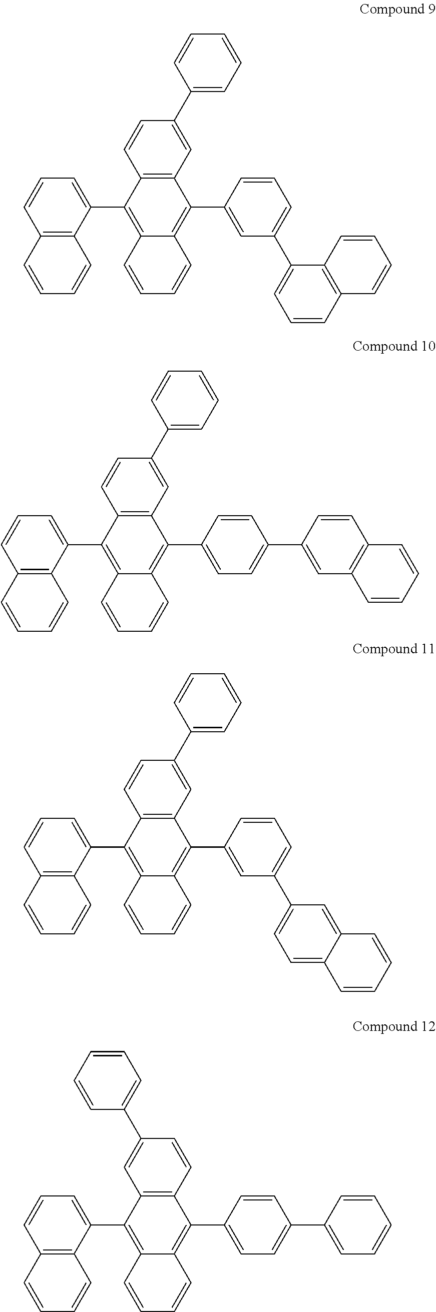

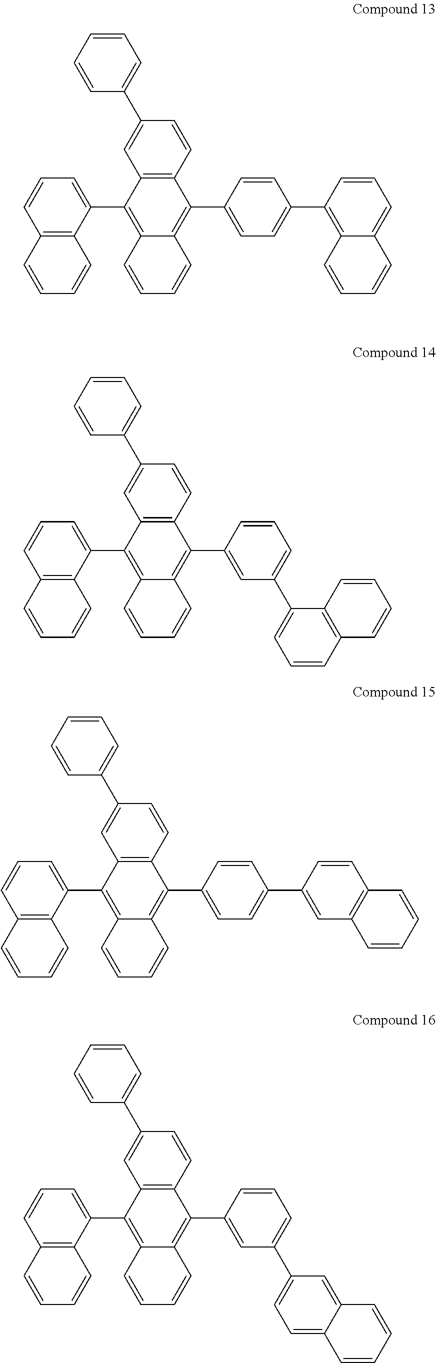

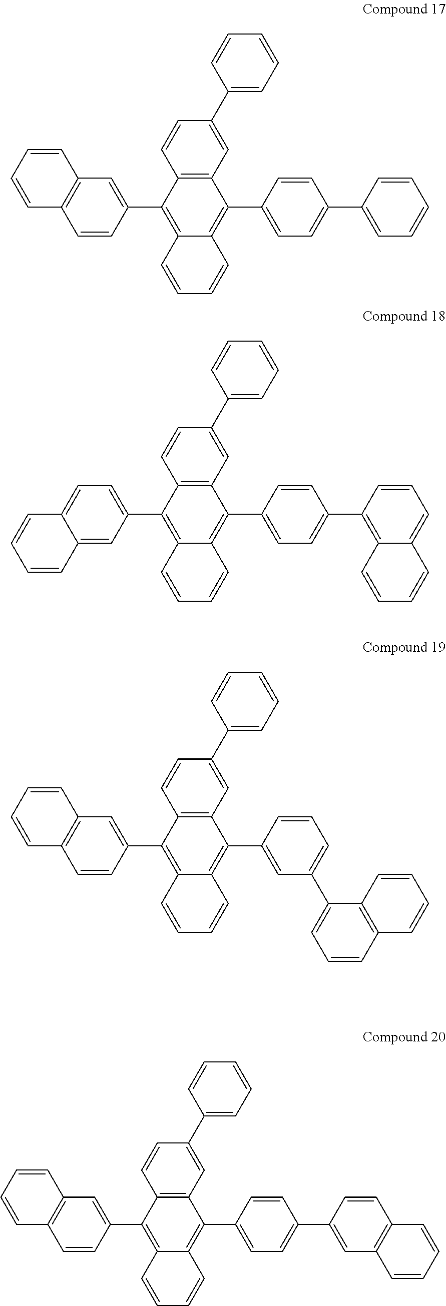

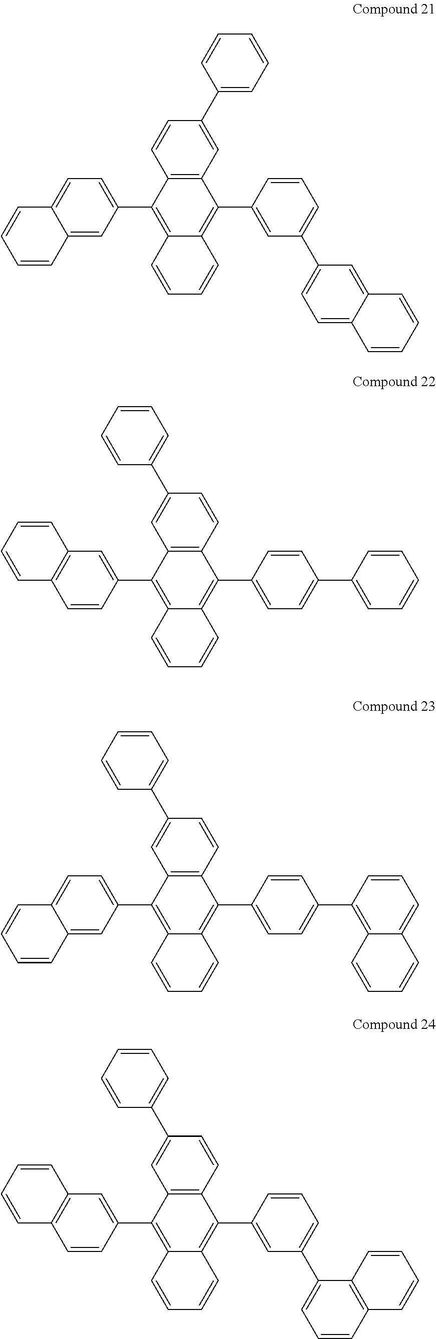

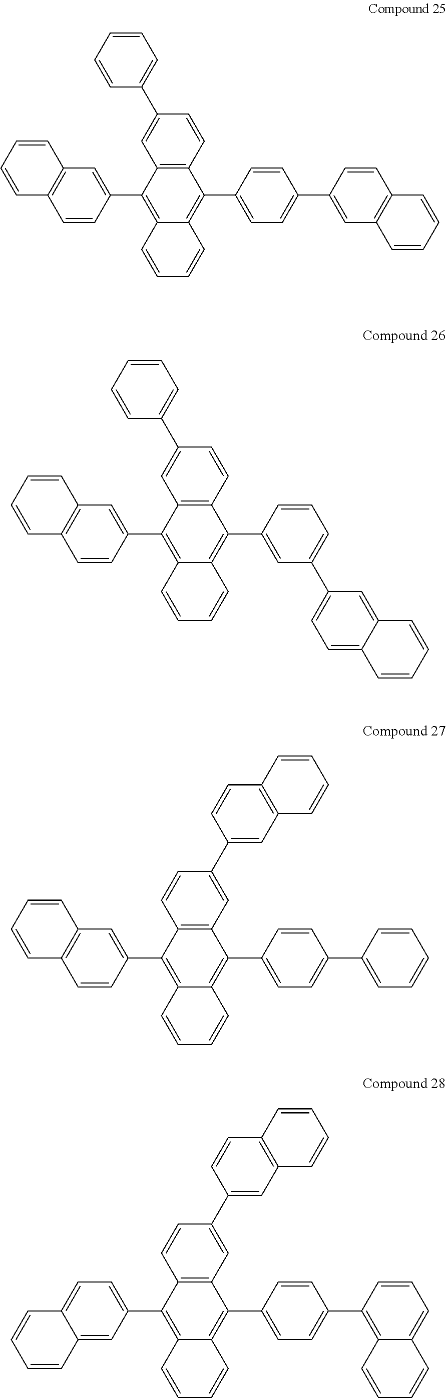

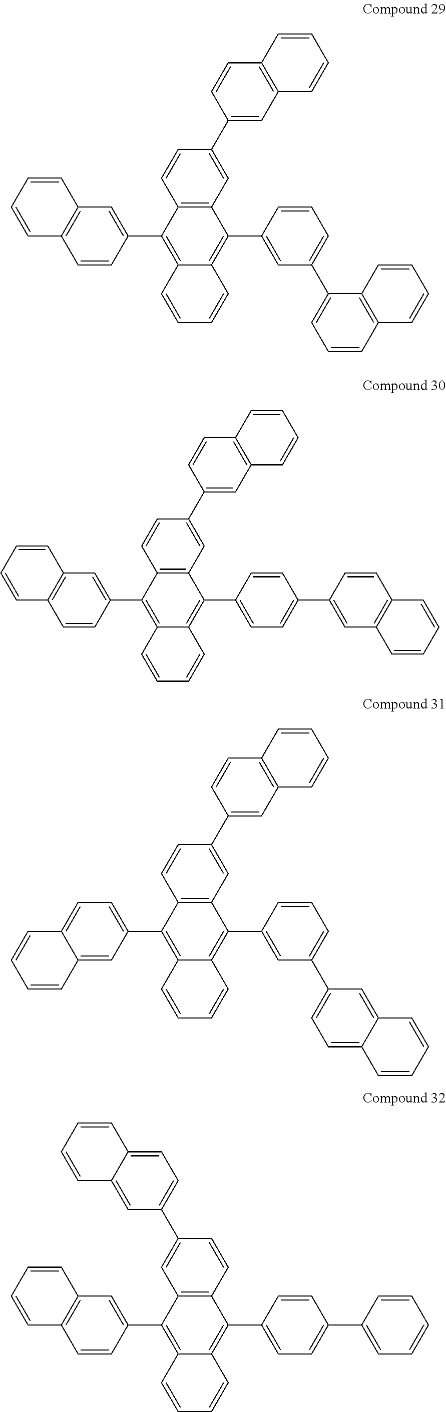

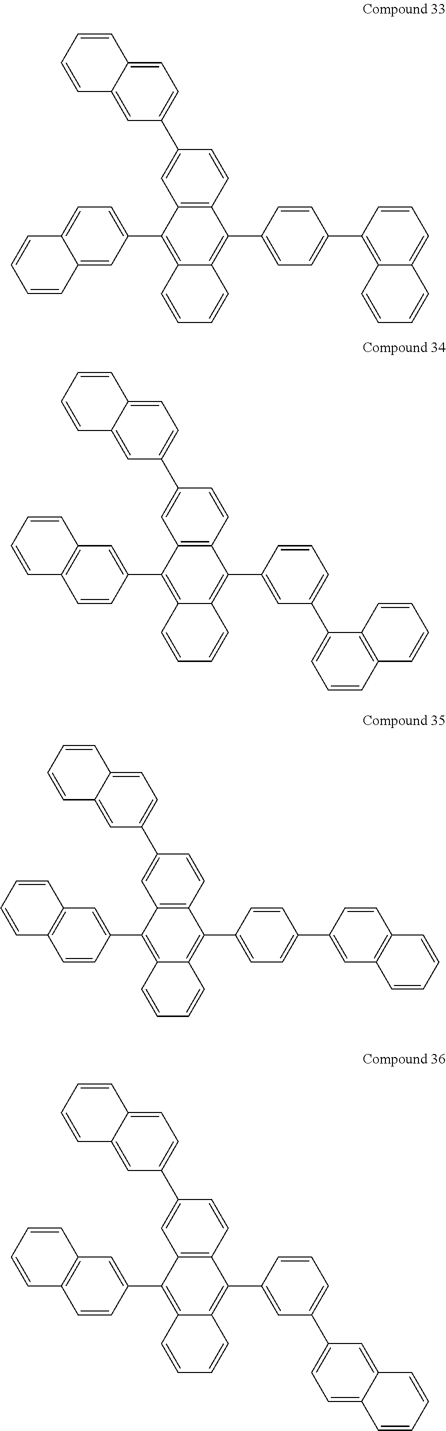

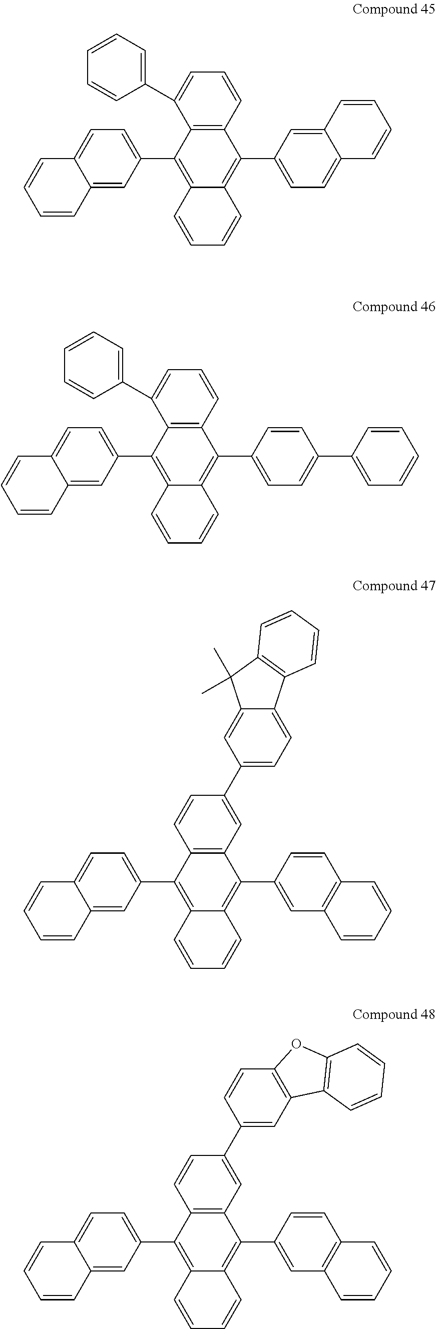

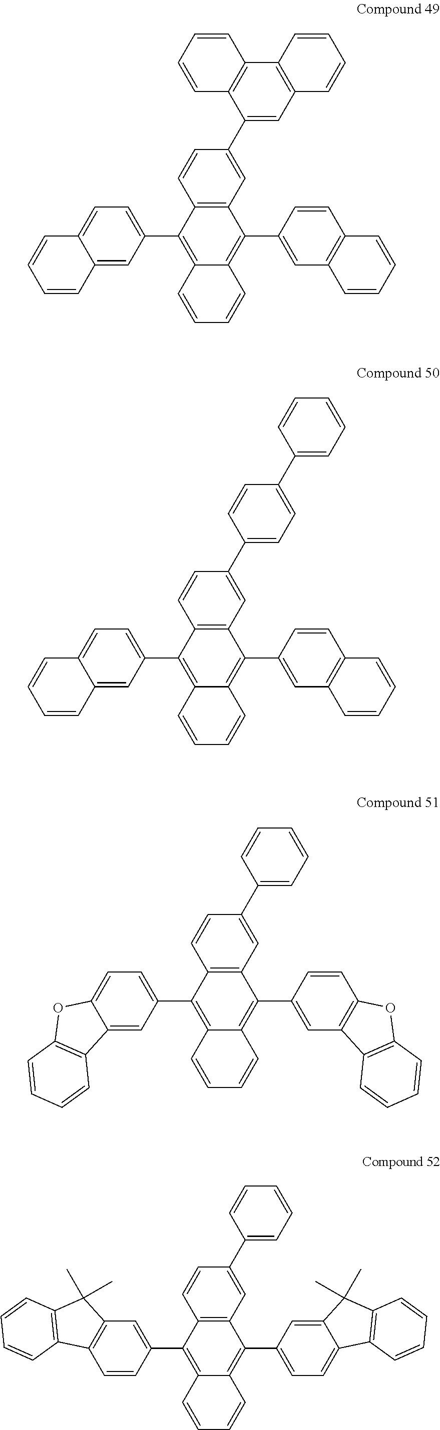

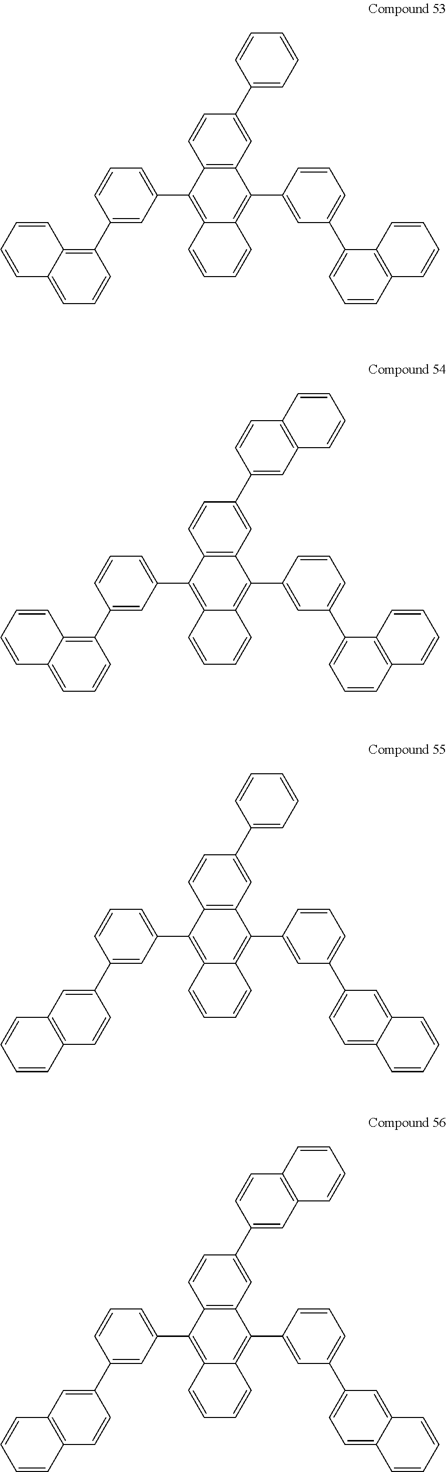

### Synthesis Example 1

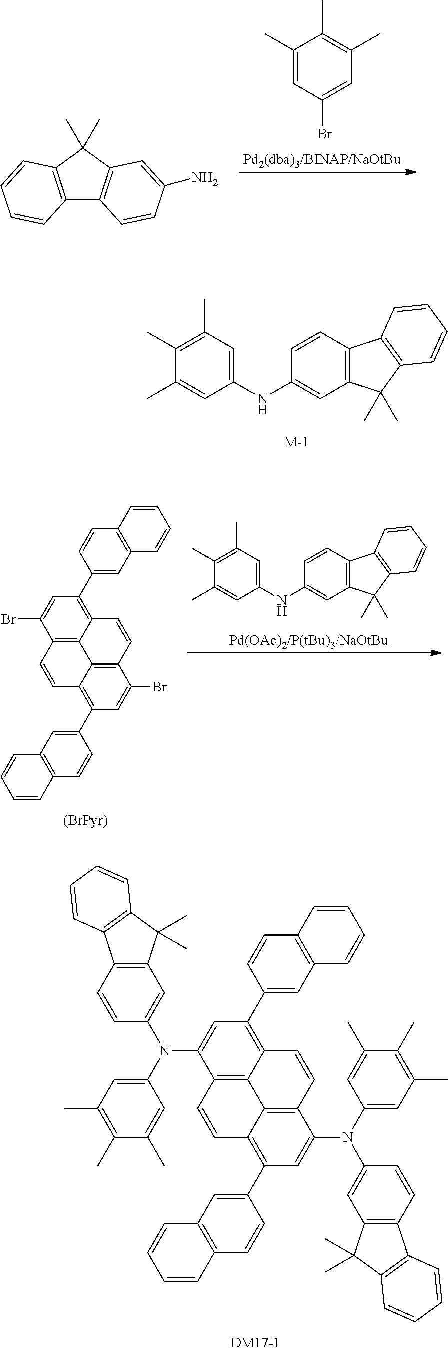

### (1) Synthesis of Intermediate M-1

A 200 ml three-necked flask was charged with 36.6 mmol (7.66 g) of 2-amino-9,9-dimethylfluorene, 0.28 mmol (0.25 g) of tris(dibenzylideneacetone)dipalladium, 0.56 mmol (0.35 g) of 2,2′-bis(diphenylphosphino)-1,1′-binaphthyl (BINAP) and 37.5 mmol (3.61 g) of sodium tert-butoxide. The flask was replaced by nitrogen gas twice under reduced pressure. Then 30 ml of toluene and 18.8 mmol (3.74 g) of 3,4,5-trimethylbromobenzene were added to the flask and reacted under reflux for 7 hours.

An insoluble matter was filtered out from the reaction solution obtained and washed with toluene. After the filtrate was washed with 200 ml of a saturated aqueous solution of sodium chloride, an organic layer was dried with magnesium sulfate. The residual oil obtained by removing the solvent after filtration was purified by means of silica columns (hexane/methylene chloride=9/1 to 8/2) to obtain 3.7 g of (M-1) (yield: 67%).

### (2) Synthesis of DM17-1

A 200 ml three-necked flask was charged with 5.09 mmol (3.1 g) of 1,6-dibromo-3,8-di(2′-naphthyl)pyrene(BrPyr), 0.51 mmol (0.11 g) of palladium acetate and 10.2 mmol (0.98 g) of sodium tert-butoxide. The flask was replaced by nitrogen gas twice under reduced pressure. Then, 60 ml of toluene, 0.51 mmol (0.10 g) of tri(t-butyl)phosphine, and 11.2 mmol (3.7 g) of (M-1) were added to the flask and reacted at 80° C. for 8 hours.

Toluene was removed from the heterogeneous solution obtained, methanol was added thereto, and an insoluble matter was filtered out. The insoluble matter was recrystallized with toluene repeatedly to obtain 3.1 g of solid matters (yield: 55%).

As a result of mass spectrometry, the resulting solid matters had an m/e value of 1104 with respect to a molecular weight of 1104.54. Therefore this was confirmed to be the intended substance DM17-1.

### Synthesis Example 2

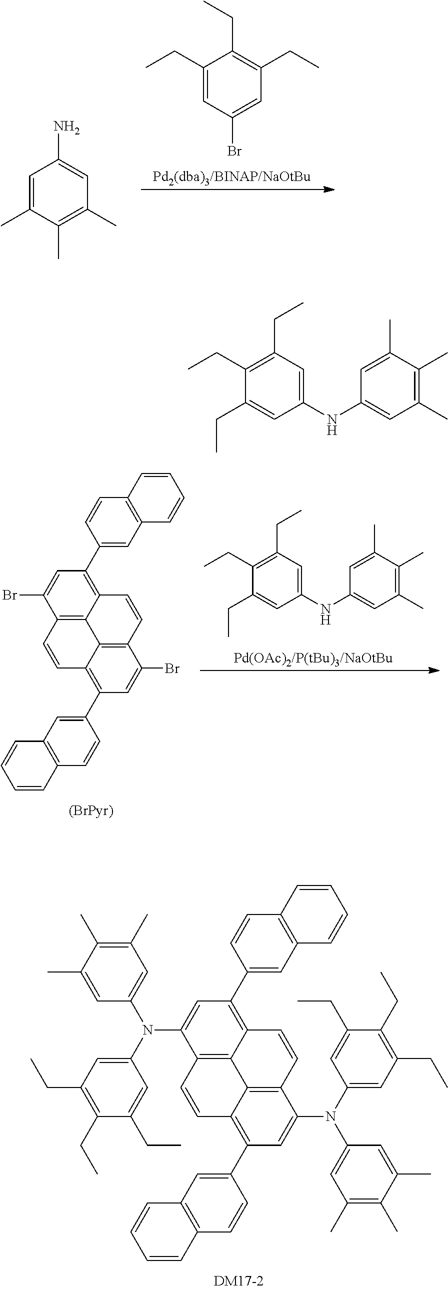

The intended substance was synthesized in the same manner as in the Synthesis of DM17-1 (Synthesis Example 1), except that 3,4,5-trimethylaniline was used instead of 2-amino-9,9-dimethylfluorene, and 3,4,5-triethylbenzene was used instead of 3,4,5-trimethylbromobenzene. As a result of mass spectrometry, the product material had an m/e value of 1040 with respect to a molecular weight of 1040.60. Therefore, this was confirmed to be the intended substance DM17-2.

### Synthesis Example 3

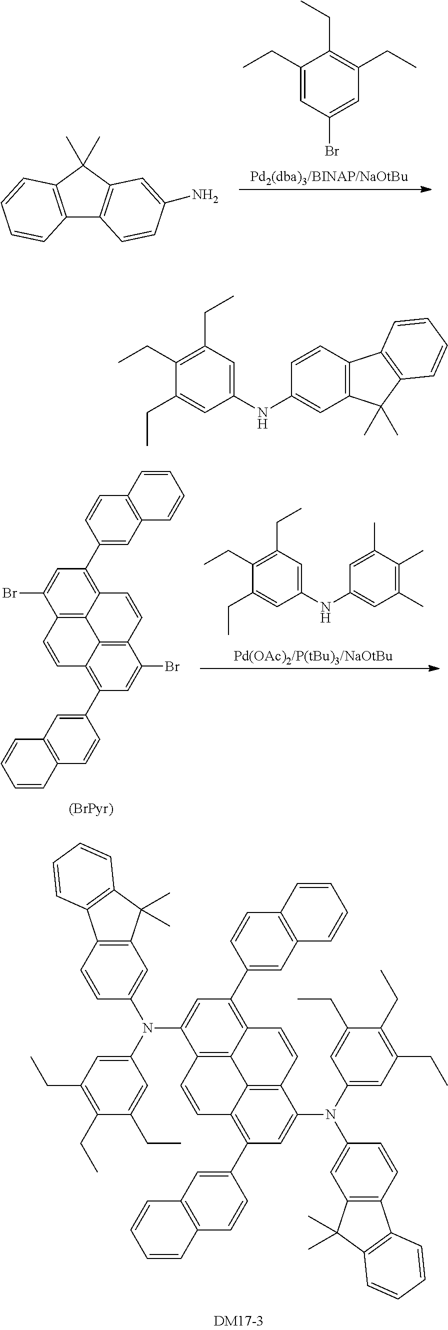

The intended substance was synthesized in the same manner as in the Synthesis of DM17-1 (Synthesis Example 1), except that 3,4,5-triethylbenzene was used instead of 3,4,5-trimethylbromobenzene. As a result of mass spectrometry, the product material had an m/e value of 1188 with respect to a molecular weight of 1188.63. Therefore, this was confirmed to be the intended substance DM17-3.

### Synthesis Example 4

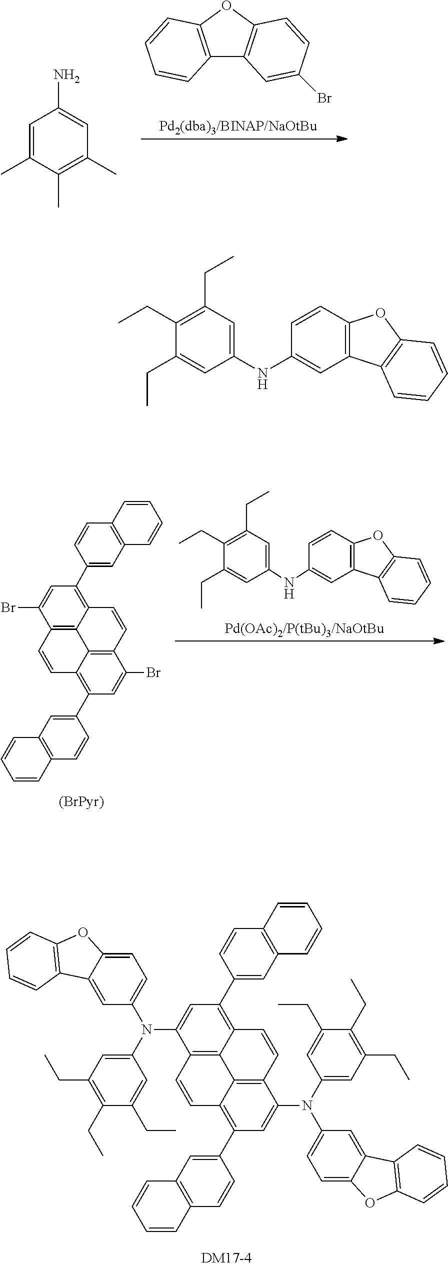

The intended substance was synthesized in the same manner as in the Synthesis of DM17-1 (Synthesis Example 1), except that 3,4,5-trimethylaniline was used instead of 2-amino-9,9-dimethylfluorene, and 2-bromodibenzofuran was used instead of 3,4,5-trimethylbromobenzene. As a result of mass spectrometry, the product had an m/e value of 1136 with respect to a molecular weight of 1136.53. Therefore, this was confirmed to be the intended substance DM17-4.

### Example 1

A glass substrate of 25 mm by 75 mm by 1.1 mm thick with an ITO transparent electrode (anode) (GEOMATEC CO., LTD.) was subjected to ultrasonic cleaning with isopropyl alcohol for 5 minutes, and cleaned with ultraviolet rays and ozone for 30 minutes. The cleaned glass substrate with transparent electrode lines was mounted in a substrate holder of a vacuum vapor deposition apparatus. First, a 60 nm-thick film formed of compound A-1 was formed on the surface where the transparent electrode lines were formed so as to cover the transparent electrode. Subsequent to forming the A-1 film, a 20 nm-thick film formed of compound A-2 was formed on the A-1 film. Subsequently, on the A-2 film, the host material compound 1 and the dopant material DM1-1 of the invention were formed into a 40 nm-thick film in a ratio by weight of 40:2. This film functioned as a green emitting layer.

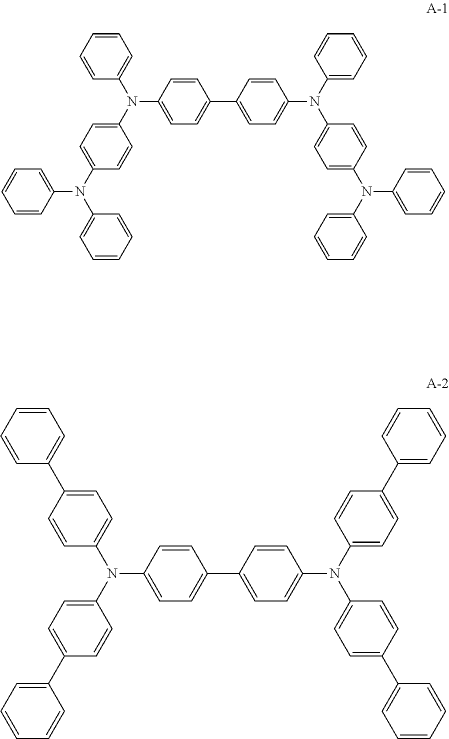

On the green emitting layer, Alq having the following structure was formed into a 20 nm-thick film by deposition. On this film, LiF was formed into a 1 nm-thick film. Then, metal Al was deposited on the LiF film in a 150 nm thickness to form a metal cathode, whereby an organic EL device was fabricated.

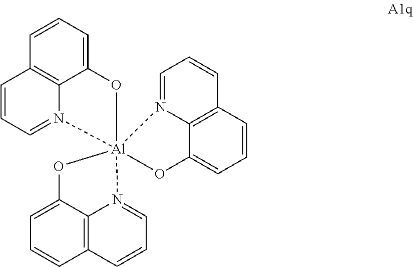

### Examples 2 to 352

Organic EL devices were fabricated in the same manner as in Example 1, except that host materials and dopant materials in Tables 1 to 9 were used instead of the host material compound 1 and the dopant material compound DM1-1.

### Comparative Example 1

An organic EL device was fabricated in the same manner as in Example 1, except that the following compound H-1 was used instead of the host material compound 1, and the dopant material DM2-4 was used instead of the dopant material DM1-1.

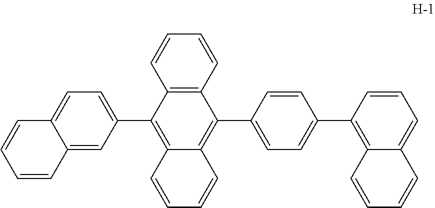

### Comparative Example 2

An organic EL device was fabricated in the same manner as in Example 1, except that the compound H-1 was used instead of the host material compound 1, and the dopant material DM10-4 was used instead of the dopant material DM1-1.

### Comparative Example 3

An organic EL device was fabricated in the same manner as in Example 1, except that the following compound H-2 was used instead of the host material compound 1, and the following compound D-1 was used instead of the dopant material DM1-1.

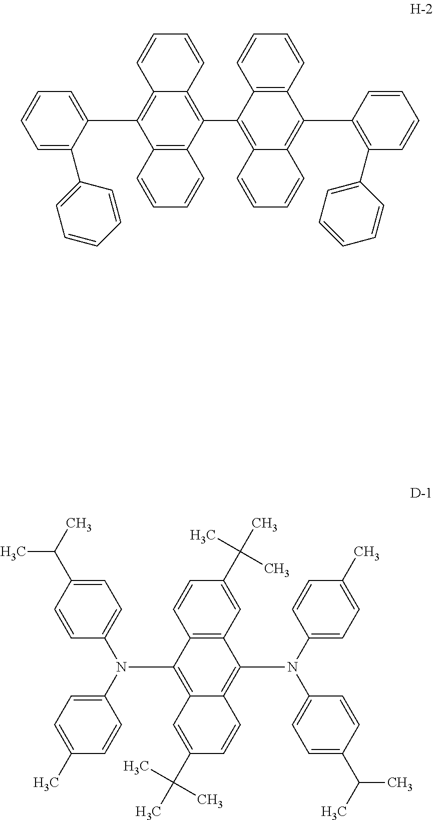

### Comparative Example 4

An organic EL device was fabricated in the same manner as in Example 1, except that the following compound H-3 was used instead of the host material compound 1, and the following compound D-2 was used instead of the dopant material DM1-1.

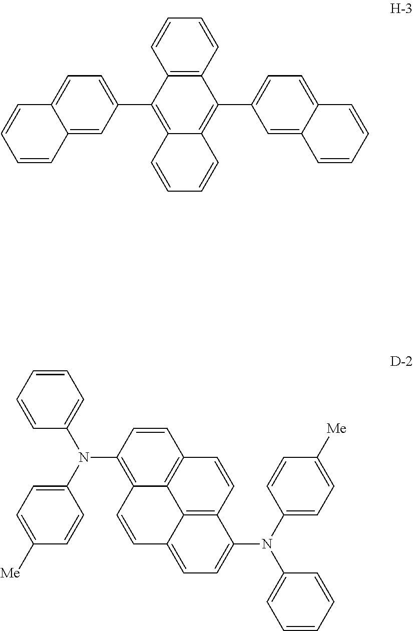

### Comparative Example 5

An organic EL device was fabricated in the same manner as in Example 1, except that the following compound H-4 was used instead of the host material compound 1, and the compound D-2 was used instead of the dopant material DM1-1.

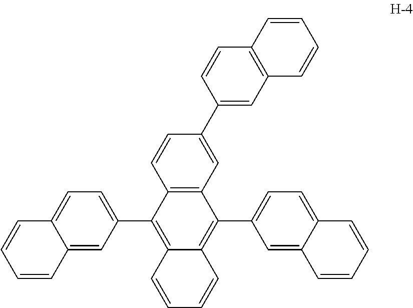

Tables 1 to 9 show luminous efficiency and the half life at an initial luminance of 1000 cd/m² for the organic EL device obtained in Examples 1 to 352 and Comparative Examples 1 to 5.

TABLE 1

| | | | Luminous | Half |
|---|---|---|---|---|
| | Host | Dopant | efficiency | life |
| Examples | Material | material | [cd/A] | [hr] |
| 1 | Compound 1 | DM1-1 | 20 | 49000 |
| 2 | Compound 2 | DM1-1 | 20 | 49000 |
| 3 | Compound 3 | DM1-1 | 20 | 49000 |
| 4 | Compound 4 | DM1-1 | 20 | 47000 |
| 5 | Compound 5 | DM1-1 | 20 | 47000 |
| 6 | Compound 6 | DM1-1 | 20 | 47000 |
| 7 | Compound 7 | DM1-1 | 20 | 54000 |
| 8 | Compound 8 | DM1-1 | 20 | 54000 |
| 9 | Compound 9 | DM1-1 | 20 | 54000 |
| 10 | Compound 10 | DM1-1 | 20 | 54000 |
| 11 | Compound 11 | DM1-1 | 20 | 54000 |
| 12 | Compound 12 | DM1-1 | 20 | 54000 |
| 13 | Compound 13 | DM1-1 | 20 | 54000 |
| 14 | Compound 14 | DM1-1 | 20 | 54000 |
| 15 | Compound 15 | DM1-1 | 20 | 54000 |
| 16 | Compound 16 | DM1-1 | 20 | 54000 |
| 17 | Compound 17 | DM1-1 | 20 | 54000 |
| 18 | Compound 18 | DM1-1 | 20 | 54000 |
| 19 | Compound 19 | DM1-1 | 20 | 54000 |
| 20 | Compound 20 | DM1-1 | 20 | 54000 |
| 21 | Compound 21 | DM1-1 | 20 | 54000 |
| 22 | Compound 22 | DM1-1 | 20 | 54000 |
| 23 | Compound 23 | DM1-1 | 20 | 54000 |
| 24 | Compound 24 | DM1-1 | 20 | 54000 |
| 25 | Compound 25 | DM1-1 | 20 | 54000 |
| 26 | Compound 26 | DM1-1 | 20 | 54000 |
| 27 | Compound 27 | DM1-1 | 20 | 59000 |
| 28 | Compound 28 | DM1-1 | 20 | 59000 |
| 29 | Compound 29 | DM1-1 | 20 | 59000 |
| 30 | Compound 30 | DM1-1 | 20 | 59000 |
| 31 | Compound 31 | DM1-1 | 20 | 59000 |
| 32 | Compound 32 | DM1-1 | 20 | 59000 |
| 33 | Compound 33 | DM1-1 | 20 | 59000 |
| 34 | Compound 34 | DM1-1 | 20 | 59000 |
| 35 | Compound 35 | DM1-1 | 20 | 59000 |
| 36 | Compound 36 | DM1-1 | 20 | 59000 |
| 37 | Compound 45 | DM1-1 | 20 | 47000 |
| 38 | Compound 46 | DM1-1 | 20 | 47000 |
| 39 | Compound 47 | DM1-1 | 20 | 49000 |
| 40 | Compound 48 | DM1-1 | 20 | 47000 |

TABLE 2

| | | | Luminous | Half |
|---|---|---|---|---|
| | Host | Dopant | efficiency | life |
| Examples | material | material | [cd/A] | [hr] |
| 41 | Compound 49 | DM1-1 | 20 | 49000 |
| 42 | Compound 50 | DM1-1 | 20 | 47000 |
| 43 | Compound 51 | DM1-1 | 20 | 49000 |
| 44 | Compound 52 | DM1-1 | 20 | 47000 |
| 45 | Compound 1 | DM2-1 | 21 | 49000 |
| 46 | Compound 2 | DM2-1 | 21 | 49000 |
| 47 | Compound 3 | DM2-1 | 21 | 49000 |
| 48 | Compound 4 | DM2-1 | 21 | 47000 |
| 49 | Compound 5 | DM2-1 | 21 | 47000 |
| 50 | Compound 6 | DM2-1 | 21 | 47000 |
| 51 | Compound 7 | DM2-1 | 21 | 54000 |
| 52 | Compound 8 | DM2-1 | 21 | 54000 |
| 53 | Compound 9 | DM2-1 | 21 | 54000 |
| 54 | Compound 10 | DM2-1 | 21 | 54000 |
| 55 | Compound 11 | DM2-1 | 21 | 54000 |
| 56 | Compound 12 | DM2-1 | 21 | 54000 |
| 57 | Compound 13 | DM2-1 | 21 | 54000 |
| 58 | Compound 14 | DM2-1 | 21 | 54000 |
| 59 | Compound 15 | DM2-1 | 21 | 54000 |
| 60 | Compound 16 | DM2-1 | 21 | 54000 |
| 61 | Compound 17 | DM2-1 | 21 | 54000 |
| 62 | Compound 18 | DM2-1 | 21 | 54000 |
| 63 | Compound 19 | DM2-1 | 21 | 54000 |
| 64 | Compound 20 | DM2-1 | 21 | 54000 |
| 65 | Compound 21 | DM2-1 | 21 | 54000 |
| 66 | Compound 22 | DM2-1 | 21 | 54000 |
| 67 | Compound 23 | DM2-1 | 21 | 54000 |
| 68 | Compound 24 | DM2-1 | 21 | 54000 |
| 69 | Compound 25 | DM2-1 | 21 | 54000 |
| 70 | Compound 26 | DM2-1 | 21 | 54000 |
| 71 | Compound 27 | DM2-1 | 21 | 59000 |
| 72 | Compound 28 | DM2-1 | 21 | 59000 |
| 73 | Compound 29 | DM2-1 | 21 | 59000 |
| 74 | Compound 30 | DM2-1 | 21 | 59000 |
| 75 | Compound 31 | DM2-1 | 21 | 59000 |
| 76 | Compound 32 | DM2-1 | 21 | 59000 |
| 77 | Compound 33 | DM2-1 | 21 | 59000 |
| 78 | Compound 34 | DM2-1 | 21 | 59000 |
| 79 | Compound 35 | DM2-1 | 21 | 59000 |
| 80 | Compound 36 | DM2-1 | 21 | 59000 |

TABLE 3

| | | | Luminous | Half |
|---|---|---|---|---|
| | Host | Dopant | efficiency | life |
| Examples | material | material | [cd/A] | [hr] |
| 81 | Compound 45 | DM2-1 | 21 | 47000 |
| 82 | Compound 46 | DM2-1 | 21 | 47000 |
| 83 | Compound 47 | DM2-1 | 21 | 49000 |
| 84 | Compound 48 | DM2-1 | 21 | 47000 |
| 85 | Compound 49 | DM2-1 | 21 | 49000 |
| 86 | Compound 50 | DM2-1 | 21 | 47000 |
| 87 | Compound 51 | DM2-1 | 21 | 49000 |
| 88 | Compound 52 | DM2-1 | 21 | 47000 |
| 89 | Compound 1 | DM3-8 | 21 | 49000 |
| 90 | Compound 2 | DM3-8 | 21 | 49000 |
| 91 | Compound 3 | DM3-8 | 21 | 49000 |
| 92 | Compound 4 | DM3-8 | 21 | 47000 |
| 93 | Compound 5 | DM3-8 | 21 | 47000 |
| 94 | Compound 6 | DM3-8 | 21 | 47000 |
| 95 | Compound 7 | DM3-8 | 21 | 54000 |
| 96 | Compound 8 | DM3-8 | 21 | 54000 |
| 97 | Compound 9 | DM3-8 | 21 | 54000 |
| 98 | Compound 10 | DM3-8 | 21 | 54000 |
| 99 | Compound 11 | DM3-8 | 21 | 54000 |
| 100 | Compound 12 | DM3-8 | 21 | 54000 |
| 101 | Compound 13 | DM3-8 | 21 | 54000 |
| 102 | Compound 14 | DM3-8 | 21 | 54000 |
| 103 | Compound 15 | DM3-8 | 21 | 54000 |
| 104 | Compound 16 | DM3-8 | 21 | 54000 |
| 105 | Compound 17 | DM3-8 | 21 | 54000 |
| 106 | Compound 18 | DM3-8 | 21 | 54000 |
| 107 | Compound 19 | DM3-8 | 21 | 54000 |
| 108 | Compound 20 | DM3-8 | 21 | 54000 |
| 109 | Compound 21 | DM3-8 | 21 | 54000 |
| 110 | Compound 22 | DM3-8 | 21 | 54000 |
| 111 | Compound 23 | DM3-8 | 21 | 54000 |
| 112 | Compound 24 | DM3-8 | 21 | 54000 |
| 113 | Compound 25 | DM3-8 | 21 | 54000 |
| 114 | Compound 26 | DM3-8 | 21 | 54000 |
| 115 | Compound 27 | DM3-8 | 21 | 59000 |
| 116 | Compound 28 | DM3-8 | 21 | 59000 |
| 117 | Compound 29 | DM3-8 | 21 | 59000 |
| 118 | Compound 30 | DM3-8 | 21 | 59000 |
| 119 | Compound 31 | DM3-8 | 21 | 59000 |
| 120 | Compound 32 | DM3-8 | 21 | 59000 |

TABLE 4

| | | | Luminous | Half |
|---|---|---|---|---|
| | Host | Dopant | efficiency | life |
| Examples | material | material | [cd/A] | [hr] |
| 121 | Compound 33 | DM3-8 | 21 | 59000 |
| 122 | Compound 34 | DM3-8 | 21 | 59000 |
| 123 | Compound 35 | DM3-8 | 21 | 59000 |
| 124 | Compound 36 | DM3-8 | 21 | 59000 |
| 125 | Compound 45 | DM3-8 | 21 | 47000 |
| 126 | Compound 46 | DM3-8 | 21 | 47000 |
| 127 | Compound 47 | DM3-8 | 21 | 49000 |
| 128 | Compound 48 | DM3-8 | 21 | 47000 |
| 129 | Compound 49 | DM3-8 | 21 | 49000 |
| 130 | Compound 50 | DM3-8 | 21 | 47000 |
| 131 | Compound 51 | DM3-8 | 21 | 49000 |
| 132 | Compound 52 | DM3-8 | 21 | 47000 |
| 133 | Compound 1 | DM2-4 | 22 | 50000 |
| 134 | Compound 2 | DM2-4 | 22 | 50000 |
| 135 | Compound 3 | DM2-4 | 22 | 50000 |
| 136 | Compound 4 | DM2-4 | 22 | 48000 |
| 137 | Compound 5 | DM2-4 | 22 | 48000 |
| 138 | Compound 6 | DM2-4 | 22 | 48000 |
| 139 | Compound 7 | DM2-4 | 22 | 55000 |
| 140 | Compound 8 | DM2-4 | 22 | 55000 |
| 141 | Compound 9 | DM2-4 | 22 | 55000 |
| 142 | Compound 10 | DM2-4 | 22 | 55000 |
| 143 | Compound 11 | DM2-4 | 22 | 55000 |
| 144 | Compound 12 | DM2-4 | 22 | 55000 |
| 145 | Compound 13 | DM2-4 | 22 | 55000 |
| 146 | Compound 14 | DM2-4 | 22 | 55000 |
| 147 | Compound 15 | DM2-4 | 22 | 55000 |
| 148 | Compound 16 | DM2-4 | 22 | 55000 |
| 149 | Compound 17 | DM2-4 | 22 | 55000 |
| 150 | Compound 18 | DM2-4 | 22 | 55000 |
| 151 | Compound 19 | DM2-4 | 22 | 55000 |
| 152 | Compound 20 | DM2-4 | 22 | 55000 |
| 153 | Compound 21 | DM2-4 | 22 | 55000 |
| 154 | Compound 22 | DM2-4 | 22 | 55000 |
| 155 | Compound 23 | DM2-4 | 22 | 55000 |
| 156 | Compound 24 | DM2-4 | 22 | 55000 |
| 157 | Compound 25 | DM2-4 | 22 | 55000 |
| 158 | Compound 26 | DM2-4 | 22 | 55000 |
| 159 | Compound 27 | DM2-4 | 22 | 60000 |
| 160 | Compound 28 | DM2-4 | 22 | 60000 |

TABLE 5

| | | | Luminous | Half |
|---|---|---|---|---|
| | Host | Dopant | efficiency | life |
| Examples | material | material | [cd/A] | [hr] |
| 161 | Compound 29 | DM2-4 | 22 | 60000 |
| 162 | Compound 30 | DM2-4 | 22 | 60000 |
| 163 | Compound 31 | DM2-4 | 22 | 60000 |
| 164 | Compound 32 | DM2-4 | 22 | 60000 |
| 165 | Compound 33 | DM2-4 | 22 | 60000 |
| 166 | Compound 34 | DM2-4 | 22 | 60000 |
| 167 | Compound 35 | DM2-4 | 22 | 60000 |
| 168 | Compound 36 | DM2-4 | 22 | 60000 |
| 169 | Compound 45 | DM2-4 | 22 | 48000 |
| 170 | Compound 46 | DM2-4 | 22 | 48000 |
| 171 | Compound 47 | DM2-4 | 22 | 50000 |
| 172 | Compound 48 | DM2-4 | 22 | 48000 |
| 173 | Compound 49 | DM2-4 | 22 | 50000 |
| 174 | Compound 50 | DM2-4 | 22 | 48000 |
| 175 | Compound 51 | DM2-4 | 22 | 50000 |
| 176 | Compound 52 | DM2-4 | 22 | 48000 |
| 177 | Compound 1 | DM9-1 | 22 | 50000 |
| 178 | Compound 2 | DM9-1 | 22 | 50000 |
| 179 | Compound 3 | DM9-1 | 22 | 50000 |
| 180 | Compound 4 | DM9-1 | 22 | 48000 |
| 181 | Compound 5 | DM9-1 | 22 | 48000 |
| 182 | Compound 6 | DM9-1 | 22 | 48000 |
| 183 | Compound 7 | DM9-1 | 22 | 55000 |
| 184 | Compound 8 | DM9-1 | 22 | 55000 |
| 185 | Compound 9 | DM9-1 | 22 | 55000 |
| 186 | Compound 10 | DM9-1 | 22 | 55000 |
| 187 | Compound 11 | DM9-1 | 22 | 55000 |
| 188 | Compound 12 | DM9-1 | 22 | 55000 |
| 189 | Compound 13 | DM9-1 | 22 | 55000 |
| 190 | Compound 14 | DM9-1 | 22 | 55000 |
| 191 | Compound 15 | DM9-1 | 22 | 55000 |
| 192 | Compound 16 | DM9-1 | 22 | 55000 |
| 193 | Compound 17 | DM9-1 | 22 | 55000 |
| 194 | Compound 18 | DM9-1 | 22 | 55000 |
| 195 | Compound 19 | DM9-1 | 22 | 55000 |
| 196 | Compound 20 | DM9-1 | 22 | 55000 |
| 197 | Compound 21 | DM9-1 | 22 | 55000 |
| 198 | Compound 22 | DM9-1 | 22 | 55000 |
| 199 | Compound 23 | DM9-1 | 22 | 55000 |
| 200 | Compound 24 | DM9-1 | 22 | 55000 |

TABLE 6

| | | | Luminous | Half |
|---|---|---|---|---|
| | Host | Dopant | efficiency | life |
| Examples | material | material | [cd/A] | [hr] |
| 201 | Compound 25 | DM9-1 | 22 | 55000 |
| 202 | Compound 26 | DM9-1 | 22 | 55000 |
| 203 | Compound 27 | DM9-1 | 22 | 60000 |
| 204 | Compound 28 | DM9-1 | 22 | 60000 |
| 205 | Compound 29 | DM9-1 | 22 | 60000 |
| 206 | Compound 30 | DM9-1 | 22 | 60000 |
| 207 | Compound 31 | DM9-1 | 22 | 60000 |
| 208 | Compound 32 | DM9-1 | 22 | 60000 |
| 209 | Compound 33 | DM9-1 | 22 | 60000 |
| 210 | Compound 34 | DM9-1 | 22 | 60000 |
| 211 | Compound 35 | DM9-1 | 22 | 60000 |
| 212 | Compound 36 | DM9-1 | 22 | 60000 |
| 213 | Compound 45 | DM9-1 | 22 | 48000 |
| 214 | Compound 46 | DM9-1 | 22 | 48000 |
| 215 | Compound 47 | DM9-1 | 22 | 50000 |
| 216 | Compound 48 | DM9-1 | 22 | 48000 |
| 217 | Compound 49 | DM9-1 | 22 | 50000 |
| 218 | Compound 50 | DM9-1 | 22 | 48000 |
| 219 | Compound 51 | DM9-1 | 22 | 50000 |
| 220 | Compound 52 | DM9-1 | 22 | 48000 |
| 221 | Compound 1 | DM10-1 | 23 | 51000 |
| 222 | Compound 2 | DM10-1 | 23 | 51000 |
| 223 | Compound 3 | DM10-1 | 23 | 51000 |
| 224 | Compound 4 | DM10-1 | 23 | 49000 |
| 225 | Compound 5 | DM10-1 | 23 | 49000 |
| 226 | Compound 6 | DM10-1 | 23 | 49000 |
| 227 | Compound 7 | DM10-1 | 23 | 56000 |
| 228 | Compound 8 | DM10-1 | 23 | 56000 |
| 229 | Compound 9 | DM10-1 | 23 | 56000 |
| 230 | Compound 10 | DM10-1 | 23 | 56000 |
| 231 | Compound 11 | DM10-1 | 23 | 56000 |
| 232 | Compound 12 | DM10-1 | 23 | 56000 |
| 233 | Compound 13 | DM10-1 | 23 | 56000 |
| 234 | Compound 14 | DM10-1 | 23 | 56000 |
| 235 | Compound 15 | DM10-1 | 23 | 56000 |
| 236 | Compound 16 | DM10-1 | 23 | 56000 |
| 237 | Compound 17 | DM10-1 | 23 | 56000 |
| 238 | Compound 18 | DM10-1 | 23 | 56000 |
| 239 | Compound 19 | DM10-1 | 23 | 56000 |
| 240 | Compound 20 | DM10-1 | 23 | 56000 |

TABLE 7

| | | | Luminous | Half |
|---|---|---|---|---|
| | Host | Dopant | efficiency | life |
| Examples | material | material | [cd/A] | [hr] |
| 241 | Compound 21 | DM10-1 | 23 | 56000 |
| 242 | Compound 22 | DM10-1 | 23 | 56000 |
| 243 | Compound 23 | DM10-1 | 23 | 56000 |
| 244 | Compound 24 | DM10-1 | 23 | 56000 |
| 245 | Compound 25 | DM10-1 | 23 | 56000 |
| 246 | Compound 26 | DM10-1 | 23 | 56000 |
| 247 | Compound 27 | DM10-1 | 23 | 61000 |
| 248 | Compound 28 | DM10-1 | 23 | 61000 |
| 249 | Compound 29 | DM10-1 | 23 | 61000 |
| 250 | Compound 30 | DM10-1 | 23 | 61000 |
| 251 | Compound 31 | DM10-1 | 23 | 61000 |
| 252 | Compound 32 | DM10-1 | 23 | 61000 |
| 253 | Compound 33 | DM10-1 | 23 | 61000 |
| 254 | Compound 34 | DM10-1 | 23 | 61000 |
| 255 | Compound 35 | DM10-1 | 23 | 61000 |
| 256 | Compound 36 | DM10-1 | 23 | 61000 |
| 257 | Compound 45 | DM10-1 | 23 | 49000 |
| 258 | Compound 46 | DM10-1 | 23 | 49000 |
| 259 | Compound 47 | DM10-1 | 23 | 51000 |
| 260 | Compound 48 | DM10-1 | 23 | 49000 |
| 261 | Compound 49 | DM10-1 | 23 | 51000 |
| 262 | Compound 50 | DM10-1 | 23 | 49000 |
| 263 | Compound 51 | DM10-1 | 23 | 51000 |
| 264 | Compound 52 | DM10-1 | 23 | 49000 |
| 265 | Compound 1 | DM11-8 | 23 | 51000 |
| 266 | Compound 2 | DM11-8 | 23 | 51000 |
| 267 | Compound 3 | DM11-8 | 23 | 51000 |
| 268 | Compound 4 | DM11-8 | 23 | 49000 |
| 269 | Compound 5 | DM11-8 | 23 | 49000 |
| 270 | Compound 6 | DM11-8 | 23 | 49000 |
| 271 | Compound 7 | DM11-8 | 23 | 56000 |
| 272 | Compound 8 | DM11-8 | 23 | 56000 |
| 273 | Compound 9 | DM11-8 | 23 | 56000 |
| 274 | Compound 10 | DM11-8 | 23 | 56000 |
| 275 | Compound 11 | DM11-8 | 23 | 56000 |
| 276 | Compound 12 | DM11-8 | 23 | 56000 |
| 277 | Compound 13 | DM11-8 | 23 | 56000 |
| 278 | Compound 14 | DM11-8 | 23 | 56000 |
| 279 | Compound 15 | DM11-8 | 23 | 56000 |
| 280 | Compound 16 | DM11-8 | 23 | 56000 |

TABLE 8

| | | | Luminous | Half |
|---|---|---|---|---|
| | Host | Dopant | efficiency | life |
| Examples | material | material | [cd/A] | [hr] |
| 281 | Compound 17 | DM11-8 | 23 | 56000 |
| 282 | Compound 18 | DM11-8 | 23 | 56000 |
| 283 | Compound 19 | DM11-8 | 23 | 56000 |
| 284 | Compound 20 | DM11-8 | 23 | 56000 |
| 285 | Compound 21 | DM11-8 | 23 | 56000 |
| 286 | Compound 22 | DM11-8 | 23 | 56000 |
| 287 | Compound 23 | DM11-8 | 23 | 56000 |
| 288 | Compound 24 | DM11-8 | 23 | 56000 |
| 289 | Compound 25 | DM11-8 | 23 | 56000 |
| 290 | Compound 26 | DM11-8 | 23 | 56000 |
| 291 | Compound 27 | DM11-8 | 23 | 61000 |
| 292 | Compound 28 | DM11-8 | 23 | 61000 |
| 293 | Compound 29 | DM11-8 | 23 | 61000 |
| 294 | Compound 30 | DM11-8 | 23 | 61000 |
| 295 | Compound 31 | DM11-8 | 23 | 61000 |
| 296 | Compound 32 | DM11-8 | 23 | 61000 |
| 297 | Compound 33 | DM11-8 | 23 | 61000 |
| 298 | Compound 34 | DM11-8 | 23 | 61000 |
| 299 | Compound 35 | DM11-8 | 23 | 61000 |
| 300 | Compound 36 | DM11-8 | 23 | 61000 |
| 301 | Compound 45 | DM11-8 | 23 | 49000 |
| 302 | Compound 46 | DM11-8 | 23 | 49000 |
| 303 | Compound 47 | DM11-8 | 23 | 51000 |
| 304 | Compound 48 | DM11-8 | 23 | 49000 |
| 305 | Compound 49 | DM11-8 | 23 | 51000 |
| 306 | Compound 50 | DM11-8 | 23 | 49000 |
| 307 | Compound 51 | DM11-8 | 23 | 51000 |
| 308 | Compound 52 | DM11-8 | 23 | 49000 |
| 309 | Compound 1 | DM10-4 | 24 | 52000 |
| 310 | Compound 2 | DM10-4 | 24 | 52000 |
| 311 | Compound 3 | DM10-4 | 24 | 52000 |
| 312 | Compound 4 | DM10-4 | 24 | 50000 |
| 313 | Compound 5 | DM10-4 | 24 | 50000 |
| 314 | Compound 6 | DM10-4 | 24 | 50000 |
| 315 | Compound 7 | DM10-4 | 24 | 57000 |
| 316 | Compound 8 | DM10-4 | 24 | 57000 |
| 317 | Compound 9 | DM10-4 | 24 | 57000 |
| 318 | Compound 10 | DM10-4 | 24 | 57000 |
| 319 | Compound 11 | DM10-4 | 24 | 57000 |
| 320 | Compound 12 | DM10-4 | 24 | 57000 |

TABLE 9

| | | | Luminous | Half |
|---|---|---|---|---|
| | Host | Dopant | efficiency | life |
| Examples | material | material | [cd/A] | [hr] |
| 321 | Compound 13 | DM10-4 | 24 | 57000 |
| 322 | Compound 14 | DM10-4 | 24 | 57000 |
| 323 | Compound 15 | DM10-4 | 24 | 57000 |
| 324 | Compound 16 | DM10-4 | 24 | 57000 |
| 325 | Compound 17 | DM10-4 | 24 | 57000 |
| 326 | Compound 18 | DM10-4 | 24 | 57000 |
| 327 | Compound 19 | DM10-4 | 24 | 57000 |
| 328 | Compound 20 | DM10-4 | 24 | 57000 |
| 329 | Compound 21 | DM10-4 | 24 | 57000 |
| 330 | Compound 22 | DM10-4 | 24 | 57000 |
| 331 | Compound 23 | DM10-4 | 24 | 57000 |
| 332 | Compound 24 | DM10-4 | 24 | 57000 |
| 333 | Compound 25 | DM10-4 | 24 | 57000 |
| 334 | Compound 26 | DM10-4 | 24 | 57000 |
| 335 | Compound 27 | DM10-4 | 24 | 62000 |
| 336 | Compound 28 | DM10-4 | 24 | 62000 |
| 337 | Compound 29 | DM10-4 | 24 | 62000 |
| 338 | Compound 30 | DM10-4 | 24 | 62000 |
| 339 | Compound 31 | DM10-4 | 24 | 62000 |
| 340 | Compound 32 | DM10-4 | 24 | 62000 |
| 341 | Compound 33 | DM10-4 | 24 | 62000 |
| 342 | Compound 34 | DM10-4 | 24 | 62000 |
| 343 | Compound 35 | DM10-4 | 24 | 62000 |
| 344 | Compound 36 | DM10-4 | 24 | 62000 |
| 345 | Compound 45 | DM10-4 | 24 | 50000 |
| 346 | Compound 46 | DM10-4 | 24 | 50000 |
| 347 | Compound 47 | DM10-4 | 24 | 52000 |
| 348 | Compound 48 | DM10-4 | 24 | 50000 |
| 349 | Compound 49 | DM10-4 | 24 | 52000 |
| 350 | Compound 50 | DM10-4 | 24 | 50000 |
| 351 | Compound 51 | DM10-4 | 24 | 52000 |
| 352 | Compound 52 | DM10-4 | 24 | 50000 |
| Com. Ex. 1 | H-1 | DM2-4 | 18 | 28000 |
| Com. Ex. 2 | H-1 | DM10-4 | 18 | 30000 |
| Com. Ex. 3 | H-2 | D-1 | 18 | 25000 |
| Com. Ex. 4 | H-3 | D-2 | 4 | 5000 |
| Com. Ex. 5 | H-4 | D-2 | 6.8 | 10000 |

### Example 353

A glass substrate of 25 mm by 75 mm by 1.1 mm thick with an ITO transparent electrode (anode) (GEOMATEC CO., LTD.) was subjected to ultrasonic cleaning with isopropyl alcohol for 5 minutes, and cleaned with ultraviolet rays and ozone for 30 minutes. The cleaned glass substrate with transparent electrode lines was mounted in a substrate holder of a vacuum vapor deposition apparatus. First, a 65 nm-thick film formed of compound A-3 was formed on the surface where the transparent electrode lines were formed so as to cover the transparent electrode. Subsequent to forming of the A-3 film, a 65 nm-thick film formed of compound A-2 was formed on the A-3 film. Subsequently, on the A-2 film, the host material compound 1 and the dopant material DM2-1 of the invention were formed into a 20 nm-thick film in a ratio by weight of 19:1. This film functioned as a green emitting layer.

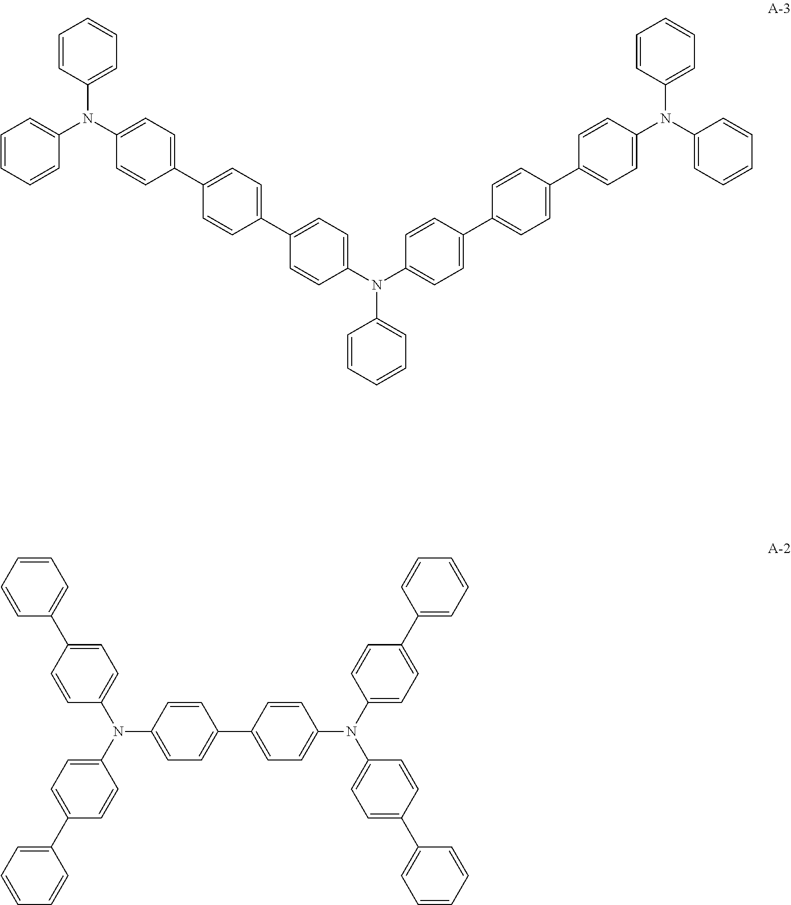

On this layer, as the electron-transporting layer, ET-2 having the following structure was formed into a 40 nm-thick film by deposition. On this film, LiF was formed into a 1 nm-thick film. Then, metal Al was deposited on the LiF film in a 150 nm thickness to form a metal cathode, whereby an organic EL device was fabricated.

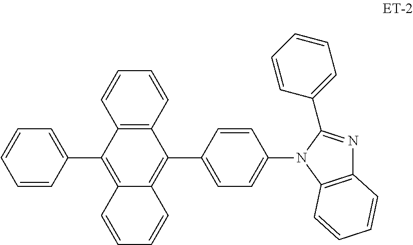

### Examples 354 to 408, Comparative Examples 6 to 8

An organic EL device was fabricated in the same manner as in Example 353, except that host materials and dopant materials shown in Table 10 were used instead of the host material compound 1 and the dopant material DM2-1.

Tables 10 and 11 show luminous efficiency, emission wavelength and the half life at an initial luminous of 1000 cd/m² for the organic EL device obtained in Examples 353 to 408 and Comparative Examples 6 to 8.

TABLE 10

| | | | Luminous | Emission | Half |
|---|---|---|---|---|---|
| | | | efficiency | wavelength | life |
| Examples | Host | Dopant | (cd/A) | (nm) | (hr) |
| 353 | Compound 1 | DM2-1 | 35 | 504 | 80000 |
| 354 | Compound 3 | DM2-1 | 33 | 504 | 90000 |
| 355 | Compound 47 | DM2-1 | 35 | 504 | 75000 |
| 356 | Compound 48 | DM2-1 | 35 | 504 | 70000 |
| 357 | Compound 53 | DM2-1 | 34 | 504 | 78000 |
| 358 | Compound 54 | DM2-1 | 35 | 504 | 76000 |
| 359 | Compound 55 | DM2-1 | 34 | 504 | 80000 |
| 360 | Compound 56 | DM2-1 | 35 | 504 | 78000 |
| 361 | Compound 1 | DM10-1 | 37 | 515 | 85000 |
| 362 | Compound 3 | DM10-1 | 35 | 515 | 95000 |
| 363 | Compound 47 | DM10-1 | 37 | 515 | 80000 |
| 364 | Compound 48 | DM10-1 | 37 | 515 | 75000 |
| 365 | Compound 53 | DM10-1 | 36 | 515 | 83000 |
| 366 | Compound 54 | DM10-1 | 37 | 515 | 81000 |
| 367 | Compound 55 | DM10-1 | 36 | 515 | 85000 |
| 368 | Compound 56 | DM10-1 | 37 | 515 | 83000 |
| 369 | Compound 1 | DM10-4 | 38 | 519 | 90000 |
| 370 | Compound 3 | DM10-4 | 36 | 519 | 100000 |
| 371 | Compound 47 | DM10-4 | 38 | 519 | 85000 |
| 372 | Compound 48 | DM10-4 | 38 | 519 | 80000 |
| 373 | Compound 53 | DM10-4 | 37 | 519 | 88000 |
| 374 | Compound 54 | DM10-4 | 38 | 519 | 86000 |
| 375 | Compound 55 | DM10-4 | 37 | 519 | 90000 |
| 376 | Compound 56 | DM10-4 | 38 | 519 | 88000 |
| 377 | Compound 1 | DM17-1 | 39 | 523 | 90000 |
| 378 | Compound 3 | DM17-1 | 37 | 523 | 100000 |
| 379 | Compound 47 | DM17-1 | 39 | 523 | 85000 |
| 380 | Compound 48 | DM17-1 | 39 | 523 | 80000 |
| 381 | Compound 53 | DM17-1 | 38 | 523 | 88000 |
| 382 | Compound 54 | DM17-1 | 39 | 523 | 86000 |
| 383 | Compound 55 | DM17-1 | 38 | 523 | 90000 |
| 384 | Compound 56 | DM17-1 | 39 | 523 | 88000 |

TABLE 11

| | | | Luminous | Emission | Half |
|---|---|---|---|---|---|
| | | | efficiency | wavelength | life |
| Examples | Host | Dopant | (cd/A) | (nm) | (hr) |
| 385 | Compound 1 | DM17-2 | 38 | 519 | 100000 |
| 386 | Compound 3 | DM17-2 | 36 | 519 | 110000 |
| 387 | Compound 47 | DM17-2 | 38 | 519 | 95000 |
| 388 | Compound 48 | DM17-2 | 38 | 519 | 90000 |
| 389 | Compound 53 | DM17-2 | 37 | 519 | 98000 |
| 390 | Compound 54 | DM17-2 | 38 | 519 | 96000 |
| 391 | Compound 55 | DM17-2 | 37 | 519 | 100000 |
| 392 | Compound 56 | DM17-2 | 38 | 519 | 98000 |
| 393 | Compound 1 | DM17-3 | 39 | 523 | 105000 |
| 394 | Compound 3 | DM17-3 | 37 | 523 | 90000 |
| 395 | Compound 47 | DM17-3 | 39 | 523 | 85000 |
| 396 | Compound 48 | DM17-3 | 39 | 523 | 93000 |
| 397 | Compound 53 | DM17-3 | 38 | 523 | 91000 |
| 398 | Compound 54 | DM17-3 | 39 | 523 | 95000 |
| 399 | Compound 55 | DM17-3 | 38 | 523 | 93000 |
| 400 | Compound 56 | DM17-3 | 39 | 523 | 95000 |
| 401 | Compound 1 | DM17-3 | 39 | 515 | 80000 |
| 402 | Compound 3 | DM17-3 | 37 | 515 | 90000 |
| 403 | Compound 47 | DM17-3 | 39 | 515 | 75000 |
| 404 | Compound 48 | DM17-3 | 39 | 515 | 70000 |
| 405 | Compound 53 | DM17-3 | 38 | 515 | 78000 |
| 406 | Compound 54 | DM17-3 | 39 | 515 | 76000 |
| 407 | Compound 55 | DM17-3 | 38 | 515 | 80000 |
| 408 | Compound 56 | DM17-3 | 39 | 515 | 78000 |
| Com. Ex. 6 | H-2 | D-1 | 30 | 528 | 10000 |
| Com. Ex. 7 | H-3 | DM2-1 | 30 | 504 | 40000 |
| Com. Ex. 8 | Compound 1 | D-1 | 33 | 528 | 15000 |

The combination of anthracene derivative and diaminopyrene derivative of the invention has a higher efficiency and much longer life time than the known combination.

In particular, referring to host materials, it is clear that the devices using 3-substituted anthracene derivative of the invention have significantly higher efficiency and longer life time than those using H-1, 1-1-2 and H-3. The possible reason therefore is as below. The emission wavelength of the host itself is shifted to the side of long wavelength by changing the number of substituents of the anthracene from 2 to 3, whereby energy transfer easily occurs between the host and the green dopant. In addition, changing the number of substituents of the anthracene from 2 to 3 reduces the energy gap of the host material slightly. As a result, an amount of energy which is applied to the material when applying current is decreased, which leads to a longer life time.

On the other hand, devices using diaminopyrene derivatives as a dopant material have much longer life time than those using the known diaminoanthracene derivatives. Although diaminopyrene derivatives tend to have a shorter wavelength as compared to the emission wavelength required for applications such as television, introduction of a fluorenyl group seen as in DM17-1 and DM17-3 can achieve the shift to the side of longer wavelength.

### INDUSTRIAL APPLICABILITY

The organic EL device using the organic light-emitting medium of the invention is useful as a light source such as a planar emitting body of a wall-hanging television and backlight of a display.

The documents described in the specification are incorporated herein by reference in its entirety.

1. An organic light-emitting medium comprising a diaminopyrene derivative represented by the following formula (1) and an anthracene derivative represented by the following formula (2): 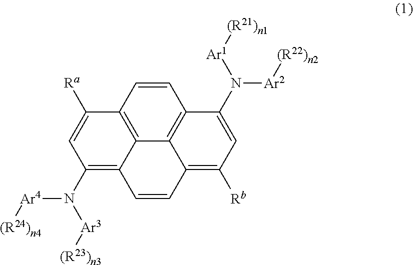
wherein Ar¹ to Ar⁴ are independently a substituted or unsubstituted aryl group having 5 to 50 ring carbon atoms or a substituted or unsubstituted heterocyclic group having 5 to 50 ring carbon atoms,
R²¹ to R²⁴ are independently a hydrogen atom, a substituted or unsubstituted alkyl group having 1 to 50 carbon atoms, a substituted or unsubstituted aryl group having 5 to 50 ring carbon atoms, a substituted or unsubstituted aralkyl group having 6 to 50 ring carbon atoms, a substituted or unsubstituted cycloalkyl group having 3 to 50 ring carbon atoms, a substituted or unsubstituted alkoxy group having 1 to 50 carbon atoms, a substituted or unsubstituted aryloxy group having 5 to 50 carbon atoms, a substituted or unsubstituted arylamino group having 5 to 50 ring carbon atoms, a substituted or unsubstituted alkylamino group having 1 to 20 carbon atoms, a substituted or unsubstituted heterocyclic group having 5 to 50 ring carbon atoms, a substituted or unsubstituted silyl group, a cyano group or a halogen atom,
n1 to n4 are independently an integer of 0 to 5,
when n1 to n4 each are 2 or more, R²¹s to R²⁴s each may be the same or different and may combine with each other to form a saturated or unsaturated ring, and
R^{a} and R^{b} are independently a substituted or unsubstituted aryl group having 5 to 50 ring carbon atoms or a substituted or unsubstituted heterocyclic group having 5 to 50 ring carbon atoms; 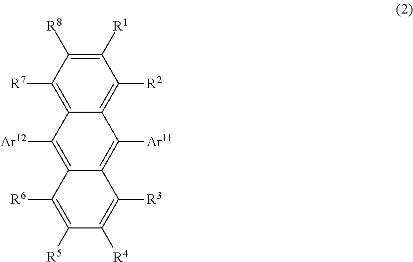
wherein Ar¹¹ and Ar¹² are independently a substituted or unsubstituted aryl group having 6 to 50 ring carbon atoms or a heterocyclic group having 5 to 50 ring atoms,
any one of R¹ to R⁸ is a substituted or unsubstituted aryl group having 6 to 50 ring carbon atoms or a substituted or unsubstituted heterocyclic group having 5 to 50 ring carbon atoms,
R¹ to R⁸ that are not a substituted or unsubstituted aryl group having 6 to 50 ring carbon atoms and a substituted or unsubstituted heterocyclic group having 5 to 50 ring atoms are independently a group selected from a hydrogen atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted silyl group, a carboxy group, a halogen atom, a cyano group, a nitro group and a hydroxyl group.

2. The organic light-emitting medium according to claim 1, wherein any one of R¹, R², R⁷ and R⁸ in the formula (2) is a substituted or unsubstituted aryl group having 6 to 50 ring carbon atoms or a substituted or unsubstituted heterocyclic group having 5 to 50 ring atoms.

3. The organic light-emitting medium according to claim 2, wherein one of R¹ and R⁸ in the formula (2) is a substituted or unsubstituted aryl group having 6 to 50 ring carbon atoms or a substituted or unsubstituted heterocyclic group having 5 to 50 ring atoms, and the other is a hydrogen atom.

4. The organic light-emitting medium according to claim 2, wherein any one of R¹, R², R⁷ and R⁸ in the formula (2) is a substituted or unsubstituted aryl group having 6 to 50 ring carbon atoms.

5. The organic light-emitting medium according to claim 4, wherein one of R¹ and R⁸ in the formula (2) is a substituted or unsubstituted aryl group having 6 to 50 ring carbon atoms, and the other is a hydrogen atom.

6. The organic light-emitting medium according to claim 5, wherein the substituted or unsubstituted aryl group having 6 to 50 ring carbon atoms is a substituted or unsubstituted phenyl group, naphthyl group, fluorenyl group or phenanthryl group.

7. The organic light-emitting medium according to claim 1, wherein Ar¹¹ in the formula (2) is a substituted or unsubstituted heterocyclic group having 5 to 50 ring atoms.

8. The organic light-emitting medium according to claim 1, wherein Ar¹¹ and Ar¹¹ in the formula (2) are independently a substituted or unsubstituted fused aryl group having 10 to 50 ring carbon atoms.

9. The organic light-emitting medium according to claim 8, wherein Ar¹¹ and Ar¹² in the formula (2) are the same groups.

10. The organic light-emitting medium according to claim 9, wherein Ar¹¹ and Ar¹² in the formula (2) are a substituted or unsubstituted 9-phenanthrenyl group.

11. The organic light-emitting medium according to claim 9, wherein Ar¹¹ and Ar¹² in the formula (2) are a substituted or unsubstituted 2-naphthyl group.

12. The organic light-emitting medium according to claim 9, wherein Ar¹¹ and Ar¹² in the formula (2) are a substituted or unsubstituted 1-naphthyl group.

13. The organic light-emitting medium according to claim 8, wherein Ar¹¹ and Ar¹² in the formula (2) are different groups.

14. The organic light-emitting medium according to claim 1, wherein Ar¹¹ and Ar¹² in the formula (2) are independently a substituted or unsubstituted phenyl group.

15. The organic light-emitting medium according to claim 14, wherein Ar¹¹ and Ar¹² in the formula (2) are independently a substituted or unsubstituted aryl group having 6 to 30 ring carbon atoms or a phenyl group substituted with a substituted or unsubstituted heterocyclic group having 5 to 30 ring atoms.

16. The organic light-emitting medium according to claim 13, wherein Ar¹¹ and Ar¹² in the formula (2) are independently a substituted or unsubstituted 9-phenanthrenyl group, a substituted or unsubstituted 1-naphthyl group, a substituted or unsubstituted 2-naphthyl group, a substituted or unsubstituted fluoranthenyl group, or a substituted or unsubstituted pyrenyl group.

17. The organic light-emitting medium according to claim 13, wherein one of Ar¹¹ and Ar¹² in the formula (2) is a substituted or unsubstituted phenyl group, and the other is a substituted or unsubstituted fused aryl group having 10 to 50 ring carbon atoms.

18. The organic light-emitting medium according to claim 17, wherein the substituted or unsubstituted fused aryl group having 10 to 50 ring carbon atoms is a substituted or unsubstituted 1-naphthyl group.

19. The organic light-emitting medium according to claim 17, wherein the substituted or unsubstituted fused aryl group having 10 to 50 ring carbon atoms is a substituted or unsubstituted 2-naphthyl group.

20. The organic light-emitting medium according to claim 17, wherein the substituted or unsubstituted fused aryl group having 10 to 50 ring carbon atoms is a substituted or unsubstituted fluoranthenyl group.

21. The organic light-emitting medium according to claim 17, wherein the substituted or unsubstituted fused aryl group having 10 to 50 ring carbon atoms is a substituted or unsubstituted pyrenyl group.

22. The organic light-emitting medium according to claim 1, wherein R^{a} and R^{b} in the formula (1) are independently is a substituted or unsubstituted phenyl group, a substituted or unsubstituted naphthyl group, or a substituted or unsubstituted fluorenyl group.

23. The organic light-emitting medium according to claim 1, wherein Ar¹ to Ar⁴ in the formula (1) are independently a group selected from a substituted or unsubstituted phenyl group, a substituted or unsubstituted naphthyl group, a substituted or unsubstituted fluorenyl group and a substituted or unsubstituted dibenzofuranyl group.

24. The organic light-emitting medium according to claim 23, wherein at least one of Ar¹ to Ar⁴ in the formula (1) is a substituted or unsubstituted fluorenyl group.

25. The organic light-emitting medium according to claim 1, wherein R²¹ to R²⁴ in the formula (1) are independently a substituted or unsubstituted phenyl group, a substituted or unsubstituted methyl group, a substituted or unsubstituted ethyl group, a substituted or unsubstituted isopropyl group, a substituted or unsubstituted t-butyl group, a substituted or unsubstituted cyclopropyl group, a substituted or unsubstituted cyclopentyl group, a substituted or unsubstituted cyclohexyl group, a substituted or unsubstituted trimethylsilyl group, or a cyano group.

26. An organic electroluminescence device comprising:
an anode, a cathode, and
one or more organic thin film layers between the anode and the cathode,
wherein at least one of the organic thin film layers comprises the organic light-emitting medium according to claim 1.

27. The organic electroluminescence device according to claim 26, wherein the organic thin film layer comprising the organic light-emitting medium is an emitting layer.
